(19) United States
(12) Patent Application Publication
(10) Pub. No.: US 2015/0118628 A1
(43) Pub. Date: Apr. 30, 2015

(54) ACTINIC-RAY- OR RADIATION-SENSITIVE RESIN COMPOSITION, ACTINIC-RAY- OR RADIATION-SENSITIVE FILM THEREFROM, METHOD OF FORMING PATTERN, PROCESS FOR MANUFACTURING SEMICONDUCTOR DEVICE, AND SEMICONDUCTOR DEVICE

(71) Applicant: FUJIFILM Corporation, Tokyo (JP)

(72) Inventors: Takeshi KAWABATA, Shizuoka (JP); Hideaki TSUBAKI, Shizuoka (JP); Hiroo TAKIZAWA, Shizuoka (JP); Natsumi YOKOKAWA, Shizuoka (JP)

(73) Assignee: FUJIFILM CORPORATION, Tokyo (JP)

(21) Appl. No.: 14/581,484

(22) Filed: Dec. 23, 2014

Related U.S. Application Data
(63) Continuation of application No. PCT/JP2013/068316, filed on Jun. 27, 2013.

(30) Foreign Application Priority Data
Jun. 27, 2012 (JP) 2012-144755
May 28, 2013 (JP) 2013-112307

(51) Int. Cl. G03F 7/20; C08F 28/02; C08F 14/18

(52) U.S. Cl. CPC G03F 7/20; C08F 14/185; C08F 28/02
USPC 430/325; 526/243; 526/287

(57) ABSTRACT

Provided is an actinic-ray- or radiation-sensitive resin composition including a resin (P) comprising any of repeating units (A) of general formula (I) below, each of which contains an ionic structural moiety that when exposed to actinic rays or radiation, is decomposed to thereby generate an acid in a side chain of the resin.

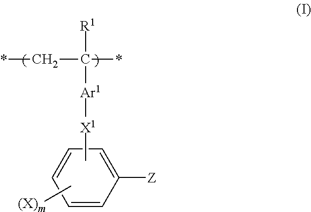

### CROSS-REFERENCE TO RELATED APPLICATIONS

This application is a Continuation Application of PCT Application No. PCT/JP2013/068316, filed Jun. 27, 2013 and based upon and claiming the benefit of priority from Japanese Patent Applications No. 2012-144755, filed Jun. 27, 2012; and No. 2013-112307, filed May 28, 2013, the entire contents of all of which are incorporated herein by reference.

### FIELD

The present invention relates to an actinic-ray- or radiation-sensitive resin composition that can find appropriate application in an ultramicrolithography process applicable to the manufacturing of a super-LSI or a high-capacity microchip, etc. and other photofabrication processes, and further relates to an actinic-ray- or radiation-sensitive film from the composition, a method of forming a pattern, a process for manufacturing a semiconductor device and a semiconductor device.

### BACKGROUND

Heretofore, the microfabrication by lithography using a photoresist composition is performed in the process for manufacturing semiconductor devices, such as an IC and an LSI. In recent years, the formation of an ultrafine pattern in the submicron region or quarter-micron region is increasingly required in accordance with the realization of high integration for integrated circuits. Accordingly, the trend of exposure wavelength toward a short wavelength, for example, from g-rays to i-rays and further to a KrF excimer laser light is seen. Further, now, the development of lithography using electron beams, X-rays or EUV light, aside from the excimer laser light, is being promoted.

In particular, the lithography comprising exposure to electron beams is positioned as the next-generation or next-next-generation pattern forming technology. Positive resists of high sensitivity and high resolution are required for this lithography. Specifically, increasing the sensitivity is a very important task to be attained for the shortening of wafer processing time. However, with respect to the positive resist exposed to electron beams, the pursuit of increasing the sensitivity is likely to cause not only the lowering of resolving power but also the deterioration of line edge roughness. Thus, there is a strong demand for the development of resists that can simultaneously satisfy these performances. Herein, the line edge roughness refers to the phenomenon that the edge at an interface of resist pattern and substrate is irregularly varied in the direction perpendicular to the line direction due to the characteristics of the resist, so that when the pattern is viewed from directly above, the pattern edge is observed uneven. This unevenness is transferred in the etching operation using the resist as a mask to thereby cause poor electrical properties resulting in poor yield. Especially in the ultrafine region of 0.25 μm or less line width, the line edge roughness is now an extremely important theme in which improvement is to be attained. High sensitivity is in a relationship of trade-off with high resolution, favorable pattern shape and favorable line edge roughness. How to simultaneously satisfy these is a critical issue.

In the lithography using X-rays or EUV light as well, it is now an important task to satisfy not only high sensitivity but also high resolution, favorable pattern shape and favorable line edge roughness. Attaining this task is required.

Moreover, when EUV light is used as a light source, as the light has a wavelength lying in the extreme ultraviolet region and hence has a high energy, the compounds in the resist film are likely to be broken into fragments differently from the use of conventional light sources. The fragments are likely to vaporize as low-molecular components during the exposure, thereby dirtying the environment within the exposure apparatus. This outgassing problem is serious in the use of EUV light as a light source.

As a means for solving these problems, using a resin comprising an acid generator in its polymer principal chain or side chain is being studied (see, for example, patent references 1 to 10).

The problems, such as unsatisfactory miscibility of an acid generator with a resin, diffusion of an acid generated from an acid generator upon exposure into an unintended area (for example, unexposed area), etc. resulting in poor resolution, tend to be alleviated by the incorporation of an acid generating moiety corresponding to an acid generator in a resin as in the technologies disclosed in patent references 1 to 10. Moreover, as no low-molecular acid generator is present, the outgassing attributed to low-molecular components tends to be lessened even when the exposure is performed using, for example, EUV light. However, with respect to these technologies, there is room for further improvement in especially the sensitivity to electron beams, X-rays and EUV light.

In particular, in the lithography using electron beams, X-rays or EUV light, the current situation is that not only is further improvement required in resolution and outgassing performance but also enhanced performances are required in sensitivity, line edge roughness, exposure latitude (EL) and pattern shape.

### CITATION LIST

### Patent Literature

Patent reference 1: Jpn. Pat. Appln. KOKAI Publication No. (hereinafter referred to as JP-A-) H9-325497,

Patent reference 2: JP-A-H10-221852,

Patent reference 3: JP-A-2006-178317,

Patent reference 4: JP-A-2007-197718,

Patent reference 5: International Publication No. 06/121096 (pamphlet),

Patent reference 6: U.S. Patent Application Publication No. 2006/121390,

Patent reference 7: International Publication No. 08/056796 (pamphlet),

Patent reference 8: JP-A-2010-250290,

Patent reference 9: JP-A-2011-53364, and

Patent reference 10: U.S. Patent Application Publication No. 2007/117043.

### DETAILED DESCRIPTION

It is an object of the present invention to provide an actinic-ray- or radiation-sensitive resin composition that not only can simultaneously satisfy high sensitivity, high resolution, favorable pattern shape, favorable line edge roughness and favorable exposure latitude (EL) at high levels but also can realize satisfactorily favorable outgassing performance during exposure.

It is another object of the present invention to provide an actinic-ray- or radiation-sensitive film from the composition. It is a further object of the present invention to provide a method of forming a pattern, a process for manufacturing a semiconductor device and a semiconductor device.

Some aspects according to the present invention are as follows.

[1] An actinic-ray- or radiation-sensitive resin composition comprising a resin (P) comprising any of repeating units (A) of general formula (I) below, each of which contains an ionic structural moiety that when exposed to actinic rays or radiation, is decomposed to thereby generate an acid in a side chain of the resin,

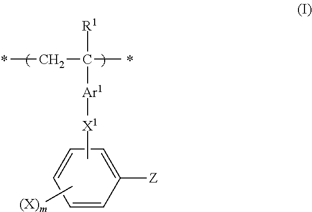

in which

R¹ represents a hydrogen atom, an alkyl group, a monovalent aliphatic hydrocarbon ring group, a halogen atom, a cyano group or an alkoxycarbonyl group;

Ar¹ represents a bivalent aromatic ring group;

X¹ represents a single bond, —O—, —S—, —C(═O)—, —S(═O)—, —S(═O)₂— or an optionally substituted methylene group;

X represents a substituent;

m is an integer of 0 to 4; and

Z represents a moiety that when exposed to actinic rays or radiation, is decomposed to thereby become a sulfonic acid group, an imidic acid group or a methide acid group.

[2] The actinic-ray- or radiation-sensitive resin composition according to item [1], wherein in general formula (I), m is an integer of 1 to 4, and at least one substituent represented by X is an F atom or a fluoroalkyl group.

[3] The actinic-ray- or radiation-sensitive resin composition according to item [1] or [2], wherein in general formula (I), X¹ is —O—.

[4] The actinic-ray- or radiation-sensitive resin composition according to any of items [1] to [3], wherein the resin (P) further comprises a repeating unit (B) containing a group that when acted on by an acid, is decomposed to thereby produce a polar group.

[5] The actinic-ray- or radiation-sensitive resin composition according to item [4], wherein the resin (P) comprises at least any of repeating units of general formula (II) below as the repeating unit (B),

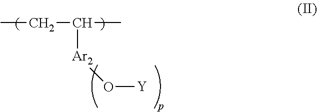

in which

Ar² represents a (p+1)-valent aromatic ring group;

Y represents a hydrogen atom or a group leaving when acted on by an acid, provided that when there are a plurality of Y's, the plurality of Y's may be identical to or different from each other, and that at least one Y is a group leaving when acted on by an acid; and

p is an integer of 1 or greater.

[6] The actinic-ray- or radiation-sensitive resin composition according to item [5], wherein in general formula (II), at least one group leaving when acted on by an acid, represented by Y is any of groups of general formula (V) below,

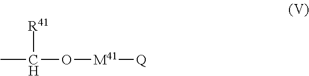

in which

R⁴¹ represents a hydrogen atom, an alkyl group, a cycloalkyl group, an aryl group or an aralkyl group;

M⁴¹ represents a single bond or a bivalent connecting group; and

Q represents an alkyl group, an alicyclic group optionally containing a heteroatom, or an aromatic ring group optionally containing a heteroatom,

provided that at least two of R⁴¹, M⁴¹ and Q may be bonded to each other to thereby form a ring.

[7] The actinic-ray- or radiation-sensitive resin composition according to any of items [4] to [6], wherein the resin (P) comprises at least any of repeating units of general formula (VI) below as the repeating unit (B),

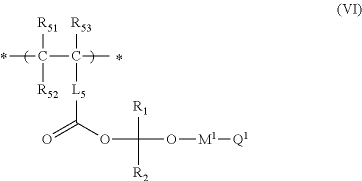

in which

each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group,

L₅ represents a single bond or a bivalent connecting group, provided that when a ring is formed in cooperation with R₅₂, L₅ represents a trivalent connecting group,

R₁ represents a hydrogen atom or an alkyl group,

R₂ represents a hydrogen atom, an alkyl group, a cycloalkyl group, an aryl group, an aralkyl group, an alkoxy group, an acyl group or a heterocyclic group,

M¹ represents a single bond or a bivalent connecting group, and

Q¹ represents an alkyl group, a cycloalkyl group, an aryl group or a heterocyclic group,

provided that at least two of Q¹, M¹ and R₂ may be bonded to each other through a single bond or a connecting group to thereby form a ring.

[8] The actinic-ray- or radiation-sensitive resin composition according to any of items [1] to [7] to be exposed to electron beams, X-rays or soft X-rays.

[9] An actinic-ray- or radiation-sensitive film formed from the actinic-ray- or radiation-sensitive resin composition according to any of items [1] to [8].

[10] A method of forming a pattern, comprising exposing the actinic-ray- or radiation-sensitive film according to item [9] to actinic rays or radiation and developing the exposed film.

[11] The method according to item [10], wherein the development is performed with a developer comprising an organic solvent to thereby form a negative pattern.

[12] The method according to item [10] or [11], wherein the exposure is performed by use of electron beams, X-rays or soft X-rays.

[13] A process for manufacturing a semiconductor device, comprising the method according to any of items [10] to [12].

[14] A semiconductor device manufactured by the process according to item [13].

The present invention has made it feasible to provide an actinic-ray- or radiation-sensitive resin composition that not only can simultaneously satisfy high sensitivity, high resolution, favorable pattern shape, favorable line edge roughness and favorable exposure latitude (EL) at high levels but also can realize satisfactorily favorable outgassing performance during exposure. Further, the present invention has made it feasible to provide an actinic-ray- or radiation-sensitive film from the composition, a method of forming a pattern, a process for manufacturing a semiconductor device and a semiconductor device.

### DESCRIPTION OF EMBODIMENTS

Embodiments of the present invention will be described in detail below.

Herein, the groups and atomic groups for which no statement is made as to substitution or nonsubstitution are to be interpreted as including those containing no substituents and also those containing substituents. For example, the “alkyl groups” for which no statement is made as to substitution or nonsubstitution are to be interpreted as including not only the alkyl groups containing no substituents (unsubstituted alkyl groups) but also the alkyl groups containing substituents (substituted alkyl groups).

Further, herein, the term “actinic rays” or “radiation” means, for example, brightline spectra from a mercury lamp, far ultraviolet represented by an excimer laser, X-rays, soft X-rays such as extreme ultraviolet (EUV) light, or electron beams (EB). The term “light” means actinic rays or radiation. The term “exposure to light” unless otherwise specified means not only irradiation with light, such as light from a mercury lamp, far ultraviolet, X-rays or EUV light, but also lithography using particle beams, such as electron beams and ion beams.

The actinic-ray- or radiation-sensitive resin composition of the present invention comprises a resin (P) to be described below. When this feature is employed, not only can high sensitivity, high resolution, favorable pattern shape and favorable line edge roughness be simultaneously satisfied at high levels but also satisfactorily favorable outgassing performance during exposure can be realized. The reason therefor would be as follows. The incorporation of a repeating unit (A) that when exposed to actinic rays or radiation, is decomposed to thereby generate an acid in a side chain of the resin in the resin (P) increases the glass transition temperature of the polymer and extensively reduces the diffusion of generated acid to thereby attain enhancement of resolution. Further, the vaporization of generated acid can be suppressed thereby with the result that outgassing performance can be enhanced. As a result, it is presumed that resolution, high sensitivity, favorable pattern shape, favorable line edge roughness and outgassing performance can be simultaneously satisfied.

The actinic-ray- or radiation-sensitive resin composition of the present invention may be used in negative development (development in which exposed areas remain as a pattern while unexposed areas are removed) and also positive development (development in which exposed areas are removed while unexposed areas remain as a pattern). Namely, the actinic-ray- or radiation-sensitive resin composition of the present invention may be an actinic-ray- or radiation-sensitive resin composition for organic solvent development that is used in the development (negative development) with a developer comprising an organic solvent, and may also be an actinic-ray- or radiation-sensitive resin composition for alkali development that is used in the development (positive development) with an alkali developer. Herein, the expression “for organic solvent development” means usage in at least the operation of developing with a developer comprising an organic solvent, and the expression “for alkali development” means usage in at least the operation of developing with an alkali developer.

The actinic-ray- or radiation-sensitive resin composition of the present invention is typically a chemically amplified resist composition.

The composition of the present invention is preferably exposed to electron beams or extreme ultraviolet (namely, composition for electron beams or extreme ultraviolet).

The individual components of this composition will be described below.

[1] Resin (P)

The resin (P) comprises a repeating unit (A) containing an ionic structural moiety that when exposed to actinic rays or radiation, is decomposed to thereby generate an acid in a side chain of the resin. The resin (P) may comprise repeating units other than the repeating unit (A).

[Repeating Unit (A)]

The repeating unit (A) is a repeating unit containing an ionic structural moiety that when exposed to actinic rays or radiation, is decomposed to thereby generate an acid in a side chain of the resin.

The repeating unit (A) is expressed by general formula (I) below.

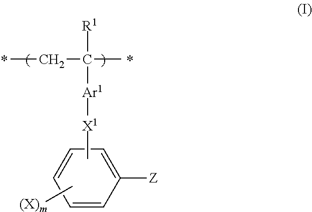

In formula (I),

R¹ represents a hydrogen atom, an alkyl group, a monovalent aliphatic hydrocarbon ring group, a halogen atom, a cyano group or an alkoxycarbonyl group.

Ar¹ represents a bivalent aromatic ring group.

X¹ represents a single bond, —O—, —S—, —C(═O)—, —S(═O)—, —S(═O)₂— or an optionally substituted methylene group.

X represents a substituent; and

m is an integer of 0 to 4.

Z represents a moiety that when exposed to actinic rays or radiation, is decomposed to thereby become a sulfonic acid group, an imidic acid group or a methide acid group.

The alkyl group represented by R¹ is, for example, an alkyl group having up to 20 carbon atoms. Preferred examples thereof are a methyl group, an ethyl group, a propyl group, an isopropyl group, an n-butyl group, a sec-butyl group, a hexyl group, a 2-ethylhexyl group, an octyl group and a dodecyl group. Alkyl groups each having up to 8 carbon atoms are more preferred. Substituents may be introduced in these alkyl groups.

The alkyl group contained in the alkoxycarbonyl group is preferably any of those set forth above in connection with R¹.

The monovalent aliphatic hydrocarbon ring group may be monocyclic or polycyclic. As preferred examples thereof, there can be mentioned monovalent aliphatic hydrocarbon ring groups each having 3 to 8 carbon atoms, such as a cyclopropyl group, a cyclopentyl group and a cyclohexyl group. Substituents may be introduced in these aliphatic hydrocarbon ring groups.

As the halogen atom, there can be mentioned a fluorine atom, a chlorine atom, a bromine atom or an iodine atom. A fluorine atom is preferred.

R¹ is preferably a hydrogen atom or an alkyl group, more preferably a hydrogen atom.

As preferred examples of the bivalent aromatic ring groups represented by Ar¹, there can be mentioned an arylene group having 6 to 18 carbon atoms, such as a phenylene group, a tolylene group or a naphthylene group, and a bivalent aromatic ring group containing a heterocycle, such as thiophene, furan, pyrrole, benzothiophene, benzofuran, benzopyrrole, triazine, imidazole, benzimidazole, triazole, thiadiazole or triazole.

A substituent may be introduced in each of the bivalent aromatic ring groups represented by Ar¹. As preferred substituents introducible in these groups, there can be mentioned alkyl groups set forth in connection with R¹, halogen atoms set forth in connection with R¹, alkoxy groups, such as a methoxy group, an ethoxy group, a hydroxyethoxy group, a propoxy group, a hydroxypropoxy group and a butoxy group, and aryl groups, such as a phenyl group.

Ar¹ is preferably an optionally substituted arylene group having 6 to 18 carbon atoms, most preferably a phenylene group.

As substituents introducible in the methylene group represented by X¹, there can be mentioned, for example, a halogen atom, such as a fluorine atom, a chlorine atom, a bromine atom or an iodine atom; an alkoxy group, such as a methoxy group, an ethoxy group or a tert-butoxy group; an aryloxy group, such as a phenoxy group or a p-tolyloxy group; an alkylthioxy group, such as a methylthioxy group, an ethylthioxy group or a tert-butylthioxy group; an arylthioxy group, such as a phenylthioxy group or a p-tolylthioxy group; an alkoxycarbonyl group, such as a methoxycarbonyl group or a butoxycarbonyl group; an aryloxycarbonyl group, such as a phenoxycarbonyl group or a p-tolyloxycarbonyl group; an acetoxy group; a linear or branched alkyl group, such as a methyl group, an ethyl group, a propyl group, a butyl group, a heptyl group, a hexyl group, a dodecyl group or a 2-ethylhexyl group; an alkenyl group, such as a vinyl group, a propenyl group or a hexenyl group; an alkynyl group, such as an acetylene group, a propynyl group or a hexynyl group; a cycloalkyl group; an aryl group, such as a phenyl group or a tolyl group; a hydroxyl group; and a carboxyl group.

X¹ is preferably —O—, —S—, —C(═O)—, —S(═O)—, —S(═O)₂— or an optionally substituted methylene group, more preferably —O— or —S—, and most preferably —O—. The smaller the number of atoms in X¹, the more effective the suppression of any thermal rotation of the aromatic ring group represented by Ar¹. Accordingly, the Tg of the actinic-ray- or radiation-sensitive film is increased, thereby realizing enhancements of resolving power and LER.

In the formula, m is the number of substituents represented by X, being an integer of 0 to 4.

In an aspect of the present invention, it is preferred for the substituent represented by X to be a fluorine atom or a fluoroalkyl group while m is an integer of 1 to 4, especially 2 to 4 and most especially 4. The greater the number of substitutions with a fluorine atom, the higher the strength of generated acid. Accordingly, a deprotection reaction is promoted, so that enhancements of resolving power and LER can be attained.

As mentioned above, it is preferred for the substituent represented by X to be a fluorine atom or a fluoroalkyl group. The fluoroalkyl group is preferably a perfluoroalkyl group, more preferably a perfluoroalkyl group having 1 to 4 carbon atoms. The substituent represented by X is more preferably a fluorine atom or a trifluoromethyl group, further more preferably a fluorine atom.

As the substituent represented by X other than the above-mentioned fluorine atom and fluoroalkyl group, there can be mentioned, for example, a linear or branched alkyl group, an alkoxy group, an alkylcarbonyl group, a halogen atom, an aryloxy group, an alkylthioxy group, an arylthioxy group, an alkoxycarbonyl group, an aryloxycarbonyl group, an alkenyl group, an alkynyl group, a cycloalkyl group, an aryl group, a hydroxyl group, a carboxyl group, a sulfonic acid group, a cyano group or the like.

When m is an integer of 2 or greater, the two or more X's may be identical to or different from each other.

Z represents a moiety that when exposed to actinic rays or radiation, is decomposed to thereby become a sulfonic acid group, an imidic acid group or a methide acid group. The moiety represented by Z is preferably an onium salt. The onium salt is preferably a sulfonium salt or an iodonium salt. It is especially preferred for the moiety to have any of the structures of general formulae (ZI), (ZII) and (ZIII) below.

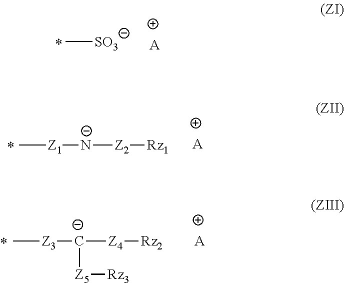

In general formulae (ZII) and (ZIII), each of Z₁, Z₂, Z₃, Z₄ and Z₅ independently represents —CO— or —SO₂—, preferably —SO₂—.

Each of Rz₁, Rz₂ and Rz₃ independently represents an alkyl group, a monovalent aliphatic hydrocarbon ring group, an aryl group or an aralkyl group. Forms of these groups having the hydrogen atoms thereof partially or entirely replaced with a fluorine atom or a fluoroalkyl group (especially a perfluoroalkyl group) are preferred. Forms of these groups having 30 to 100% of the hydrogen atoms thereof replaced with a fluorine atom are most preferred.

* represents a site of bonding to the benzene ring in general formula (I).

The above alkyl group may be linear or branched. As a preferred form thereof, there can be mentioned, for example, an alkyl group having 1 to 8 carbon atoms, such as a methyl group, an ethyl group, a propyl group, a butyl group, a hexyl group or an octyl group. An alkyl group having 1 to 6 carbon atoms is more preferred. An alkyl group having 1 to 4 carbon atoms is most preferred.

The monovalent aliphatic hydrocarbon ring group is preferably a cycloalkyl group, more preferably a monovalent cycloalkyl group having 3 to 10 carbon atoms, such as a cyclobutyl group, a cyclopentyl group or a cyclohexyl group. A cycloalkyl group having 3 to 6 carbon atoms is further more preferred.

The aryl group is preferably one having 6 to 18 carbon atoms. An aryl group having 6 to 10 carbon atoms is more preferred. A phenyl group is most preferred.

As a preferred form of the aralkyl group, there can be mentioned one resulting from the bonding of the above aryl group to an alkylene group having 1 to 8 carbon atoms. An aralkyl group resulting from the bonding of the above aryl group to an alkylene group having 1 to 6 carbon atoms is more preferred. An aralkyl group resulting from the bonding of the above aryl group to an alkylene group having 1 to 4 carbon atoms is most preferred.

Each of Rz₁, Rz₂ and Rz₃ is preferably an alkyl group having the hydrogen atoms thereof partially or entirely replaced with a fluorine atom or a fluoroalkyl group (especially a perfluoroalkyl group), most preferably an alkyl group having 30 to 100% of the hydrogen atoms thereof replaced with a fluorine atom.

In general formulae (ZI) to (ZIII) above, A⁺ represents a sulfonium cation or an iodonium cation. It is preferred for the cation represented by A⁺ to have any of the structures of general formulae (ZA-1) and (ZA-2) below.

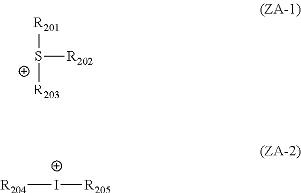

In general formula (ZA-1), each of R₂₀₁, R₂₀₂ and R₂₀₃ independently represents an organic group. The number of carbon atoms of each of the organic groups represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure (including a condensed ring), and the ring within the same may contain an oxygen atom, a sulfur atom, an ester bond, an amido bond or a carbonyl group aside from the sulfur atom appearing in the formula. As the group formed by bonding of two of R₂₀₁ to R₂₀₃, there can be mentioned, for example, an alkylene group such as a butylene group or a pentylene group.

As the organic groups represented by R₂₀₁, R₂₀₂ and R₂₀₃, there can be mentioned, for example, the corresponding groups contained in the (ZA-1-1), (ZA-1-2) and (ZA-1-3) groups to be described below as preferred forms of the groups of general formula (ZA-1), preferably the corresponding groups contained in the (ZA-1-1) and (ZA-1-3) groups.

First, the (ZA-1-1) groups will be described.

The (ZA-1-1) groups are arylsulfonium cations of general formula (ZA-1) wherein at least one of R₂₀₁ to R₂₀₃ is an aryl group.

In the (ZA-1-1) group, all of the R₂₀₁ to R₂₀₃ may be aryl groups. It is also appropriate that the R₂₀₁ to R₂₀₃ are partially an aryl group and the remainder is an alkyl group or a cycloalkyl group.

As the (ZA-1-1) group, there can be mentioned, for example, a group corresponding to each of a triarylsulfonium, a diarylalkylsulfonium, an aryldialkylsulfonium, a diarylcycloalkylsulfonium and an aryldicycloalkylsulfonium.

The aryl group of the arylsulfonium is preferably a phenyl group or a naphthyl group. The aryl group may be one having a heterocyclic structure containing an oxygen atom, a nitrogen atom, a sulfur atom or the like. As the heterocyclic structure, there can be mentioned, for example, a pyrrole, a furan, a thiophene, an indole, a benzofuran, a benzothiophene or the like.

When the arylsulfonium has two or more aryl groups, the two or more aryl groups may be identical to or different from each other.

The alkyl group or monovalent aliphatic hydrocarbon ring group contained in the arylsulfonium according to necessity is preferably a linear or branched alkyl group having 1 to 15 carbon atoms or a monovalent aliphatic hydrocarbon ring group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like. The monovalent aliphatic hydrocarbon ring group is preferably a cycloalkyl group.

The aryl group, alkyl group or monovalent aliphatic hydrocarbon ring group represented by R₂₀₁ to R₂₀₃ may have as its substituent an alkyl group (for example, 1 to 15 carbon atoms), a monovalent aliphatic hydrocarbon ring group (for example, 3 to 15 carbon atoms; preferably a cycloalkyl group having 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a monovalent aliphatic hydrocarbon ring group having 3 to 12 carbon atoms (preferably a cycloalkyl group having 3 to 12 carbon atoms) and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be contained in any one of the three R₂₀₁ to R₂₀₃, or alternatively may be contained in all three of R₂₀₁ to R₂₀₃. When R₂₀₁ to R₂₀₃ represent an aryl group, the substituent preferably lies at the p-position of the aryl group.

As more preferred groups of (ZA-1-1), there can be mentioned a triarylsulfonium, or structures of general formula (ZA-1-1A) or (ZA-1-1B) below.

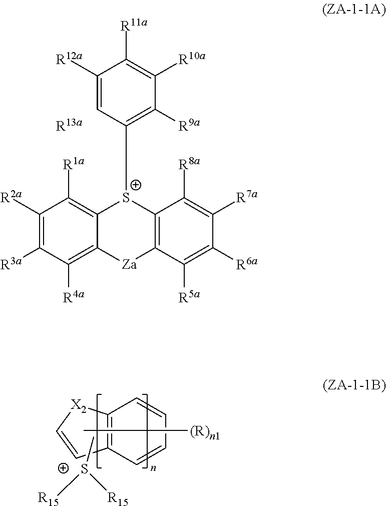

In the general formula (ZA-1-1A),

each of R^{1a} to R^{13a} independently represents a hydrogen atom or a substituent, provided that at least one of R^{1a} to R^{13a} is a substituent containing an alcoholic hydroxyl group.

Za represents a single bond or a bivalent connecting group.

In the present invention, the alcoholic hydroxyl group refers to a hydroxyl group bonded to a carbon atom of a linear, branched or cyclic alkyl group.

When R^{1a} to R^{13a} represent substituents containing an alcoholic hydroxyl group, it is preferred for the R^{1a} to R^{13a} to represent the groups of the formula —W—Y, wherein Y represents a hydroxyl-substituted linear, branched or cyclic alkyl group and W represents a single bond or a bivalent connecting group.

As the linear, branched or cyclic alkyl group represented by Y, there can be mentioned a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, a cyclopropyl group, a cyclopentyl group, a cyclohexyl group, an adamantyl group, a norbornyl group, a boronyl group or the like. Of these, an ethyl group, a propyl group, an isopropyl group, an n-butyl group, an isobutyl group and a sec-butyl group are preferred. An ethyl group, a propyl group and an isopropyl group are more preferred. Especially preferably, Y contains the structure of —CH₂CH₂OH.

W is preferably a single bond, or a bivalent group as obtained by replacing with a single bond any hydrogen atom of a group selected from among an alkoxy group, an acyloxy group, an acylamino group, an alkyl- or arylsulfonylamino group, an alkylthio group, an alkylsulfonyl group, an acyl group, an alkoxycarbonyl group and a carbamoyl group. More preferably, W is a single bond, or a bivalent group as obtained by replacing with a single bond any hydrogen atom of a group selected from among an acyloxy group, an alkylsulfonyl group, an acyl group and an alkoxycarbonyl group.

When R^{1a} to R^{13a} represent substituents containing an alcoholic hydroxyl group, the number of carbon atoms contained in each of the substituents is preferably in the range of 2 to 10, more preferably 2 to 6 and further preferably 2 to 4.

Each of the substituents containing an alcoholic hydroxyl group represented by R^{1a} to R^{13a} may have two or more alcoholic hydroxyl groups. The number of alcoholic hydroxyl groups contained in each of the substituents containing an alcoholic hydroxyl group represented by R^{1a} to R^{13a} is in the range of 1 to 6, preferably 1 to 3 and more preferably 1.

The number of alcoholic hydroxyl groups contained in any of the cation structures of the general formula (ZA-1-1A) as the total of those of R^{1a} to R^{13a} is preferably in the range of 1 to 10, more preferably 1 to 6 and still more preferably 1 to 3.

When R^{1a} to R^{13a} do not contain any alcoholic hydroxyl group, each of R^{1a} to R^{13a} preferably represents a hydrogen atom, a halogen atom, an alkyl group, a monovalent aliphatic hydrocarbon ring group (preferably a cycloalkyl group), any of alkenyl groups (including a cycloalkenyl group and a bicycloalkenyl group), an alkynyl group, an aryl group, a cyano group, a carboxyl group, an alkoxy group, an aryloxy group, an acyloxy group, a carbamoyloxy group, an acylamino group, an aminocarbonylamino group, an alkoxycarbonylamino group, an aryloxycarbonylamino group, a sulfamoylamino group, an alkyl- or arylsulfonylamino group, an alkylthio group, an arylthio group, a sulfamoyl group, an alkyl- or arylsulfonyl group, an aryloxycarbonyl group, an alkoxycarbonyl group, a carbamoyl group, an imido group, a silyl group or a ureido group.

When R^{1a} to R^{13a} do not contain any alcoholic hydroxyl group, each of R^{1a} to R^{13a} more preferably represents a hydrogen atom, a halogen atom, an alkyl group, a monovalent aliphatic hydrocarbon ring group (preferably a cycloalkyl group), a cyano group, an alkoxy group, an acyloxy group, an acylamino group, an aminocarbonylamino group, an alkoxycarbonylamino group, an alkyl- or arylsulfonylamino group, an alkylthio group, a sulfamoyl group, an alkyl- or arylsulfonyl group, an alkoxycarbonyl group or a carbamoyl group.

When R^{1a} to R^{13a} do not contain any alcoholic hydroxyl group, especially preferably, each of R^{1a} to R^{13a} represents a hydrogen atom, an alkyl group, a monovalent aliphatic hydrocarbon ring group (preferably a cycloalkyl group), a halogen atom or an alkoxy group.

Any two adjacent to each other of R^{1a} to R^{13a} can cooperate with each other so as to form a ring (an aromatic or nonaromatic cyclohydrocarbon or heterocycle which can form a condensed polycycle through further combination; as such, there can be mentioned, for example, a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring or a phenazine ring).

In the general formula (ZA-1-1A), at least one of R^{1a} to R^{13a} contains an alcoholic hydroxyl group. Preferably, at least one of R^{9a} to R^{13a} contains an alcoholic hydroxyl group.

Za represents a single bond or a bivalent connecting group. The bivalent connecting group is, for example, an alkylene group, an arylene group, a carbonyl group, a sulfonyl group, a carbonyloxy group, a carbonylamino group, a sulfonylamido group, an ether group, a thioether group, an amino group, a disulfide group, an acyl group, an alkylsulfonyl group, —CH═CH—, —C≡C—, an aminocarbonylamino group, an aminosulfonylamino group or the like. The bivalent connecting group may have a substituent. The same substituents as mentioned above with respect to R^{1a} to R^{13a} can be employed. Preferably, Za is a single bond or a substituent exhibiting no electron withdrawing properties, such as an alkylene group, an arylene group, an ether group, a thioether group, an amino group, —CH═CH—, —CH≡CH—, an aminocarbonylamino group or an aminosulfonylamino group. More preferably, Z is a single bond, an ether group or a thioether group. Most preferably, Z is a single bond.

Now, general formula (ZA-1-1B) will be described. In general formula (ZA-1-1B), each of R₁₅s independently represents an alkyl group, a monovalent aliphatic hydrocarbon ring group (preferably a cycloalkyl group) or an aryl group, provided that two R₁₅s may be bonded to each other to thereby form a ring.

X₂ represents any of —CR₂₁═CR₂₂—, —NR₂₃—, —S— and —O—. Each of R₂₁ and R₂₂ independently represents a hydrogen atom, an alkyl group, a monovalent aliphatic hydrocarbon ring group (preferably a cycloalkyl group) or an aryl group. R₂₃ represents a hydrogen atom, an alkyl group, a monovalent aliphatic hydrocarbon ring group (preferably a cycloalkyl group), an aryl group or an acyl group.

R, or each of R's independently, represents a substituent. As the substituent represented by R, there can be mentioned, for example, the corresponding groups in general formulae (ZI-1) to (ZI-3) to be described below as preferred forms of general formula (ZA-1-1B).

In the formula, n is an integer of 0 to 3, and

n1 is an integer of 0 to 11.

Substituents may be introduced in the alkyl groups represented by R₁₅ and R₂₁ to R₂₃. A linear or branched alkyl group having 1 to 20 carbon atoms is a preferred substituent. An oxygen atom, a sulfur atom or a nitrogen atom may be introduced in the alkyl chain.

In particular, as a substituted alkyl group, there can be mentioned a linear or branched alkyl group substituted with a monovalent aliphatic hydrocarbon ring group (preferably a cycloalkyl group) (for example, an adamantylmethyl group, an adamantylethyl group, a cyclohexylethyl group, a camphor residue or the like).

Substituents may be introduced in the monovalent aliphatic hydrocarbon ring groups represented by R₁₅ and R₂₁ to R₂₃. A cycloalkyl group is a preferred substituent, and a cycloalkyl group having 3 to 20 carbon atoms is a more preferred substituent. An oxygen atom may be introduced in the ring.

Substituents may be introduced in the aryl groups represented by R₁₅ and R₂₁ to R₂₃. An aryl group having 6 to 14 carbon atoms is a preferred substituent.

With respect to the alkyl group contained in the acyl group represented by R₂₃, particular examples and preferred range thereof are the same as those of alkyl groups mentioned above.

As substituents that may be introduced in these groups, there can be mentioned, for example, a halogen atom, a hydroxyl group, a nitro group, a cyano group, a carboxyl group, a carbonyl group, an alkyl group (preferably 1 to 10 carbon atoms), a monovalent aliphatic hydrocarbon ring group (preferably 3 to 10 carbon atoms, more preferably a cycloalkyl group having 3 to 10 carbon atoms), an aryl group (preferably 6 to 14 carbon atoms), an alkoxy group (preferably 1 to 10 carbon atoms), an aryloxy group (preferably 6 to 14 carbon atoms), an acyl group (preferably 2 to 20 carbon atoms), an acyloxy group (preferably 2 to 10 carbon atoms), an alkoxycarbonyl group (preferably 2 to 20 carbon atoms), an aminoacyl group (preferably 2 to 20 carbon atoms), an alkylthio group (preferably 1 to 10 carbon atoms), an arylthio group (preferably 6 to 14 carbon atoms), and the like. In the cyclic structure of the aryl group, monovalent aliphatic hydrocarbon ring group or the like and in the aminoacyl group, an alkyl group (preferably 1 to 20 carbon atoms) may further be introduced as a substituent.

The ring that may be formed by the mutual bonding of two R₁₅s is a ring structure formed in cooperation with —S⁺ shown in formula (ZA-1-1B), preferably a 5-membered ring containing one sulfur atom or a condensed ring containing the same. The condensed ring is preferably one containing one sulfur atom and up to 18 carbon atoms, more preferably any of the ring structures of general formulae (IV-1) to (IV-3) below.

In the formulae, * represents a bonding hand. R represents an arbitrary substituent. As such, there can be mentioned, for example, any of the same substituents that may be introduced in the groups represented by R₁₅ and R₂₁ to R₂₃. In the formulae, n is an integer of 0 to 4, and n2 is an integer of 0 to 3.

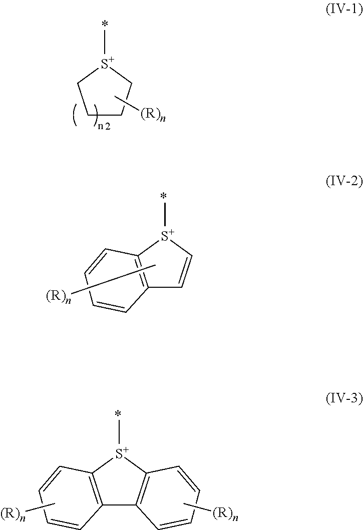

Among the cations of general formula (ZA-1-1B), as preferred cation structures, there can be mentioned the following cation structures (ZI-1) to (ZI-3).

The cation structure (ZI-1) refers to the structure of general formula (ZI-1) below.

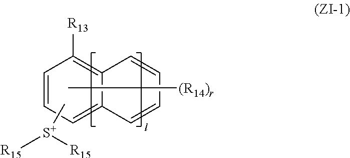

In general formula (ZI-1),

R₁₃ represents a hydrogen atom, a fluorine atom, a hydroxyl group, an alkyl group, a monovalent aliphatic hydrocarbon ring group, an alkoxy group, an alkoxycarbonyl group or a group with a mono- or polycycloalkyl skeleton.

R₁₄, or each of R₁₄s independently, represents an alkyl group, a monovalent aliphatic hydrocarbon ring group, an alkoxy group, an alkylsulfonyl group, a cycloalkylsulfonyl group, a hydroxyl group or a group with a mono- or polycycloalkyl skeleton.

Each of R₁₅s independently represents an alkyl group, a monovalent aliphatic hydrocarbon ring group or an aryl group, provided that two R₁₅s may be bonded to each other to thereby form a ring.

In the formula, 1 is an integer of 0 to 2, and r is an integer of 0 to 8.

In general formula (ZI-1), the alkyl groups represented by R₁₃, R₁₄ and R₁₅ may be linear or branched and preferably each have 1 to 10 carbon atoms. As such, there can be mentioned a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group and the like. Of these alkyl groups, a methyl group, an ethyl group, an n-butyl group, a t-butyl group and the like are more preferred.

Each of the monovalent aliphatic hydrocarbon ring groups represented by R₁₃, R₁₄ and R₁₅ may be monocyclic or polycyclic, and preferably has 3 to 12 carbon atoms. As such, there can be mentioned cyclopropyl, cyclobutyl, cyclopentyl, cyclohexyl, cycloheptyl, cyclooctyl, cyclododecanyl, cyclopentenyl, cyclohexenyl, cyclooctadienyl, bicycloheptyl(norbornyl), adamantyl or the like. Cyclopropyl, cyclopentyl, cyclohexyl and cyclooctyl are preferred. It is preferred for the monovalent aliphatic hydrocarbon ring group to be a cycloalkyl group.

The aryl group represented by R₁₅ is preferably an aryl group having 6 to 14 carbon atoms, more preferably a phenyl group or a naphthyl group.

The alkoxy groups represented by R₁₃ and R₁₄ may be linear, branched or cyclic and preferably each have 1 to 10 carbon atoms. As such, there can be mentioned, for example, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group and the like. Of these alkoxy groups, a methoxy group, an ethoxy group, an n-propoxy group, an n-butoxy group and the like are preferred.

The alkoxycarbonyl group represented by R₁₃ is linear or branched, preferably having 2 to 11 carbon atoms, and can be, for example, any of the alkyl groups represented by R₁₃, R₁₄ and R₁₅ that are substituted with an oxycarbonyl group. As such, there can be mentioned a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group and the like. Of these alkoxycarbonyl groups, a methoxycarbonyl group, an ethoxycarbonyl group, an n-butoxycarbonyl group and the like are more preferred.

As the groups with a cycloalkyl skeleton of a single ring or multiple rings represented by R₁₃ and R₁₄, there can be mentioned, for example, a cycloalkyloxy group of a single ring or multiple rings and an alkoxy group with a cycloalkyl group of a single ring or multiple rings. These groups may further have one or more substituents.

With respect to each of the cycloalkyloxy groups of a single ring or multiple rings represented by R₁₃ and R₁₄, the sum of carbon atoms thereof is preferably 7 or greater, more preferably in the range of 7 to 15. Further, having a cycloalkyl skeleton of a single ring is preferred. The cycloalkyloxy group of a single ring of which the sum of carbon atoms is 7 or greater is one composed of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally having a substituent selected from among an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group and the like, provided that the sum of carbon atoms thereof, including those of any optional substituent introduced in the cycloalkyl group, is 7 or greater.

As the cycloalkyloxy group of multiple rings of which the sum of carbon atoms is 7 or greater, there can be mentioned a norbornyloxy group, a tricyclodecanyloxy group, a tetracyclodecanyloxy group, an adamantyloxy group or the like.

With respect to each of the alkyloxy groups having a cycloalkyl skeleton of a single ring or multiple rings represented by R₁₃ and R₁₄, the sum of carbon atoms thereof is preferably 7 or greater, more preferably in the range of 7 to 15. Further, the alkoxy group having a cycloalkyl skeleton of a single ring is preferred. The alkoxy group having a cycloalkyl skeleton of a single ring of which the sum of carbon atoms is 7 or greater is one composed of an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with the above optionally substituted cycloalkyl group of a single ring, provided that the sum of carbon atoms thereof, including those of the substituents, is 7 or greater. For example, there can be mentioned a cyclohexylmethoxy group, a cyclopentylethoxy group, a cyclohexylethoxy group or the like. A cyclohexylmethoxy group is preferred.

As the alkoxy group having a cycloalkyl skeleton of multiple rings of which the sum of carbon atoms is 7 or greater, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like. Of these, a norbornylmethoxy group, a norbornylethoxy group and the like are preferred.

The alkylsulfonyl and cycloalkylsulfonyl groups represented by R₁₄ may be linear, branched or cyclic and preferably each having 1 to 10 carbon atoms, and can be, for example, any of the alkyl groups represented by R₁₃, R₁₄ and R₁₅ that are substituted with a sulfonyl group. As such, there can be mentioned a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group and the like. Of these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group and the like are more preferred.

Substituents may further be introduced in the groups represented by R₁₃, R₁₄ and R₁₅. As optionally introduced substituents, there can be mentioned an alkyl group, such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group or an isoamyl group; a monovalent aliphatic hydrocarbon ring group (may be monocyclic or polycyclic, preferably having 3 to 20 carbon atoms, more preferably 5 to 8 carbon atoms); a hydroxyl group; a halogen atom (fluorine, chlorine, bromine or iodine); a nitro group; a cyano group; an amido group; a sulfonamido group; an alkoxy group; an alkoxyalkyl group; an alkoxycarbonyl group; an alkoxycarbonyloxy group; an acyl group, such as a formyl group, an acetyl group or a benzoyl group; an acyloxy group, such as an acetoxy group or a butyryloxy group; a carboxyl group; and the like

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

As the ring structure that may be formed by the mutual bonding of two R₁₅s, there can be mentioned a 5-membered or 6-membered ring, especially preferably a 5-membered ring (namely, a tetrahydrothiophene ring), formed by a bivalent group resulting from the bonding of two R₁₅s in cooperation with the sulfur atom in general formula (ZI-1). The ring may be condensed with an aryl group or an aliphatic hydrocarbon ring group (preferably a cycloalkyl group). A substituent may be introduced in this bivalent group. As the substituent, there can be mentioned, for example, an alkyl group, a cycloalkyl group, a hydroxyl group, a carboxyl group, a cyano group, a nitro group, an alkoxy group, an alkoxyalkyl group, an alkoxycarbonyl group, an alkoxycarbonyloxy group or the like.

In general formula (ZI-1), R₁₅ is preferably a methyl group, an ethyl group, a naphthyl group, a bivalent group resulting from the mutual bonding of two R₁₅s that forms a tetrahydrothiophene ring structure in cooperation with a sulfur atom, or the like.

As aforementioned, substituents may be introduced in the alkyl group, monovalent aliphatic hydrocarbon ring group, alkoxy group and alkoxycarbonyl group represented by R₁₃ and the alkyl group, monovalent aliphatic hydrocarbon ring group, alkoxy group, alkylsulfonyl group and cycloalkylsulfonyl group represented by R₁₄. Preferred substituents are a hydroxyl group, an alkoxy group, an alkoxycarbonyl group and a halogen atom (especially a fluorine atom).

Preferred particular examples of the cation structures of general formula (ZI-1) are shown below.

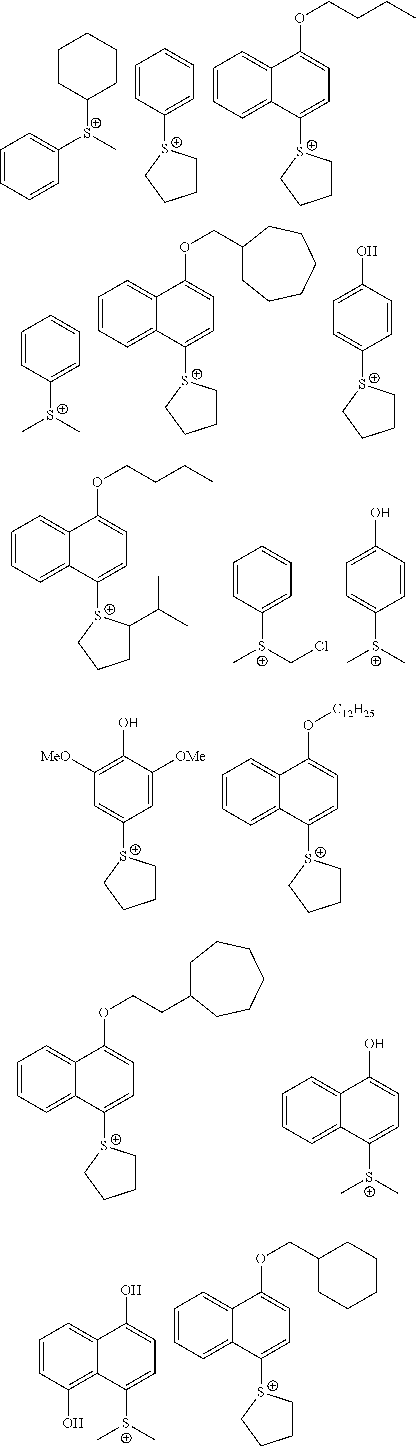

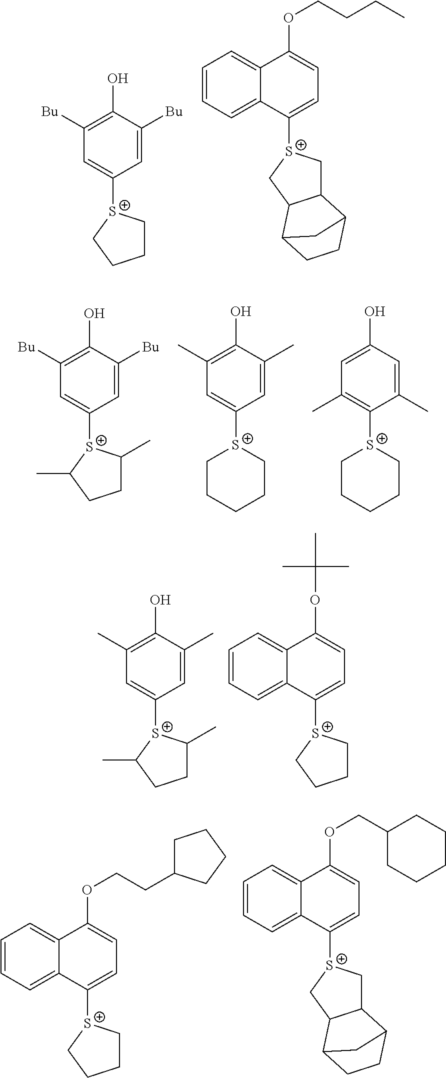

The cation structure (ZI-2) refers to the structure of general formula (ZI-2) below.

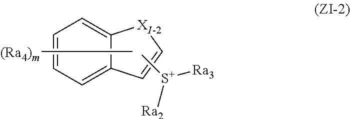

In general formula (ZI-2),

X_{I-2} represents an oxygen atom, a sulfur atom or any of the groups of the formula —NRa₁—, in which Ra₁ represents a hydrogen atom, an alkyl group, a monovalent aliphatic hydrocarbon ring group, an aryl group or an acyl group.

Each of Ra₂ and Ra₃ independently represents an alkyl group, a monovalent aliphatic hydrocarbon ring group, an alkenyl group or an aryl group, provided that Ra₂ and Ra₃ may be bonded to each other to thereby form a ring.

Ra₄, or each of Ra₄s independently, represents a monovalent group.

In the formula, m is an integer of 0 to 3.

Each of the alkyl groups represented by Ra₁ to Ra₃ is preferably a linear or branched alkyl group having 1 to 20 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group or the like.

Each of the monovalent aliphatic hydrocarbon ring groups represented by Ra₁ to Ra₃ is preferably a monovalent aliphatic hydrocarbon ring group having 3 to 20 carbon atoms. As such, there can be mentioned, for example, a cyclopropyl group, a cyclobutyl group, a cyclopentyl group, a cyclohexyl group, a cyclooctyl group, an adamantyl group, a norbornyl group, an isobornyl group, a camphonyl group, a dicyclopentyl group, an α-pinanyl group, a tricyclodecanyl group, a tetracyclododecyl group, an androstanyl group or the like. It is preferred for the monovalent aliphatic hydrocarbon ring group to be a cycloalkyl group.

Each of the aryl groups represented by Ra₁ to Ra₃ is preferably an aryl group having 6 to 10 carbon atoms. As such, there can be mentioned, for example, a phenyl group, a naphthyl group or the like.

The acyl group represented by Ra₁ is preferably one having 2 to 20 carbon atoms. As such, there can be mentioned, for example, a formyl group, an acetyl group, a propanoyl group, a butanoyl group, a pivaloyl group, a benzoyl group or the like.

Each of the alkenyl groups represented by Ra₂ and Ra₃ is preferably an alkenyl group having 2 to 15 carbon atoms. As such, there can be mentioned, for example, a vinyl group, an allyl group, a butenyl group, a cyclohexenyl group or the like.

The ring structure that may be formed by the mutual bonding of Ra₂ and Ra₃ is preferably a group forming a 5- or 6-membered ring, especially a 5-membered ring (for example, a tetrahydrothiophene ring) in cooperation with the sulfur atom in general formula (ZI-2), in which an oxygen atom may be contained. As such, there can be mentioned, for example, the same ring as may be formed by the mutual linkage of R₁₅s in general formula (ZI-1).

As the monovalent group represented by Ra₄, there can be mentioned, for example, an alkyl group (preferably 1 to 20 carbon atoms), a monovalent aliphatic hydrocarbon ring group (preferably 3 to 20 carbon atoms, more preferably a cycloalkyl group having 3 to 20 carbon atoms), an aryl group (preferably 6 to 10 carbon atoms), an alkoxy group (preferably 1 to 20 carbon atoms), an acyl group (preferably 2 to 20 carbon atoms), an acyloxy group (preferably 2 to 20 carbon atoms), a fluorine atom, a chlorine atom, a bromine atom, an iodine atom, a hydroxyl group, a carboxyl group, a nitro group, a cyano group, an alkoxycarbonyl group, an alkylsulfonyl group, an arylsulfonyl group, an arylcarbonyl group, an alkylcarbonyl group, an alkenylcarbonyl group or the like.

Ra₁ is preferably an alkyl group, more preferably an alkyl group having 1 to 4 carbon atoms.

Preferably, Ra₂ and Ra₃ are connected to each other to thereby form a 5- or 6-membered ring.

Substituents may further be introduced in the groups represented by Ra₁ to Ra₄. As optionally introduced further substituents, there can be mentioned those set forth above as being optionally introduced in the groups represented by R₁₃ to R₁₅ in general formula (ZI-1).

Preferred particular examples of the cation structures (ZI-2) are shown below.

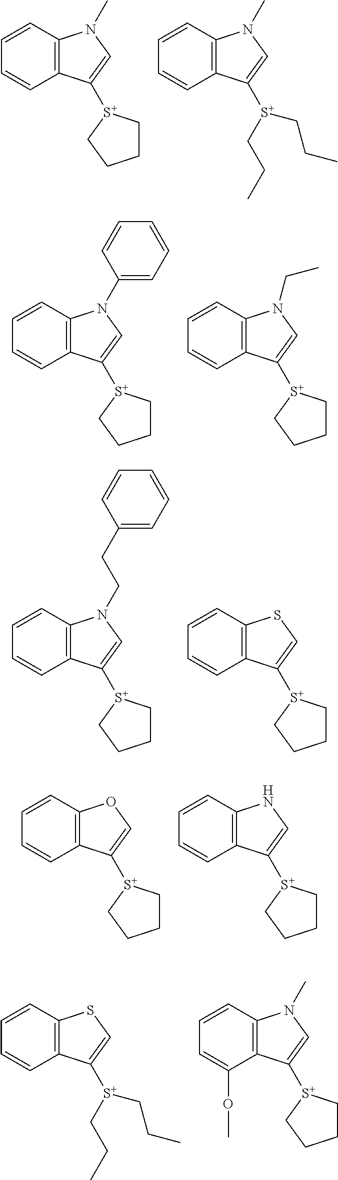

The cation structure (ZI-3) refers to the structure of general formula (ZI-3) below.

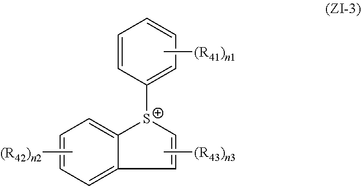

In general formula (ZI-3), each of R₄₁ to R₄₃ independently represents an alkyl group, an acetyl group, an alkoxy group, a carboxyl group, a halogen atom, a hydroxyl group or a hydroxyalkyl group.

As the alkyl group and alkoxy group represented by R₄₁ to R₄₃, there can be mentioned those set forth above in connection with R₁₃ to R₁₅ in general formula (ZI-1).

The hydroxyalkyl group is preferably any of the above alkyl groups wherein one or a plurality of hydrogen atoms are replaced by hydroxyl groups. As such, there can be mentioned a hydroxymethyl group, a hydroxyethyl group, a hydroxypropyl group or the like.

In the formula, n1 is an integer of 0 to 3, preferably 1 or 2 and more preferably 1;

n2 is an integer of 0 to 3, preferably 0 or 1 and more preferably 0; and

n3 is an integer of 0 to 2, preferably 0 or 1 and more preferably 1.

Substituents may further be introduced in the groups represented by R₄₁ to R₄₃. As optionally introduced further substituents, there can be mentioned those set forth above as being optionally introduced in the groups represented by R₁₃ to R₁₅ in general formula (ZI-1).

Preferred particular examples of the cation structures (ZI-3) are shown below.

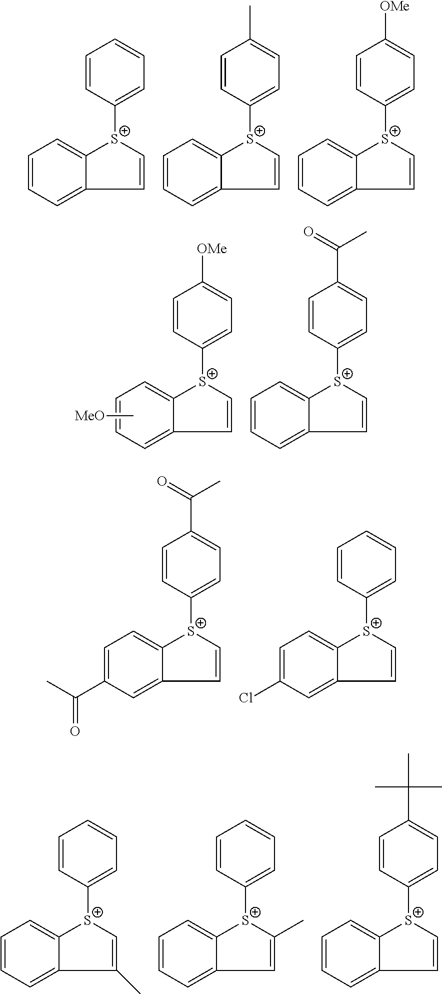

Among the cation structures of general formulae (ZI-1) to (ZI-3), the structures of general formulae (ZI-1) and (ZI-2) are preferred. The structure of general formula (ZI-1) is more preferred.

The groups (ZA-1-2) will be described below.

The groups (ZA-1-2) refer to the groups of general formula (ZA-1) wherein each of R₂₀₁ to R₂₀₃ independently represents an organic group containing no aromatic ring. Herein, the aromatic ring includes one containing a heteroatom.

Each of the organic groups containing no aromatic ring represented by R₂₀₁ to R₂₀₃ generally has 1 to 30 carbon atoms, preferably 1 to 20 carbon atoms.

Preferably, each of R₂₀₁ to R₂₀₃ independently is an alkyl group, a monovalent aliphatic hydrocarbon ring group, an allyl group or a vinyl group. A linear or branched 2-oxoalkyl group, 2-oxo aliphatic hydrocarbon ring group and alkoxycarbonylmethyl group are more preferred. A linear or branched 2-oxo aliphatic hydrocarbon ring group is most preferred.

As preferred alkyl groups and aliphatic hydrocarbon ring groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and an aliphatic hydrocarbon ring group having 3 to 10 carbon atoms (for example, a cyclopentyl group, a cyclohexyl group or a norbornyl group). The alkyl group is more preferably a 2-oxoalkyl group or an alkoxycarbonylmethyl group. The aliphatic hydrocarbon ring group is more preferably a 2-oxo aliphatic hydrocarbon ring group. It is preferred for the aliphatic hydrocarbon ring group to be a cycloalkyl group.

The 2-oxoalkyl group may be linear or branched. Preferably, it is any of the above alkyl groups in which >C═O is introduced in the 2-position thereof.

Preferably, the 2-oxo aliphatic hydrocarbon ring group is any of the above aliphatic hydrocarbon ring groups in which >C═O is introduced in the 2-position thereof. It is preferred for the 2-oxo aliphatic hydrocarbon ring group to be a 2-oxocycloalkyl group.

As preferred alkoxy groups contained in the alkoxycarbonylmethyl groups, there can be mentioned alkoxy groups each having 1 to 5 carbon atoms (a methoxy group, an ethoxy group, a propoxy group, a butoxy group and a pentoxy group).

These R₂₀₁ to R₂₀₃ may further be substituted with a halogen atom, an alkoxy group (for example, 1 to 5 carbon atoms), a hydroxyl group, a cyano group or a nitro group.

The groups (ZA-1-3) will be described below.

The groups (ZA-1-3) refer to the groups of general formula below, that each have a phenacylsulfonium cation structure.

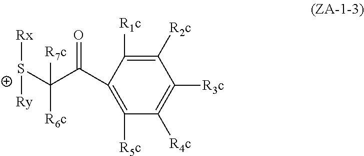

In general formula (ZA-1-3), each of R_{1c} to R_{5c} independently represents a hydrogen atom, an alkyl group, a monovalent aliphatic hydrocarbon ring group, an alkoxy group, a phenylthio group or a halogen atom.

Each of R_{6c} and R_{7c} independently represents a hydrogen atom, an alkyl group or a monovalent aliphatic hydrocarbon ring group.

Each of Rₓ and R_{y} independently represents an alkyl group, a monovalent aliphatic hydrocarbon ring group, an allyl group or a vinyl group.

Any two or more of R_{1c} to R_{5c}, and R_{6c} and R_{7c}, and Rₓ and R_{y} may be bonded to each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Each of the alkyl groups represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group).

Each of the monovalent aliphatic hydrocarbon ring groups represented by R_{1c} to R_{7c} may be monocyclic or polycyclic. As such, there can be mentioned, for example, a monovalent aliphatic hydrocarbon ring group having 3 to 8 carbon atoms (for example, a cyclopentyl group or a cyclohexyl group). It is preferred for the monovalent aliphatic hydrocarbon ring group to be a cycloalkyl group.

Each of the alkoxy groups represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group, or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a monovalent aliphatic hydrocarbon ring group or a linear, branched or cyclic alkoxy group. More preferably, the sum of carbon atoms of R_{1c} to R_{5c} is in the range of 2 to 15. These contribute toward an enhancement of solvent solubility and inhibition of particle generation during storage.

As the alkyl groups and monovalent aliphatic hydrocarbon ring groups represented by Rₓ and R_{y}, there can be mentioned the same alkyl groups and monovalent aliphatic hydrocarbon ring groups as mentioned above with respect to R_{1c} to R_{7c}. Among them, a 2-oxoalkyl group, a 2-oxo aliphatic hydrocarbon ring group and an alkoxycarbonylmethyl group are preferred.

As the 2-oxoalkyl group and 2-oxo aliphatic hydrocarbon ring group, there can be mentioned any of the alkyl groups and aliphatic hydrocarbon ring groups represented by R_{1c} to R_{7c} in which >C═O is introduced at the 2-position thereof.

As the alkoxy group contained in the alkoxycarbonylmethyl group, there can be mentioned any of the same alkoxy groups as set forth above with respect to R_{1c} to R_{5c}.

Each of Rₓ and R_{y} is preferably an alkyl group or monovalent aliphatic hydrocarbon ring group having preferably 4 or more carbon atoms. The alkyl group or monovalent aliphatic hydrocarbon ring group more preferably has 6 or more carbon atoms, further more preferably 8 or more carbon atoms.

The ring structure that may be formed by the mutual bonding of Rₓ and R_{y} is a 5- or 6-membered ring, especially preferably a 5-membered ring (namely, a tetrahydrothiophene ring) formed by bivalent Rₓ and R_{y} (for example, a methylene group, an ethylene group, a propylene group or the like) in cooperation with the sulfur atom in general formula (ZA-1-3).

Now, general formula (ZA-2) will be described.

In general formula (ZA-2), each of R₂₀₄ and R₂₀₅ independently represents an aryl group, an alkyl group or a monovalent aliphatic hydrocarbon ring group.

Each of the aryl groups represented by R₂₀₄ and R₂₀₅ is preferably a phenyl group or a naphthyl group, more preferably a phenyl group. Each of the aryl groups represented by R₂₀₄ and R₂₀₅ may be one having a heterocyclic structure containing an oxygen atom, a nitrogen atom, a sulfur atom or the like. As the aryl group having a heterocyclic structure, there can be mentioned, for example, a pyrrole residue (group formed by the loss of one hydrogen atom from pyrrole), a furan residue (group formed by the loss of one hydrogen atom from furan), a thiophene residue (group formed by the loss of one hydrogen atom from thiophene), an indole residue (group formed by the loss of one hydrogen atom from indole), a benzofuran residue (group formed by the loss of one hydrogen atom from benzofuran), a benzothiophene residue (group formed by the loss of one hydrogen atom from benzothiophene) or the like.

As preferred alkyl groups and monovalent aliphatic hydrocarbon ring groups represented by R₂₀₄ and R₂₀₅, there can be mentioned a linear or branched alkyl group having 1 to 10 carbon atoms (for example, a methyl group, an ethyl group, a propyl group, a butyl group or a pentyl group) and a monovalent aliphatic hydrocarbon ring group having 3 to 10 carbon atoms (a cyclopentyl group, a cyclohexyl group or a norbornyl group). It is preferred for the monovalent aliphatic hydrocarbon ring group to be a cycloalkyl group.

Substituents may be introduced in the aryl groups, alkyl groups and monovalent aliphatic hydrocarbon ring groups represented by R₂₀₄ and R₂₀₅. As substituents introducible in the aryl groups, alkyl groups and monovalent aliphatic hydrocarbon ring groups represented by R₂₀₄ and R₂₀₅, there can be mentioned, for example, an alkyl group (for example, 1 to 15 carbon atoms), a monovalent aliphatic hydrocarbon ring group (for example, 3 to 15 carbon atoms, preferably a cycloalkyl group having 3 to 15 carbon atoms), an aryl group (for example, 6 to 15 carbon atoms), an alkoxy group (for example, 1 to 15 carbon atoms), a halogen atom, a hydroxyl group, a phenylthio group and the like.

Particular examples of cations for constituting onium salts preferred as Z in general formula (I) are shown below.

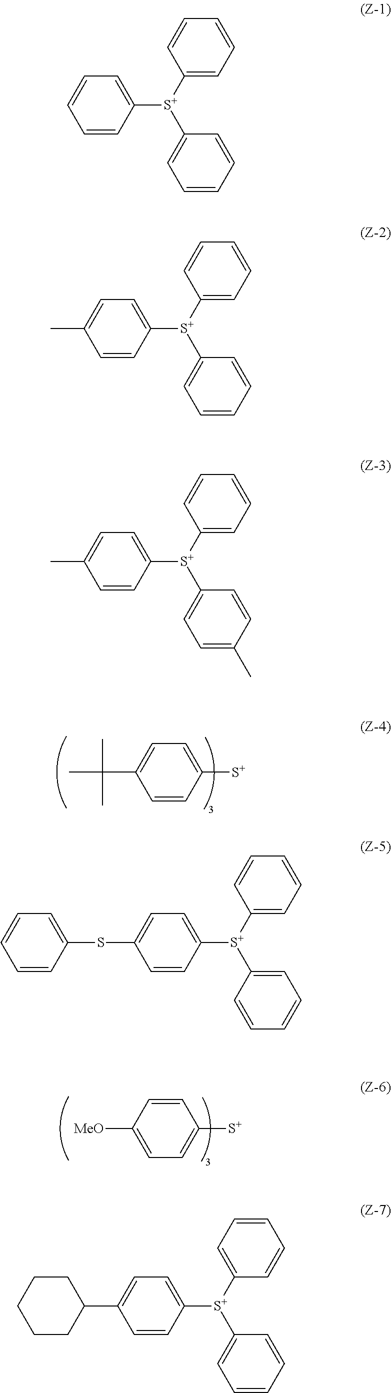

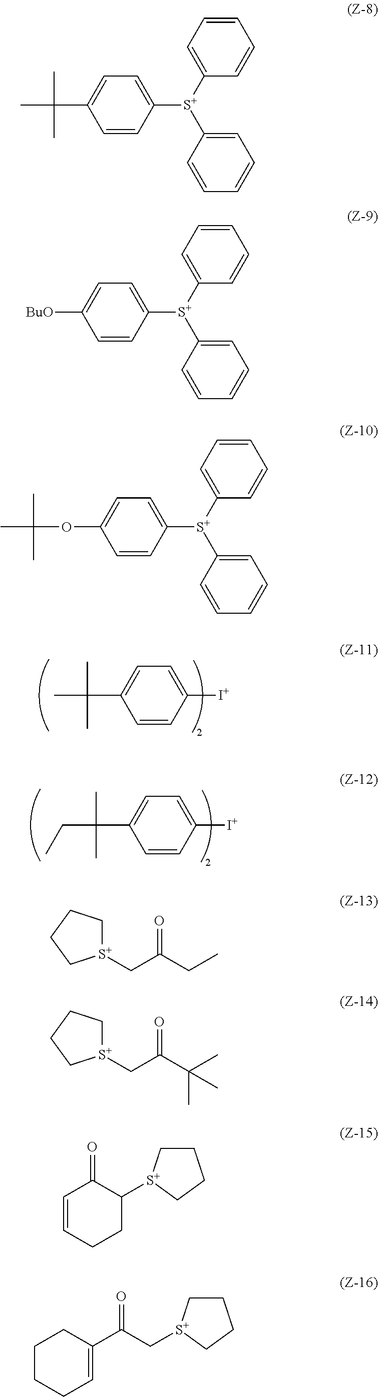

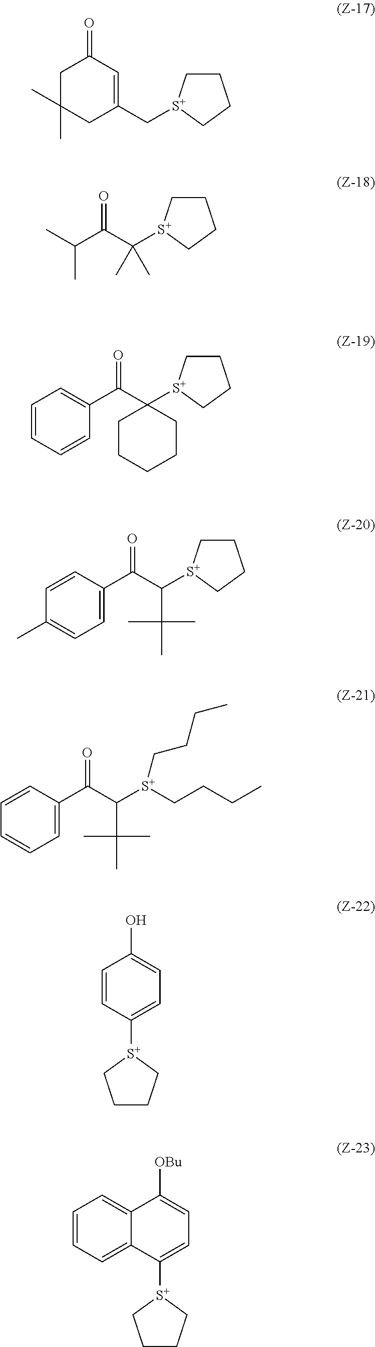

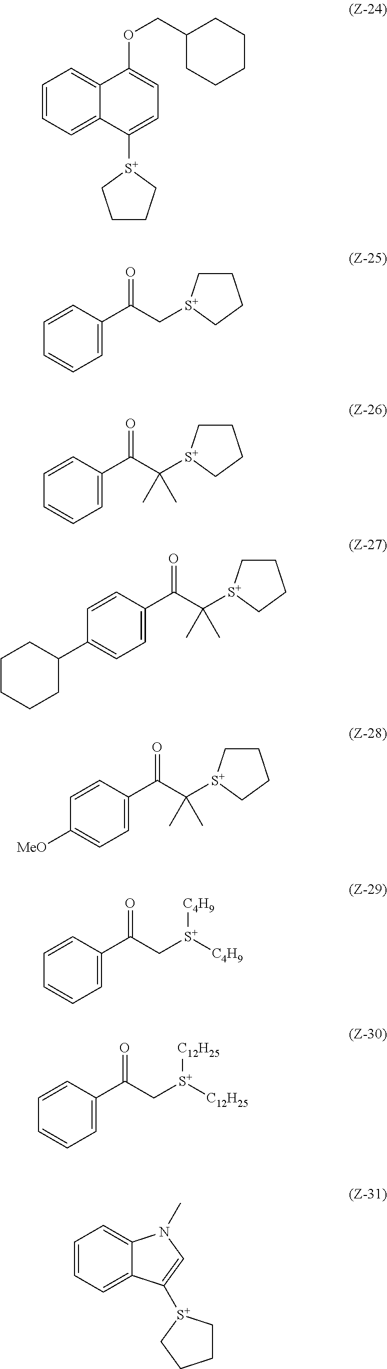

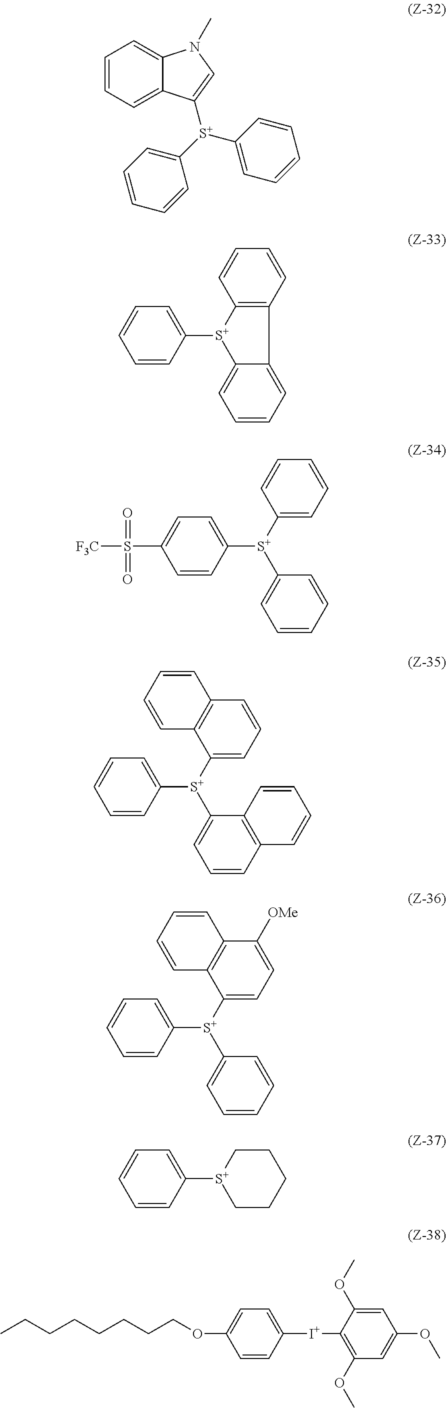

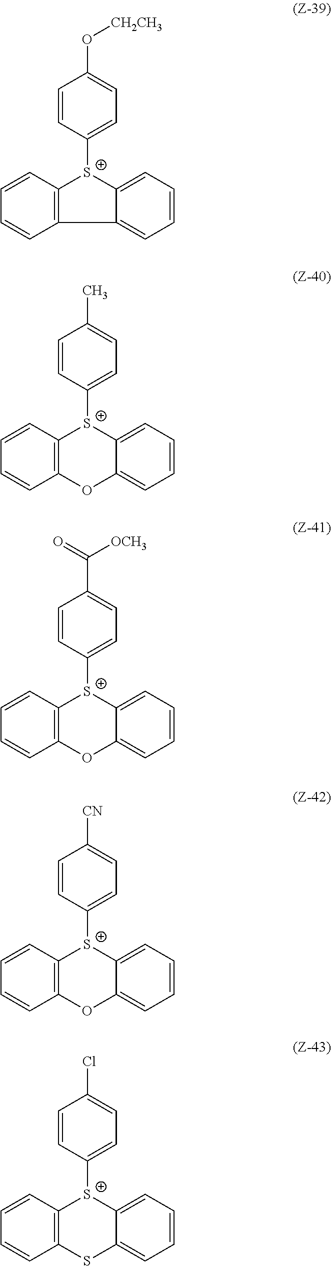

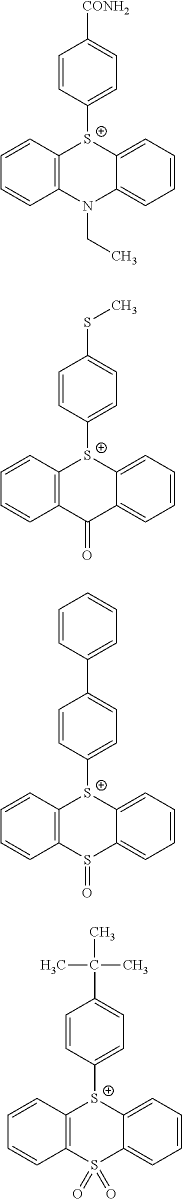

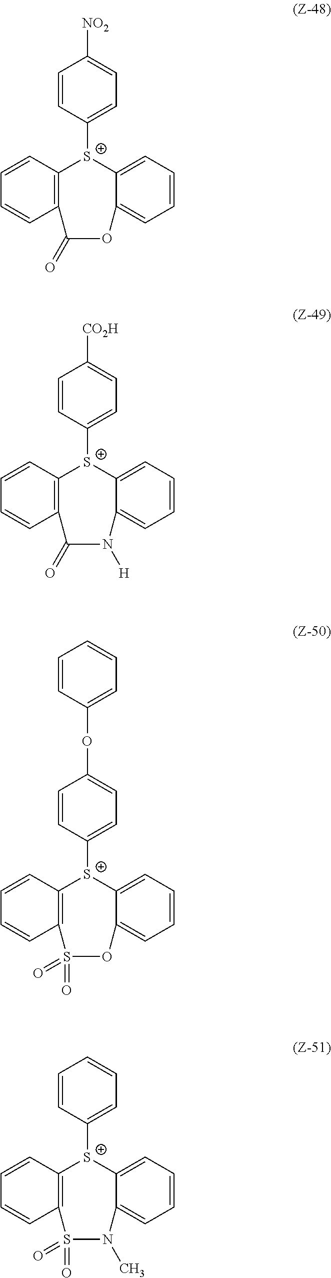

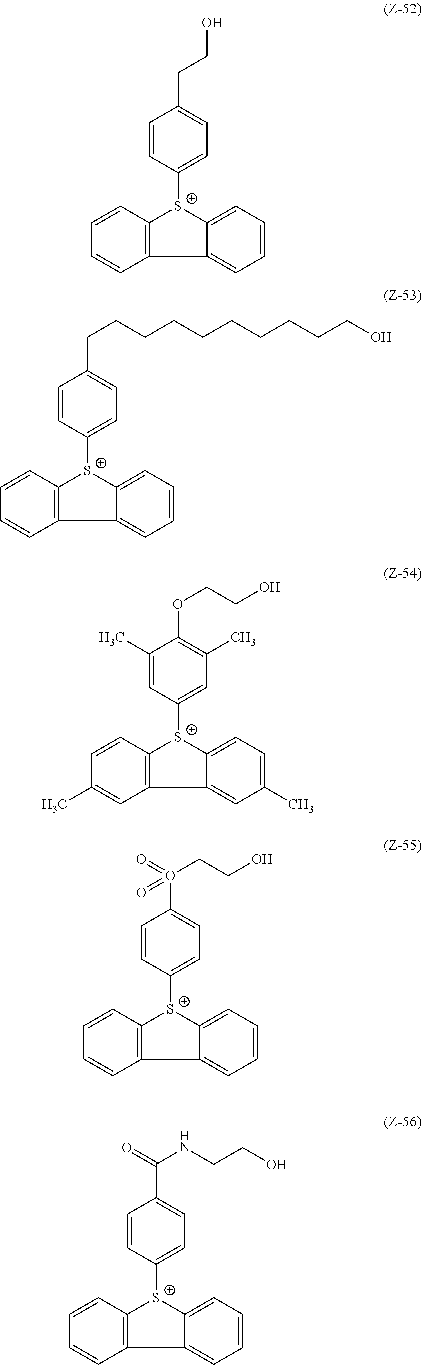

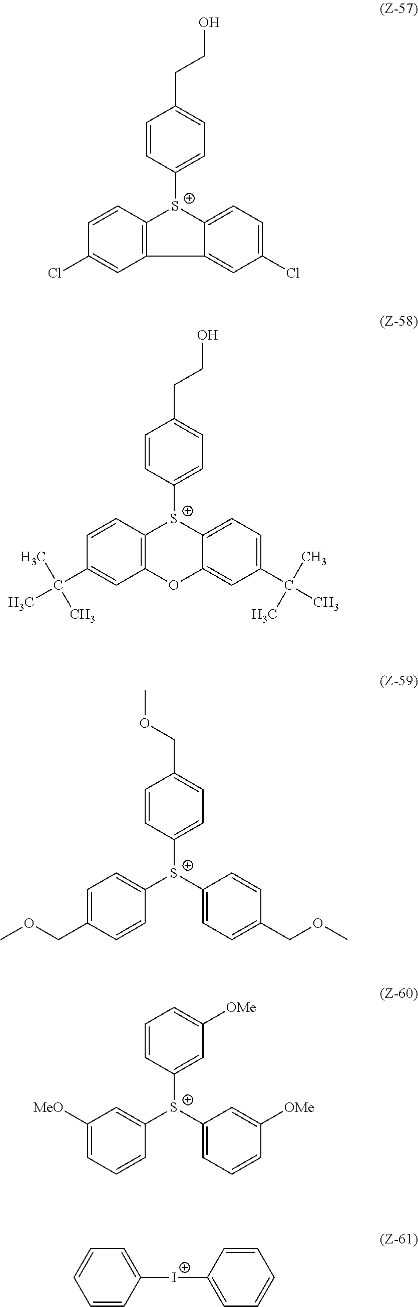

With respect to the repeating units of general formula (I), particular examples of monomers corresponding to acid anions formed by the leaving of cations when exposed to actinic rays or radiation are shown below.

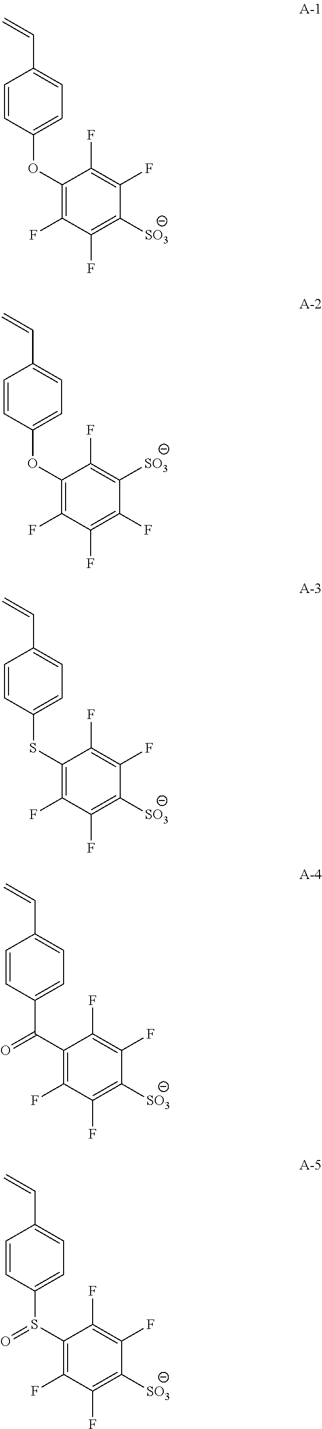

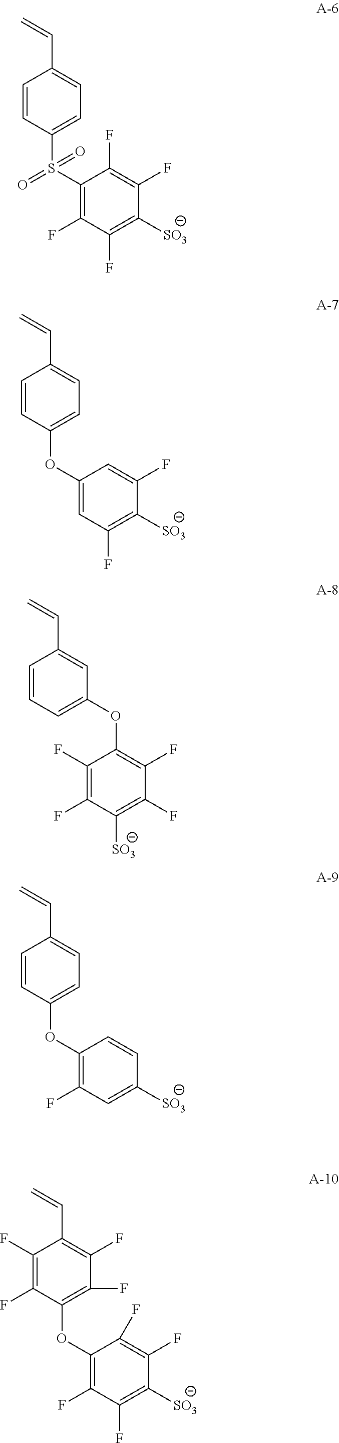

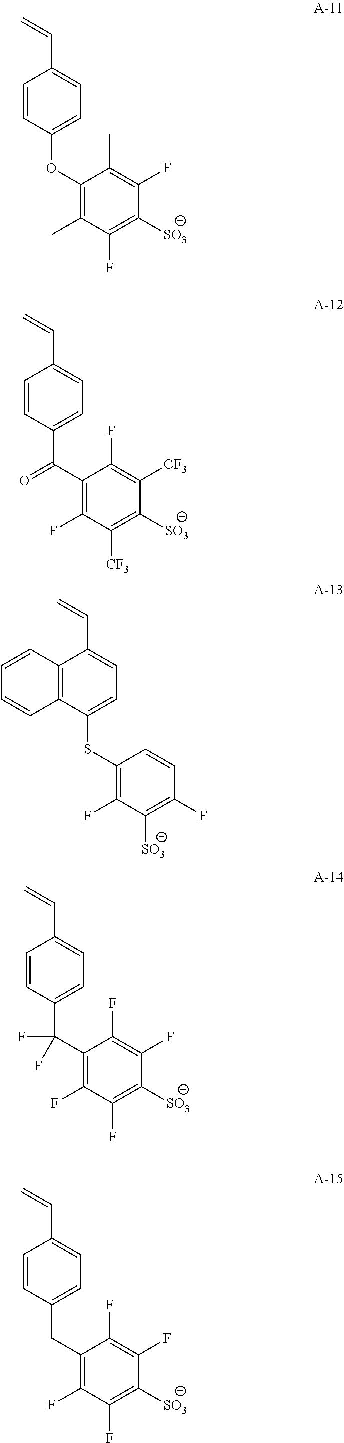

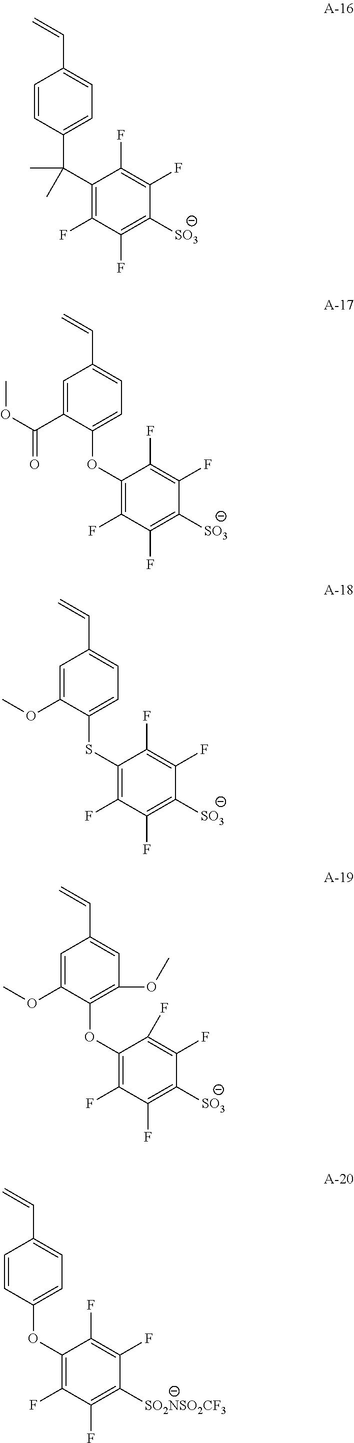

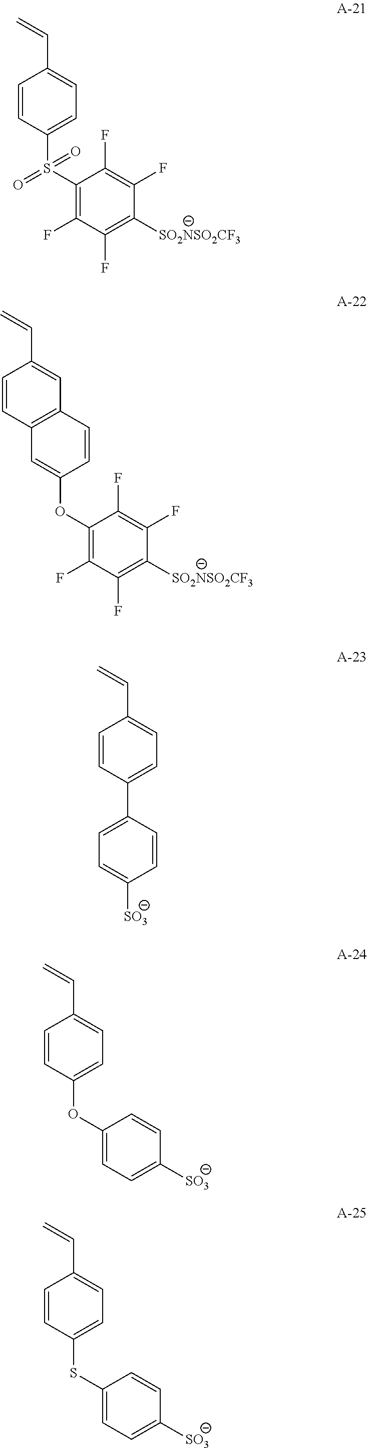

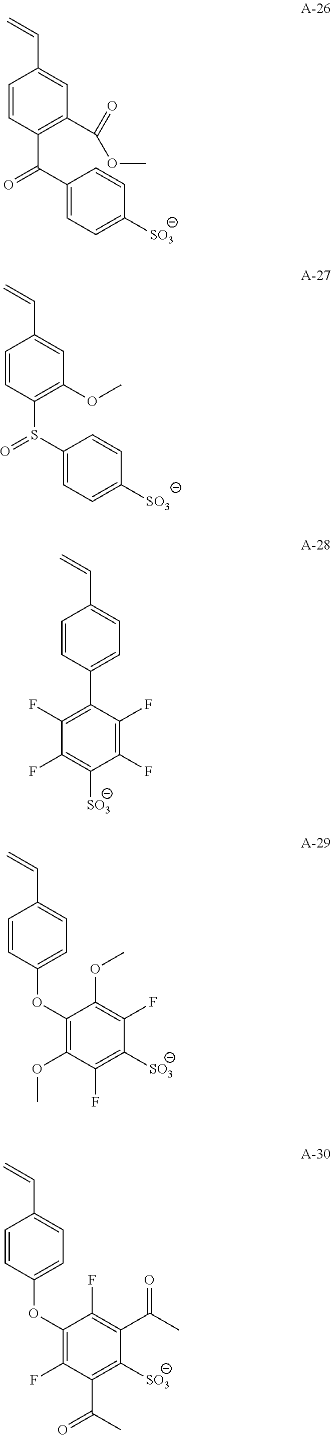

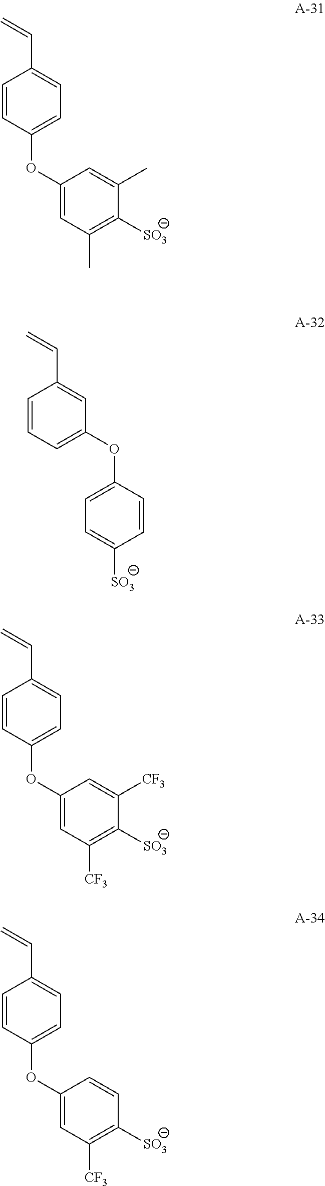

Table 1 below lists particular examples of the monomers corresponding to the repeating units (A) as combinations of a cation structure (any of structures (Z-1) to (Z-60) shown above by way of example) and an anion structure (any of structures (A-1) to (A-22) shown above by way of example).

TABLE 1

| Repeating | | |
|---|---|---|
| unit | Cation | Anion |
| (A) | structure | structure |
| M-001 | Z-1 | A-1 |
| M-002 | Z-8 | A-1 |
| M-003 | Z-11 | A-1 |
| M-004 | Z-26 | A-1 |
| M-005 | Z-27 | A-1 |
| M-006 | Z-33 | A-1 |
| M-007 | Z-38 | A-1 |
| M-008 | Z-52 | A-1 |
| M-009 | Z-55 | A-1 |
| M-010 | Z-56 | A-1 |
| M-011 | Z-59 | A-1 |
| M-012 | Z-60 | A-1 |
| M-013 | Z-1 | A-2 |
| M-014 | Z-2 | A-2 |
| M-015 | Z-4 | A-2 |
| M-016 | Z-6 | A-2 |
| M-017 | Z-15 | A-2 |
| M-018 | Z-29 | A-2 |
| M-019 | Z-37 | A-2 |
| M-020 | Z-45 | A-2 |
| M-021 | Z-60 | A-2 |
| M-022 | Z-1 | A-3 |
| M-023 | Z-2 | A-3 |
| M-024 | Z-16 | A-3 |
| M-025 | Z-22 | A-3 |
| M-026 | Z-33 | A-3 |
| M-027 | Z-37 | A-3 |
| M-028 | Z-38 | A-3 |
| M-029 | Z-40 | A-3 |
| M-030 | Z-44 | A-3 |
| M-031 | Z-53 | A-3 |
| M-032 | Z-57 | A-3 |
| M-033 | Z-59 | A-3 |
| M-034 | Z-60 | A-3 |
| M-035 | Z-1 | A-4 |
| M-036 | Z-4 | A-4 |
| M-037 | Z-11 | A-4 |
| M-038 | Z-27 | A-4 |
| M-039 | Z-33 | A-4 |
| M-040 | Z-38 | A-4 |
| M-041 | Z-40 | A-4 |
| M-042 | Z-52 | A-4 |
| M-043 | Z-60 | A-4 |
| M-044 | Z-1 | A-5 |
| M-045 | Z-12 | A-5 |
| M-046 | Z-24 | A-5 |
| M-047 | Z-33 | A-5 |
| M-048 | Z-38 | A-5 |
| M-049 | Z-52 | A-5 |
| M-050 | Z-60 | A-5 |
| M-051 | Z-18 | A-6 |
| M-052 | Z-31 | A-6 |
| M-053 | Z-47 | A-6 |
| M-054 | Z-1 | A-7 |
| M-055 | Z-8 | A-7 |
| M-056 | Z-23 | A-7 |
| M-057 | Z-38 | A-7 |
| M-058 | Z-55 | A-7 |
| M-059 | Z-1 | A-8 |
| M-060 | Z-3 | A-8 |
| M-061 | Z-16 | A-8 |
| M-062 | Z-28 | A-8 |
| M-063 | Z-1 | A-9 |
| M-064 | Z-6 | A-9 |
| M-065 | Z-32 | A-9 |
| M-066 | Z-46 | A-9 |
| M-067 | Z-1 | A-10 |
| M-068 | Z-2 | A-10 |
| M-069 | Z-12 | A-10 |
| M-070 | Z-27 | A-10 |
| M-071 | Z-38 | A-10 |
| M-072 | Z-39 | A-10 |
| M-073 | Z-59 | A-10 |
| M-074 | Z-60 | A-10 |
| M-075 | Z-1 | A-11 |
| M-076 | Z-19 | A-11 |
| M-077 | Z-4 | A-12 |
| M-078 | Z-49 | A-12 |
| M-079 | Z-7 | A-13 |
| M-080 | Z-33 | A-13 |
| M-081 | Z-41 | A-13 |
| M-082 | Z-9 | A-14 |
| M-083 | Z-48 | A-14 |
| M-084 | Z-13 | A-15 |
| M-085 | Z-29 | A-15 |
| M-086 | Z-23 | A-16 |
| M-087 | Z-36 | A-16 |
| M-088 | Z-1 | A-17 |
| M-089 | Z-26 | A-17 |
| M-090 | Z-2 | A-18 |
| M-091 | Z-43 | A-18 |
| M-092 | Z-4 | A-19 |
| M-093 | Z-32 | A-19 |
| M-094 | Z-57 | A-19 |
| M-095 | Z-1 | A-20 |
| M-096 | Z-25 | A-20 |
| M-097 | Z-5 | A-21 |
| M-098 | Z-49 | A-21 |
| M-099 | Z-8 | A-22 |
| M-100 | Z-29 | A-22 |
| M-101 | Z-43 | A-22 |
| M-102 | Z-59 | A-22 |
| M-103 | Z-1 | A-23 |
| M-104 | Z-11 | A-23 |
| M-105 | Z-2 | A-24 |
| M-106 | Z-24 | A-24 |
| M-107 | Z-1 | A-25 |
| M-108 | Z-2 | A-26 |
| M-109 | Z-47 | A-26 |
| M-110 | Z-7 | A-27 |
| M-111 | Z-33 | A-27 |
| M-112 | Z-1 | A-28 |
| M-113 | Z-2 | A-28 |
| M-114 | Z-4 | A-28 |
| M-115 | Z-7 | A-29 |
| M-116 | Z-1 | A-30 |
| M-117 | Z-13 | A-30 |
| M-118 | Z-28 | A-30 |
| M-119 | Z-4 | A-31 |
| M-120 | Z-26 | A-31 |
| M-121 | Z-37 | A-31 |
| M-122 | Z-1 | A-32 |
| M-123 | Z-23 | A-32 |
| M-124 | Z-38 | A-32 |
| M-125 | Z-46 | A-32 |
| M-126 | Z-1 | A-33 |
| M-127 | Z-22 | A-33 |
| M-128 | Z-30 | A-33 |
| M-129 | Z-52 | A-33 |
| M-130 | Z-2 | A-34 |
| M-131 | Z-12 | A-34 |

The content of repeating unit (A) in the resin (P), based on all the repeating units of the resin (P), is preferably in the range of 0.5 to 80 mol %, more preferably 1 to 60 mol % and further more preferably 3 to 40 mol %.

[Repeating Unit (B)]

It is preferred for the resin (P) to further comprise a repeating unit (B) containing a group that when acted on by an acid, is decomposed to thereby produce a polar group. The repeating unit (B) containing a group that when acted on by an acid, is decomposed to thereby produce a polar group can be a repeating unit exhibiting an increased solubility in an alkali developer, and also can be a repeating unit exhibiting a decreased solubility in an organic developer.

It is preferred for the group that when acted on by an acid, is decomposed to thereby produce a polar group (hereinafter also referred to as “acid-decomposable group”) to have a structure in which a polar group is protected by a group that when acted on by an acid, is decomposed to thereby leave therefrom.

The resin (P) in an aspect thereof is a resin whose polarity is changed under the action of an acid, in particular, being a resin that under the action of an acid, increases its solubility in an alkali developer, or decreases its solubility in a developer comprising an organic solvent.

As the polar group, there can be mentioned a phenolic hydroxyl group, a carboxyl group, a fluoroalcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

The polar group is preferably a carboxyl group, a fluoroalcohol group (especially a hexafluoroisopropanol group) or a sulfonic acid group.

The resin (P) in an aspect thereof preferably comprises any of repeating units of general formula (a) below as the repeating unit (B).

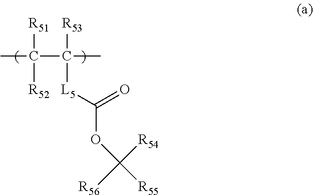

In general formula (a), each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group.

L₅ represents a single bond or a bivalent connecting group, provided that when a ring is formed in cooperation with R₅₂, L₅ represents a trivalent connecting group.

R₅₄ represents an alkyl group. Each of R₅₅ and R₅₆ independently represents a hydrogen atom, an alkyl group, a cycloalkyl group or a monovalent aromatic ring group. R₅₅ and R₅₆ may be bonded to each other to thereby form a ring. In no event, R₅₅ and R₅₆ are simultaneously hydrogen atoms.

General formula (a) will be described in greater detail below.

As a preferred alkyl group represented by each of R₅₁, R₅₂ and R₅₃ in general formula (a), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred, and an alkyl group having up to 3 carbon atoms is most preferred.

The alkyl group contained in the alkoxycarbonyl group is preferably the same as that represented by each of R₅₁ to R₅₃ above.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is most preferred.

As preferred substituents that can be introduced in these groups, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

When R₅₂ is an alkylene group and is bonded to L₅ to thereby form a ring, the alkylene group is preferably an alkylene group having 1 to 8 carbon atoms, such as a methylene group, an ethylene group, a propylene group, a butylene group, a hexylene group or an octylene group. An alkylene group having 1 to 4 carbon atoms is more preferred, and an alkylene group having 1 or 2 carbon atoms is most preferred. The ring formed by the mutual bonding of R₅₂ and L₅ is most preferably a 5- or 6-membered ring.

In formula (a), each of R₅₁ and R₅₃ is preferably a hydrogen atom, an alkyl group or a halogen atom, most preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is preferably a hydrogen atom, an alkyl group, a halogen atom or an alkylene group (forming a ring in cooperation with L₅), most preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring in cooperation with L₅) or an ethylene group (forming a ring in cooperation with L₅).

As the bivalent connecting group represented by L₅, there can be mentioned an alkylene group, a bivalent aromatic ring group, —COO-L₁-, —O-L₁-, -L₁-O—, a group comprised of a combination of two or more thereof, or the like. In the formulae, L₁ represents an alkylene group, a cycloalkylene group, a bivalent aromatic ring group, a group comprised of an alkylene group combined with a bivalent aromatic ring group, or a group comprised of an alkylene group combined with —O—. Substituents, such as a fluorine atom, may further be introduced in these groups.

L₅ is preferably a single bond, any of the groups of the formula —COO-L₁-(L₁ is preferably an alkylene group having 1 to 5 carbon atoms, more preferably a methylene group or a propylene group) or a bivalent aromatic ring group.

The alkyl group represented by each of R₅₄ to R₅₆ is preferably one having 1 to 20 carbon atoms, more preferably one having 1 to 10 carbon atoms and most preferably one having 1 to 4 carbon atoms, such as a methyl group, an ethyl group, an n-propyl group, an isopropyl group, an n-butyl group, an isobutyl group or a t-butyl group.

The cycloalkyl group represented by each of R₅₅ and R₅₆ is preferably one having 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group.

The ring formed by the mutual bonding of R₅₅ and R₅₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅₅ and R₅₆ are bonded to each other to thereby form a ring, R₅₄ is preferably an alkyl group having 1 to 3 carbon atoms, more preferably a methyl group or an ethyl group.

The monovalent aromatic ring group represented by each of R₅₅ and R₅₆ is preferably one having 6 to 20 carbon atoms. As such, there can be mentioned, for example, a phenyl group, a naphthyl group or the like. When either R₅₅ or R₅₆ is a hydrogen atom, it is preferred for the other to be a monovalent aromatic ring group.

As the method of synthesizing the monomers corresponding to the repeating units of general formula (a), use can be made of a routine process for synthesizing esters containing a polymerizable group. The method is not particularly limited.

Particular examples of the repeating units of general formula (a) are shown below, which in no way limit the scope of the present invention.

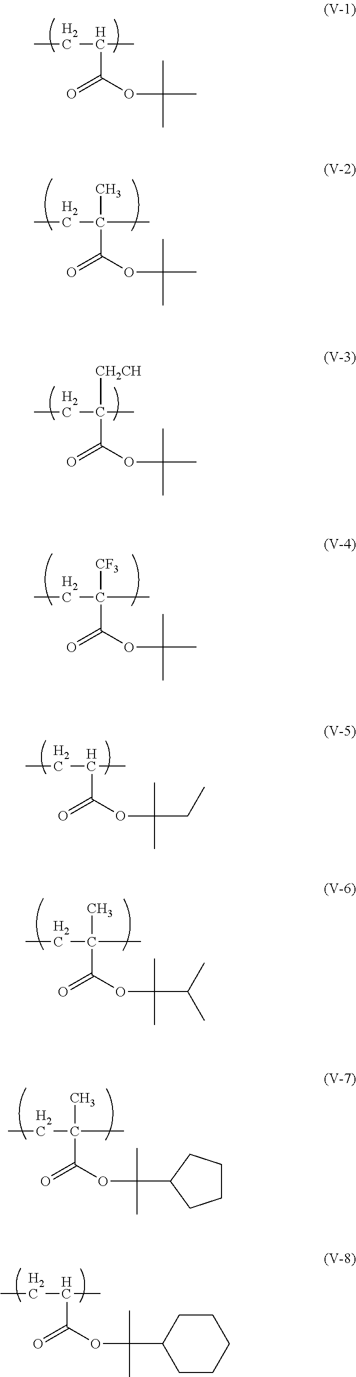

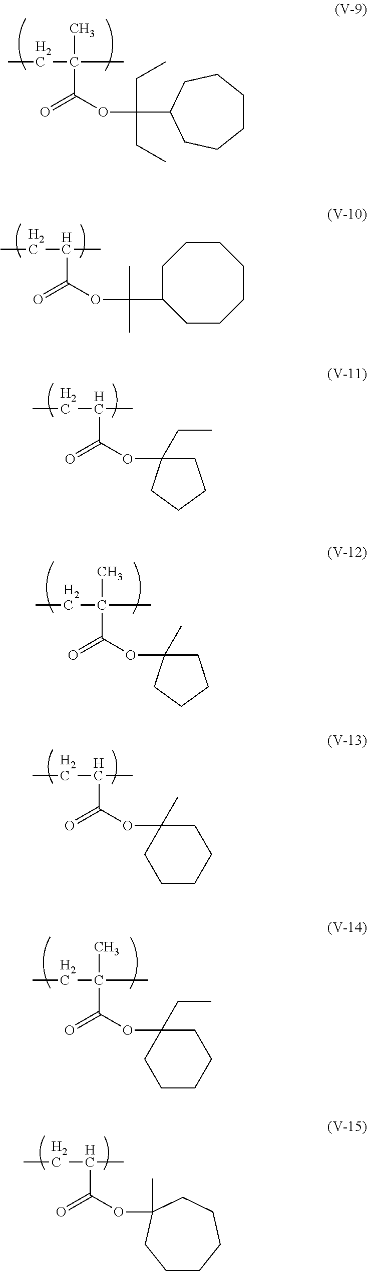

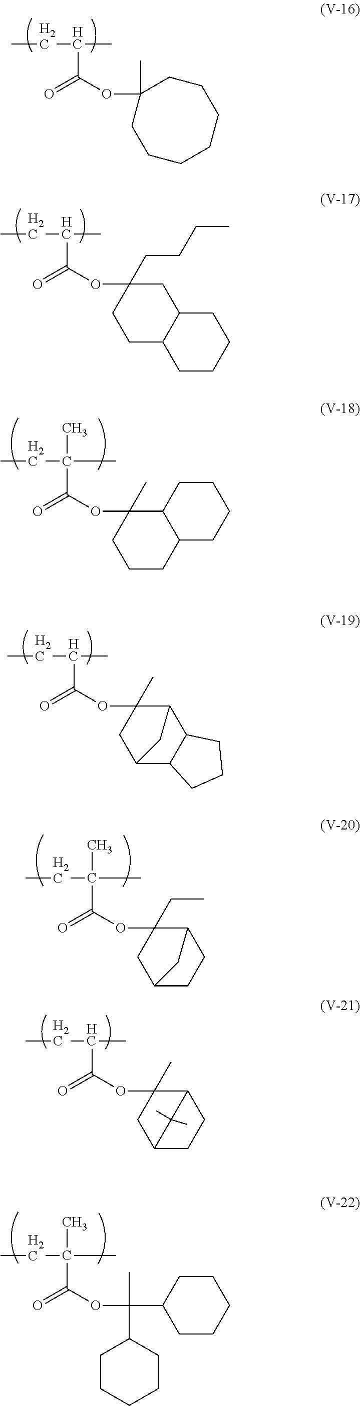

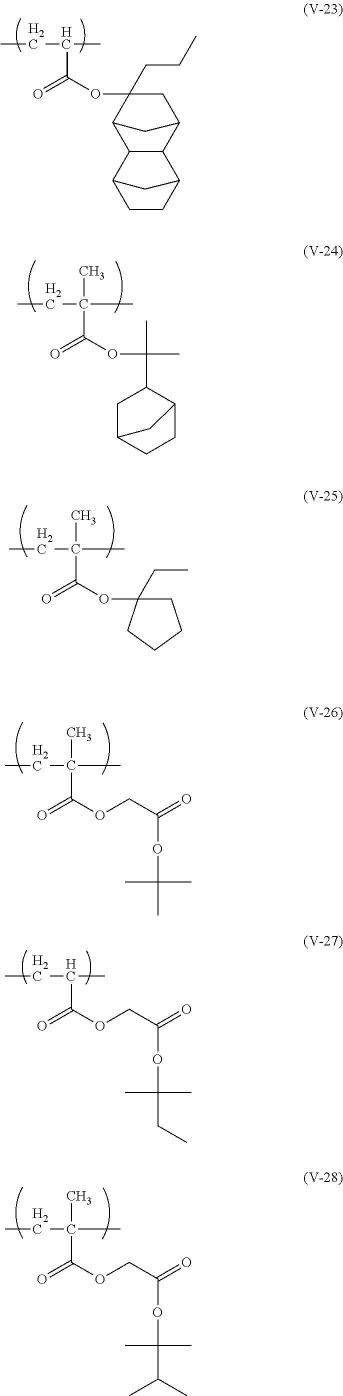

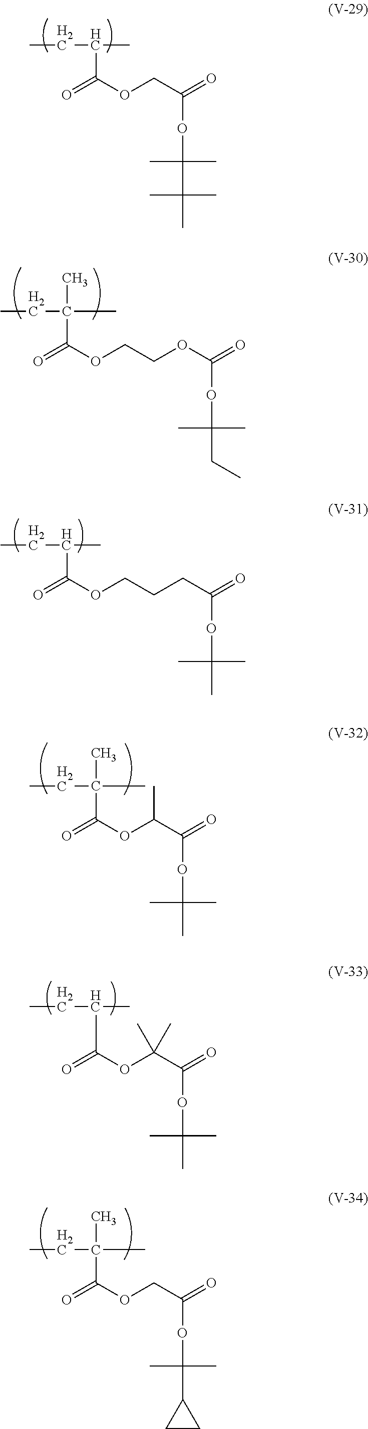

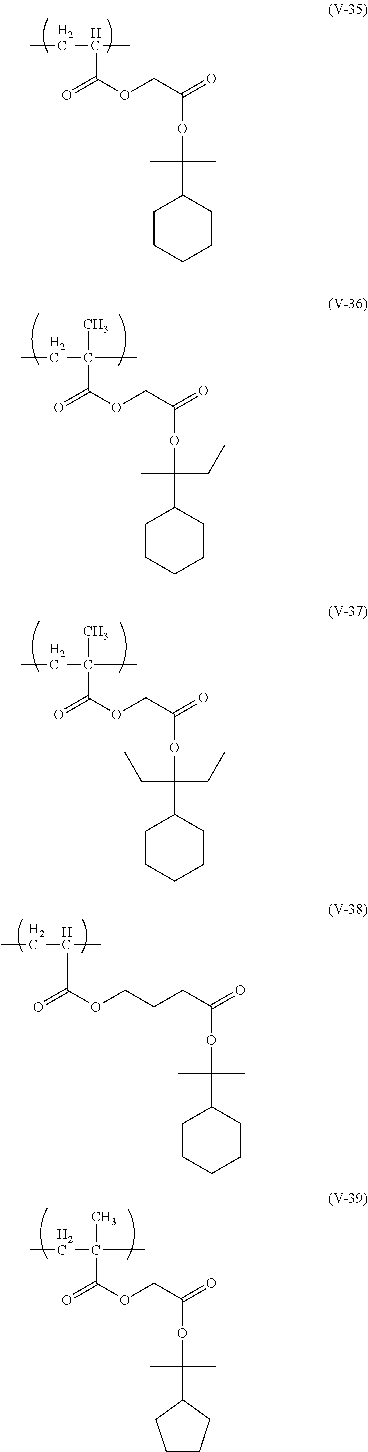

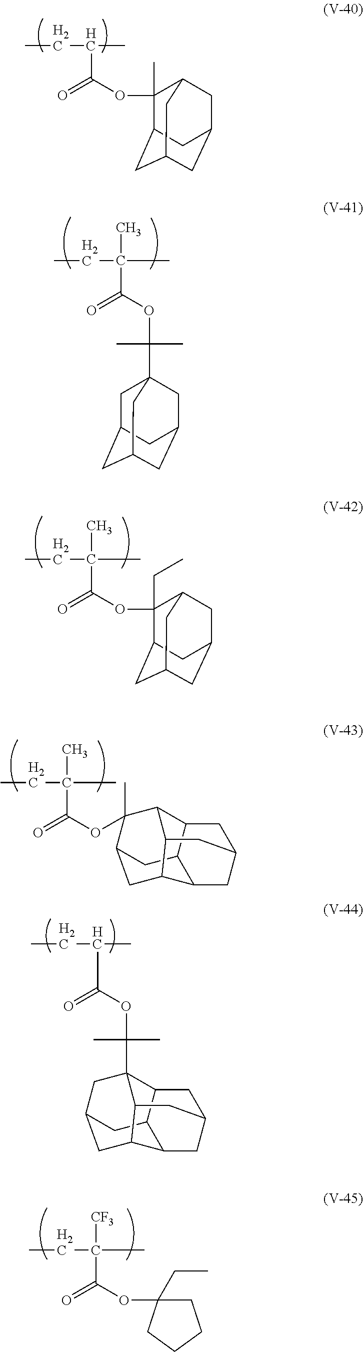

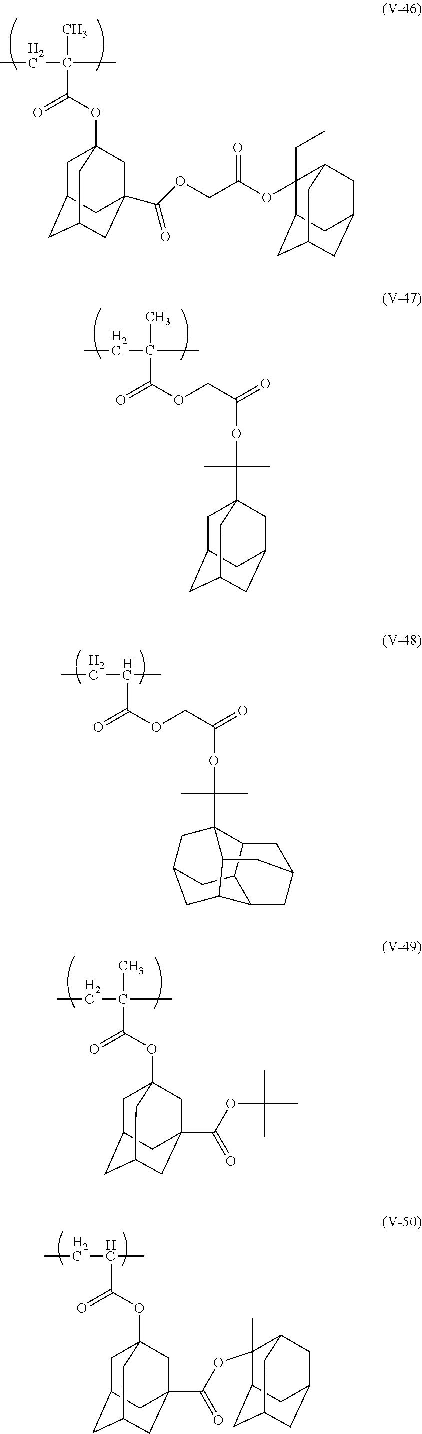

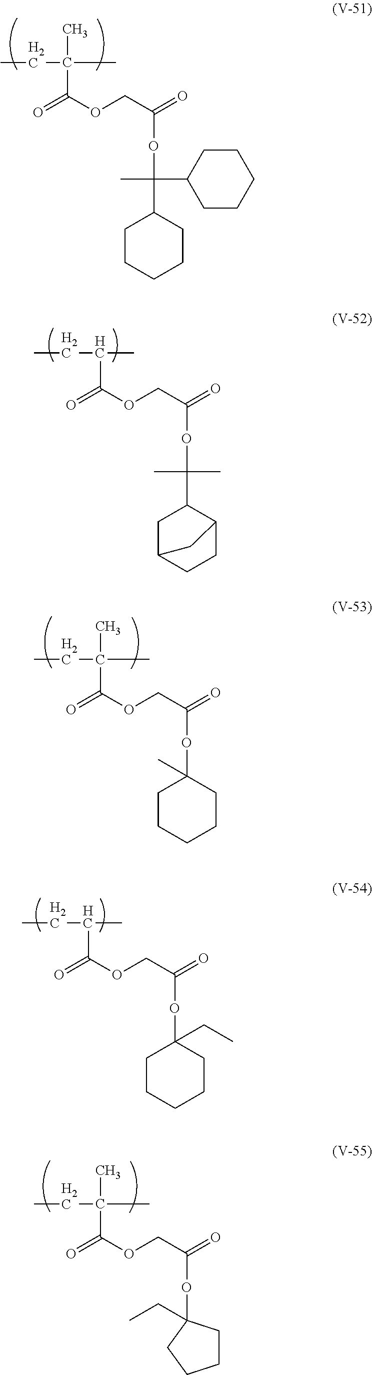

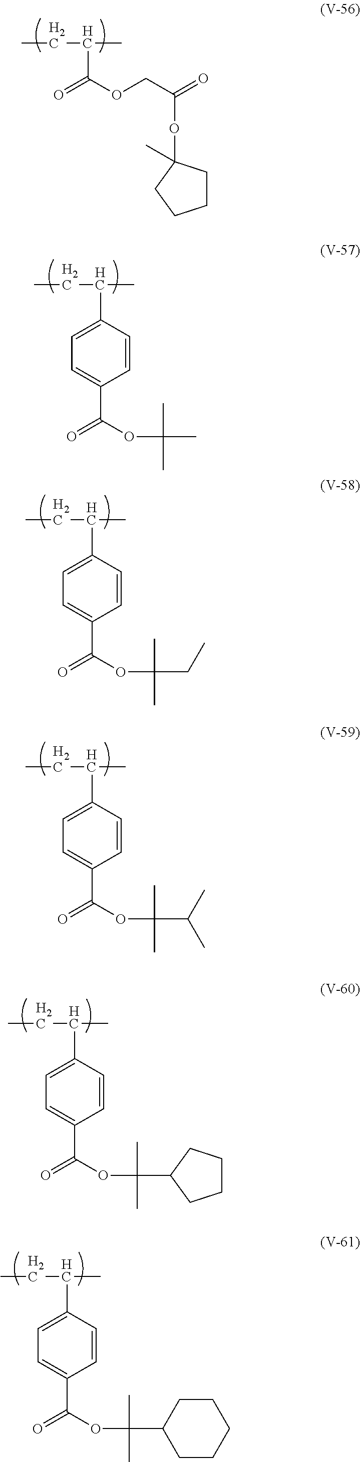

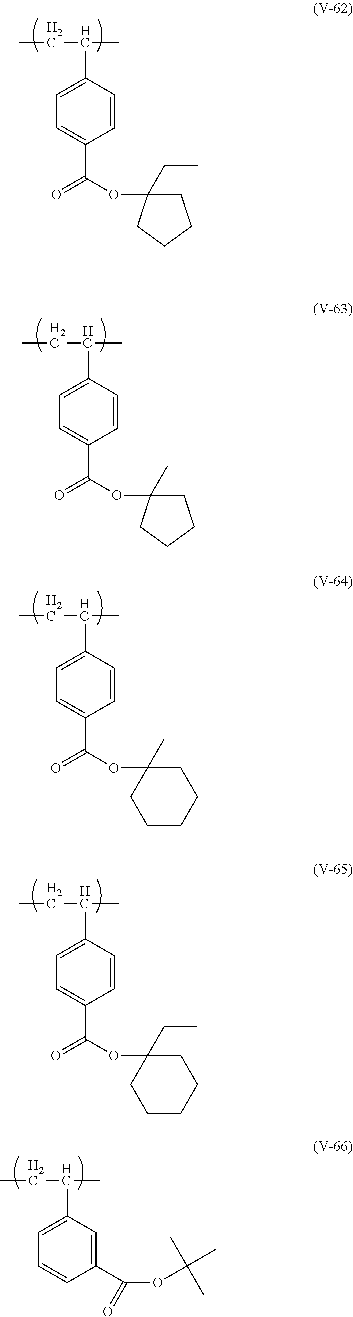

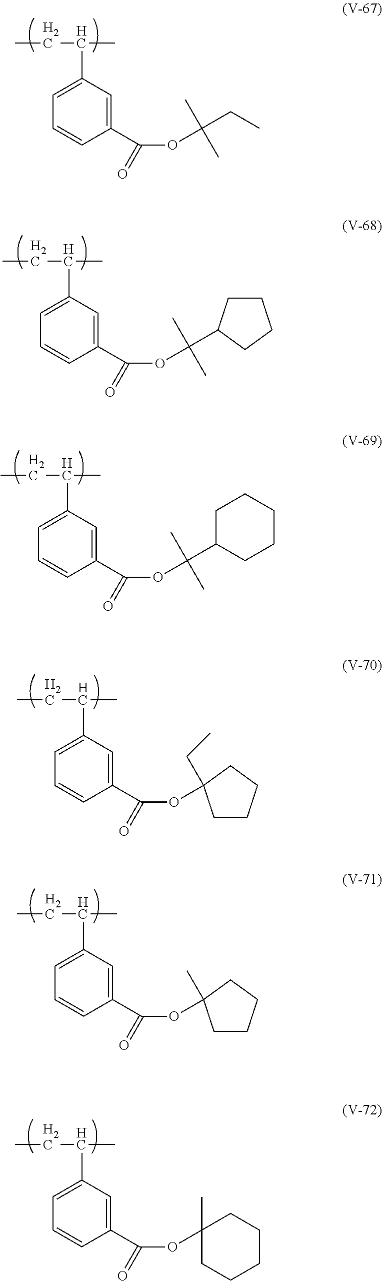

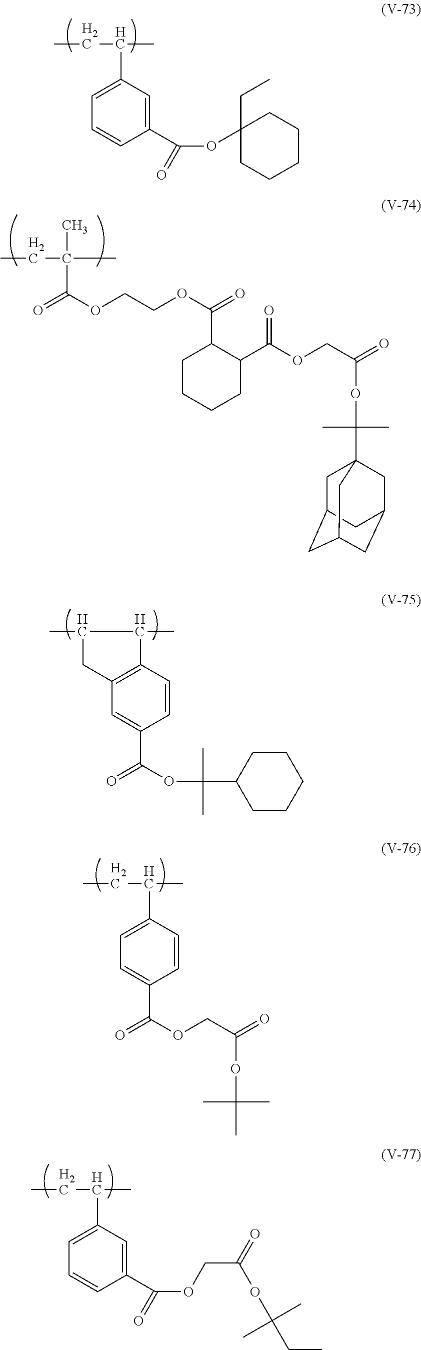

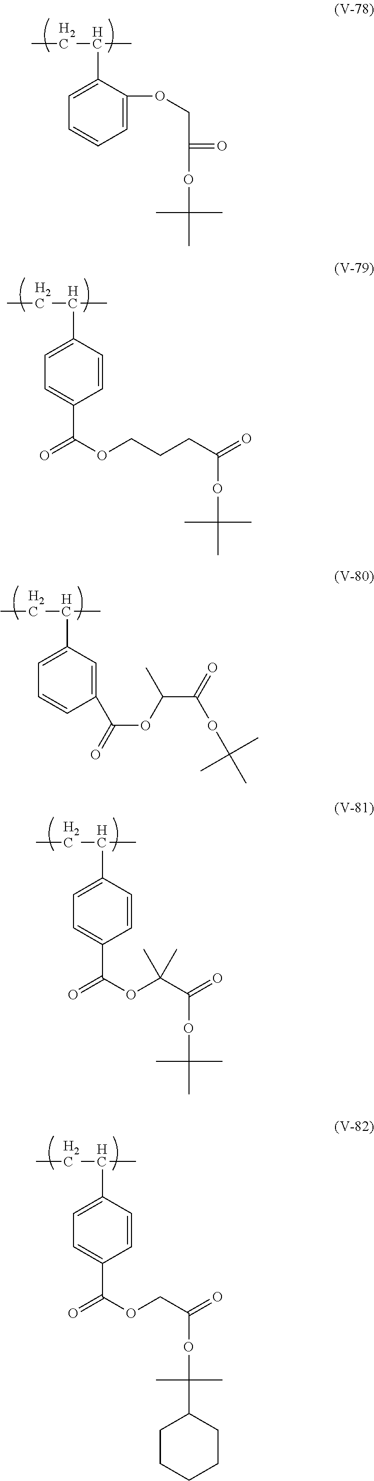

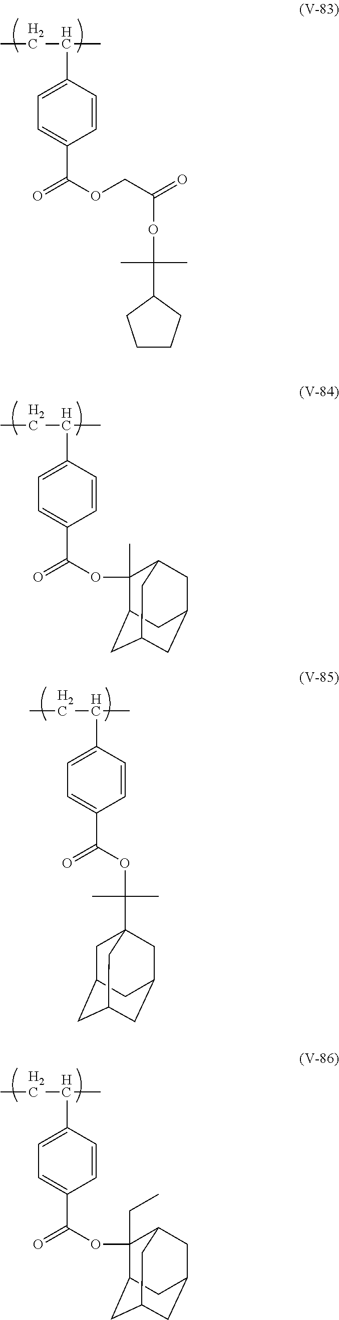

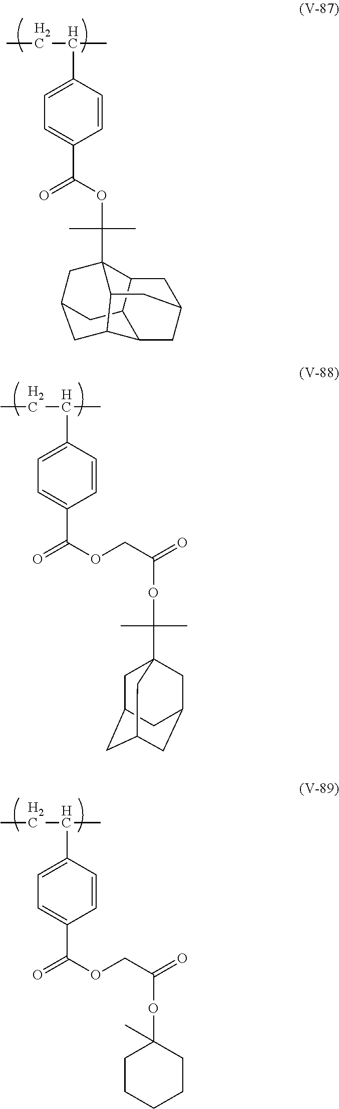

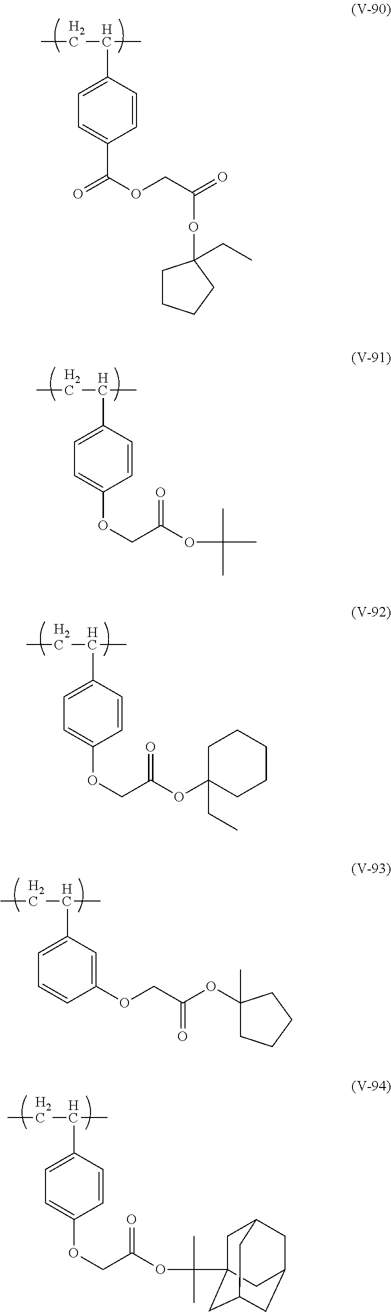

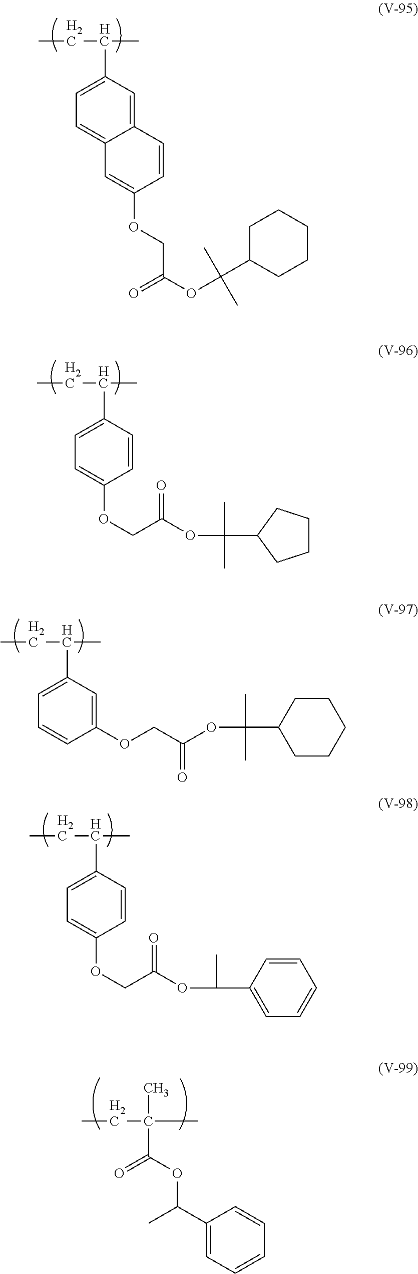

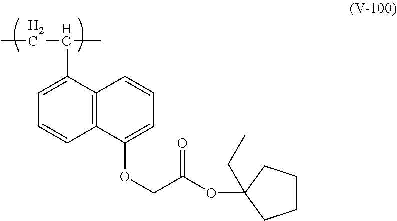

The resin (P) in another aspect thereof preferably comprises any of repeating units of general formula (II) below as the repeating unit (B).

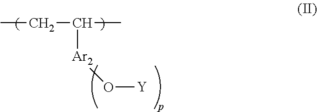

In general formula (II),

Ar² represents a (p+1)-valent aromatic ring group.

Y represents a hydrogen atom or a group leaving when acted on by an acid, provided that when there are a plurality of Y's, the plurality of Y's may be identical to or different from each other, and that at least one Y is a group leaving when acted on by an acid; and

p is an integer of 1 or greater.

When p is 1, as preferred examples of the bivalent aromatic ring groups represented by Ar², there can be mentioned an arylene group having 6 to 18 carbon atoms, such as a phenylene group, a tolylene group or a naphthylene group, and a bivalent aromatic ring group containing a heteroring, such as thiophene, furan, pyrrole, benzothiophene, benzofuran, benzopyrrole, triazine, imidazole, benzimidazole, triazole, thiadiazole or triazole.

Substituents may be introduced in the (p+1)-valent aromatic ring groups represented by Ar² in general formula (II). As such substituents, there can be mentioned, for example, a hydroxyl group; a halogen atom (a fluorine atom, a chlorine atom, a bromine atom or an iodine atom; a nitro group; a cyano group; an amido group; a sulfonamido group; an alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group; a cycloalkyl group having 3 to 17 carbon atoms, such as a cyclopentyl group, a cyclohexyl group, a norbornyl group or an adamantyl group; an alkoxy group, such as a methoxy group, an ethoxy group, a hydroxyethoxy group, a propoxy group, a hydroxypropoxy group or a butoxy group; an alkoxycarbonyl group, such as a methoxycarbonyl group or an ethoxycarbonyl group; an acyl group, such as a formyl group, an acetyl group or a benzoyl group; an acyloxy group, such as an acetoxy group or a butyryloxy group; and a carboxyl group.

As particular examples of the (p+1)-valent aromatic ring groups represented by Ar² in which p is an integer of 2 or greater, there can be mentioned groups resulting from the removal of (p−1) arbitrary hydrogen atoms from each of the above-mentioned particular examples of bivalent aromatic ring groups.

In the formula, p is an integer of 1 or greater, preferably 1 to 5, more preferably 1 or 2 and most preferably 1.

In each of the repeating units of general formula (II), when Ar² is a phenylene group, the position of bonding of the group of the formula —O—Y to the benzene ring of Ar² may be any of the para-, meta- and ortho-positions to the site of bonding of the benzene ring to the principal chain of the polymer. However, the para- or meta-position is preferred, and the para-position is most preferred.

As the group leaving when acted on by an acid, Y, there can be mentioned, for example, any of the groups of the formulae —C(R₃₆)(R₃₇)(R₃₈), —C(═O)—O—C(R₃₆) (R₃₇) (R₃₈), —C(R₀₁)(R₀₂)(OR₃₉), —C(R₀₁)(R₀₂)—C(═O)—O—C(R₃₆)(R₃₇)(R₃₈) and —CH(R₃₆)(Ar).

In the formulae, each of R₃₆ to R₃₉ independently represents an alkyl group, a cycloalkyl group, an aryl group, an aralkyl group or an alkenyl group. R₃₆ and R₃₇ may be bonded to each other to thereby form a ring structure.

Each of R₀₁ and R₀₂ independently represents a hydrogen atom, an alkyl group, a cycloalkyl group, an aryl group, an aralkyl group or an alkenyl group.

Ar represents an aryl group.

Each of the alkyl groups represented by R₃₆ to R₃₉, R₀₁ and R₀₂ preferably has 1 to 8 carbon atoms. For example, there can be mentioned a methyl group, an ethyl group, a propyl group, an n-butyl group, a sec-butyl group, a hexyl group or an octyl group.

Each of the cycloalkyl groups represented by R₃₆ to R₃₉, R₀₁ and R₀₂ may be monocyclic or polycyclic. When the cycloalkyl group is monocyclic, it is preferably a cycloalkyl group having 3 to 8 carbon atoms. As such, there can be mentioned, for example, a cyclopropyl group, a cyclobutyl group, a cyclopentyl group, a cyclohexyl group or a cyclooctyl group. When the cycloalkyl group is polycyclic, it is preferably a cycloalkyl group having 6 to 20 carbon atoms. As such, there can be mentioned, for example, an adamantyl group, a norbornyl group, an isobornyl group, a camphonyl group, a dicyclopentyl group, an α-pinanyl group, a tricyclodecanyl group, a tetracyclododecyl group or an androstanyl group. With respect to these, the carbon atoms of each of the cycloalkyl groups may be partially replaced with a heteroatom, such as an oxygen atom.

Each of the aryl groups represented by R₃₆ to R₃₉, R₀₁, R₀₂ and Ar is preferably one having 6 to 10 carbon atoms. For example, there can be mentioned a phenyl group, a naphthyl group or an anthryl group.

Each of the aralkyl groups represented by R₃₆ to R₃₉, R₀₁ and R₀₂ is preferably an aralkyl group having 7 to 12 carbon atoms. Preferred aralkyl groups are, for example, a benzyl group, a phenethyl group and a naphthylmethyl group.

Each of the alkenyl groups represented by R₃₆ to R₃₉, R₀₁ and R₀₂ is preferably one having 2 to 8 carbon atoms. For example, there can be mentioned a vinyl group, an allyl group, a butenyl group or a cyclohexenyl group.

The ring formed by the mutual bonding of R₃₆ and R₃₇ may be monocyclic or polycyclic. The monocyclic structure is preferably a cycloalkane structure having 3 to 8 carbon atoms. As such, there can be mentioned, for example, a cyclopropane structure, a cyclobutane structure, a cyclopentane structure, a cyclohexane structure, a cycloheptane structure or a cyclooctane structure. The polycyclic structure is preferably a cycloalkane structure having 6 to 20 carbon atoms. As such, there can be mentioned, for example, an adamantane structure, a norbornane structure, a dicyclopentane structure, a tricyclodecane structure or a tetracyclododecane structure. With respect to these, the carbon atoms of each of the cyclic structures may be partially replaced with a heteroatom, such as an oxygen atom.

Substituents may be introduced in these groups. As the substituents, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group and a nitro group. Preferably, the number of carbon atoms of each of these substituents is up to 8.

More preferably, the group leaving when acted on by an acid, Y, has any of the structures of general formula (V) below.

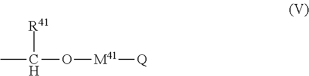

In general formula (V), R⁴¹ represents a hydrogen atom, an alkyl group, a cycloalkyl group, an aryl group or an aralkyl group.

M⁴¹ represents a single bond or a bivalent connecting group.

Q represents an alkyl group, an alicyclic group optionally containing a heteroatom or an aromatic ring group optionally containing a heteroatom.

At least two of R⁴¹, M⁴¹ and Q may be bonded to each other to thereby form a ring. It is preferred for the formed ring to be a 5- or 6-membered ring.

The alkyl group represented by R⁴¹ is, for example, an alkyl group having 1 to 8 carbon atoms. As preferred examples thereof, there can be mentioned a methyl group, an ethyl group, a propyl group, an isopropyl group, an n-butyl group, a sec-butyl group, a tert-butyl group, a hexyl group and an octyl group.

A substituent may be introduced in the alkyl group represented by R⁴¹. As the substituent, there can be mentioned, for example, a cyano group, a halogen atom, a hydroxyl group, an alkoxy group, a carboxyl group, an alkoxycarbonyl group or a cycloalkyl group.

The cycloalkyl group represented by R⁴¹ is, for example, a cycloalkyl group having 3 to 15 carbon atoms. As preferred examples thereof, there can be mentioned a cyclohexyl group, a norbornyl group and an adamantyl group.

The aryl group represented by R⁴¹ is, for example, an aryl group having 6 to 15 carbon atoms. As preferred examples thereof, there can be mentioned a phenyl group, a tolyl group, a naphthyl group and an anthryl group.

The aralkyl group represented by R⁴¹ is, for example, an aralkyl group having 6 to 20 carbon atoms. As preferred examples thereof, there can be mentioned a benzyl group and a phenethyl group.

R⁴¹ is preferably a hydrogen atom, a methyl group, an isopropyl group, a tert-butyl group, a cyclohexyl group, an adamantyl group, a phenyl group or a benzyl group, more preferably a methyl group or an adamantyl group.

The bivalent connecting group represented by M⁴¹ is preferably, for example, an alkylene group (preferably one having 1 to 8 carbon atoms, e.g., a methylene group, an ethylene group, a propylene group, a butylene group, a hexylene group or an octylene group), a cycloalkylene group (preferably one having 3 to 15 carbon atoms, e.g., a cyclopentylene group or a cyclohexylene group), —S—, —O—, —CO—, —CS—, —SO₂—, —N(R₀)— or a combination of two or more of these having up to 20 carbon atoms in total. R₀ represents a hydrogen atom or an alkyl group (for example, an alkyl group having 1 to 8 carbon atoms; for example, a methyl group, an ethyl group, a propyl group, an n-butyl group, a sec-butyl group, a hexyl group, an octyl group or the like).

M⁴¹ is preferably a single bond, an alkylene group, or a bivalent connecting group comprised of an alkylene group combined with at least one of —O—, —CO—, —CS— and —N(R₀)—; more preferably a single bond, an alkylene group, or a bivalent connecting group comprised of an alkylene group combined with —O—. R₀ is as defined above.

The alkyl group represented by Q is, for example, the same as set forth above in connection with R⁴¹.

As the alicyclic group and aromatic ring group represented by Q, there can be mentioned, for example, the cycloalkyl group and aryl group set forth above as being represented by R⁴¹. Each thereof preferably has 3 to 18 carbon atoms. In the present invention, a group (for example, a biphenyl group or a terphenyl group) comprised of a plurality of aromatic rings connected to each other through a single bond is also included in the aromatic ring groups represented by Q.

As the alicyclic group containing a heteroatom and aromatic ring group containing a heteroatom, there can be mentioned, for example, thiirane, cyclothiorane, thiophene, furan, pyrrole, benzothiophene, benzofuran, benzopyrrole, triazine, imidazole, benzimidazole, triazole, thiadiazole, triazole and pyrrolidone. In the present invention, a group (for example, a viologen group) comprised of a plurality of “aromatic rings each containing a heteroatom” connected to each other through a single bond is also included in the aromatic ring groups represented by Q.

Substituents may be introduced in the alicyclic group and aromatic ring group represented by Q. As the substituents, there can be mentioned, for example, an alkyl group, a cycloalkyl group, a cyano group, a halogen atom, a hydroxyl group, an alkoxy group, a carboxyl group and an alkoxycarbonyl group.

It is especially preferred for (-M⁴¹-Q) to be a methyl group, an ethyl group, a cyclohexyl group, a norbornyl group, an aryloxyethyl group, a cyclohexylethyl group or an arylethyl group.

As an instance in which a ring is formed by the mutual bonding of at least two of R⁴¹, M⁴¹ and Q, there can be mentioned, for example, one in which either M⁴¹ or Q is bonded to R⁴¹ to thereby form a propylene group or a butylene group, followed by formation of a 5-membered or 6-membered ring containing an oxygen atom.

When Nc denoting the sum of carbons of R⁴¹, M⁴¹ and Q is large, the resin (P) exhibits a large change of alkali dissolution rate between before and after the leaving of any of groups of general formula (V), thereby favorably realizing an enhancement of dissolution contrast. Nc is preferably in the range of 4 to 30, more preferably 7 to 25 and most preferably 7 to 20. It is preferred for Nc to be up to 30 from the viewpoint that lowering of the glass transition temperature of the resin (P) can be inhibited to thereby inhibit not only deterioration of the exposure latitude (EL) of the resist but also remaining of any residue resulting from the leaving of groups of general formula (V) on the resist pattern as a defect.

From the viewpoint of dry etching resistance, it is preferred for at least one of R⁴¹, M⁴¹ and Q to contain an alicycle or an aromatic ring. The alicyclic group and aromatic ring group are, for example, the same as set forth above in connection with Q.

Nonlimiting particular examples of the repeating units of general formula (II) are shown below.

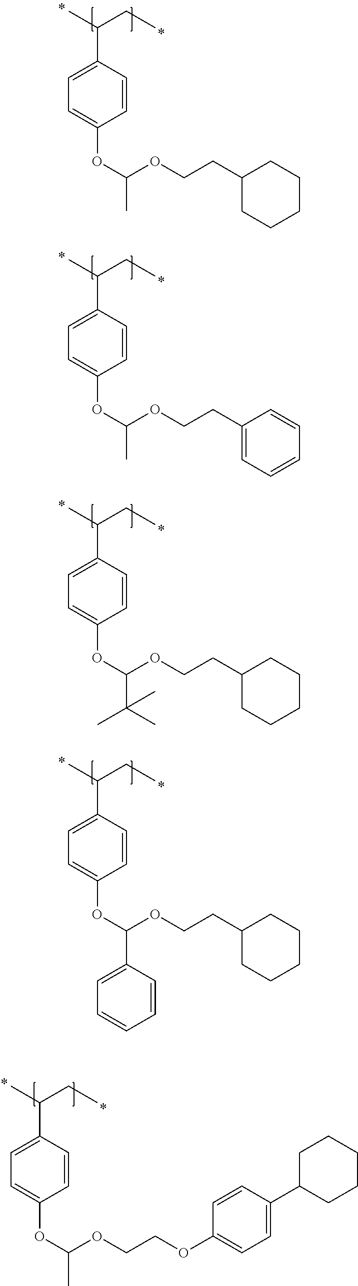

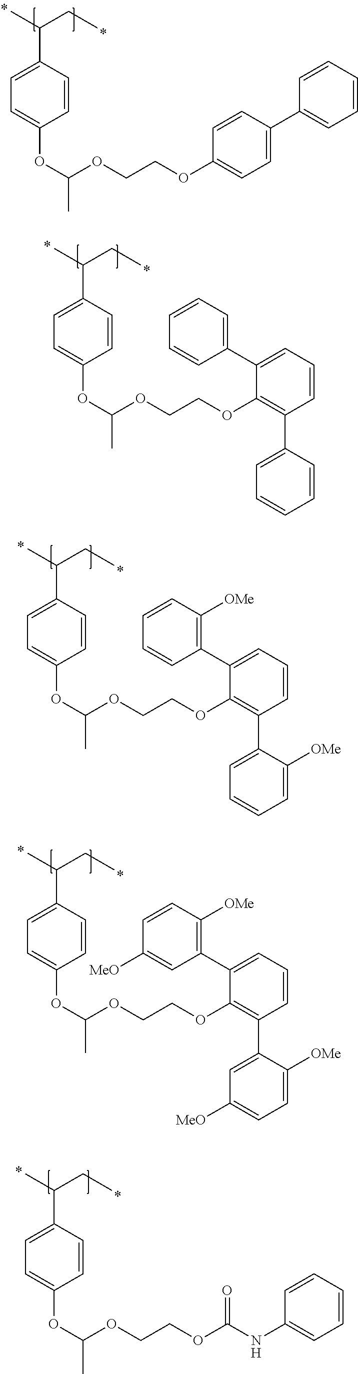

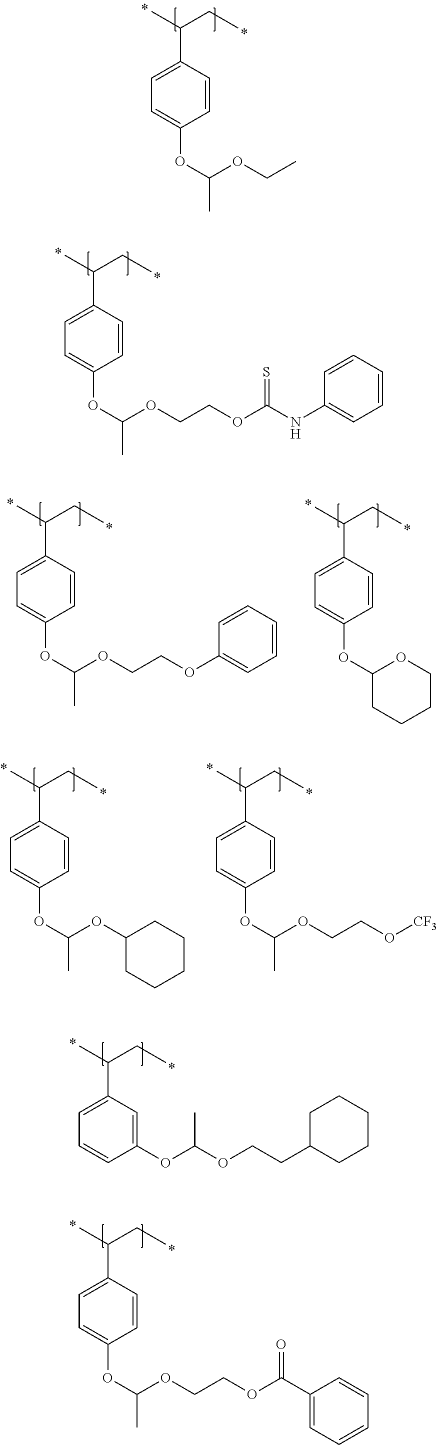

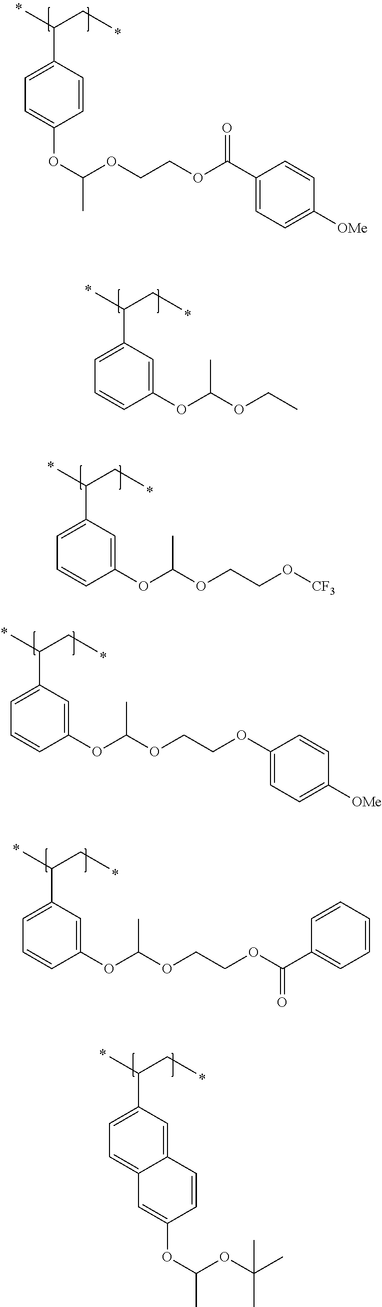

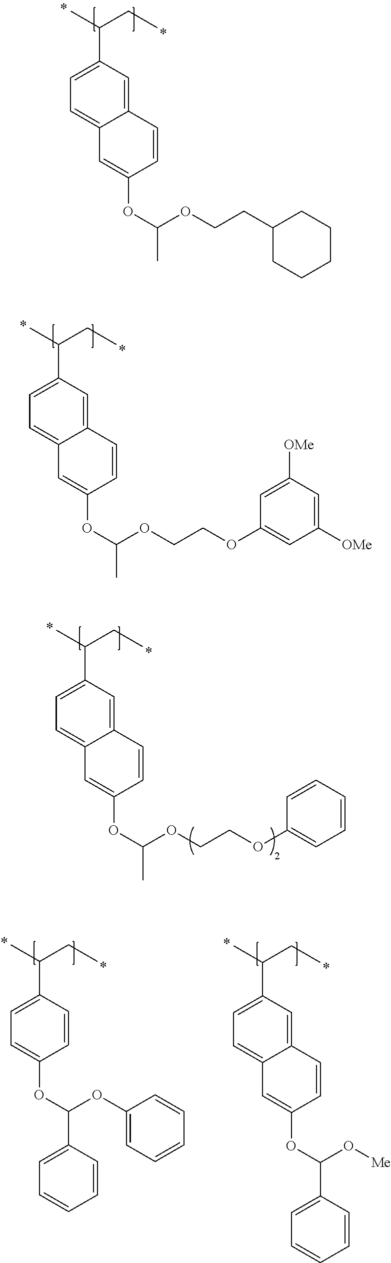

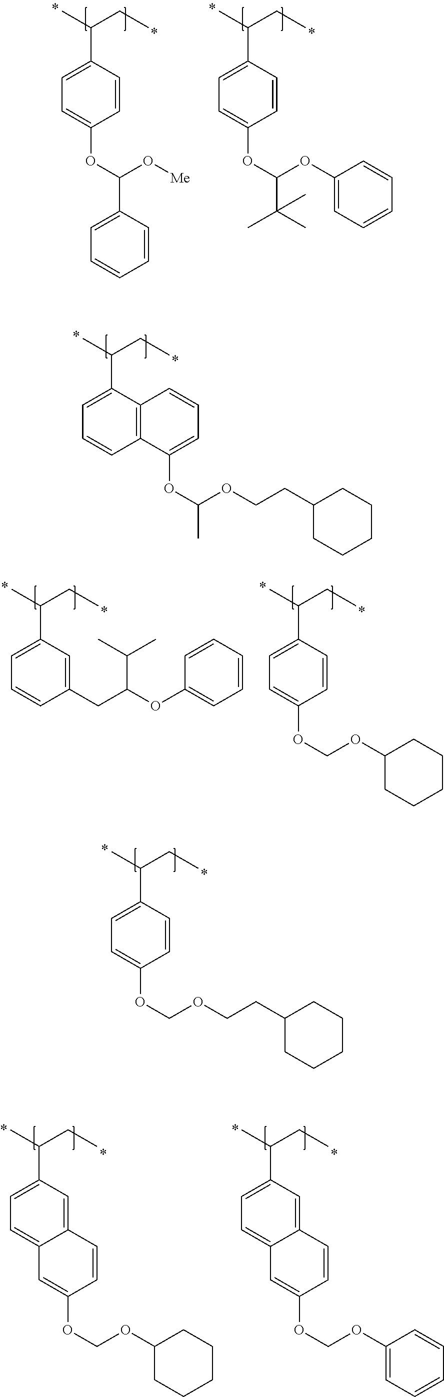

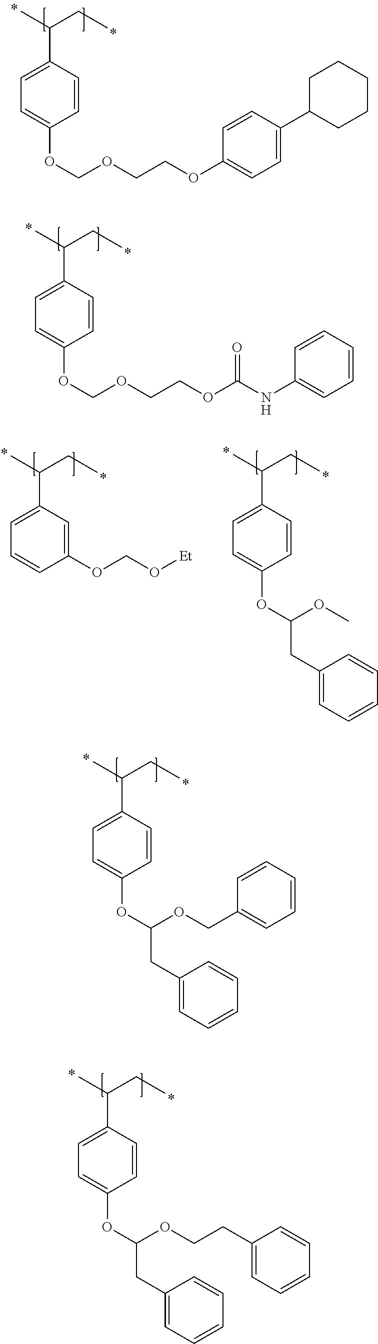

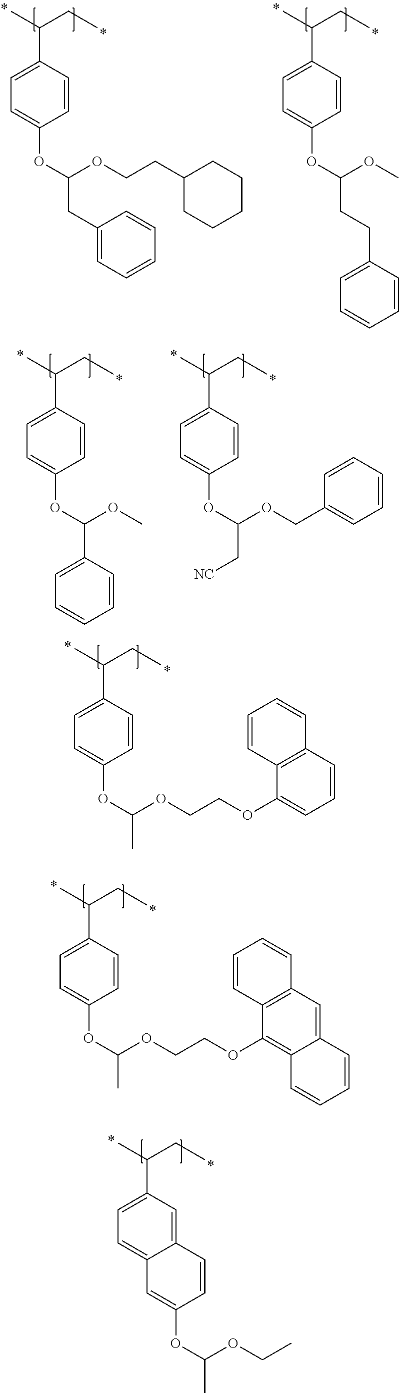

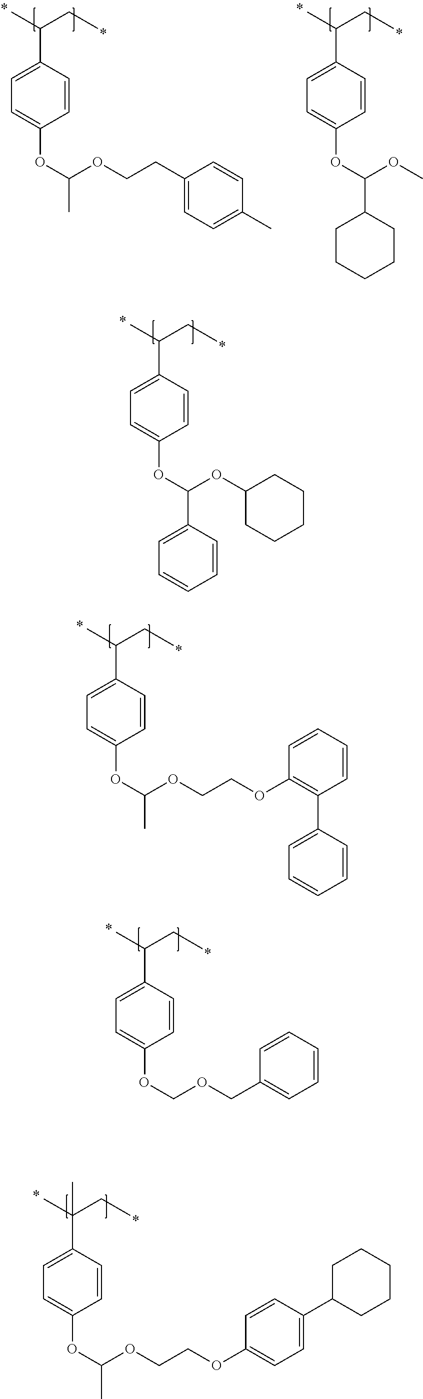

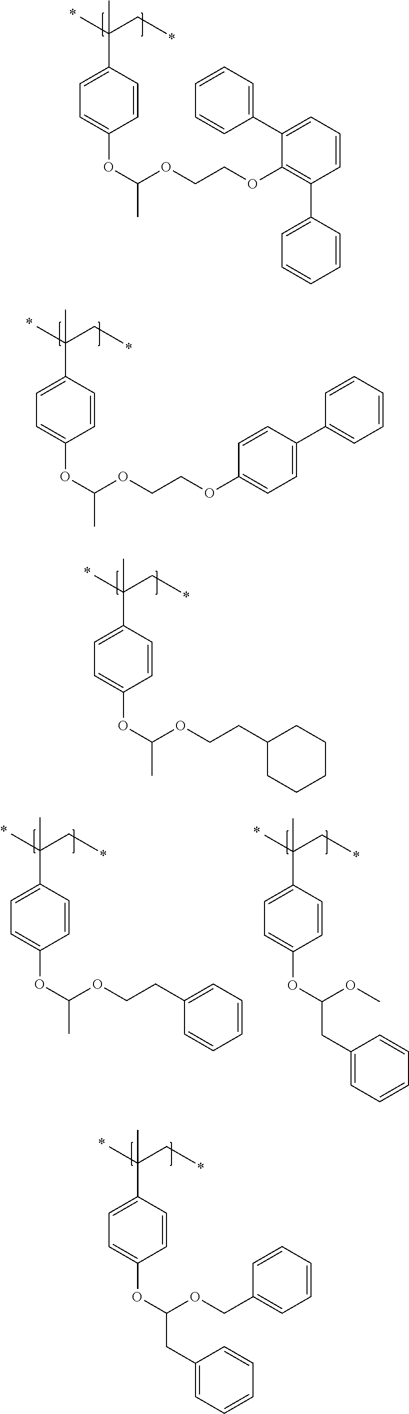

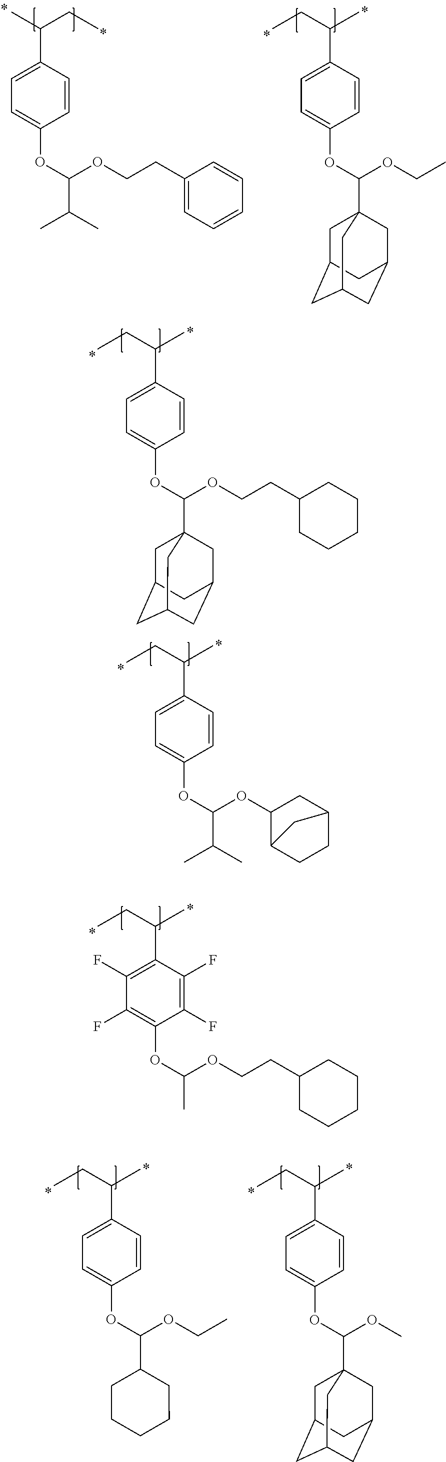

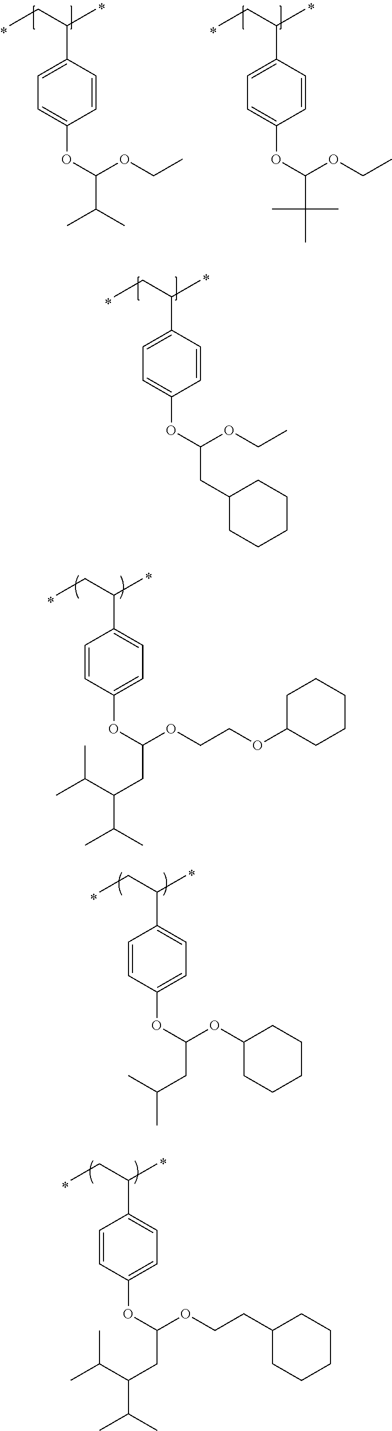

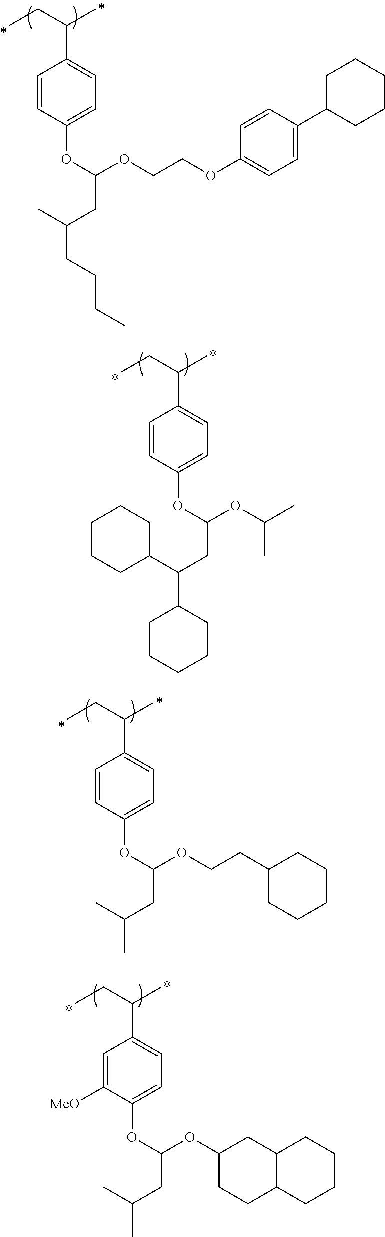

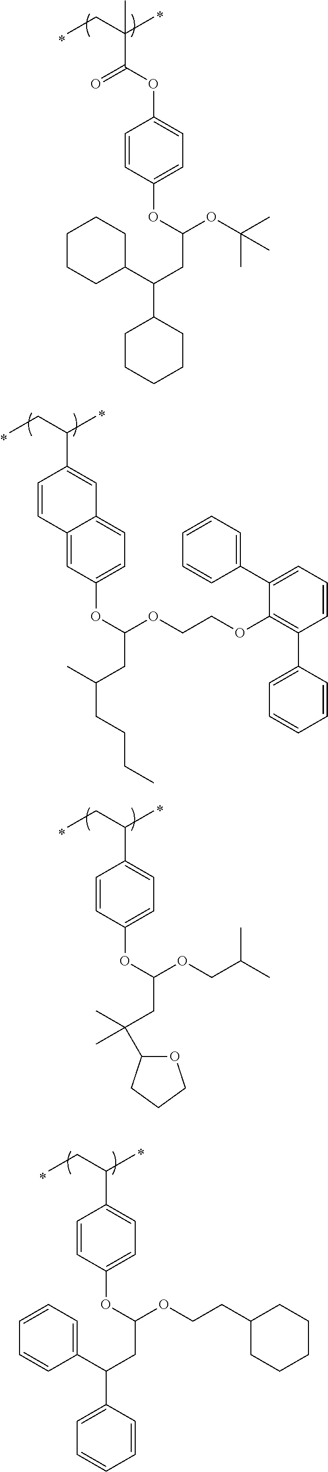

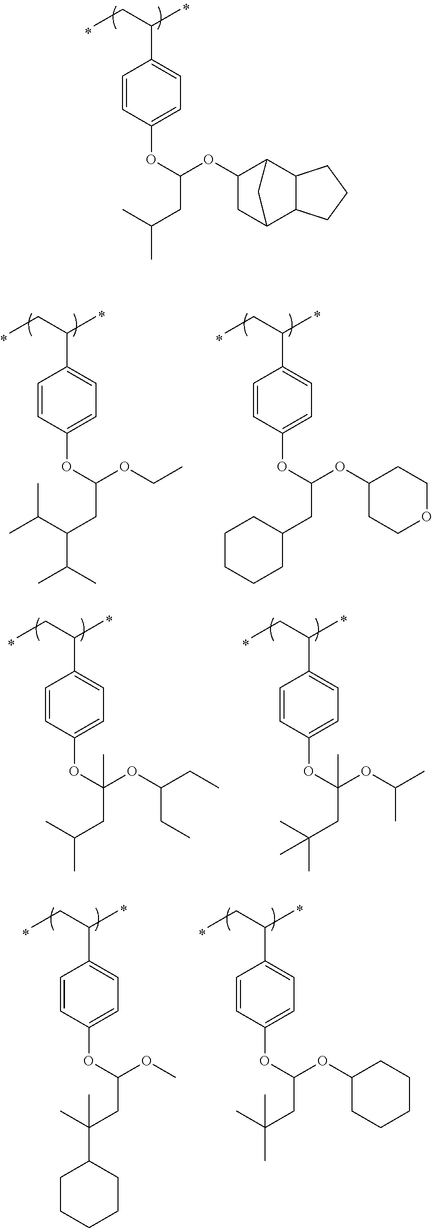

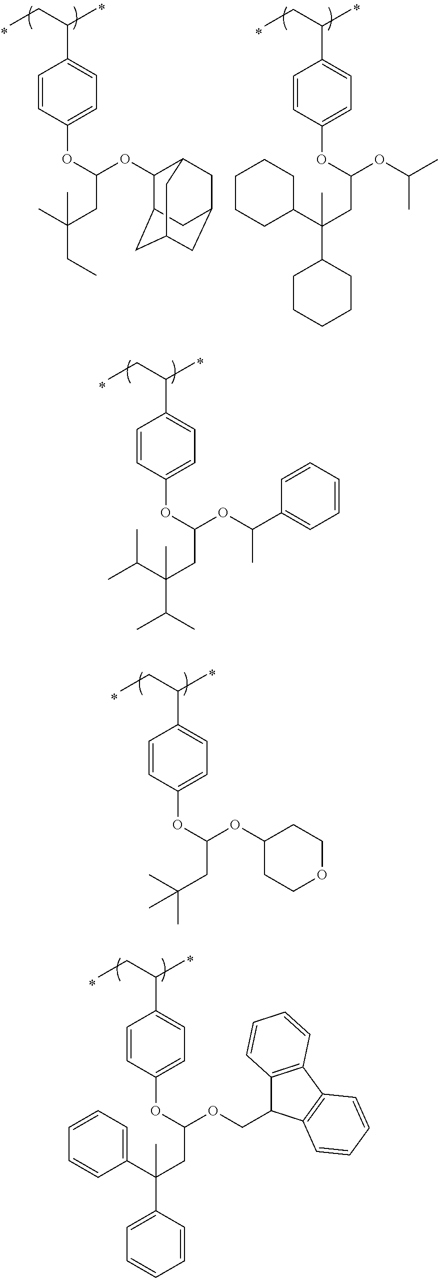

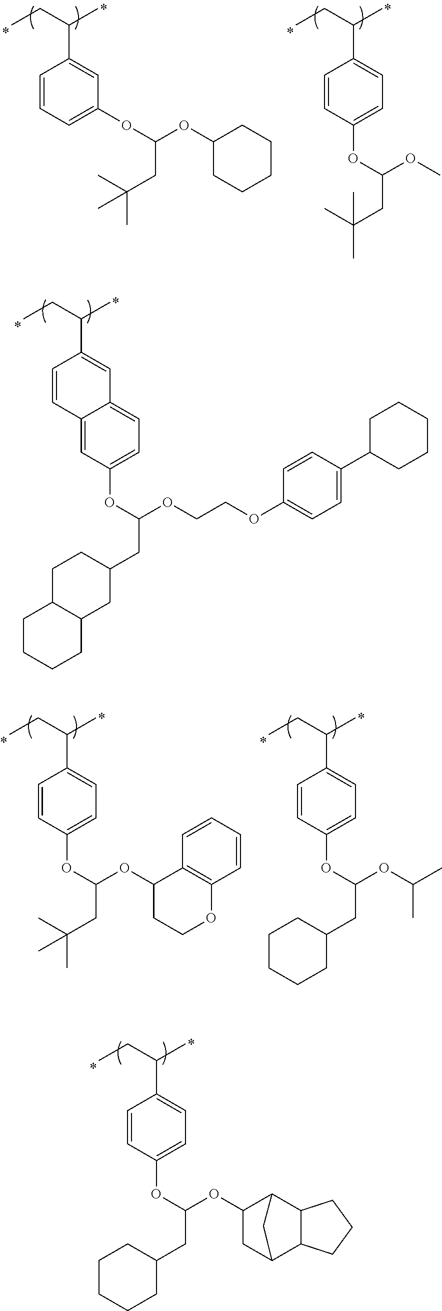

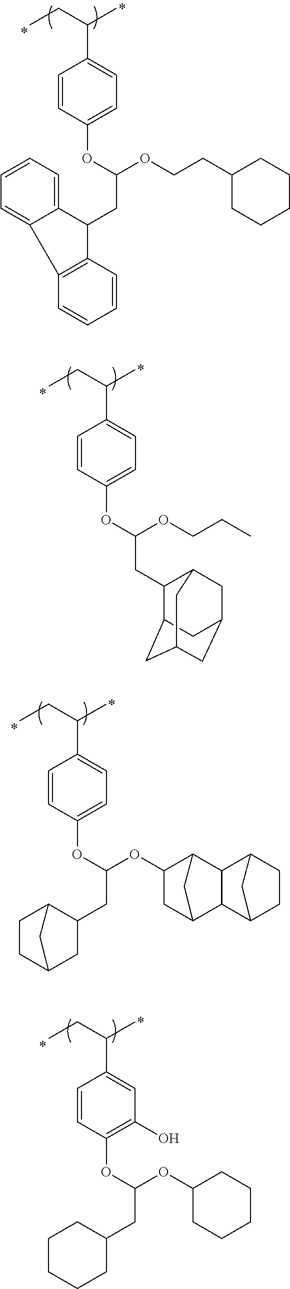

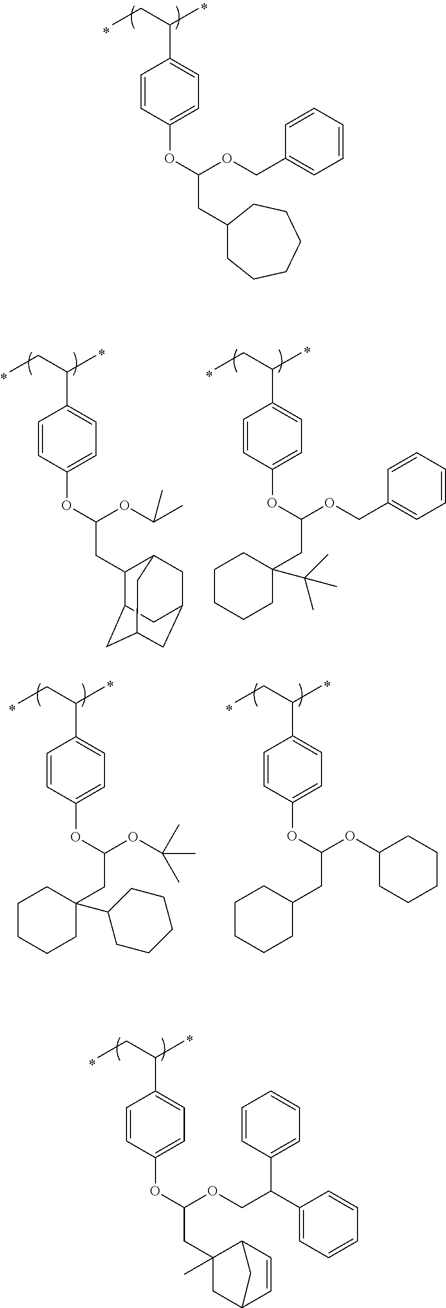

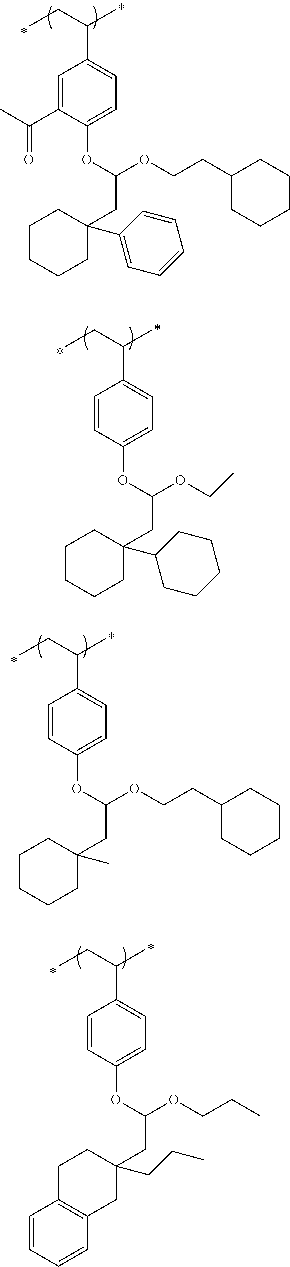

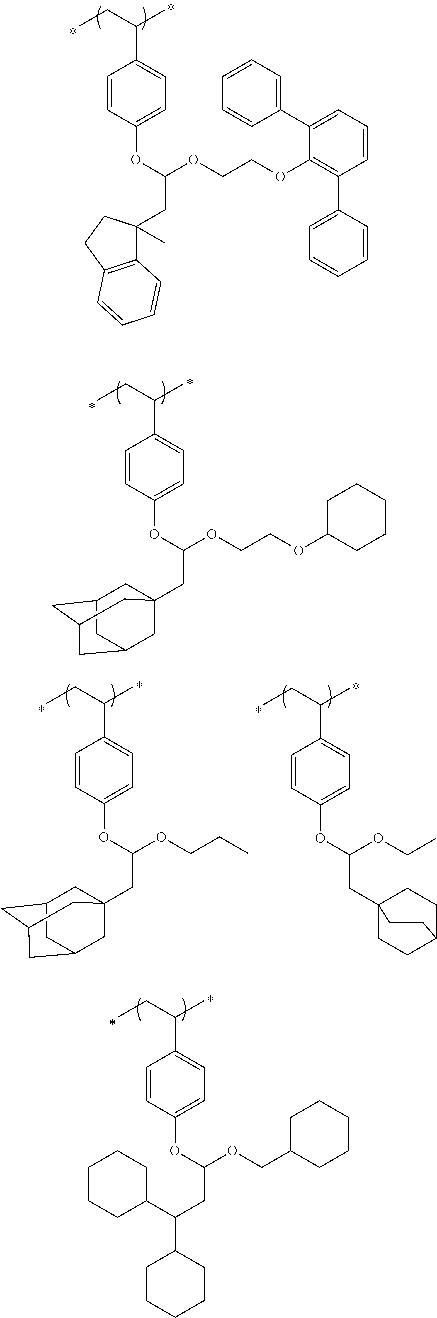

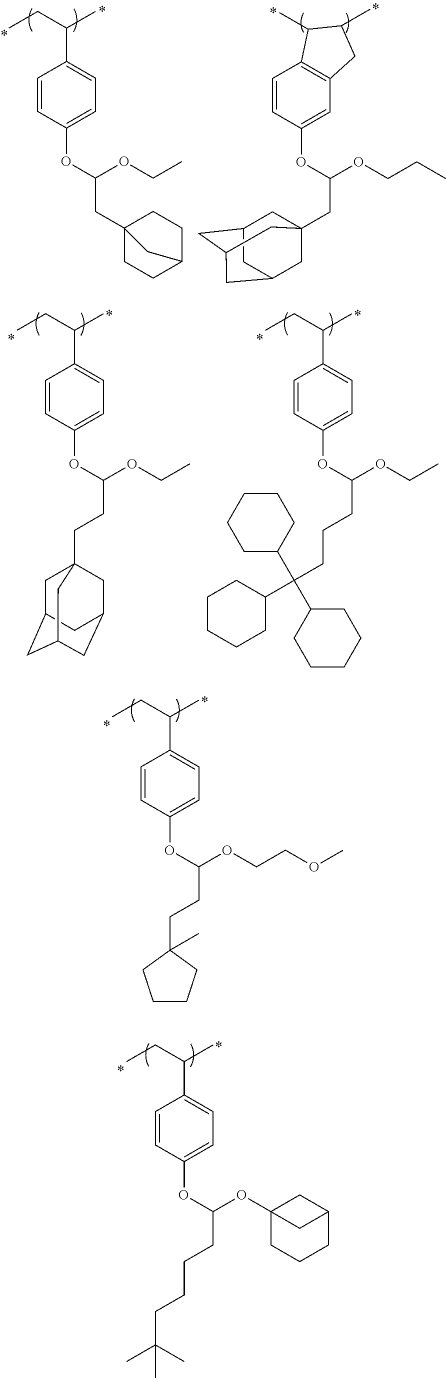

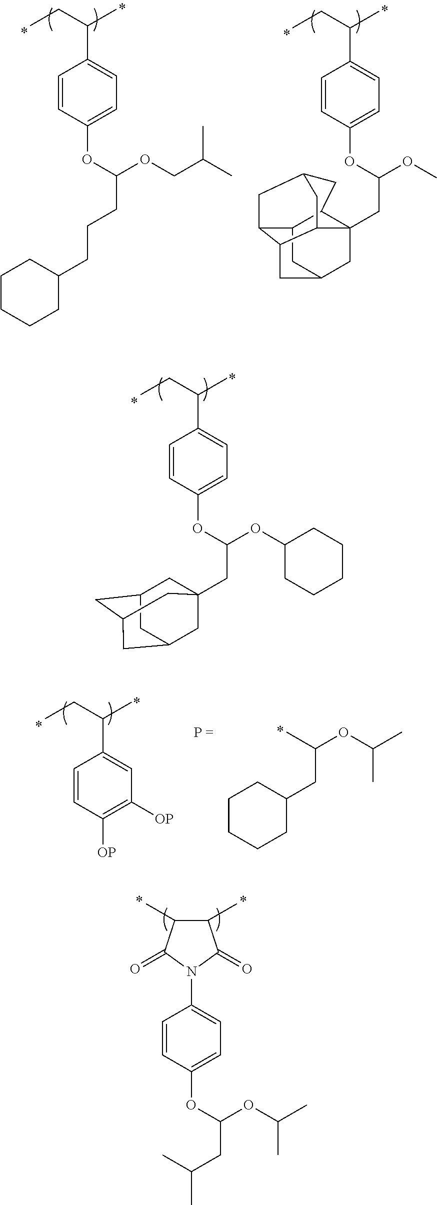

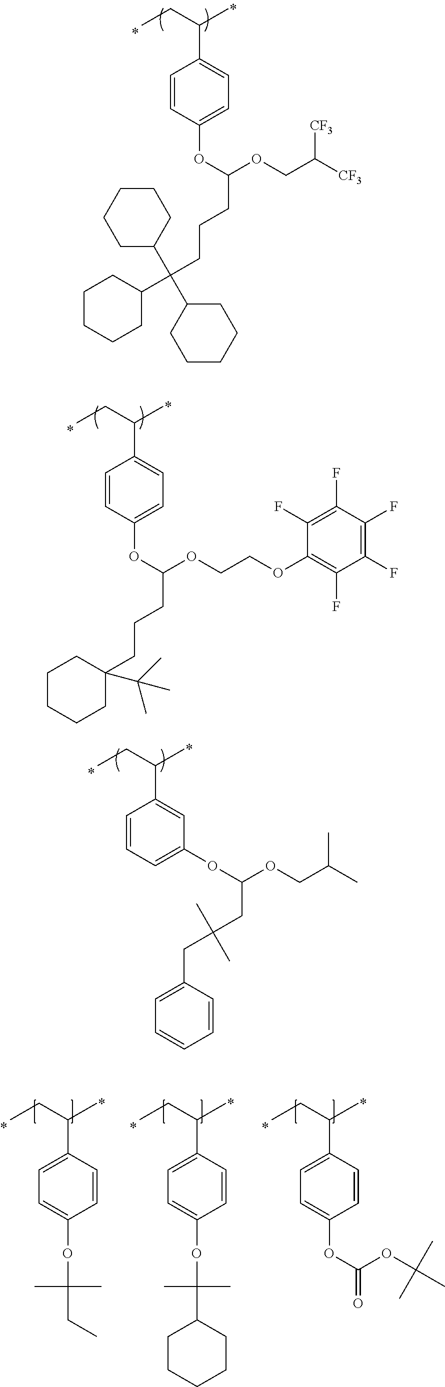

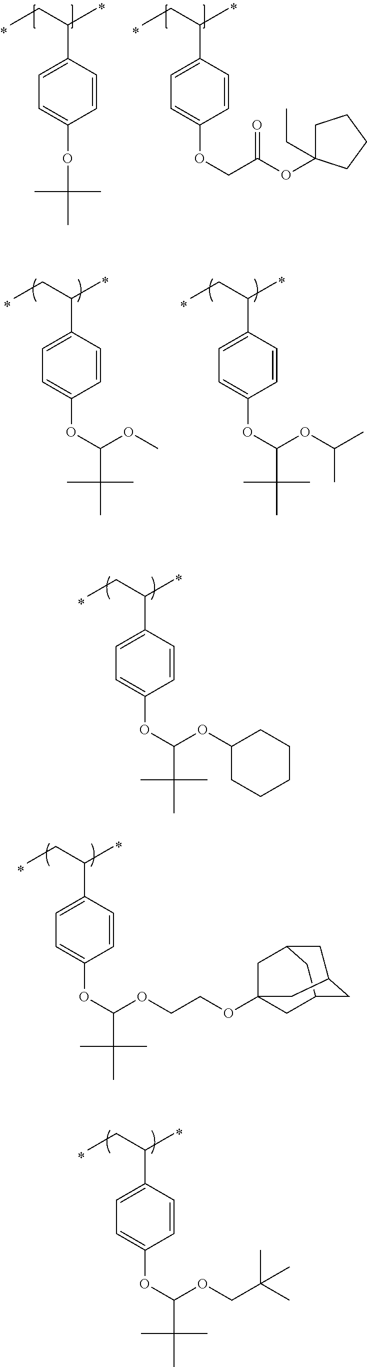

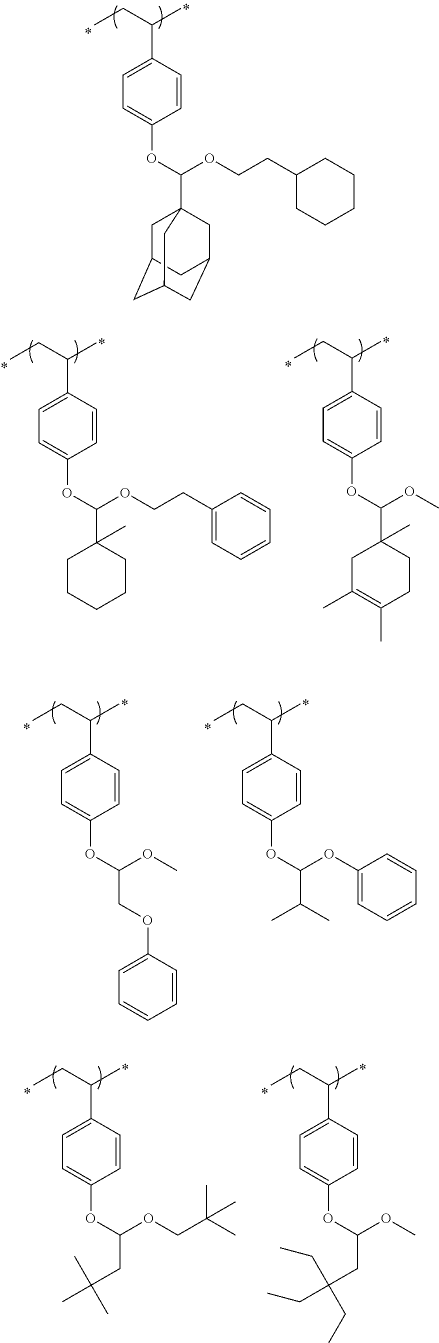

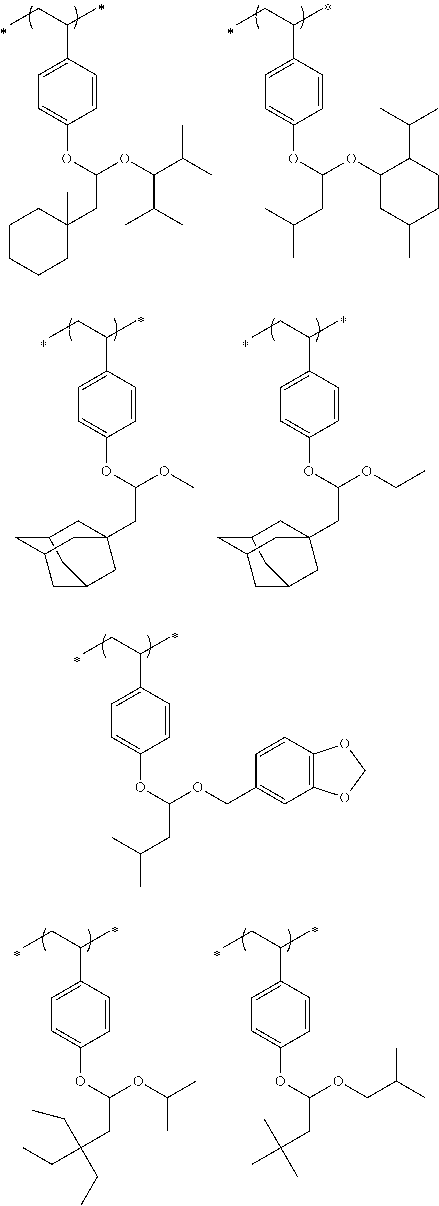

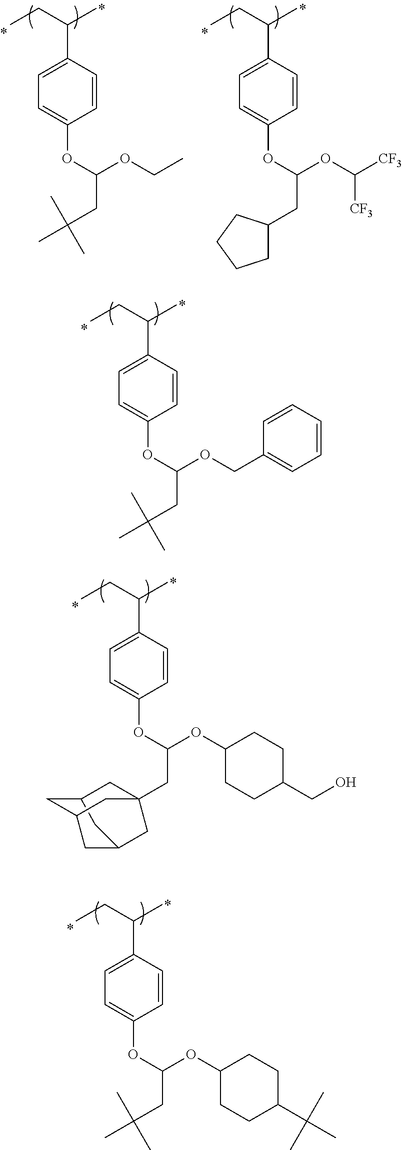

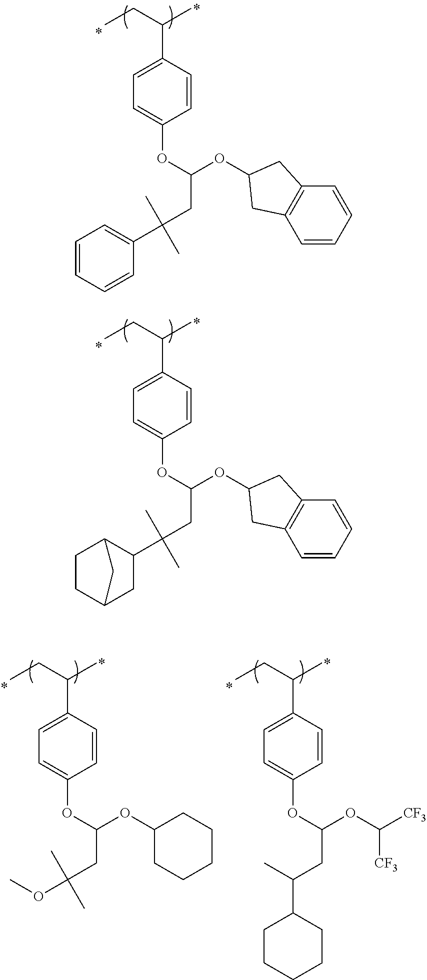

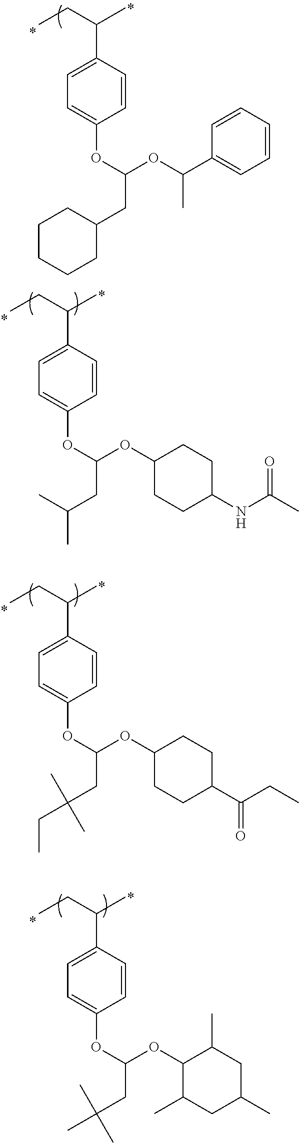

The resin (P) in a further aspect thereof preferably comprises any of repeating units of general formula (VI) below as the repeating unit (B).

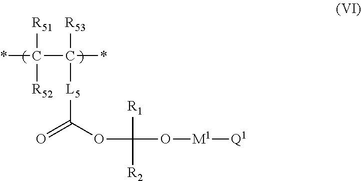

In general formula (VI),

each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group.

L₅ represents a single bond or a bivalent connecting group, provided that when a ring is formed in cooperation with R₅₂, L₅ represents a trivalent connecting group.

R₁ represents a hydrogen atom or an alkyl group.

R₂ represents a hydrogen atom, an alkyl group, a cycloalkyl group, an aryl group, an aralkyl group, an alkoxy group, an acyl group or a heterocyclic group.

M¹ represents a single bond or a bivalent connecting group.

Q¹ represents an alkyl group, a cycloalkyl group, an aryl group or a heterocyclic group.

At least two of Q¹, M¹ and R₂ may be bonded to each other through a single bond or a connecting group to thereby form a ring.

General formula (VI) will be described in detail below.

Particular examples and preferred forms of the groups represented by R₅₁, R₅₂ and R₅₃ in general formula (VI) are the same as set forth above in connection with general formula (a).

As the bivalent connecting group represented by L₅, there can be mentioned an alkylene group, a bivalent aromatic ring group, —COO-L₁-, —O-L₁-, a group comprised of a combination of two or more thereof, or the like. In the formulae, L₁ represents an alkylene group, a cycloalkylene group, a bivalent aromatic ring group, or a group comprised of an alkylene group combined with a bivalent aromatic ring group.

The bivalent aromatic ring group is preferably a 1,4-phenylene group, a 1,3-phenylene group, a 1,2-phenylene group or a 1,5-naphthylene group, more preferably a 1,4-phenylene group.

L₅ is preferably a single bond, any of groups of the formula —COO-L₁-, or any of groups of the formula -L₂-O—CH₂—, most preferably a single bond. In the formulae, L₂ represents a bivalent aromatic ring group.

The cycloalkylene group represented by L₁ may contain an ester bond to thereby form a lactone ring.

L₁ is preferably an alkylene group having 1 to 15 carbon atoms in which a heteroatom or carbonyl bond may be introduced, more preferably an alkylene group in which a heteroatom may be introduced. L₁ is most preferably a methylene group, an ethylene group and a propylene group.

L₂ is preferably an arylene group (preferably 1 to 10 carbon atoms), more preferably a 1,4-phenylene group, a 1,3-phenylene group or a 1,2-phenylene group. Further more preferably, L₂ is a 1,4-phenylene group or a 1,3-phenylene group.

As appropriate trivalent connecting groups represented by L₅ when L₅ is bonded to R₅₂ to thereby form a ring, there can be mentioned groups resulting from the removal of an arbitrary hydrogen atom from any of the above-mentioned particular examples of the bivalent connecting groups represented by L₅.

Particular examples of the partial structures (structures of principal chain portion) of general formula (1-1) below in the repeating units of general formula (VI) are shown below, which in no way limit the scope of the present invention.

In the formulae, “•” represents a bonding hand linked to the oxygen atom of any of acetal structures in general formula (VI).

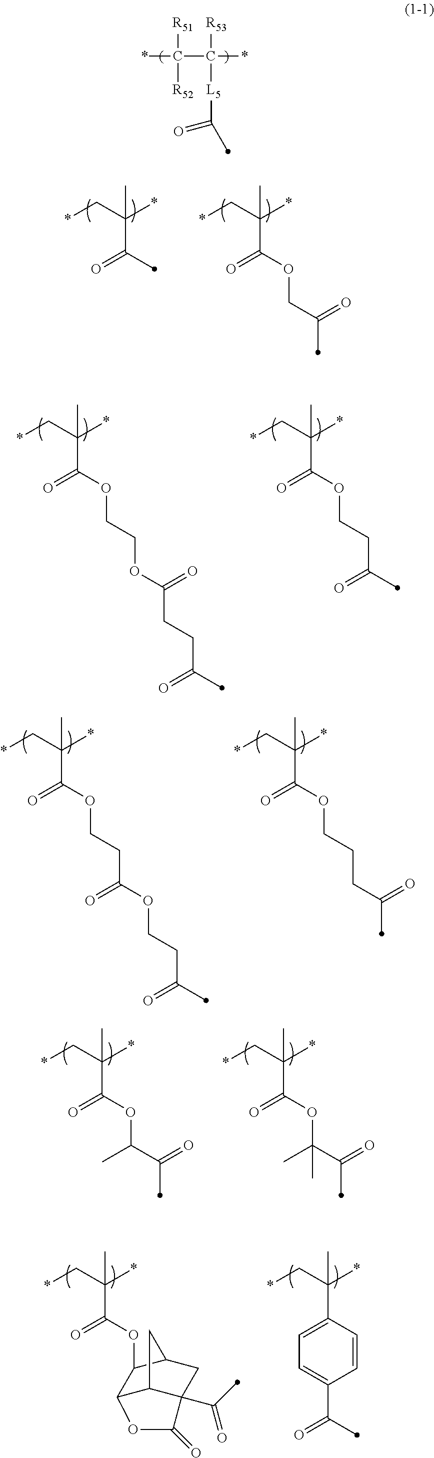

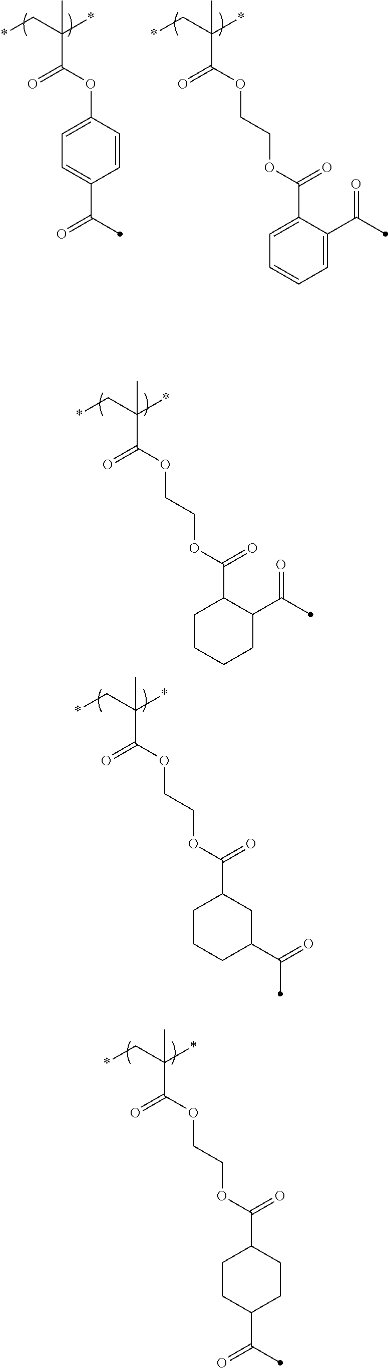

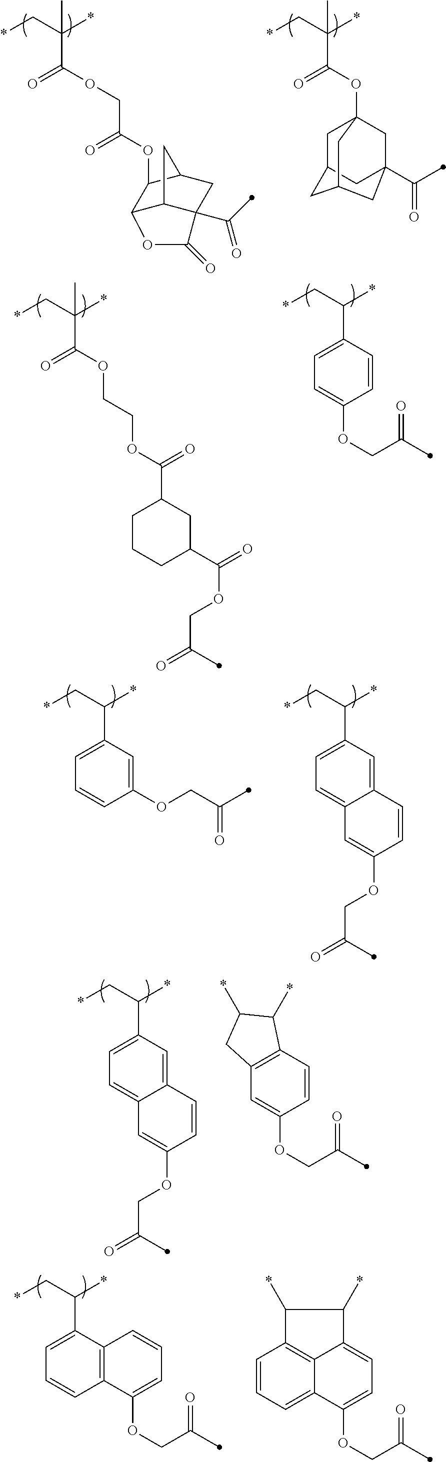

In general formula (VI) above, the alkyl group represented by R₁ is preferably an alkyl group having 1 to 10 carbon atoms, more preferably an alkyl group having 1 to 5 carbon atoms, further more preferably an alkyl group having 1 to 3 carbon atoms, and most preferably an alkyl group having 1 or 2 carbon atoms (namely a methyl group or an ethyl group). As particular examples of the alkyl groups represented by R₁, there can be mentioned a methyl group, an ethyl group, an n-propyl group, an isopropyl group, an n-butyl group, an isobutyl group, a sec-butyl group, a t-butyl group and the like.

R₁ is preferably a hydrogen atom or an alkyl group having 1 to 5 carbon atoms, more preferably a hydrogen atom or an alkyl group having 1 to 3 carbon atoms, and further more preferably a hydrogen atom, a methyl group or an ethyl group. A hydrogen atom is most preferred.

R₂ represents a hydrogen atom, an alkyl group, a cycloalkyl group, an aryl group, an aralkyl group, an alkoxy group, an acyl group or a heterocyclic group. From the viewpoint of lowering the film retention ratio of the resin (P), it is preferred for R₂ to have 15 or less carbon atoms.

The alkyl group represented by R₂ is preferably an alkyl group having 1 to 15 carbon atoms, more preferably an alkyl group having 1 to 10 carbon atoms and further more preferably an alkyl group having 1 to 6 carbon atoms. As particular examples of the alkyl groups represented by R₂, there can be mentioned a methyl group, an ethyl group, a propyl group, an isopropyl group, an n-butyl group, a sec-butyl group, a t-butyl group, a neopentyl group, a hexyl group, a 2-ethylhexyl group, an octyl group, a dodecyl group and the like. The alkyl group represented by R₂ is preferably a methyl group, an ethyl group, a propyl group, an isopropyl group or a t-butyl group.

The cycloalkyl group represented by R₂ may be monocyclic or polycyclic. The cycloalkyl group is preferably a cycloalkyl group having 3 to 15 carbon atoms, more preferably a cycloalkyl group having 3 to 10 carbon atoms and further more preferably a cycloalkyl group having 3 to 6 carbon atoms. As particular examples of the cycloalkyl groups represented by R₂, there can be mentioned a cyclopropyl group, a cyclobutyl group, a cyclopentyl group, a cyclohexyl group, a cycloheptyl group, a cyclooctyl group, a decahydronaphthyl group, a cyclodecyl group, a 1-adamantyl group, a 2-adamantyl group, a 1-norbornyl group, a 2-norbornyl group and the like. The cycloalkyl group represented by R₂ is preferably a cyclopropyl group, a cyclopentyl group, or a cyclohexyl group.

The aryl group represented by R₂ is preferably an aryl group having 6 to 15 carbon atoms, more preferably an aryl group having 6 to 12 carbon atoms. The aryl groups include a structure (for example, a biphenyl group or a terphenyl group) in which a plurality of aromatic rings are linked to each other through a single bond. As particular examples of the aryl groups represented by R₂, there can be mentioned a phenyl group, a naphthyl group, an anthranyl group, a biphenyl group, a terphenyl group and the like. The aryl group represented by R₂ is preferably a phenyl group, a naphthyl group or a biphenyl group.

The aralkyl group represented by R₂ is preferably an aralkyl group having 6 to 15 carbon atoms, more preferably an aralkyl group having 7 to 12 carbon atoms. As particular examples of the aralkyl groups represented by R₂, there can be mentioned a benzyl group, a phenethyl group, a naphthylmethyl group, a naphthylethyl group and the like.

As the alkyl group moiety in the alkoxy group represented by R₂, there can be mentioned, for example, any of the alkyl groups set forth above as being represented by R₂. It is especially preferred for the alkoxy group to be a methoxy group, an ethoxy group, an n-propoxy group or an n-butoxy group.

As the acyl group represented by R₂, there can be mentioned, for example, a linear or branched acyl group having 2 to 12 carbon atoms, such as an acetyl group, a propionyl group, an n-butanoyl group, an i-butanoyl group, an n-heptanoyl group, a 2-methylbutanoyl group, a 1-methylbutanoyl group or a t-heptanoyl group.

The heterocyclic group represented by R₂ is preferably a heterocyclic group having 6 to 15 carbon atoms, more preferably a heterocyclic group having 6 to 12 carbon atoms. As particular examples of the heterocyclic groups represented by R₂, there can be mentioned a pyridyl group, a pyrazyl group, a tetrahydrofuranyl group, a tetrahydropyranyl group, a tetrahydrothiophene group, a piperidyl group, a piperazyl group, a furanyl group, a pyranyl group, a chromanyl group and the like.

Substituents may further be introduced in the alkyl group represented by R₁ and the alkyl group, cycloalkyl group, aryl group, aralkyl group, alkoxy group, acyl group and heterocyclic group represented by R₂.

As the substituents that may further be introduced in the alkyl groups represented by R₁ and R₂, there can be mentioned, for example, a cycloalkyl group, an aryl group, an amino group, an amido group, a ureido group, a urethane group, a hydroxyl group, a carboxyl group, a halogen atom, an alkoxy group, an aralkyloxy group, a thioether group, an acyl group, an acyloxy group, an alkoxycarbonyl group, a cyano group, a nitro group and the like.

As the substituent that may further be introduced in the cycloalkyl group represented by R₂, there can be mentioned an alkyl group or any of the particular examples of substituents set forth above as being further introducible in the alkyl groups.

The number of carbon atoms of the alkyl group and the number of carbon atoms of each of the substituents further introducible in the cycloalkyl groups are each preferably in the range of 1 to 8.

As the substituents that may further be introduced in the aryl group, aralkyl group and heterocyclic group represented by R₂, there can be mentioned, for example, a nitro group, a halogen atom such as a fluorine atom, a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms) and the like.

R² will be described in greater detail below.

It is preferred for R₂ in general formula (VI) to be a hydrogen atom or any of groups of the general formula —(CH₂)ₙ₁— C(R₂₁) (R₂₂) (R₂₃).

In the above general formula, each of R²¹ to R²³ independently represents a hydrogen atom, an alkyl group, a cycloalkyl group, an aryl group, an aralkyl group or a heterocyclic group, provided that each of at least two of R²¹ to R²³ independently represents an alkyl group, a cycloalkyl group, an aryl group, an aralkyl group or a heterocyclic group.

At least two of R²¹ to R²³ may be bonded to each other to thereby form a ring. In the general formula, n1 is an integer of 0 to 6.

When R₂ in general formula (VI) is any of groups of the general formula —(CH₂)ₙ₁—C(R²¹) (R²²) (R²³), the bulkiness is increased, and the glass transition temperature (Tg) of the resin (P) is increased. As a result, the dissolution contrast of the resin (P) is increased to thereby realize an enhanced resolving power.

Particular examples and preferred examples of the alkyl groups represented by R²¹ to R²³ are the same as set forth above in connection with R₂.

As mentioned above, each of at least two of R²¹ to R²³ independently represents an alkyl group, a cycloalkyl group, an aryl group, an aralkyl group or a heterocyclic group. Preferably, all of R²¹ to R²³ each represent an alkyl group, a cycloalkyl group, an aryl group, an aralkyl group or a heterocyclic group.

Particular examples and preferred examples of the cycloalkyl groups represented by R²¹ to R²³ are the same as set forth above in connection with R₂.

Particular examples and preferred examples of the aryl groups represented by R²¹ to R²³ are the same as set forth above in connection with R₂.

Particular examples and preferred examples of the aralkyl groups represented by R²¹ to R²³ are the same as set forth above in connection with R₂.

Particular examples and preferred examples of the heterocyclic groups represented by R²¹ to R²³ are the same as set forth above in connection with R₂.

Substituents may further be introduced in the alkyl group, cycloalkyl group, aryl group, aralkyl group and heterocyclic group represented by R²¹ to R²³.

Particular examples of the substituents further introducible in the alkyl groups represented by R²¹ to R²³ are the same as set forth above in connection with R₂.

As particular examples of the substituents further introducible in the cycloalkyl groups represented by R²¹ to R²³, there can be mentioned an alkyl group and those set forth above as particular examples of the substituents further introducible in the alkyl groups.

The number of carbon atoms of the alkyl group and the number of carbon atoms of each of the substituents further introducible in the cycloalkyl groups are each preferably in the range of 1 to 8.

When each of R²¹ to R²³ represents an alkyl group or a cycloalkyl group, all of R²¹ to R²³ being alkyl groups and all of R²¹ to R²³ being cycloalkyl groups are preferred. All of R²¹ to R²³ being alkyl groups is more preferred. All of R²¹ to R²³ being methyl groups is most preferred.

Particular examples and preferred examples of the substituents further introducible in the aryl groups, aralkyl groups and heterocyclic groups represented by

R²¹ to R²³ are the same as set forth above in connection with R₂.

At least two of R²¹ to R²³ may cooperate with each other to thereby form a ring.

When at least two of R²¹ to R²³ are bonded to each other to thereby form a ring, the formed ring is, for example, a cyclopentane ring, a cyclohexane ring, an adamantane ring, a norbornene ring, a norbornane ring or the like. Substituents may be introduced in these rings. As introducible substituents, there can be mentioned an alkyl group and those set forth above as particular examples of the substituents further introducible in the alkyl groups.

When all of R²¹ to R²³ are bonded to each other to thereby form a ring, the formed ring is, for example, any of an adamantane ring, a norbornane ring, a norbornene ring, a bicyclo[2,2,2]octane ring and a bicyclo[3,1,1]heptane ring. Of these, an adamantane ring is most preferred. Substituents may be introduced in these. As introducible substituents, there can be mentioned an alkyl group and those set forth above as particular examples of the substituents further introducible in the alkyl groups.

From the viewpoint of increasing the glass transition temperature of the resin (P) to thereby attain an enhanced resolution, it is preferred for each of R²¹ to R²³ to independently represent an alkyl group.

When R₂ in general formula (VI) is any of groups of the general formula —(CH₂)ₙ₁—C(R²¹) (R²²)(R²³), each of the groups preferably has 15 or less carbon atoms. This renders the affinity of the obtained resist film to developers satisfactory, so that exposed areas can be securely removed by developers (namely, satisfactory developability can be obtained).

From the viewpoint of increasing the glass transition temperature of the resin, n1 is preferably an integer of 0 to 3, more preferably 0 or 1.

Particular examples of the groups of the formula —C(R²¹) (R²²) (R²³) in R₂ (preferably groups of the formula —(CH₂)ₙ₁—C(R²¹) (R²²) (R²³)) are shown below, which in no way limit the scope of the present invention. In the following particular examples, * represents a bonding hand linked to either the connecting group of the formula —(CH₂)ₙ₁— in R₂ or the carbon atom to which R₁ is linked in general formula (VI) above.

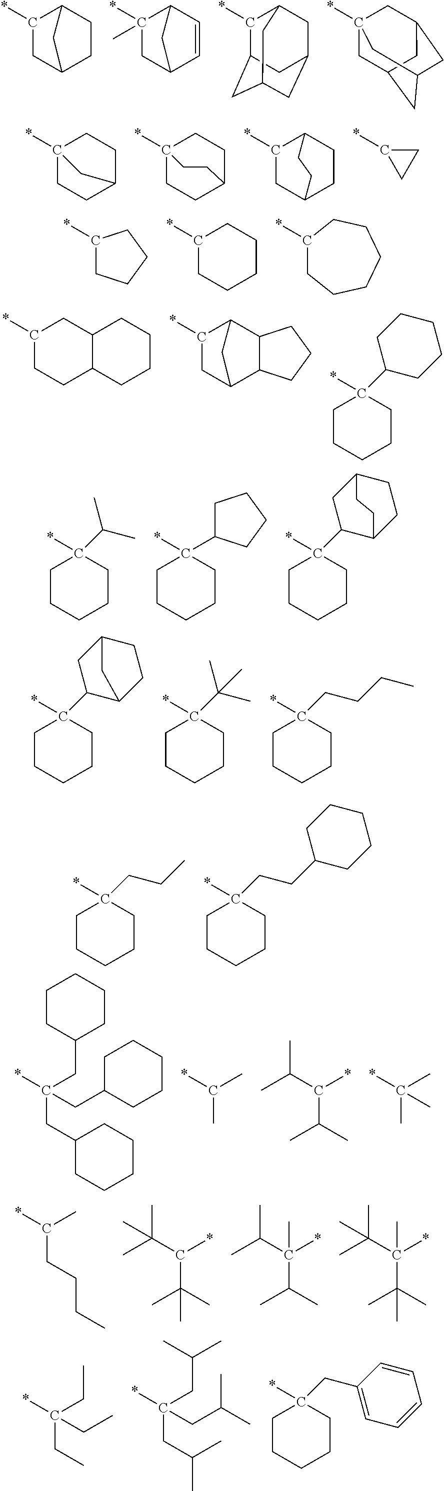

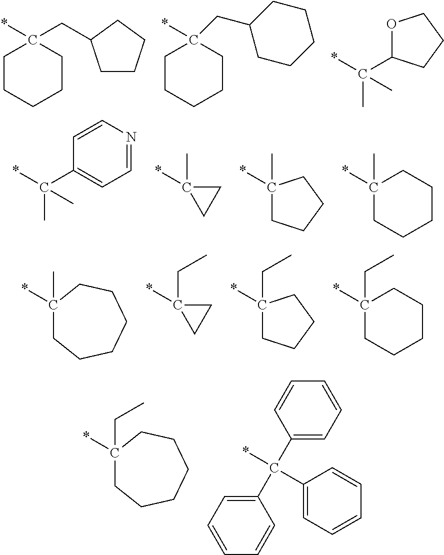

The bivalent connecting group represented by M¹ is, for example, an alkylene group (preferably an alkylene group having 1 to 8 carbon atoms, e.g., a methylene group, an ethylene group, a propylene group, a butylene group, a hexylene group or an octylene group), a cycloalkylene group (preferably a cycloalkylene group having 3 to 15 carbon atoms, e.g., a cyclopentylene group or a cyclohexylene group), —S—, —O—, —CO—, —CS—, —SO₂—, —N(R₀)— or a combination of two or more of these in which the total number of carbon atoms is preferably 20 or less. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group or the like).

It is preferred for M¹ to be a single bond, an alkylene group, or a bivalent connecting group comprised of a combination of an alkylene group and at least one of —O—, —CO—, —CS— and —N(R₀)—. A single bond, an alkylene group and a bivalent connecting group comprised of a combination of an alkylene group and —O— are more preferred. Herein, R₀ is as defined above.

A substituent may further be introduced in the bivalent connecting group represented by M¹. Particular examples of further introducible substituents are the same as set forth above in connection with the alkyl group represented by R²¹.

Particular examples and preferred examples of the alkyl groups represented by Q¹ are, for example, the same as set forth above in connection with R²¹.

The cycloalkyl group represented by Q¹ may be monocyclic or polycyclic. The cycloalkyl group preferably has 3 to 10 carbon atoms. The cycloalkyl group can be, for example, any of a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}.0^{2,7}]dodecyl group, a 8-tricyclo[5.2.1.0^{2,6}]decyl group and a 2-bicyclo[2.2.1]heptyl group. Of these, a cyclopentyl group, a cyclohexyl group, a 2-adamantyl group, an 8-tricyclo[5.2.1.0^{2,6}]decyl group and a 2-bicyclo[2.2.1]heptyl group are preferred.

Particular examples and preferred examples of the aryl groups represented by Q¹ are, for example, the same as set forth above in connection with R²¹.

Particular examples and preferred examples of the heterocyclic groups represented by Q¹ are, for example, the same as set forth above in connection with R²¹.

Substituents may be introduced in the alkyl group, cycloalkyl group, aryl group and heterocyclic group represented by Q¹. Such substituents can be, for example, an alkyl group, a cycloalkyl group, a cyano group, a halogen atom, a hydroxyl group, an alkoxy group, a carboxyl group and an alkoxycarbonyl group.

It is preferred for the groups of the formula -M¹-Q¹ to be an unsubstituted alkyl group, an alkyl group substituted with a cycloalkyl group, a cycloalkyl group, an aralkyl group, an aryloxyalkyl group and a heterocyclic group. Particular examples and preferred examples of the unsubstituted alkyl groups represented by -M¹-Q¹, “cycloalkyl groups” represented by -M¹-Q¹ and cycloalkyl groups in “alkyl groups substituted with a cycloalkyl group” represented by -M¹-Q¹, and aryl groups in “aralkyl groups (arylalkyl groups)” and “aryloxyalkyl groups” represented by -M¹-Q¹ are respectively the same as set forth above in connection with the alkyl group, cycloalkyl group and aryl group represented by Q¹.

Particular examples and preferred examples of the alkyl moieties in the “alkyl groups substituted with a cycloalkyl group,” “aralkyl groups (arylalkyl groups)” and “aryloxyalkyl groups” represented by -M¹-Q¹ are the same as set forth above in connection with the alkylene group represented by M¹.

Particular examples and preferred examples of the heterocyclic groups represented by -M¹-Q¹ are the same as set forth above in connection with Q¹.

In particular, the groups of the formula -M¹-Q¹ include, for example, a methyl group, an ethyl group, an isopropyl group, a cyclopentyl group, a cyclohexyl group, a cyclohexylethyl group, a 2-adamantyl group, an 8-tricyclo[5.2.1.0^{2,6}]decyl group, a 2-bicyclo[2.2.1]heptyl group, a benzyl group, a 2-phenethyl group, a 2-phenoxyethylene group and the like.

As mentioned above, at least two of Q¹, M¹ and R₂ may be bonded to each other through a single bond or a connecting group to thereby form a ring. For example, when M¹ is a bivalent connecting group, Q¹ may be bonded to M¹ through a single bond or another connecting group to thereby form a ring. As the other connecting group, there can be mentioned an alkylene group (preferably having 1 to 3 carbon atoms). The formed ring is preferably a 5- or 6-membered ring.

Preferably, for example, Q¹, M¹ and R₂ (especially Q¹ and R₂) are bonded to each other to thereby form an oxygen-containing heterocycle. The oxygen-containing heterocycle may have the structure of a monocyclic, polycyclic or spiro ring. A monocyclic oxygen-containing heterocycle structure is preferred, which preferably has 3 to 10 carbon atoms, more preferably 4 or 5 carbon atoms.

Particular examples of the groups of the formula -M¹-Q¹ are shown below, which in no way limit the scope of the present invention. In the following particular examples, * represents a bonding hand linked to the oxygen atom in general formula (VI) above. Further, Me represents a methyl group, Et an ethyl group, and Pr an n-propyl group.

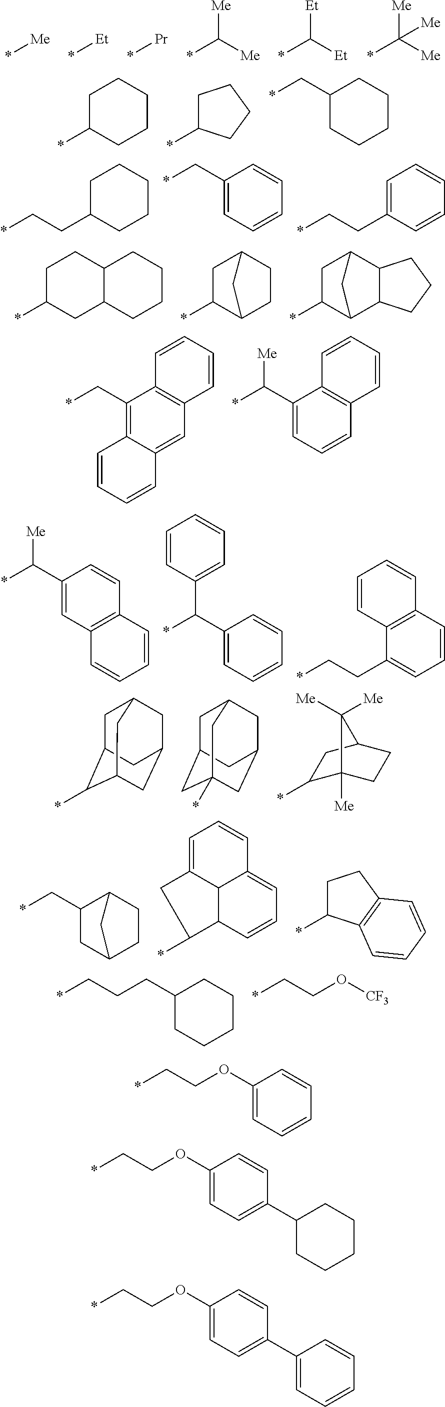

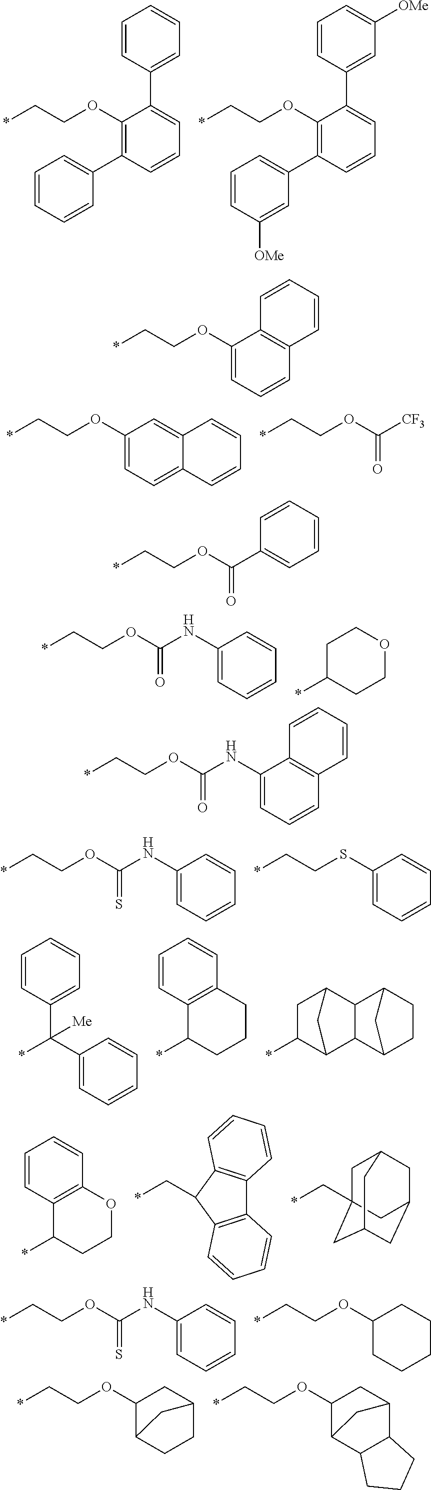

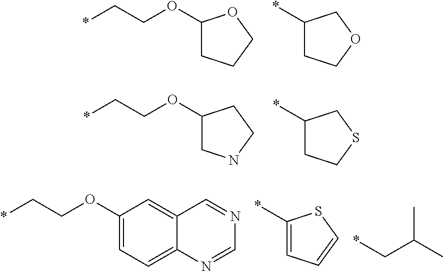

When Q¹, M¹ and R₂ are bonded to each other to thereby form a ring in the repeating units of general formula (VI) above, particular examples of formed rings are shown below. In the following particular examples, * represents a bonding hand linked to the oxygen atom in general formula (VI). R₄ has the same meaning as that of R₁ in general formula (VI).

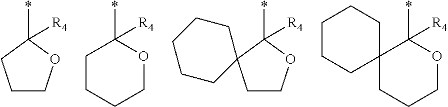

Particular examples of the leaving group moieties in the acetal sites in the repeating units of general formula (VI) are shown below, which in no way limit the scope of the present invention. In the following particular examples, * represents a bonding hand linked to the oxygen atom of the ester bond connected to L₅ in general formula (VI).

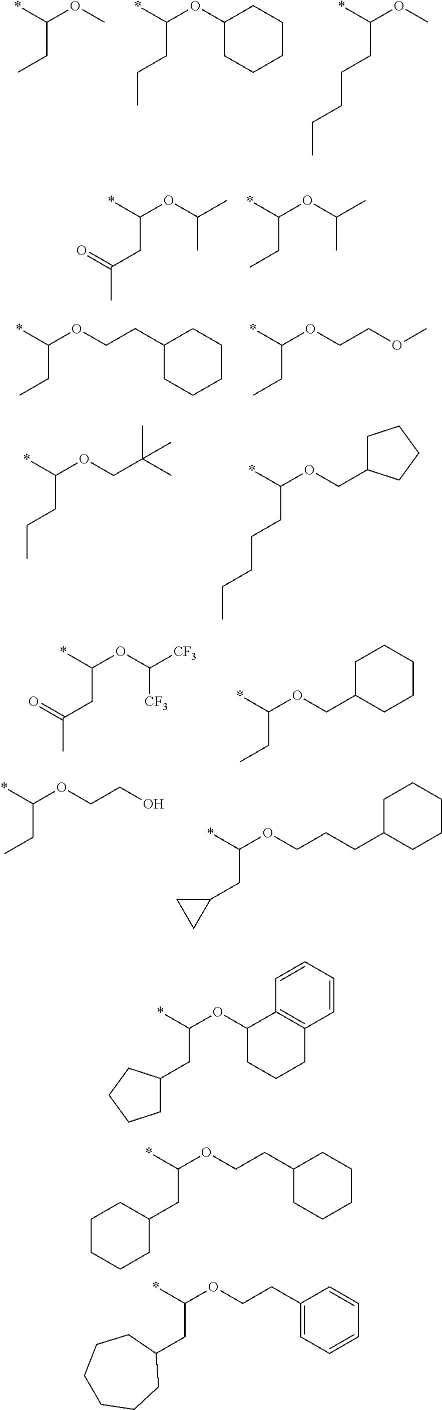

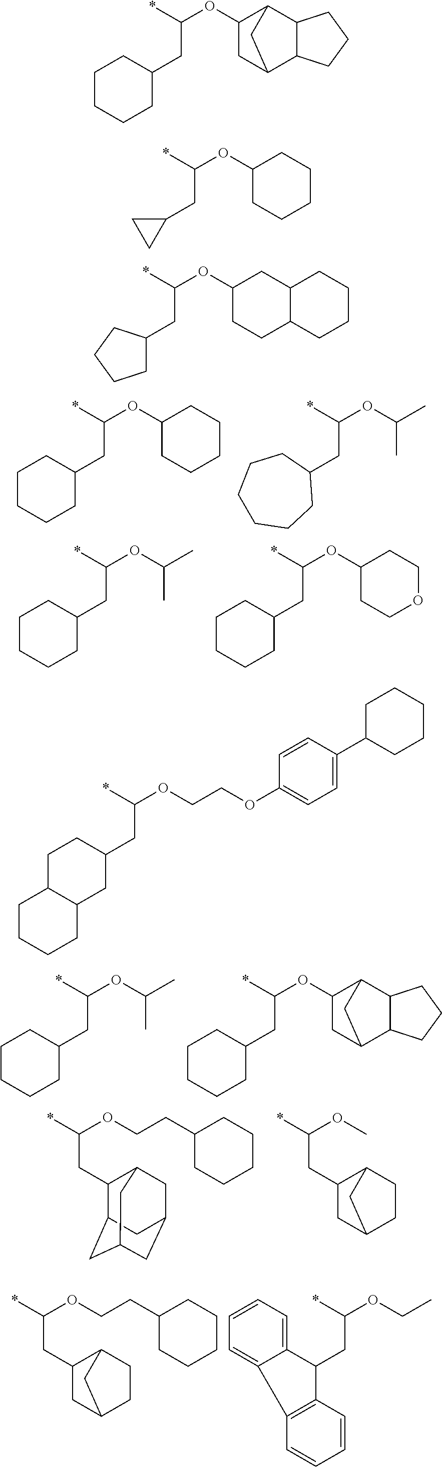

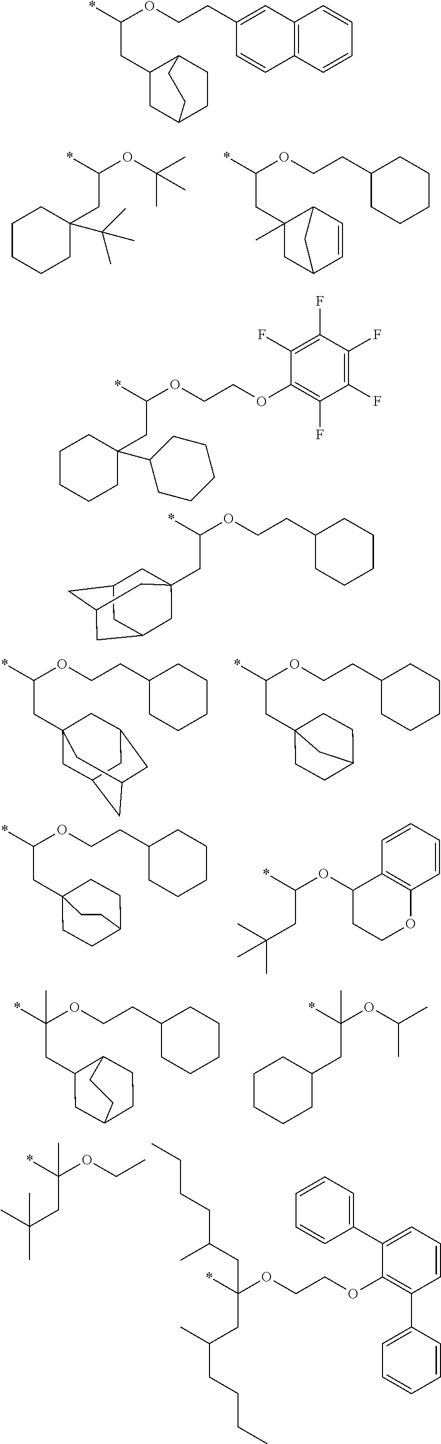

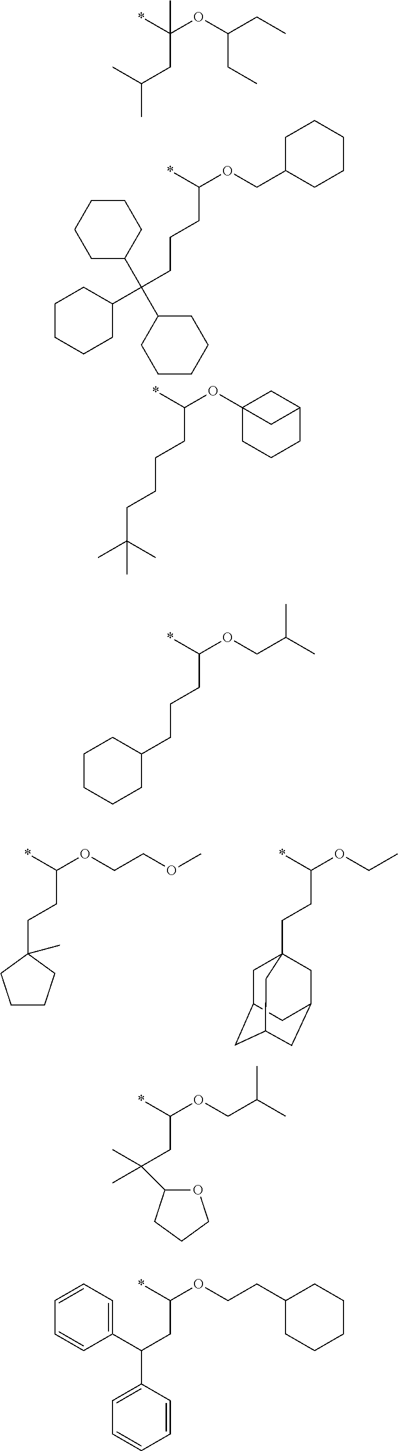

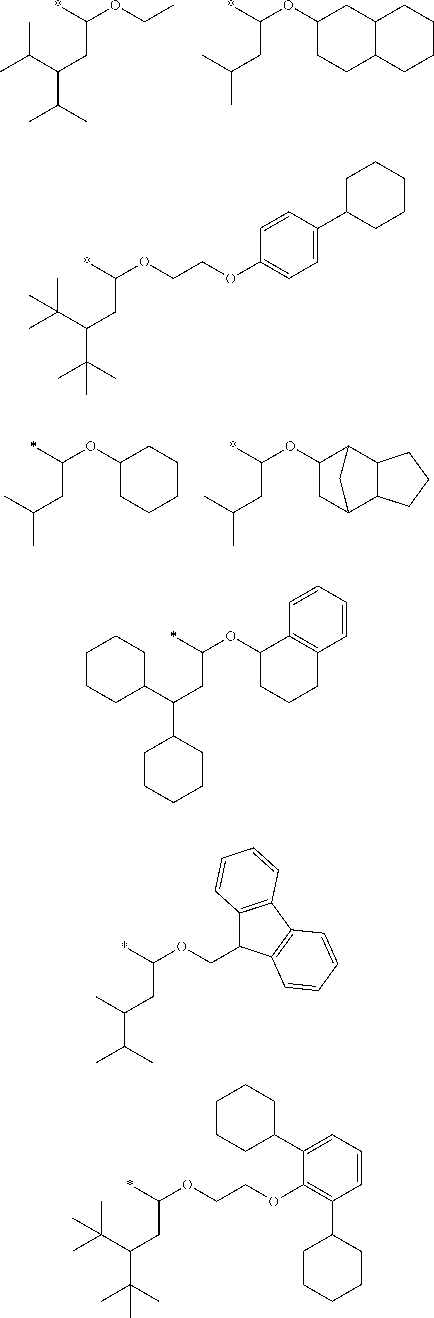

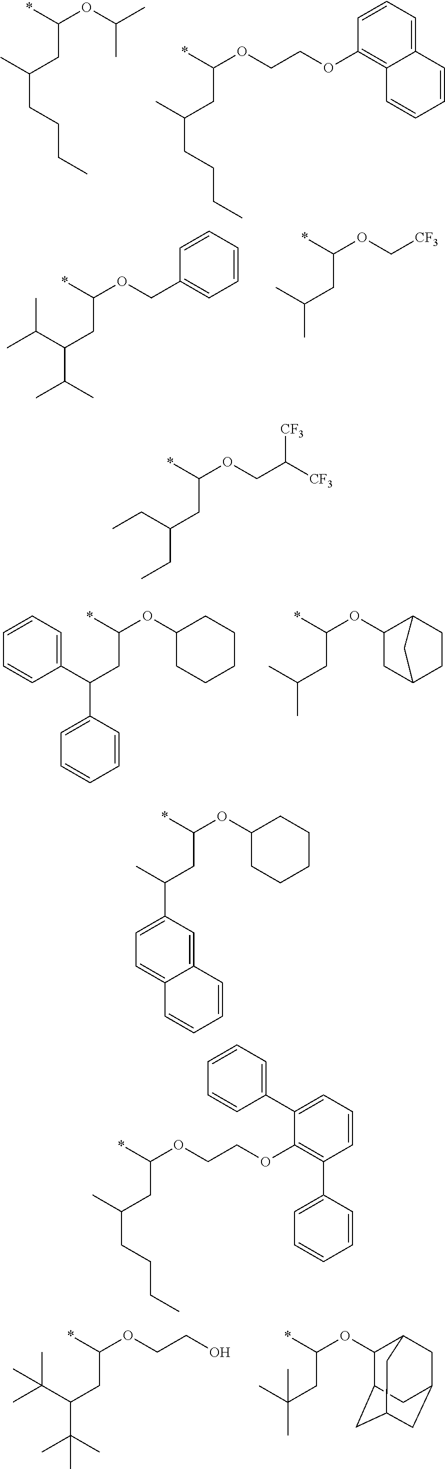

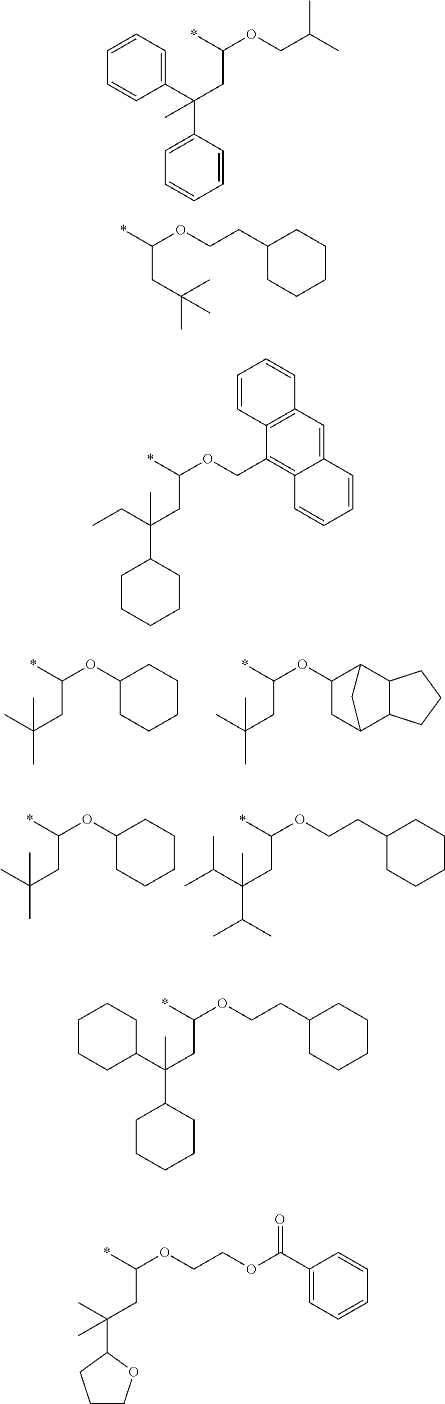

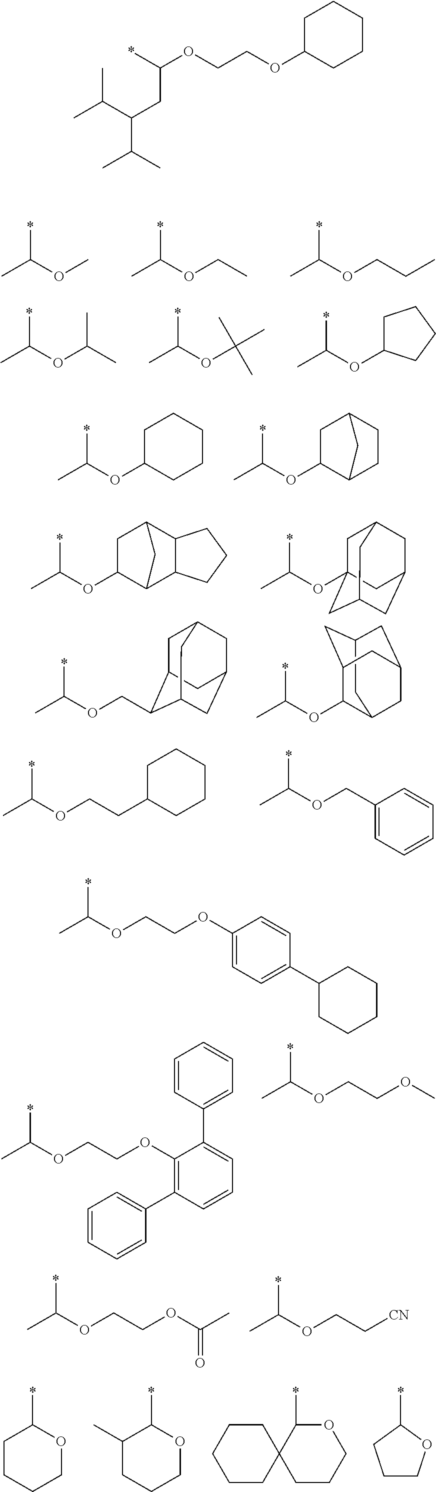

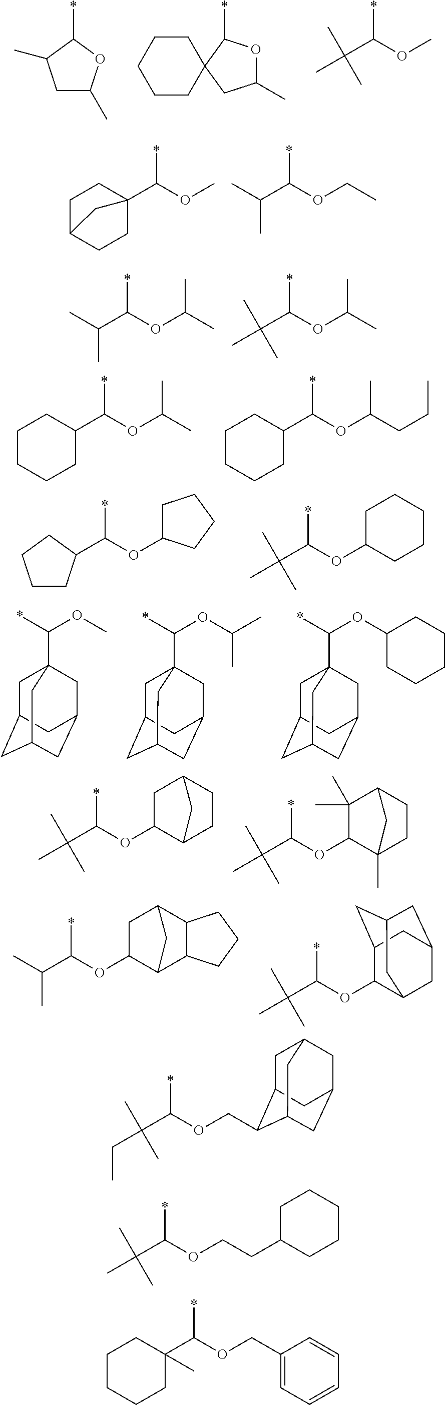

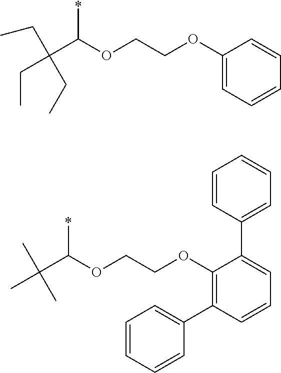

Particular examples of the repeating units of general formula (VI) are shown below, which in no way limit the scope of the present invention.

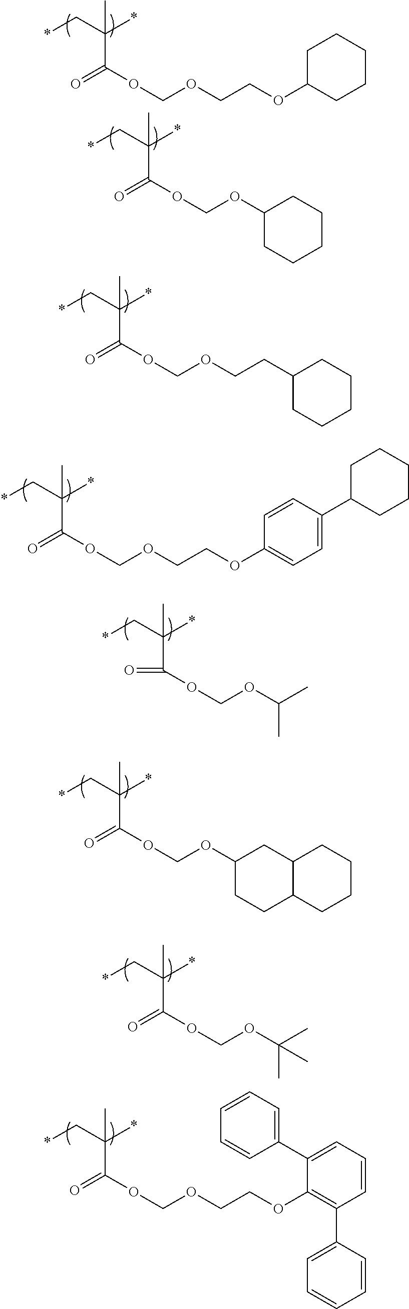

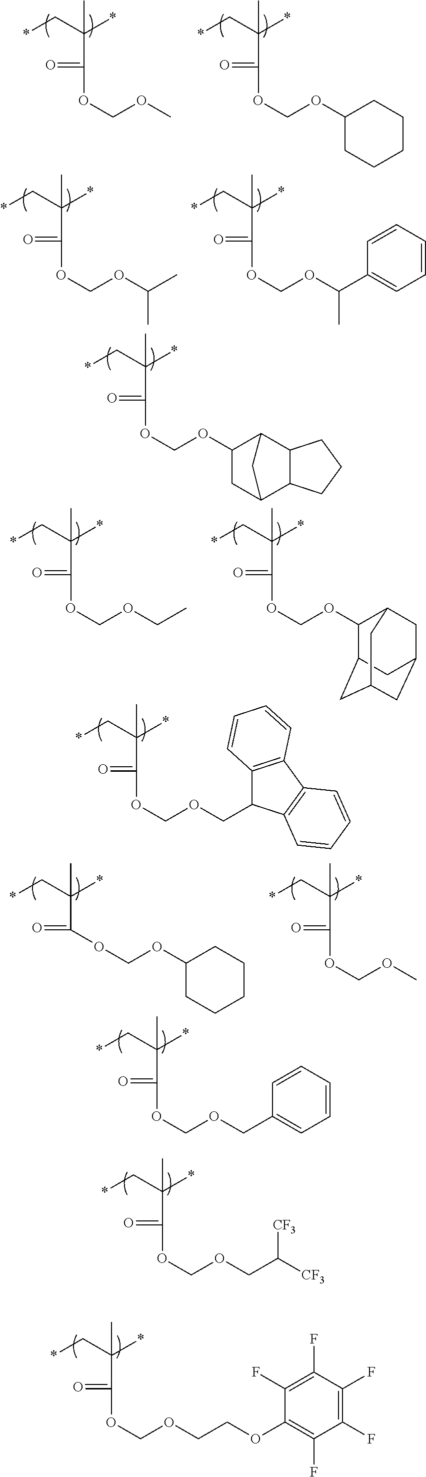

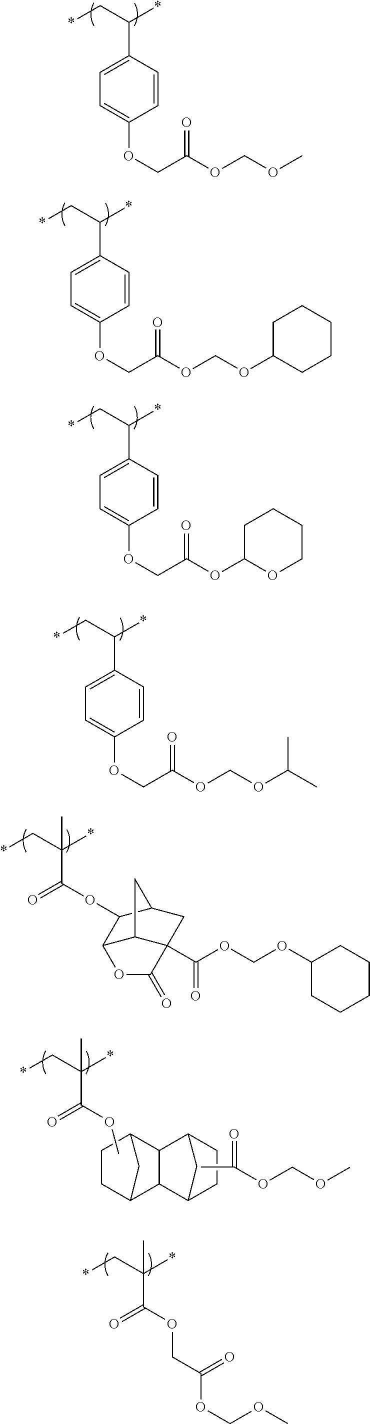

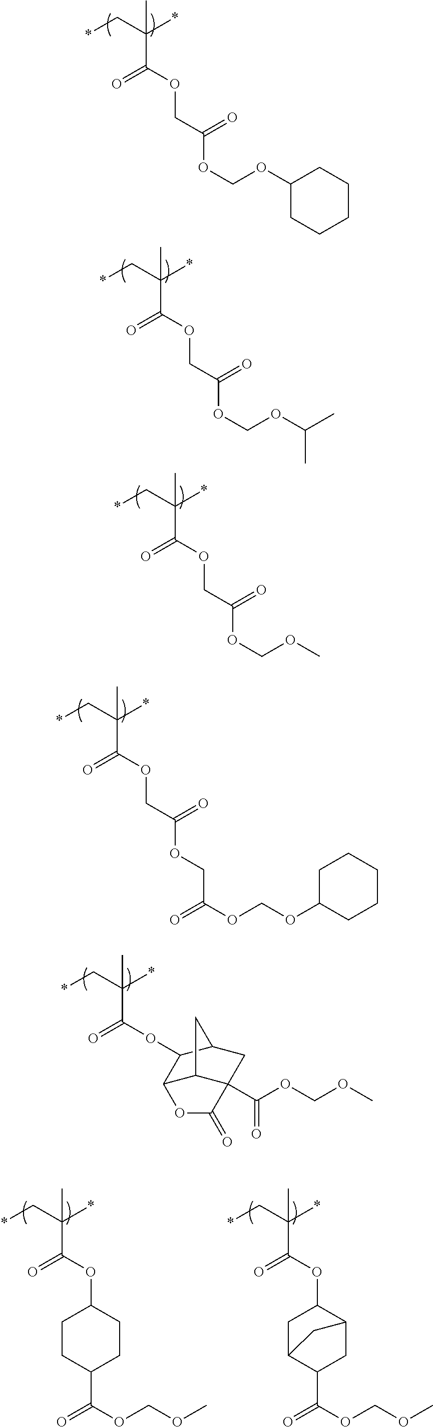

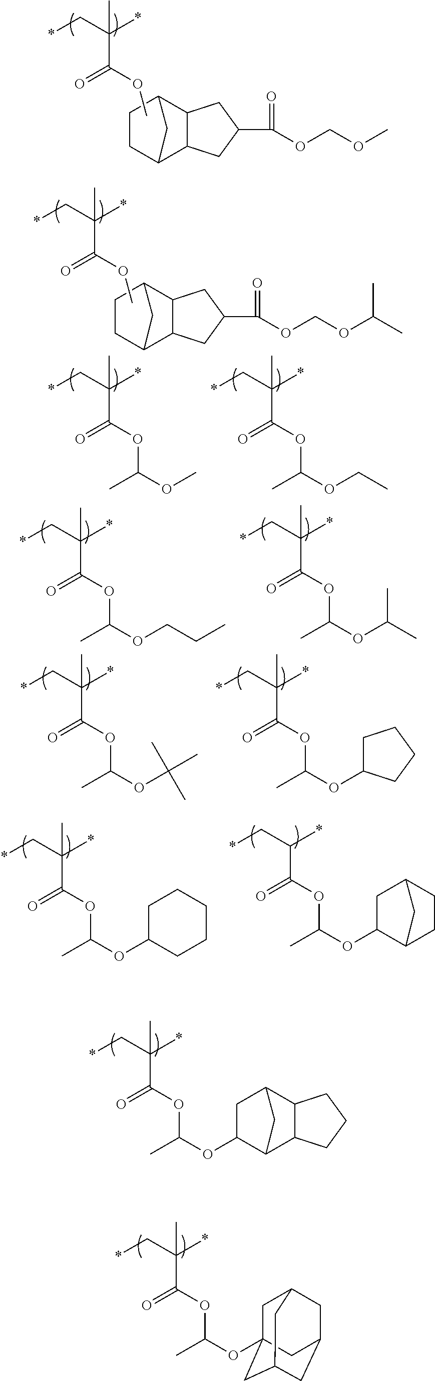

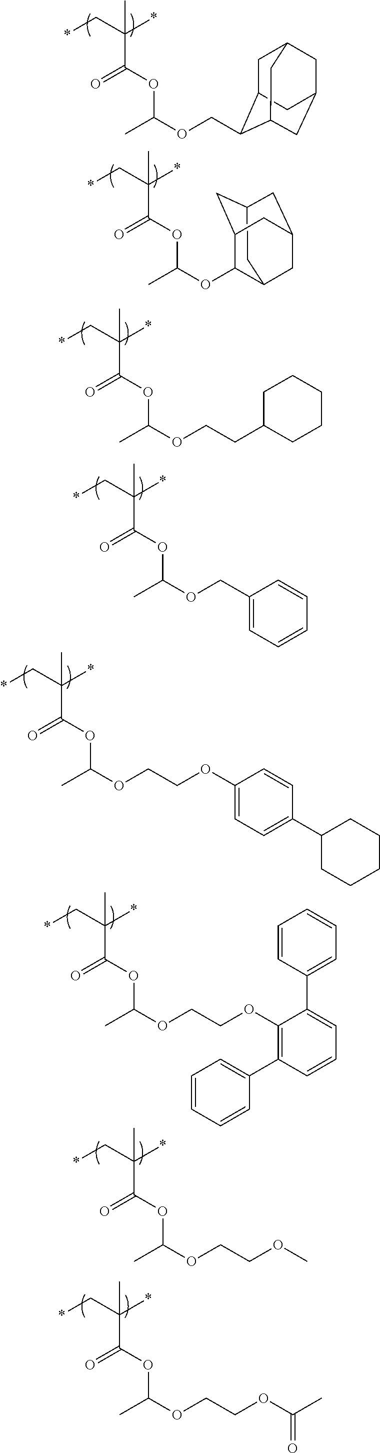

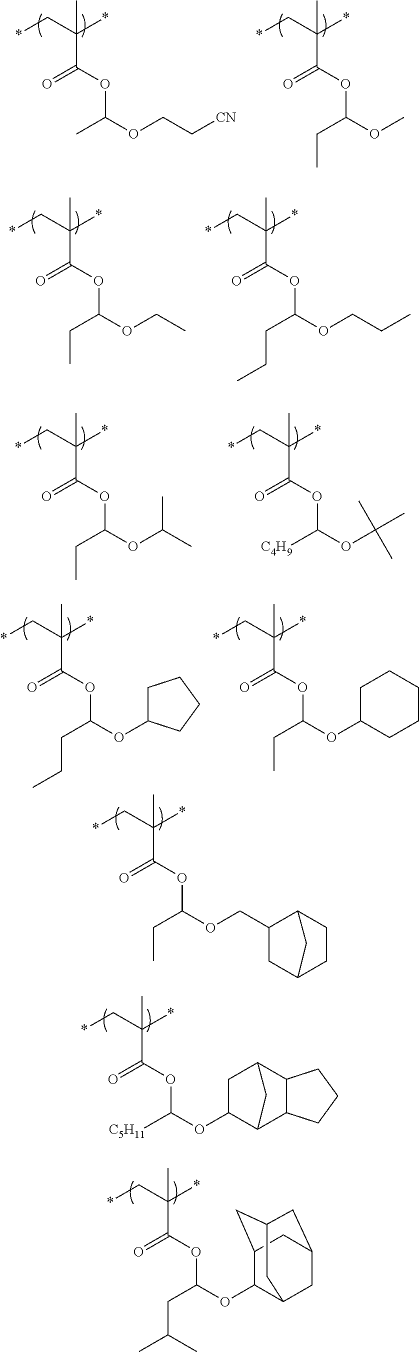

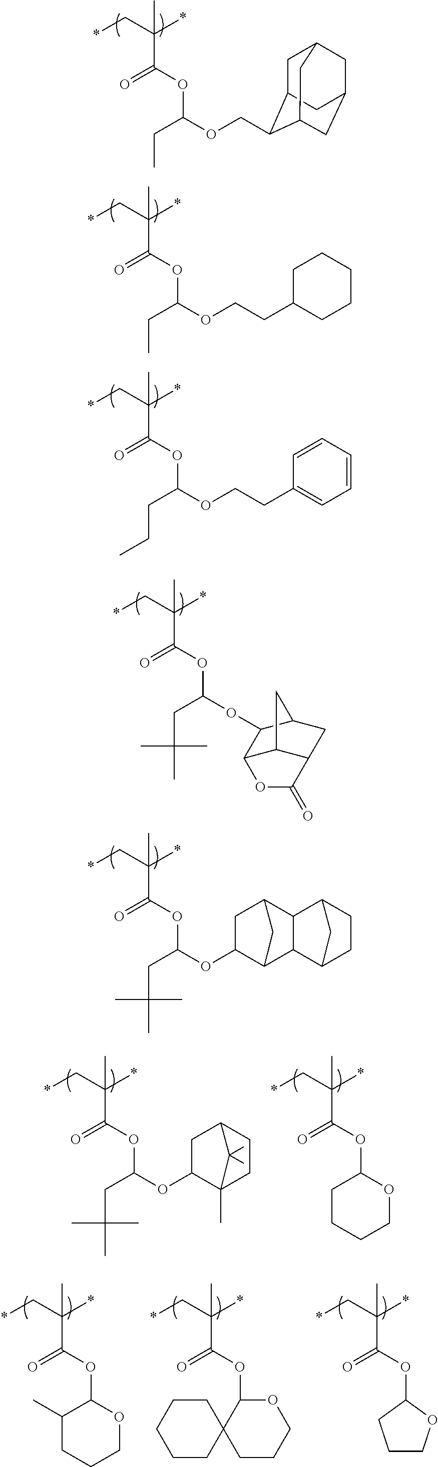

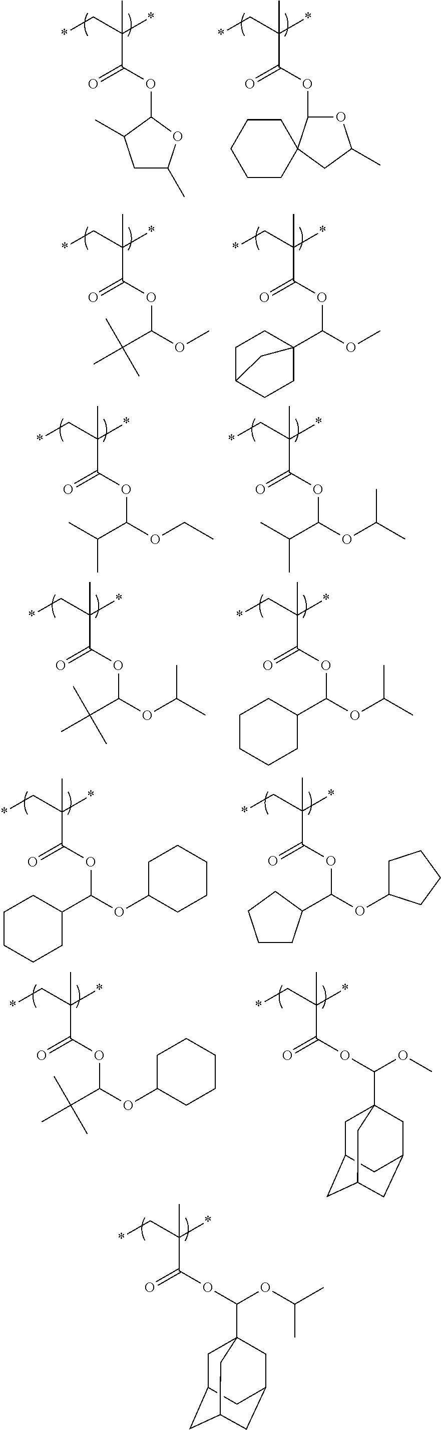

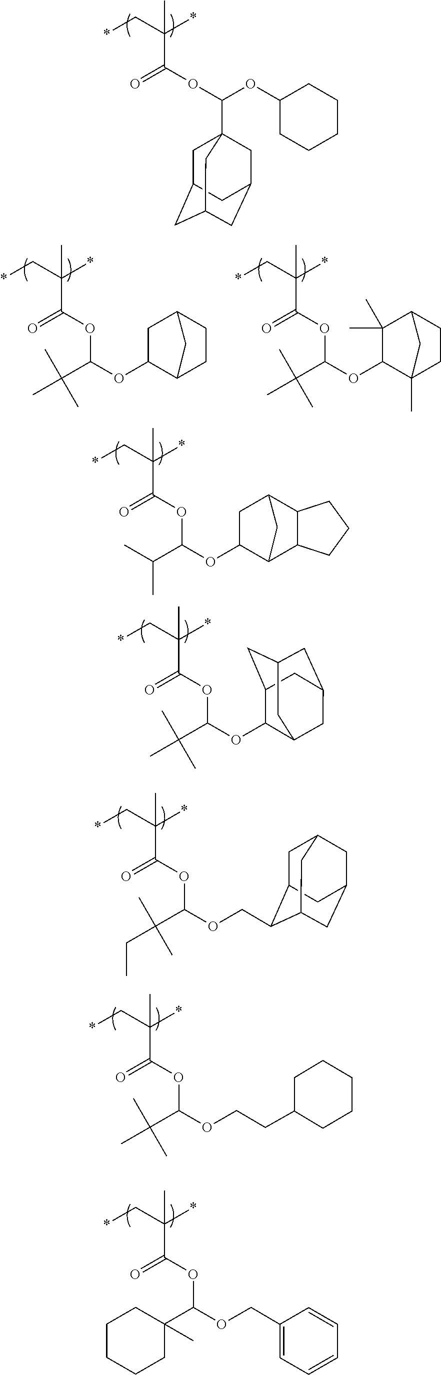

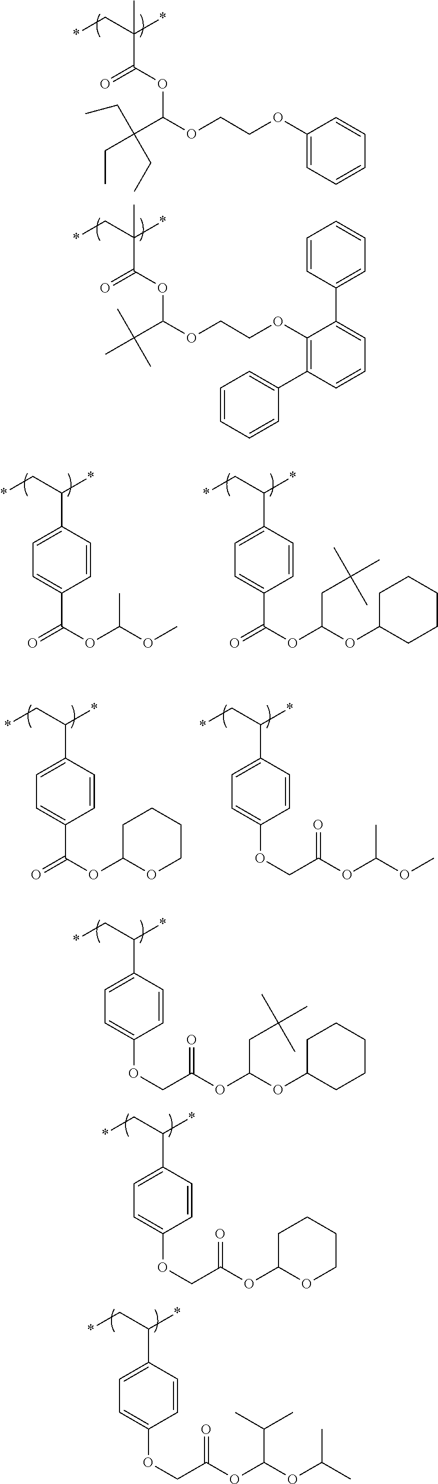

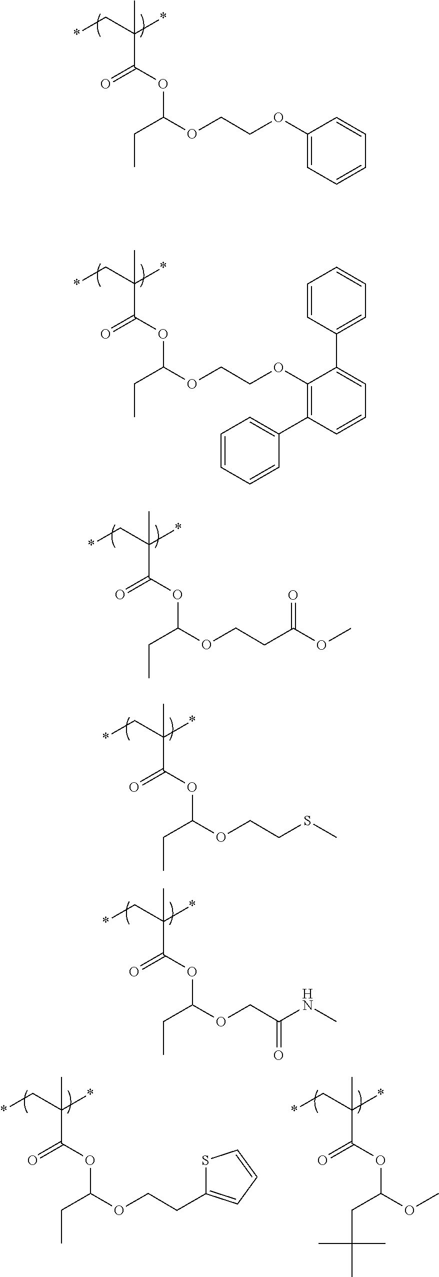

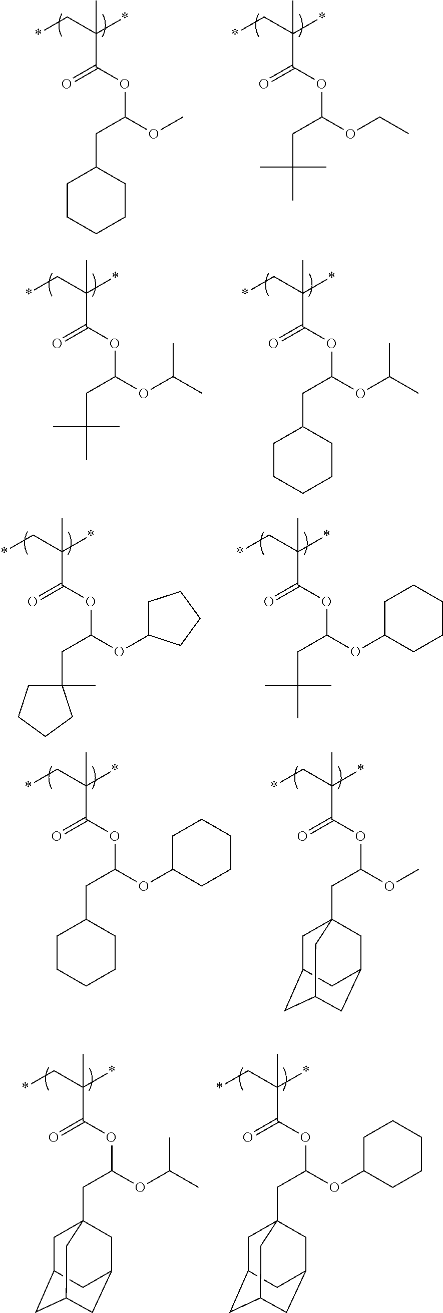

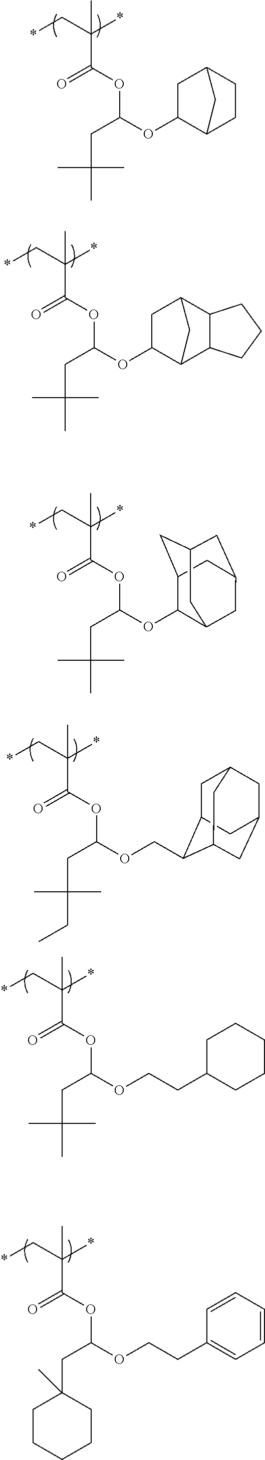

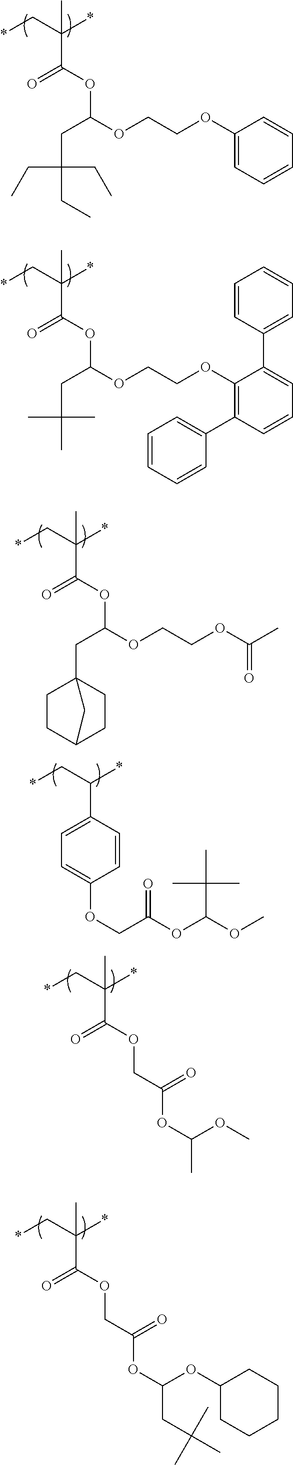

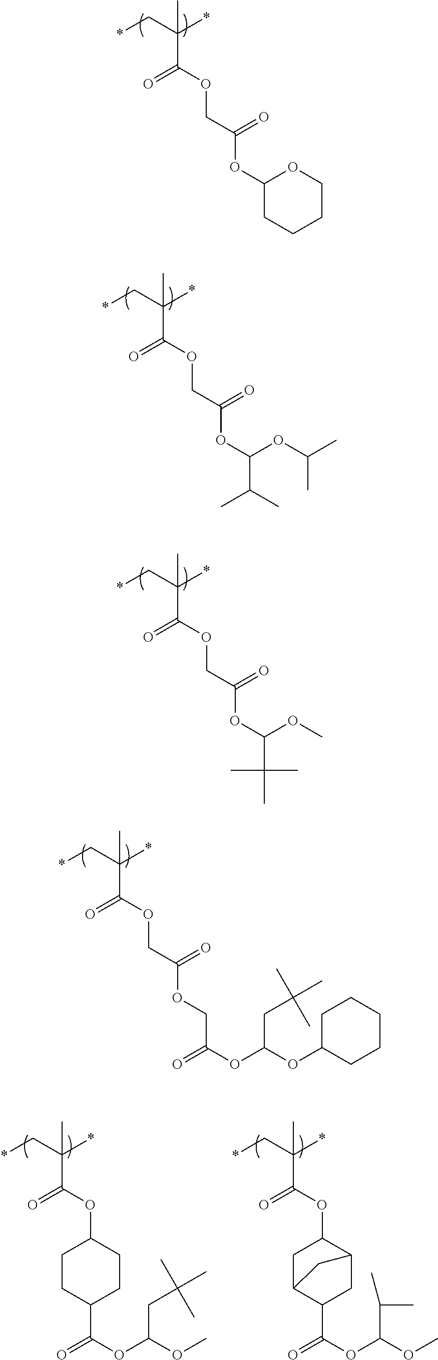

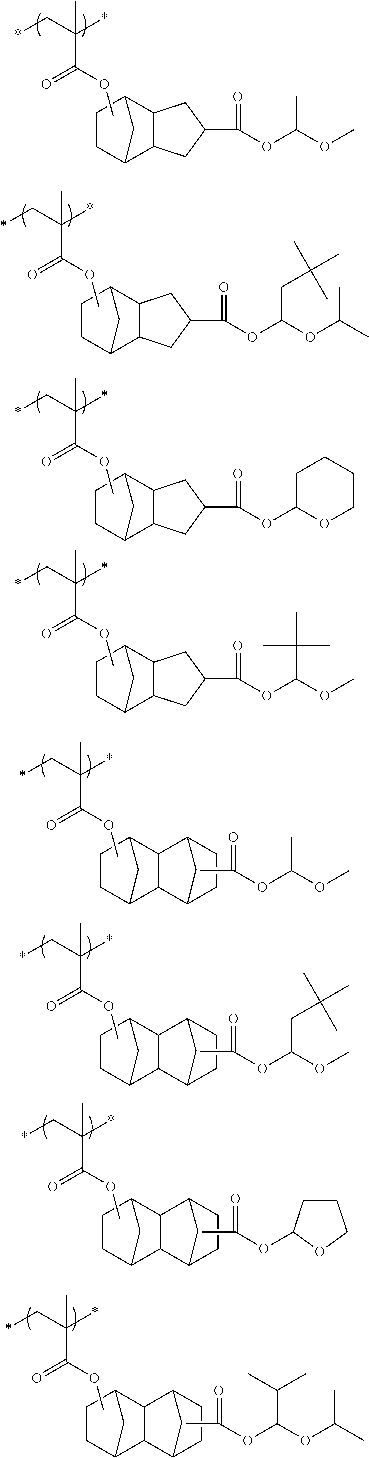

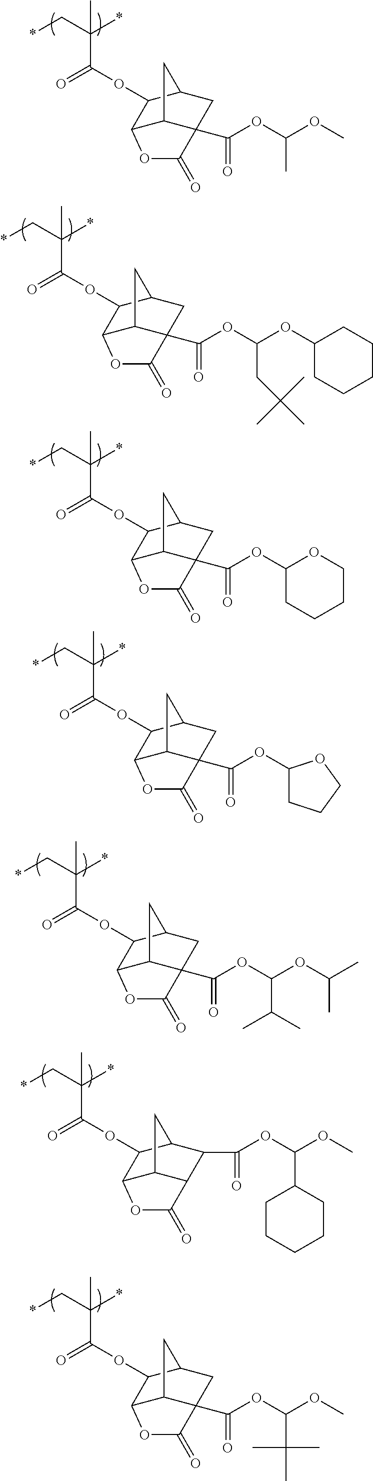

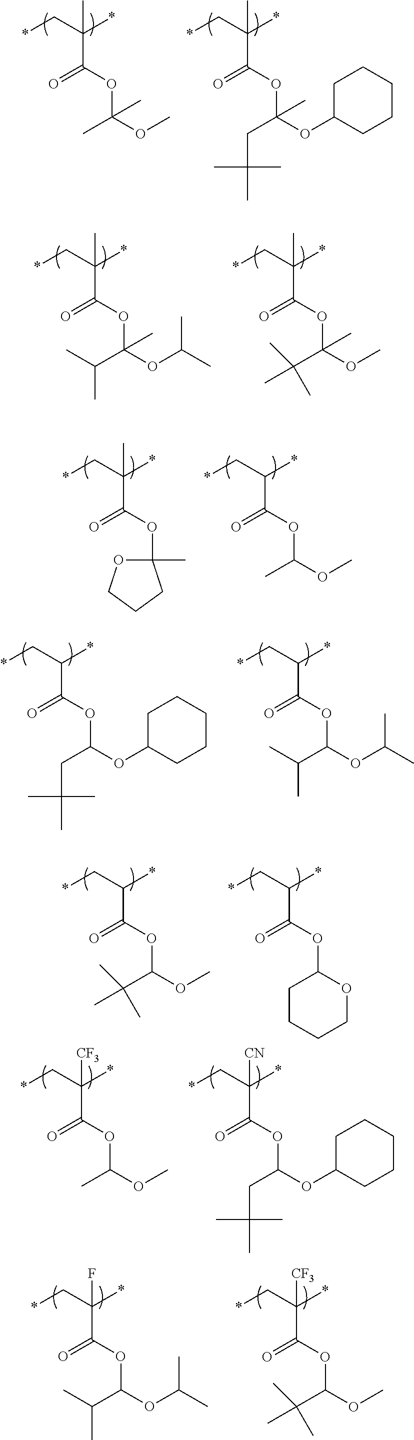

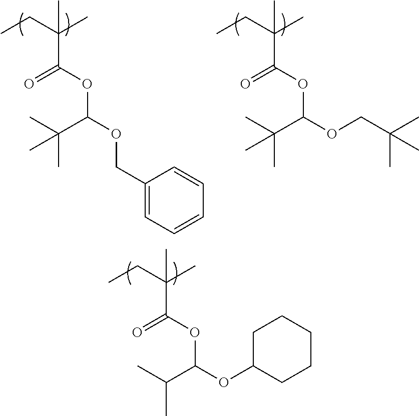

It is optional for the resin (P) to contain the repeating unit (B). When the repeating unit (B) is contained, the content thereof in the resin (P) based on all the repeating units of the resin (P) is preferably in the range of 1 to 80 mol %, more preferably 10 to 70 mol % and further more preferably 20 to 60 mol %.

[Repeating Unit (C)]

The resin (P) may comprise any of repeating units (C) of general formula (III) below.

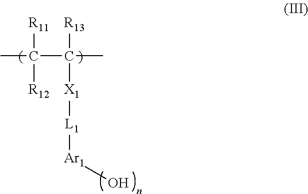

In general formula (III),

each of R₁₁, R₁₂ and R₁₃ independently represents a hydrogen atom, an alkyl group, a cycloalkyl group, a halogen atom, a cyano group or an alkoxycarbonyl group, provided that R₁₂ may be bonded to Ar₁ to thereby form a ring, which R₁₂ represents an alkylene group.

X₁ represents a single bond, —COO— or —CONR₁₄— in which R₁₄ represents a hydrogen atom or an alkyl group.

L₁ represents a single bond or an alkylene group.

Ar₁ represents a (n+1)-valent aromatic ring group, provided that Ar₁, when bonded to R₁₂, represents a (n+2)-valent aromatic ring group; and

n is an integer of 1 or greater.

Each of the alkyl groups represented by R₁₁ to R₁₃ is, for example, an alkyl group having up to 20 carbon atoms. Preferred examples thereof are a methyl group, an ethyl group, a propyl group, an isopropyl group, an n-butyl group, a sec-butyl group, a hexyl group, a 2-ethylhexyl group, an octyl group and a dodecyl group. Alkyl groups each having up to 8 carbon atoms are more preferred. Substituents may be introduced in these alkyl groups.

The alkyl group contained in the alkoxycarbonyl group is preferably any of those set forth above in connection with R₁₁ to R₁₃.

The cycloalkyl group may be monocyclic or polycyclic. As preferred examples thereof, there can be mentioned monocycloalkyl groups each having 3 to 8 carbon atoms, such as a cyclopropyl group, a cyclopentyl group and a cyclohexyl group. Substituents may be introduced in these cycloalkyl groups.

As the halogen atom, there can be mentioned a fluorine atom, a chlorine atom, a bromine atom or an iodine atom. A fluorine atom is preferred.

When R₁₂ is an alkylene group, the alkylene group is preferably one having 1 to 8 carbon atoms, such as a methylene group, an ethylene group, a propylene group, a butylene group, a hexylene group or an octylene group.

Preferably, each of R₁₁, R₁₂ and R₁₃ independently is a hydrogen atom or an alkyl group. A hydrogen atom is more preferred.

X₁ represents a single bond, —COO— or —CONR₁₄— in which R₁₄ represents a hydrogen atom or an alkyl group.

The alkyl groups represented by R₁₄ are the same as set forth above in connection with R₁₁ to R₁₃. Preferred ranges are also the same.

X₁ is most preferably a single bond.

L₁ represents a single bond or an alkylene group.

The alkylene group represented by L₁ is preferably a linear or branched alkylene group having 1 to 20 carbon atoms, more preferably 1 to 10 carbon atoms. As such, there can be mentioned, for example, a methylene group, an ethylene group, a propylene group or the like.

L₁ is most preferably a single bond.

Ar¹ represents a (n+1)-valent aromatic ring group, provided that Ar₁, when bonded to R₁₂, represents a (n+2)-valent aromatic ring group.

When n is 1, the bivalent aromatic ring groups represented by Ar₁ are the same as those represented by Ar² when p is 1 in general formula (II) above. Preferred ranges are also the same.

Substituents may be introduced in the (n+1)-valent aromatic ring groups represented by Ar₁ in general formula (III). Such substituents are the same as those that may be introduced in the (p+1)-valent aromatic ring groups represented by Ar² in general formula (II) above. Preferred ranges are also the same.

As particular examples of the (n+1)-valent aromatic ring groups represented by Ar₁ when n is an integer of 2 or greater, there can be mentioned the groups resulting from the removal of (n−1) arbitrary hydrogen atoms from each of the bivalent aromatic ring groups set forth above.

In the formula, n is an integer of 1 or greater, preferably 1 to 5 and more preferably 1 or 2. Most preferably, n is 1.

In each of the repeating units of general formula (III), when Ar¹ is a phenylene group, the site of bonding of —OH to the benzene ring of Ar₁ may be any of para-, meta- and ortho-positions to the site of bonding of the benzene ring to L₁ or X₁ (principal chain of polymer when L₁ and X₁ are simultaneously single bonds). Para- and meta-positions are preferred, and para-position is most preferred.

It is preferred for the repeating unit (C) to be any of repeating units of general formula (IV) below from the viewpoint of simultaneous enhancement of sensitivity and resolution.

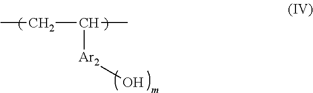

In general formula (IV),

Ar₂ represents a (m+1)-valent aromatic ring group, and m is an integer of 1 or greater.

Ar₂ represents a (m+1)-valent aromatic ring group.

When m is 1, the bivalent aromatic ring groups represented by Ar₂ are the same as those represented by Ar² when p is 1 in general formula (II) above. Preferred ranges are also the same.

Substituents may be introduced in the (m+1)-valent aromatic ring groups represented by Ar₂ in general formula (IV). Such substituents are the same as those that may be introduced in the (p+1)-valent aromatic ring groups represented by Ar² in general formula (II) above. Preferred ranges are also the same.

As particular examples of the (m+1)-valent aromatic ring groups represented by Ar₂ when m is an integer of 2 or greater, there can be mentioned the groups resulting from the removal of (m−1) arbitrary hydrogen atoms from each of the bivalent aromatic ring groups set forth above.

In the formula, m is an integer of 1 or greater, preferably 1 to 5 and more preferably 1 or 2. Most preferably, m is 1.

In each of the repeating units of general formula (IV), when Ar₂ is a phenylene group, the site of bonding of —OH to the benzene ring of Ar₂ may be any of para-, meta- and ortho-positions to the site of bonding of the benzene ring to the principal chain of polymer. Para- and meta-positions are preferred, and para-position is most preferred.

The repeating unit (C) is a repeating unit containing an alkali-soluble group and functions as a controller of the alkali developability of the resist.

Nonlimiting particular examples of the repeating units (C) are shown below.

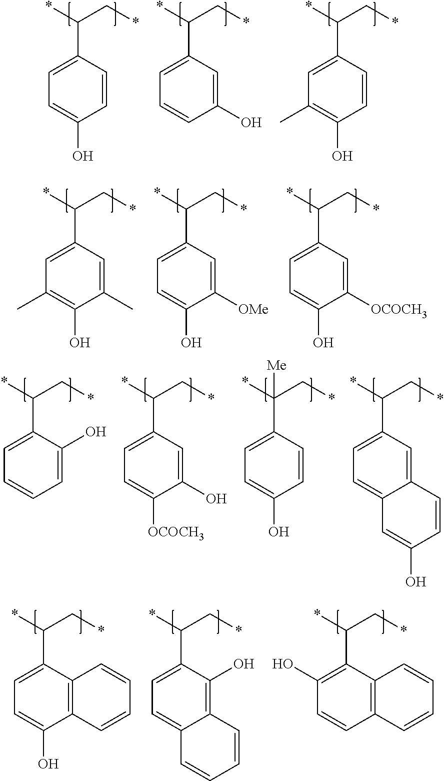

Among these, preferred examples of the repeating units (C) are those in which the aromatic ring group represented by Ar₁ or Ar₂ is an unsubstituted phenylene group. Preferred examples of the repeating units (C) are as follows.

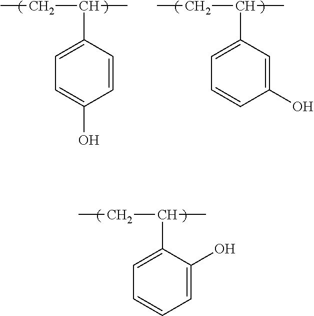

The content of repeating unit (C) in the resin (P), based on all the repeating units of the resin (P), is preferably in the range of 3 to 98 mol %, more preferably 10 to 80 mol % and further more preferably 25 to 70 mol %.

The resin (P) for use in the present invention preferably further comprises the following repeating units as repeating units other than the foregoing repeating units (A) to (C).

For example, there can be mentioned a repeating unit containing a group that is decomposed by the action of an alkali developer to thereby increase its rate of dissolution in the alkali developer. As such a group, there can be mentioned a group with a lactone structure, a group with a phenyl ester structure, or the like. The repeating unit containing a group that is decomposed by the action of an alkali developer to thereby increase its rate of dissolution in the alkali developer is preferably any of repeating units of general formula (AII) below.

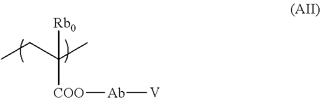

In general formula (AII), V represents a group that is decomposed by the action of an alkali developer to thereby increase its rate of dissolution into the alkali developer. Rb₀ represents a hydrogen atom or a methyl group. Ab represents a single bond or a bivalent organic group.

V representing a group that is decomposed by the action of an alkali developer is a group with an ester bond. In particular, a group with a lactone structure is preferred. The group with a lactone structure is not limited as long as a lactone structure is introduced therein. A 5 to 7-membered ring lactone structure is preferred, and one resulting from the condensation of a 5 to 7-membered ring lactone structure with another cyclic structure effected in a fashion to form a bicyclo structure or spiro structure is especially preferred.

Preferred Ab is a single bond or any of bivalent connecting groups of the formula -AZ-CO₂— (AZ represents an alkylene group or an aliphatic ring group (preferably a cycloalkylene group)). AZ is preferably a methylene group, an ethylene group, a cyclohexylene group, an adamantylene group or a norbornylene group.

Particular examples of these repeating units are shown below. In the formulae, Rx represents H or CH₃.

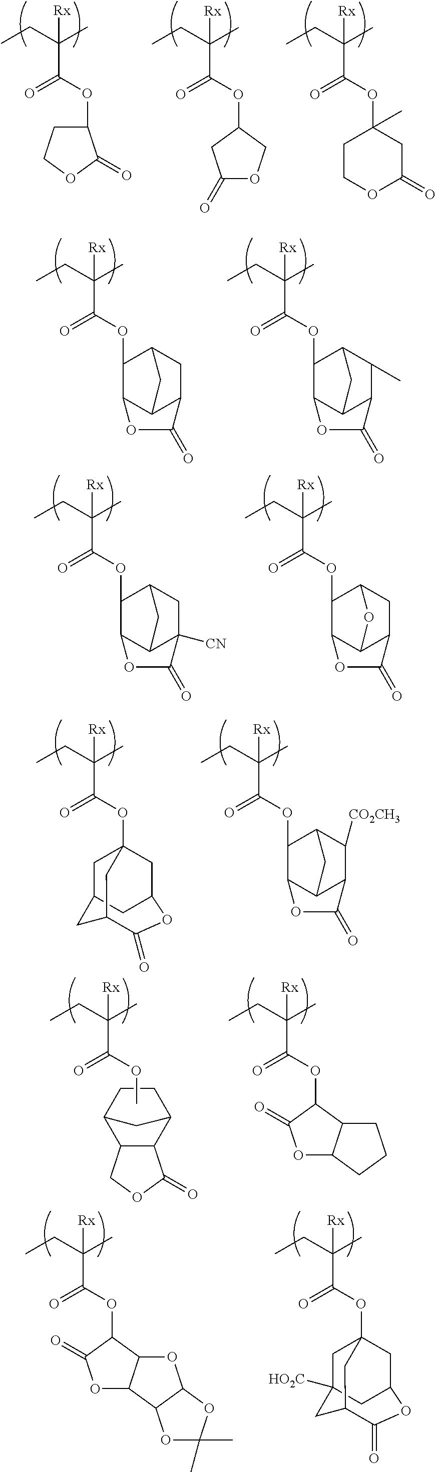

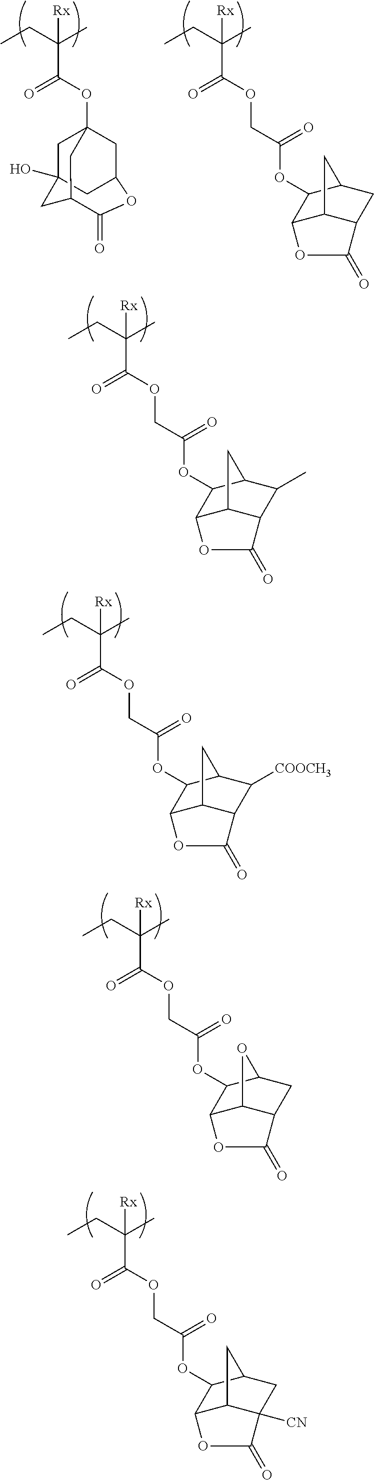

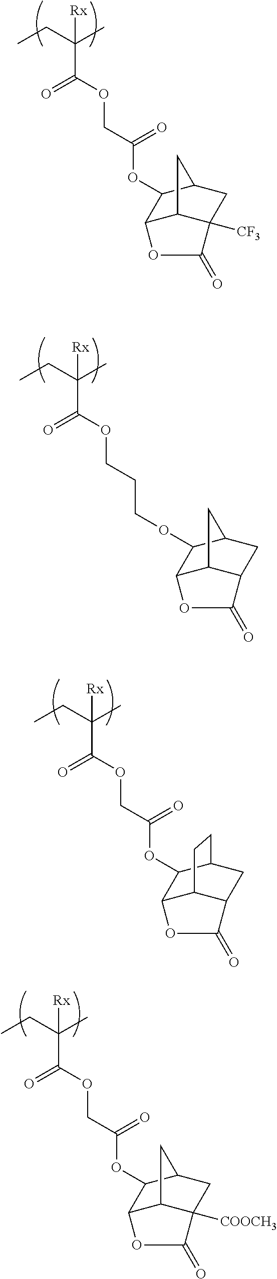

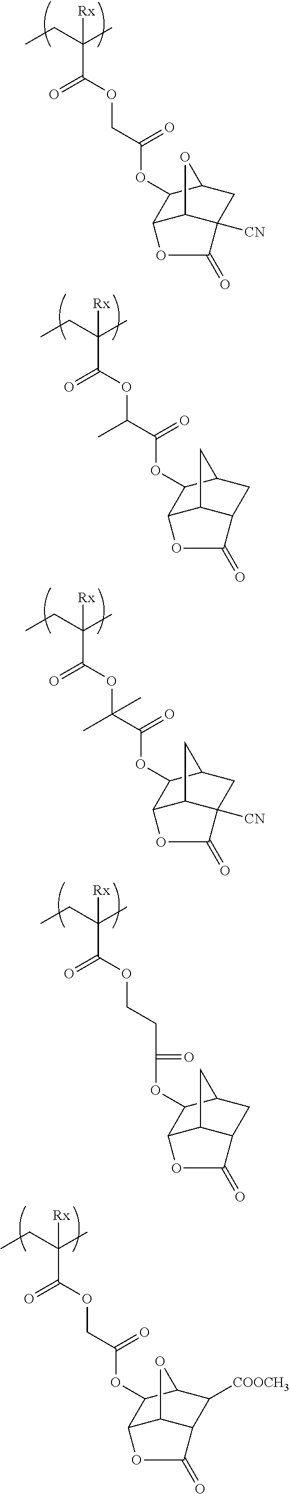

It is optional for the resin (P) to contain a repeating unit containing a group that is decomposed by the action of an alkali developer to thereby increase its rate of dissolution in the alkali developer. When the repeating unit containing the group is contained, the content thereof in the resin (P), based on all the repeating units of the resin (P), is preferably in the range of 5 to 60 mol %, more preferably 5 to 50 mol % and further more preferably 10 to 50 mol %.

As examples of polymerizable monomers for the formation of repeating units other than those mentioned above in the resin (P) according to the present invention, there can be mentioned styrene, an alkyl-substituted styrene, an alkoxy-substituted styrene, an O-alkylated styrene, an O-acylated styrene, a hydrogenated hydroxystyrene, maleic anhydride, an acrylic acid derivative (acrylic acid, an acrylic ester or the like), a methacrylic acid derivative (methacrylic acid, a methacrylic ester or the like), an N-substituted maleimide, acrylonitrile, methacrylonitrile, vinylnaphthalene, vinylanthracene, an optionally substituted indene and the like. Preferred substituted styrenes are 4-(1-naphthylmethoxyl)styrene, 4-benzyloxystyrene, 4-(4-chlorobenzyloxyl)styrene, 3-(1-naphthylmethoxyl)styrene, 3-benzyloxystyrene, 3-(4-chlorobenzyloxyl)styrene and the like.

It is optional for the resin (P) to contain repeating units therefrom. When repeating units therefrom are contained, the content thereof in the resin (P), based on all the repeating units of the resin (P), is preferably in the range of 1 to 80 mol %, more preferably 5 to 50 mol %.

The resin (P) has, for example, any of the following structures.

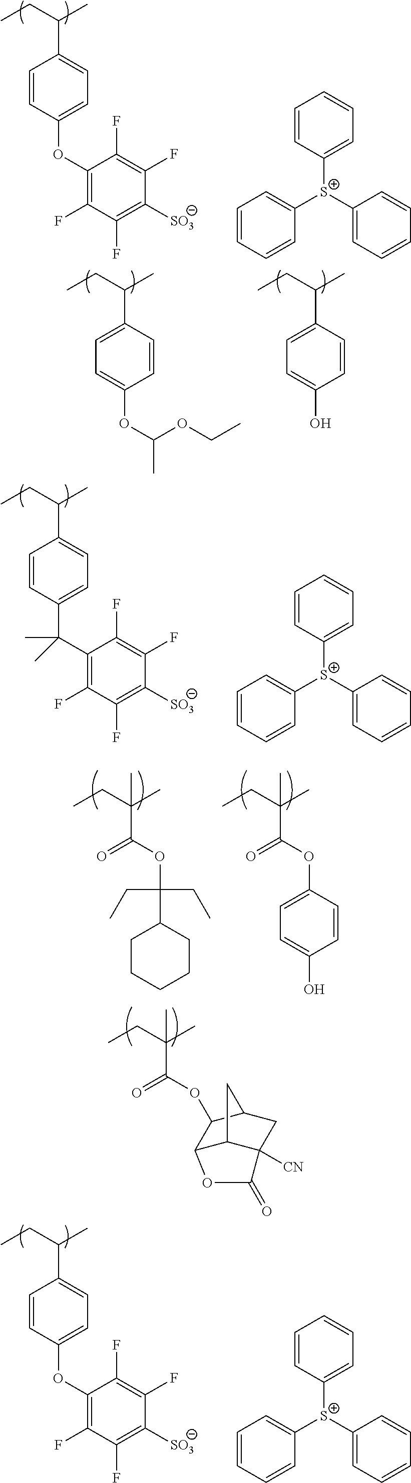

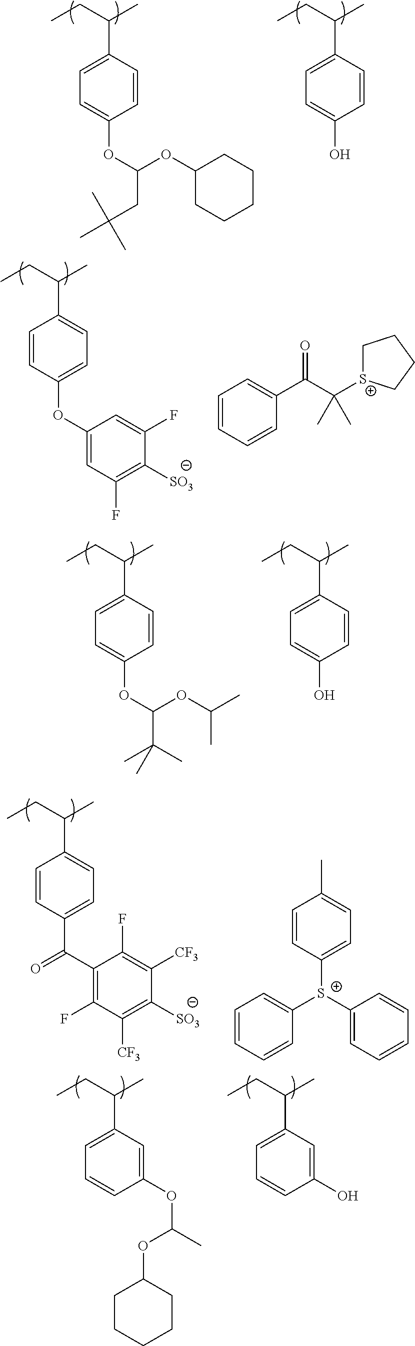

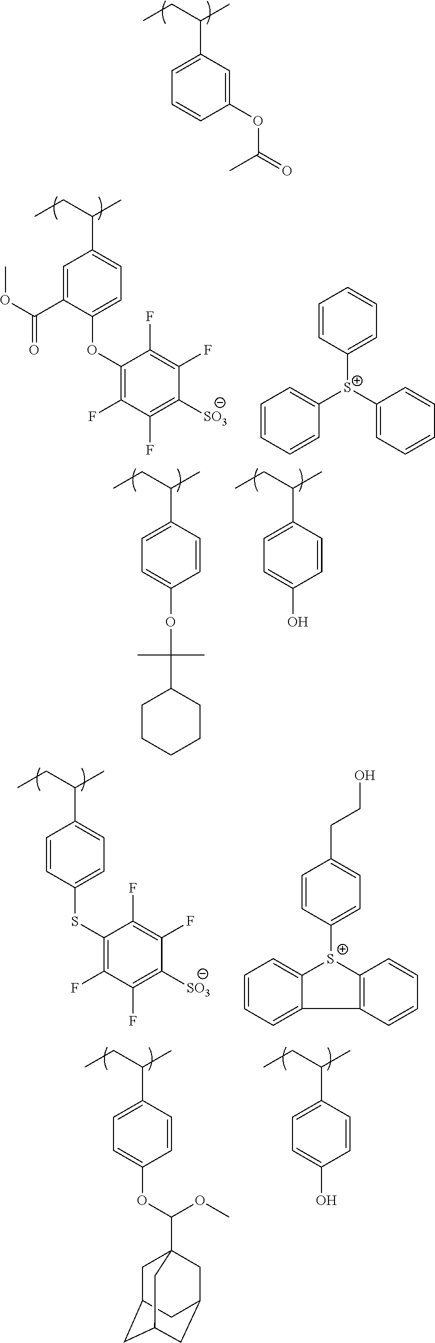

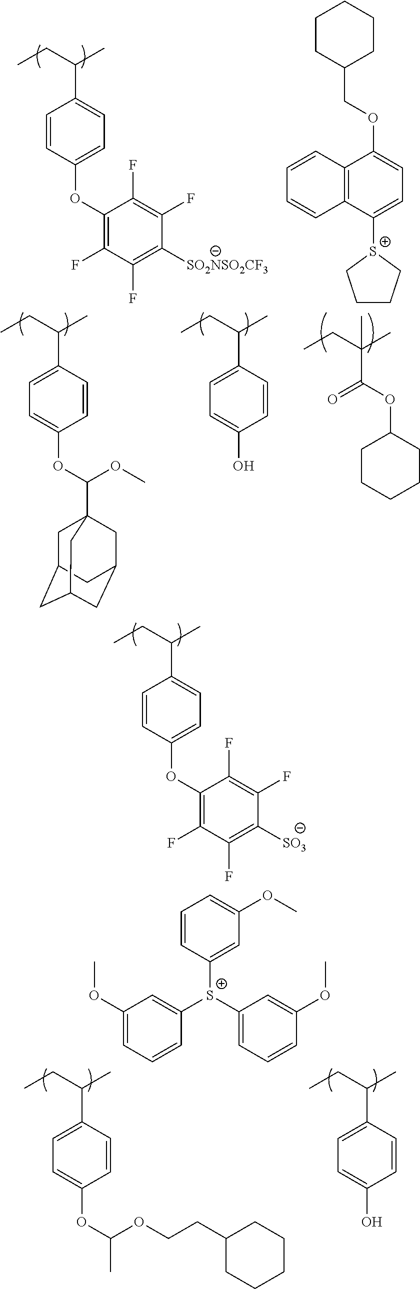

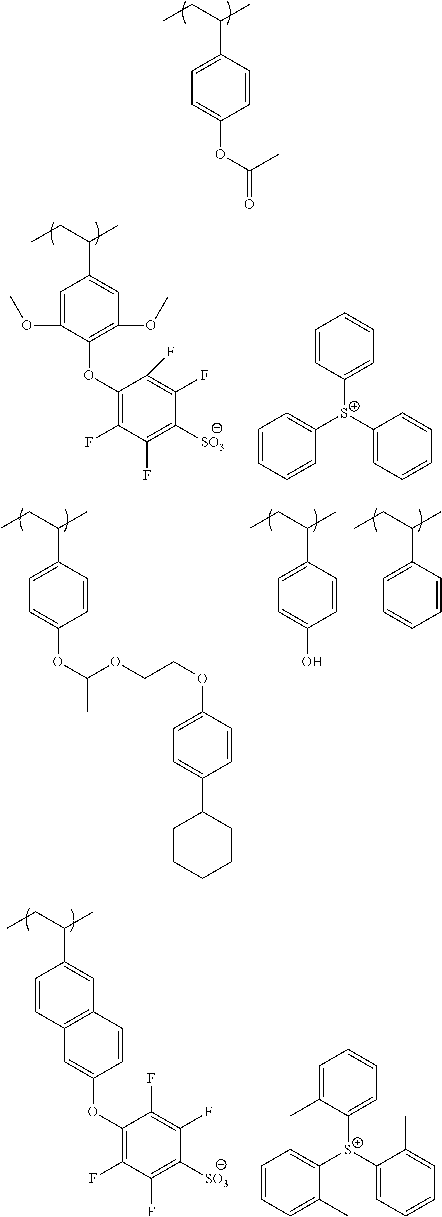

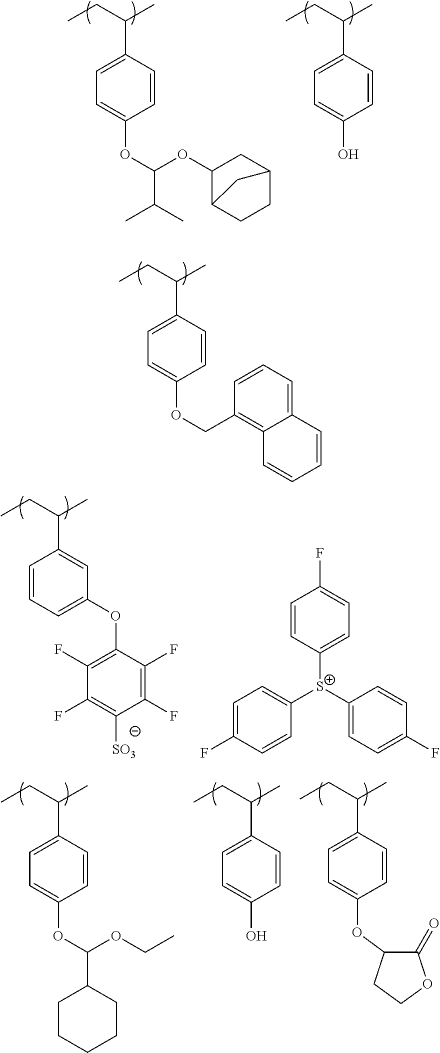

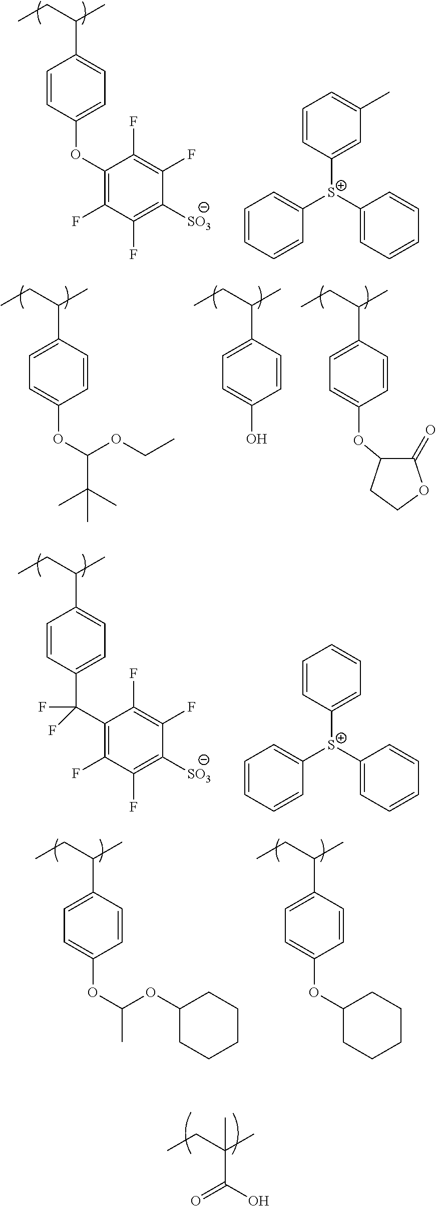

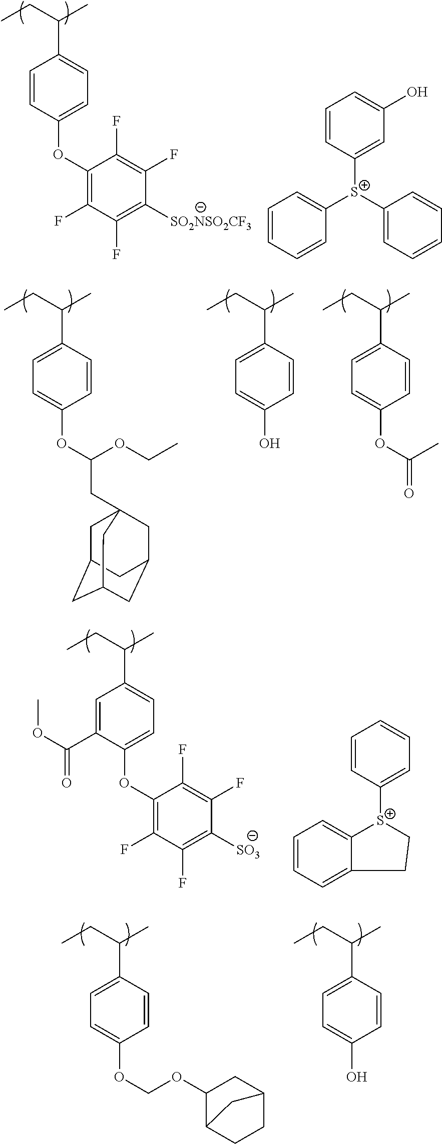

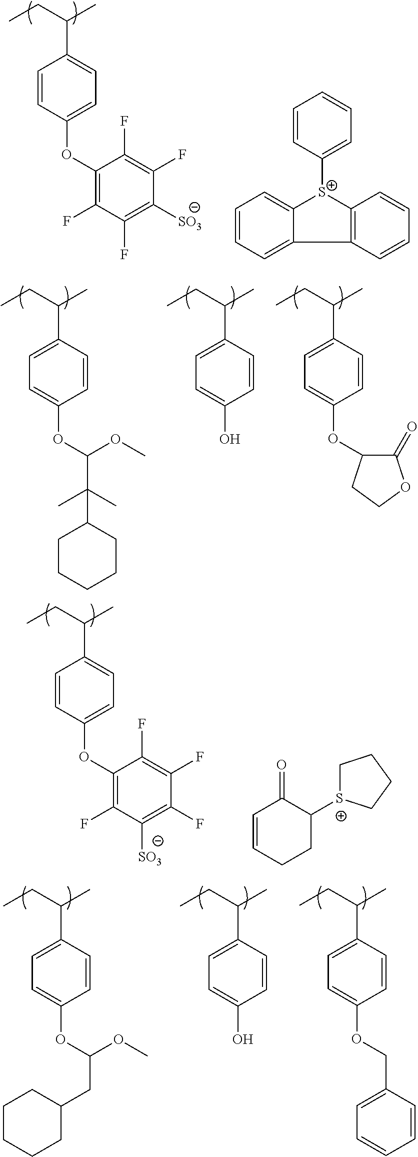

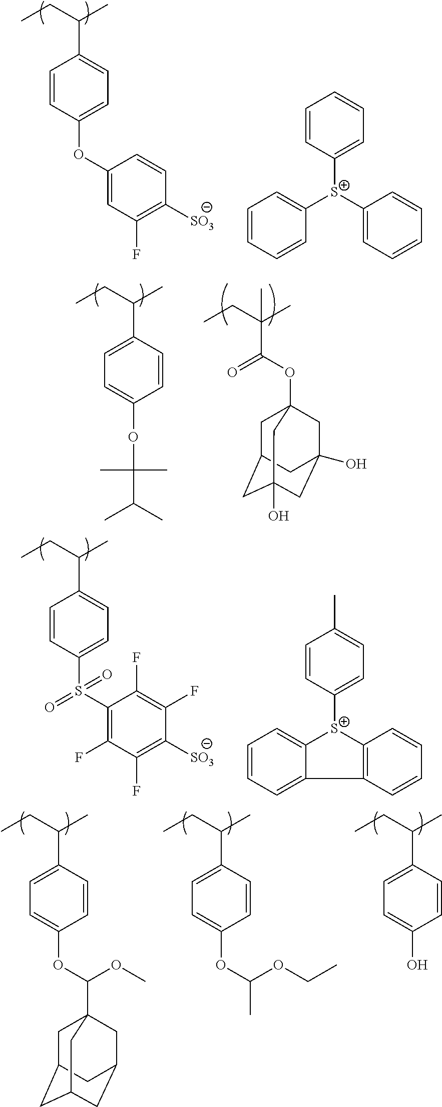

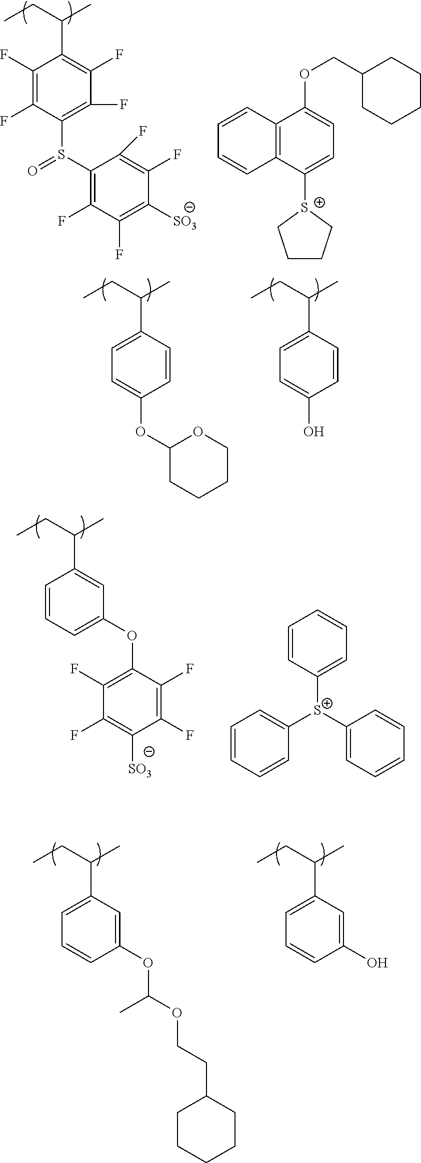

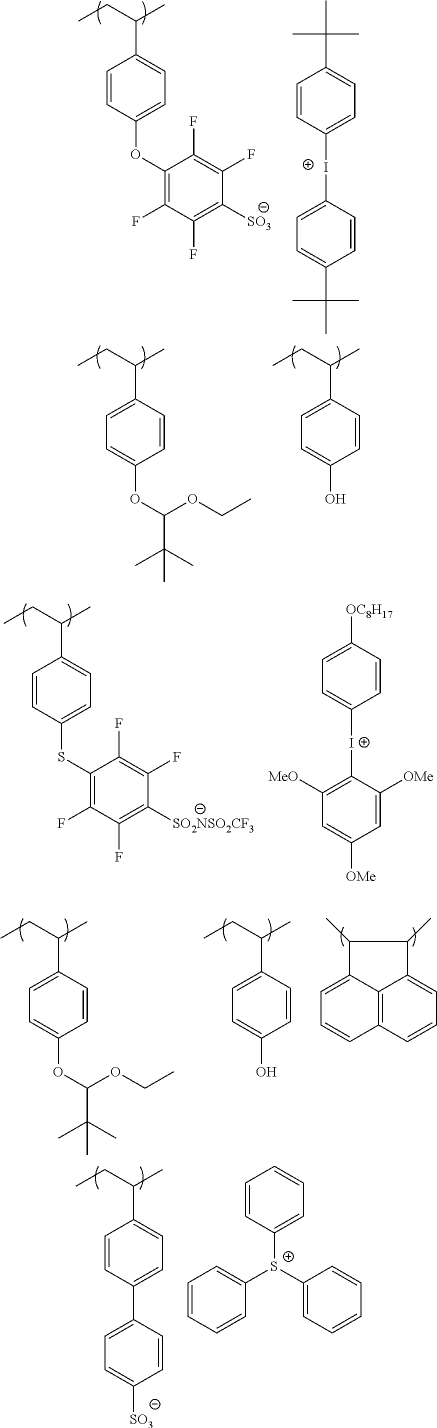

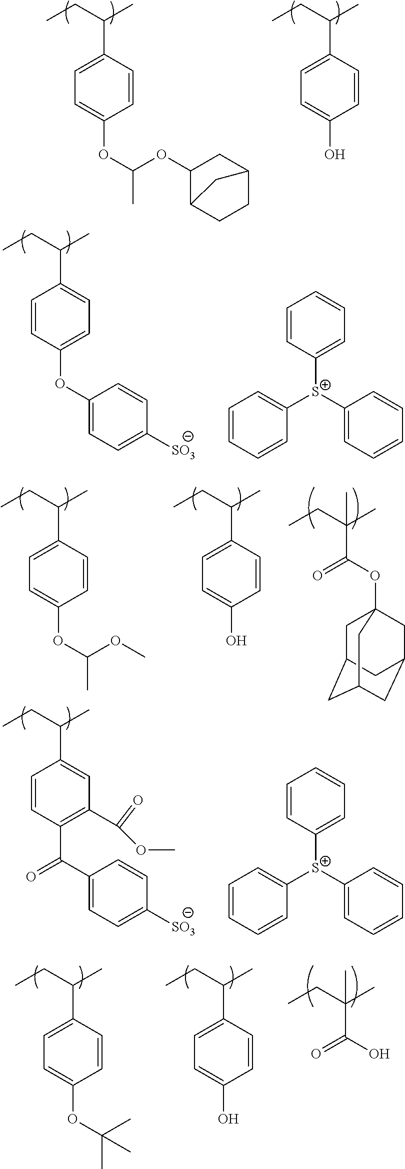

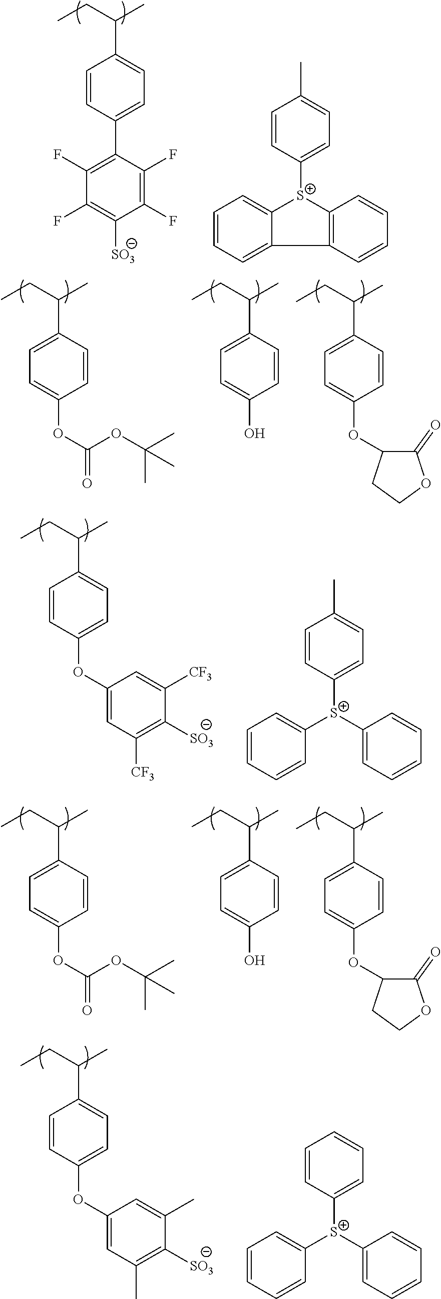

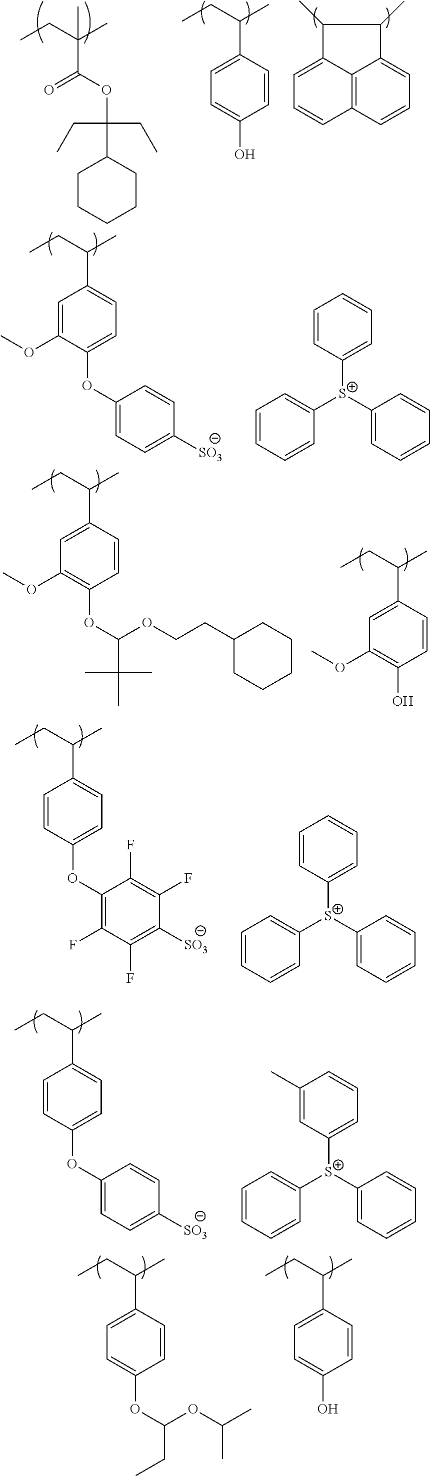

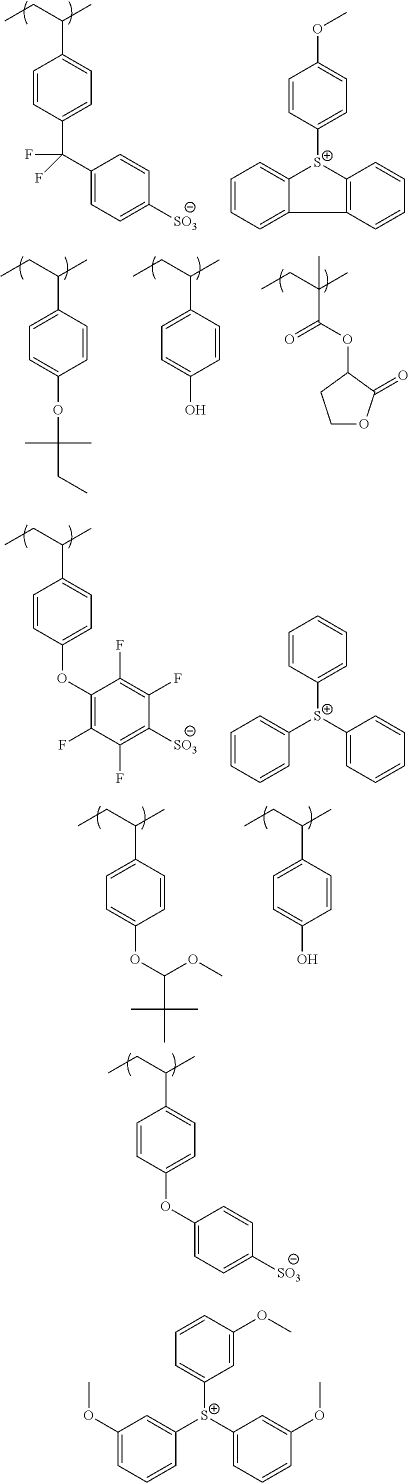

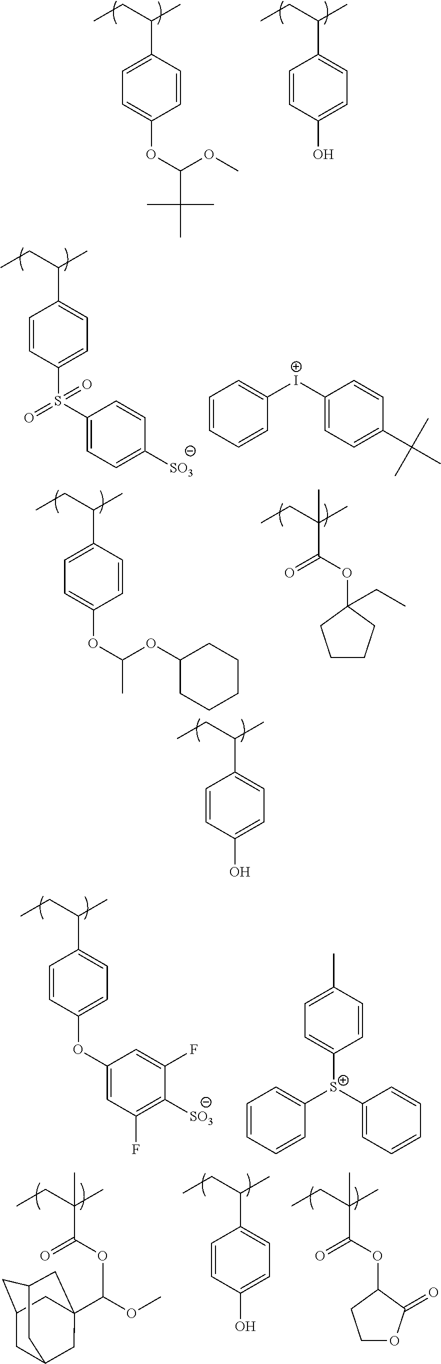

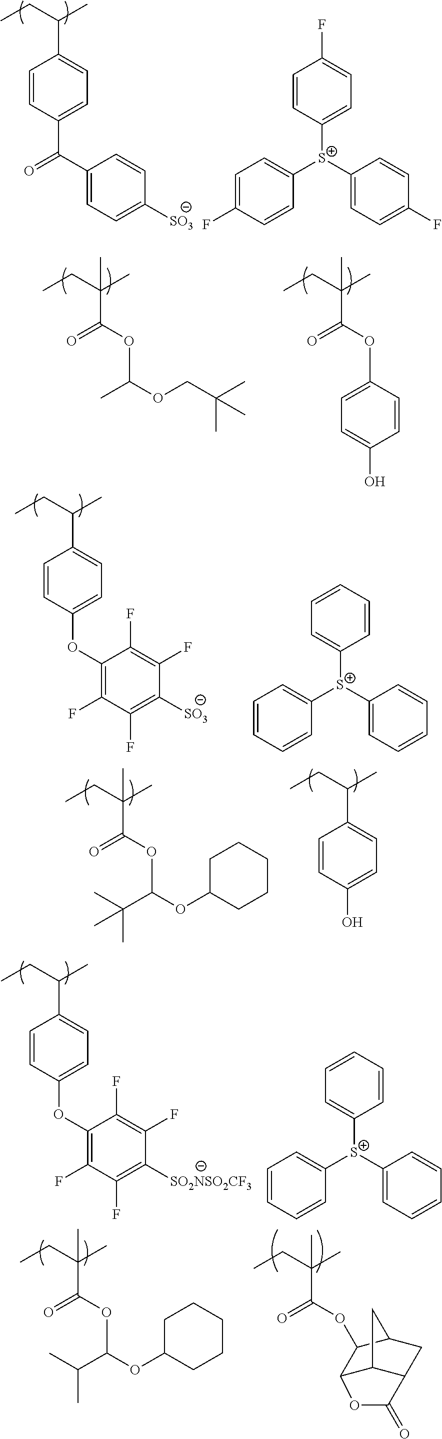

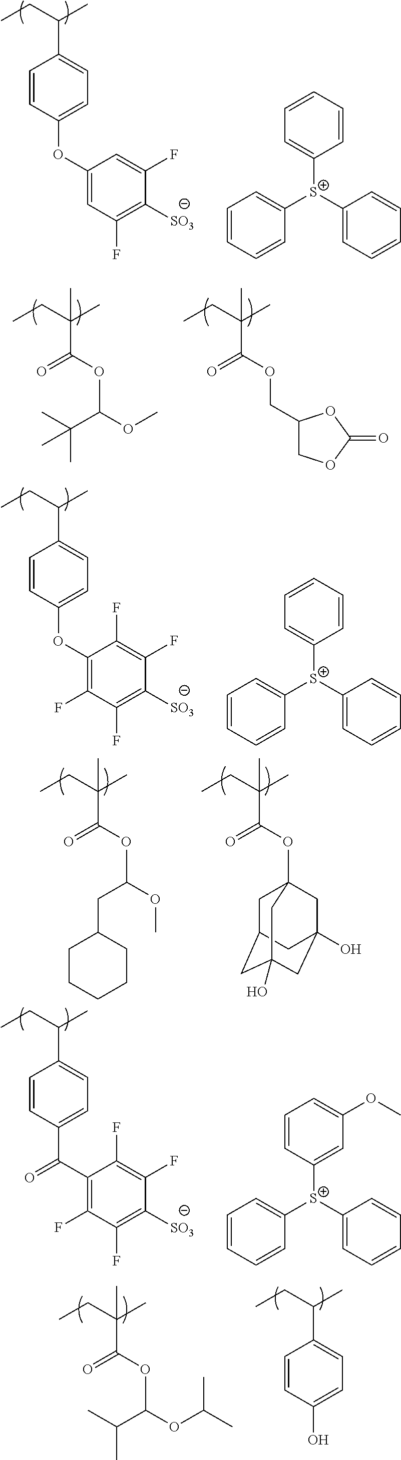

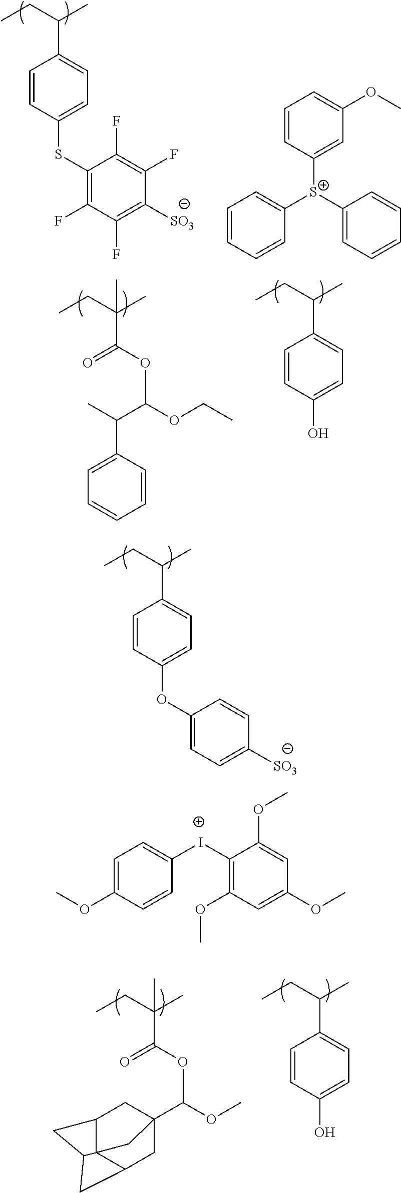

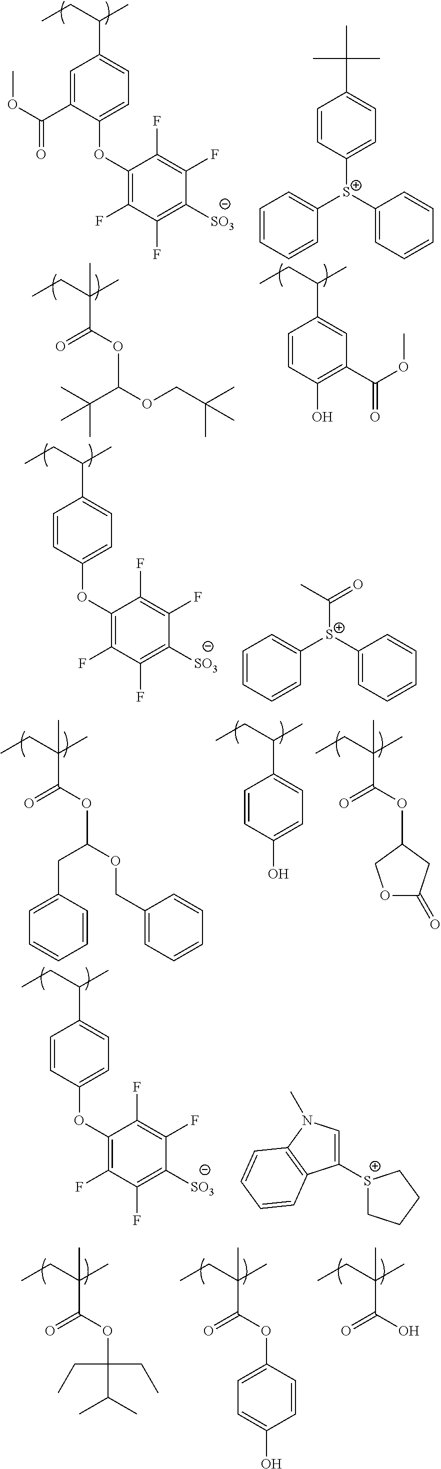

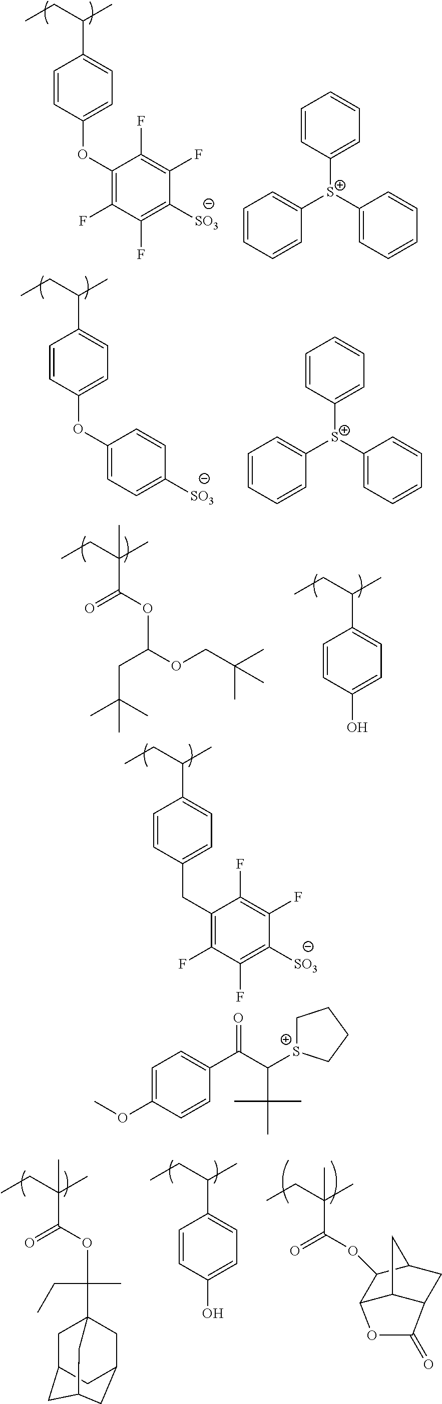

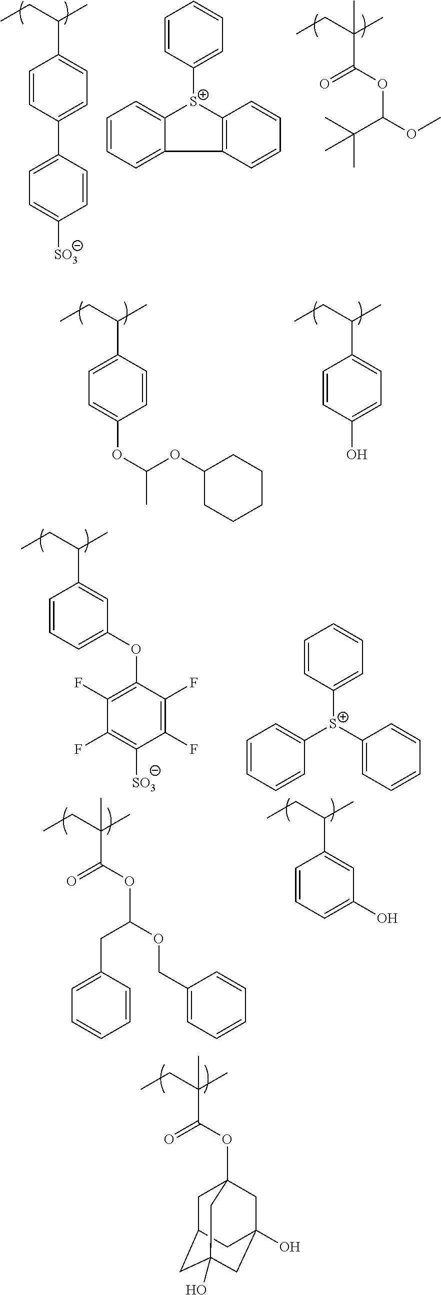

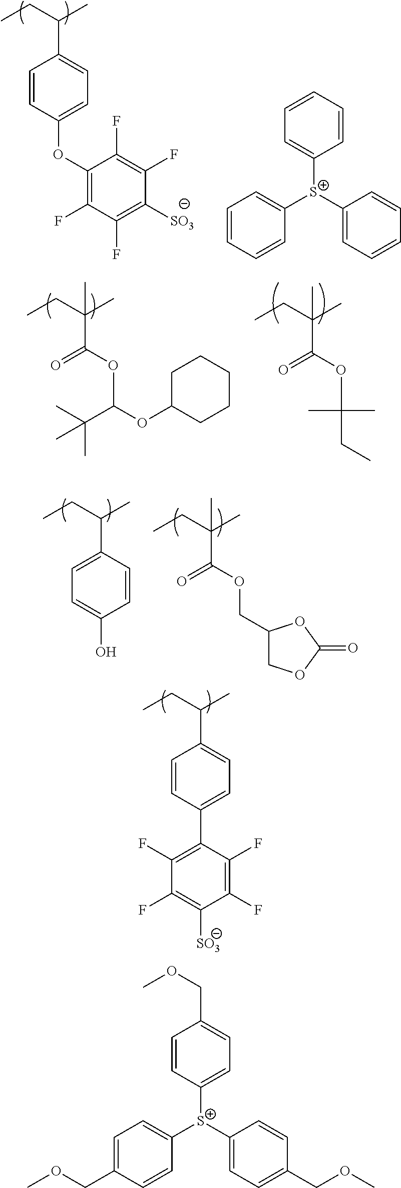

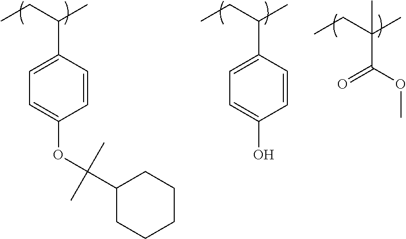

The resin (P) according to the present invention can comprise, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

The use of such repeating structural units can realize fine regulation of the required properties of the resin for use in the composition of the present invention, especially:

(1) solubility in applied solvents,

(2) film forming easiness (glass transition point),

(3) alkali developability,

(4) film thinning (selections of hydrophilicity/hydrophobicity and alkali-soluble group),

(5) adhesion of unexposed area to substrate,

(6) dry etching resistance, etc.

As appropriate monomers, there can be mentioned, for example, a compound having one unsaturated bond capable of addition polymerization, selected from among acrylic esters, methacrylic esters, acrylamides, methacrylamides, allyl compounds, vinyl ethers, vinyl esters, styrenes, crotonic esters and the like. As other appropriate monomers, there can be mentioned maleic anhydride, maleimide, acrylonitrile, methacrylonitrile and maleironitrile.

Moreover, any unsaturated compound capable of addition polymerization that is copolymerizable with monomers corresponding to the above various repeating structural units may be copolymerized therewith.

Nonlimiting preferred specific examples of the repeating units derived from such other polymerizable monomers are shown below.

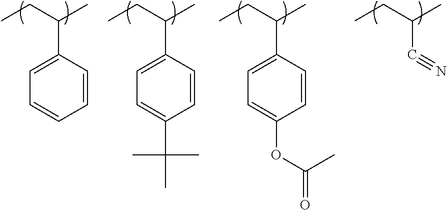

In the resin (P) for use in the composition of the present invention, the molar ratios of individual repeating structural units contained are appropriately determined from the viewpoint of regulating the dry etching resistance, standard developer adaptability, substrate adhesion and profile of the resist and generally required properties of the resist such as resolving power, heat resistance and sensitivity.

The resin (P) according to the present invention may have any of the random, block, comb and star forms.

The resin (P) can be synthesized by, for example, the radical, cation or anion polymerization of unsaturated monomers corresponding to given structures. Alternatively, the intended resin can be obtained by first polymerizing unsaturated monomers corresponding to the precursors of given structures and thereafter carrying out a polymer reaction.

As general synthesizing methods, there can be mentioned, for example, a batch polymerization method in which unsaturated monomers and a polymerization initiator are dissolved in a solvent and heated to thereby carry out polymerization, a dropping polymerization method in which a solution of unsaturated monomers and polymerization initiator is dropped into a heated solvent over a period of 1 to 10 hours, and the like. The dropping polymerization method is preferred.

As the solvents for use in polymerization, there can be mentioned, for example, those employable in the preparation of the actinic-ray- or radiation-sensitive resin composition to be described hereinafter. It is preferred to perform the polymerization with the use of the same solvent as employed in the composition of the present invention. This inhibits any particle generation during storage.

The polymerization reaction is preferably carried out in an atmosphere of inert gas, such as nitrogen or argon. The polymerization is initiated using a commercially available radical initiator (azo initiator, peroxide, etc.) as a polymerization initiator. Among the radical initiators, an azo initiator is preferred. An azo initiator having an ester bond, a cyano group or a carboxyl group is preferred. As preferred initiators, there can be mentioned azobisisobutyronitrile, azobisdimethylvaleronitrile, dimethyl 2,2′-azobis(2-methylpropionate) and the like. According to necessity, the polymerization may be carried out in the presence of a chain transfer agent (for example, an alkyl mercaptan or the like).

The concentration of solute in a reaction liquid is in the range of 5 to 70 mass %, preferably 10 to 50 mass %.

The reaction temperature is generally in the range of 10 to 150° C., preferably 30 to 120° C. and more preferably 40 to 100° C.

The reaction time is generally in the range of 1 to 48 hours, preferably 1 to 24 hours and more preferably 1 to 12 hours.

After the completion of the reaction, the reaction mixture is allowed to stand still to cool to room temperature and purified. In the purification, use can be made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any solvent appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of the polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account. Generally, the amount is in the range of 100 to 10,000 parts by mass, preferably 200 to 2000 parts by mass and more preferably 300 to 1000 parts by mass per 100 parts by mass of polymer solution.

The temperature at which the precipitation or re-precipitation is carried out can be appropriately selected taking efficiency and operation easiness into account. Generally, the temperature is in the range of about 0 to 50° C., preferably about room temperature (for example, about 20 to 35° C.). The operation of precipitation or re-precipitation can be carried out by a routine method, such as a batch or continuous method, with the use of a customary mixing container, such as an agitation vessel.

The polymer resulting from the precipitation or re-precipitation is generally subjected to customary solid/liquid separation, such as filtration or centrifugal separation, and dried before use. The filtration is carried out with the use of a filter medium ensuring solvent resistance, preferably under pressure.

The drying is performed at about 30 to 100° C., preferably about 30 to 50° C. under ordinary pressure or reduced pressure (preferably reduced pressure).

Alternatively, after the precipitation and separation of the resin, the resultant resin may be once more dissolved in a solvent and brought into contact with a solvent in which the resin is poorly soluble or insoluble. Specifically, this method may include the steps of, after the completion of the radical polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution A (step c), thereafter bringing the resin solution A into contact with a solvent wherein the resin is poorly soluble or insoluble amounting to less than 10 times (preferably 5 times or less) the volume of the resin solution A to thereby precipitate a resin solid (step d) and separating the precipitated resin (step e).

The weight average molecular weight of the resin (P) for use in the present invention is preferably in the range of 1000 to 200,000, more preferably 2000 to 50,000 and further more preferably 2000 to 20,000.

The polydispersity index (molecular weight distribution, Mw/Mn) of the resin (P) is preferably in the range of 1.0 to 3.0, more preferably 1.0 to 2.5 and further more preferably 1.0 to 2.0. The weight average molecular weight and polydispersity index of the resin (P) are defined as polystyrene-equivalent values determined by GPC measurement.

Two or more of these resins (P) may be used in combination.

The resin (P) for use in the present invention is preferably added in an amount of 30 to 100 mass %, more preferably 50 to 99.95 mass % and most preferably 70 to 99.90 mass %, based on the total solids of the composition.

The actinic-ray- or radiation-sensitive resin composition of the present invention may comprise a hydrophobic resin (HR) in addition to the above resin (P). It is preferred to incorporate the hydrophobic resin (HR) in the composition when the exposure is performed in the condition that the interstice between an actinic-ray- or radiation-sensitive film and a lens is filled with a liquid (for example, pure water) whose refractive index is higher than that of air, namely, liquid-immersion exposure is carried out, or when an organic solvent is used as the developer so as to obtain a negative pattern.

As the hydrophobic resin (HR) is localized in the surface of the film, the hydrophobic resin (HR) preferably comprises a group containing a fluorine atom, a group containing a silicon atom or a hydrocarbon group having 5 or more carbon atoms. These groups may be introduced in the principal chain of the resin, or side chains of the resin as substituents.

The standard-polystyrene-equivalent weight average molecular weight of the hydrophobic resin (HR) is preferably in the range of 1000 to 100,000, more preferably 1000 to 50,000 and further more preferably 2000 to 15,000.

One of the hydrophobic resins (HR) may be used alone, or two or more thereof may be used in combination.

The content of hydrophobic resin (HR) in the composition, based on the total solids of the composition of the present invention, is preferably in the range of 0.01 to 15 mass %, more preferably 0.05 to 10 mass % and further more preferably 0.1 to 6 mass %.

Particular examples of the hydrophobic resins (HR) are shown below.

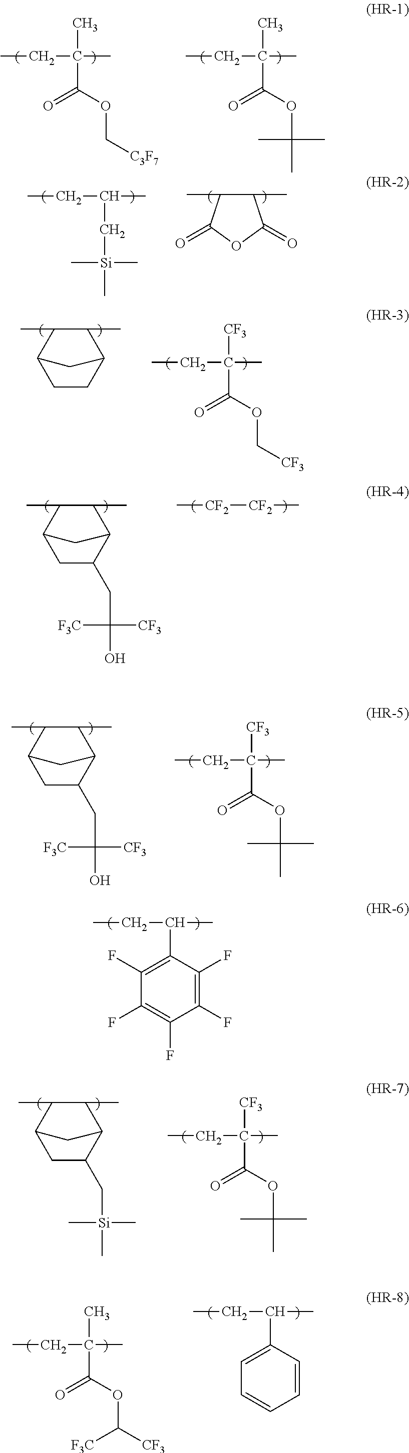

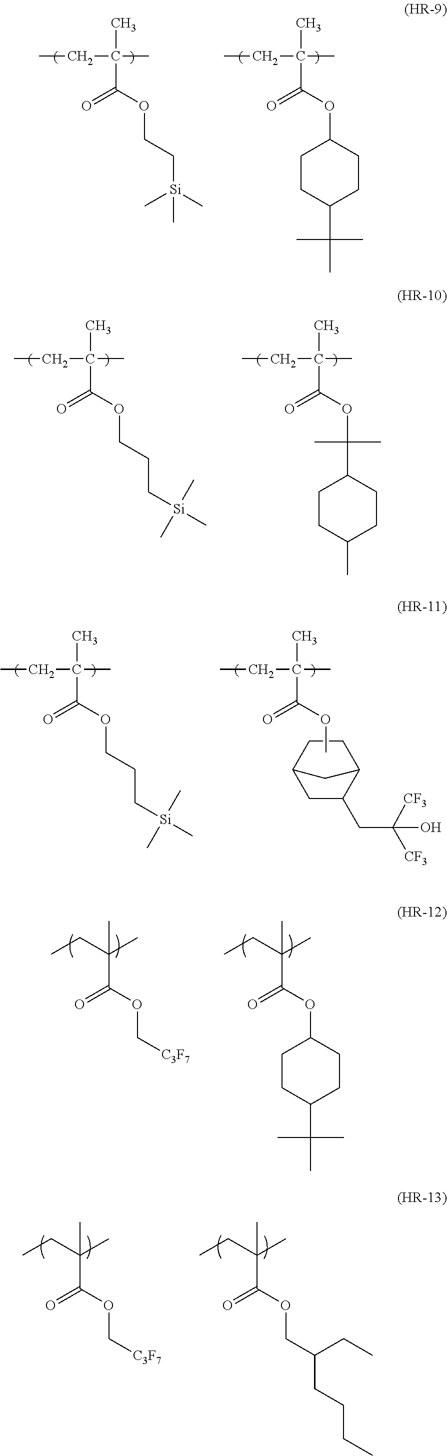

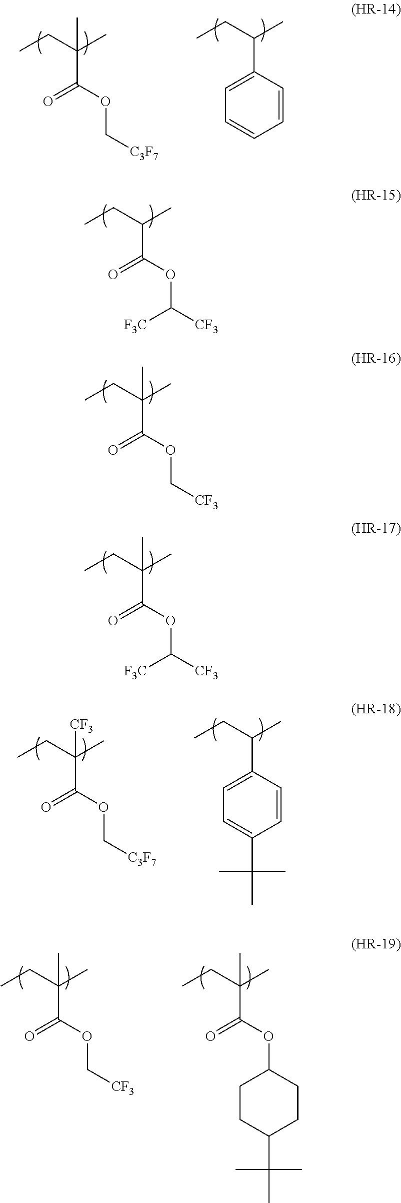

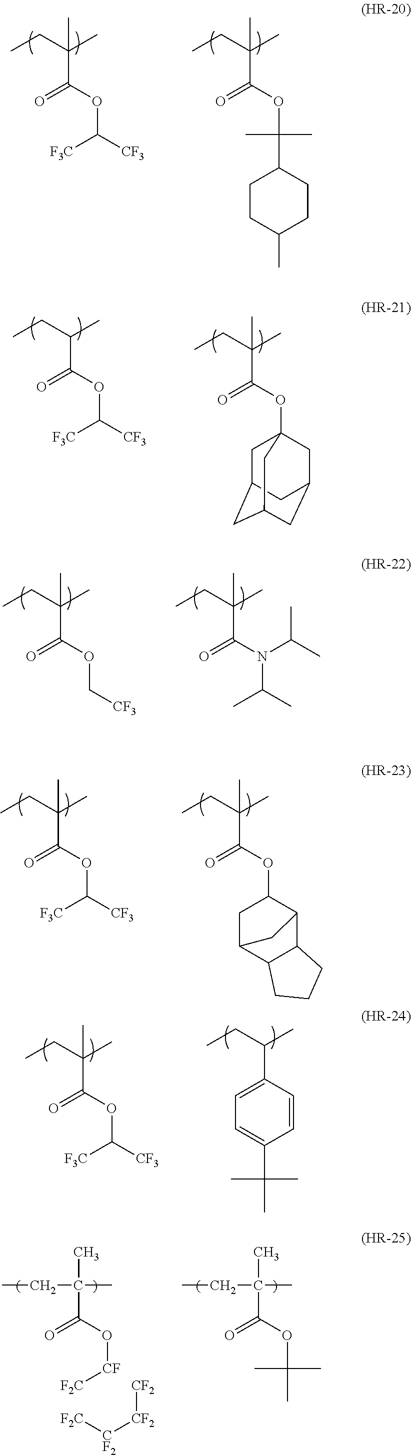

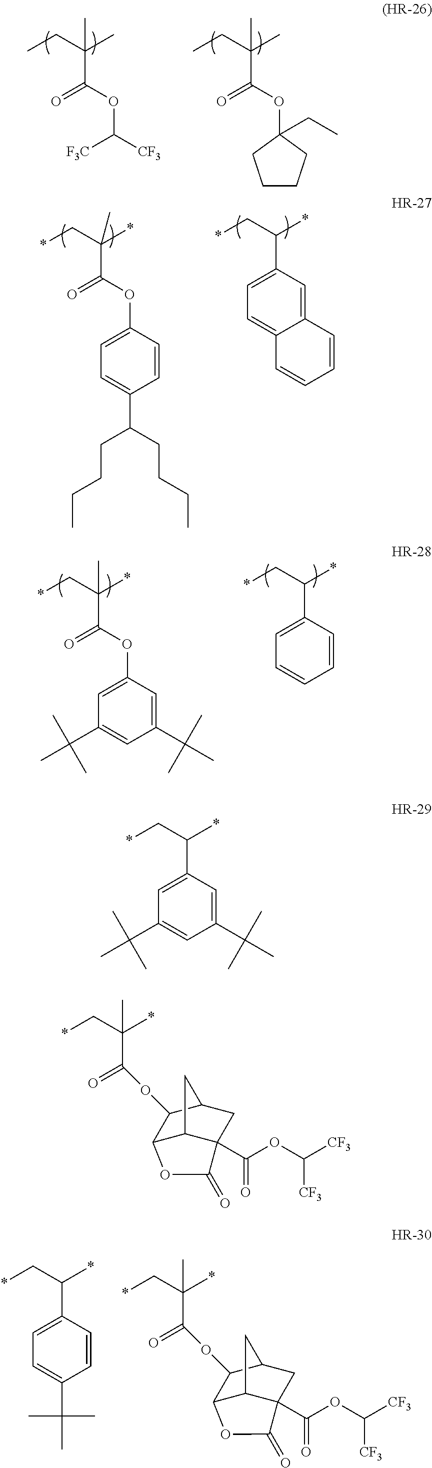

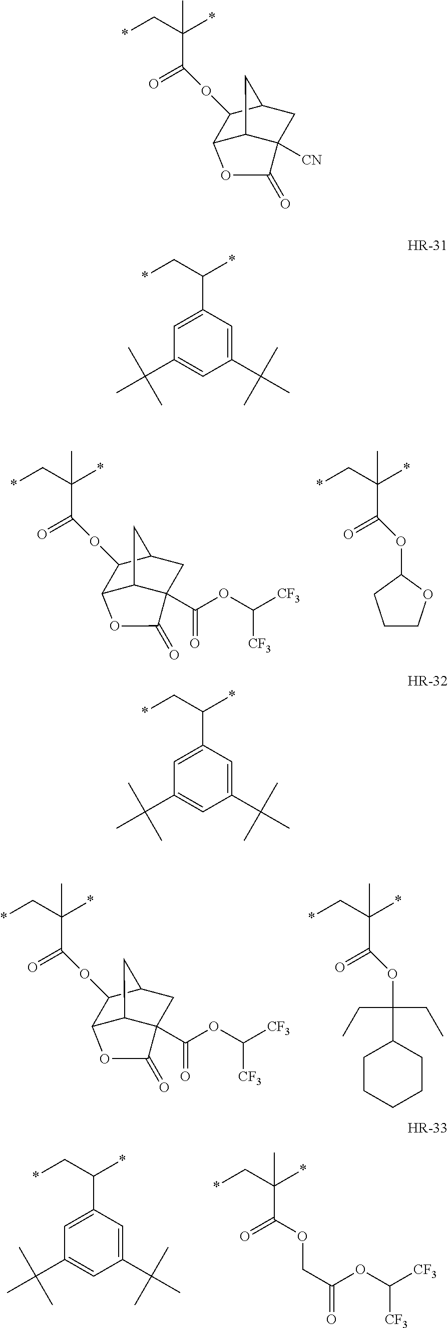

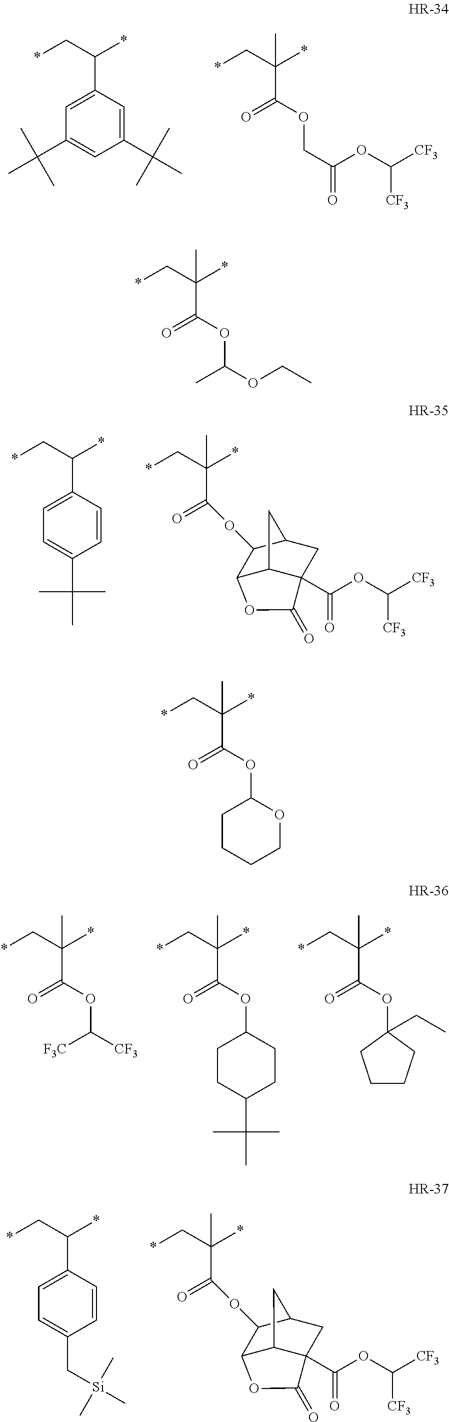

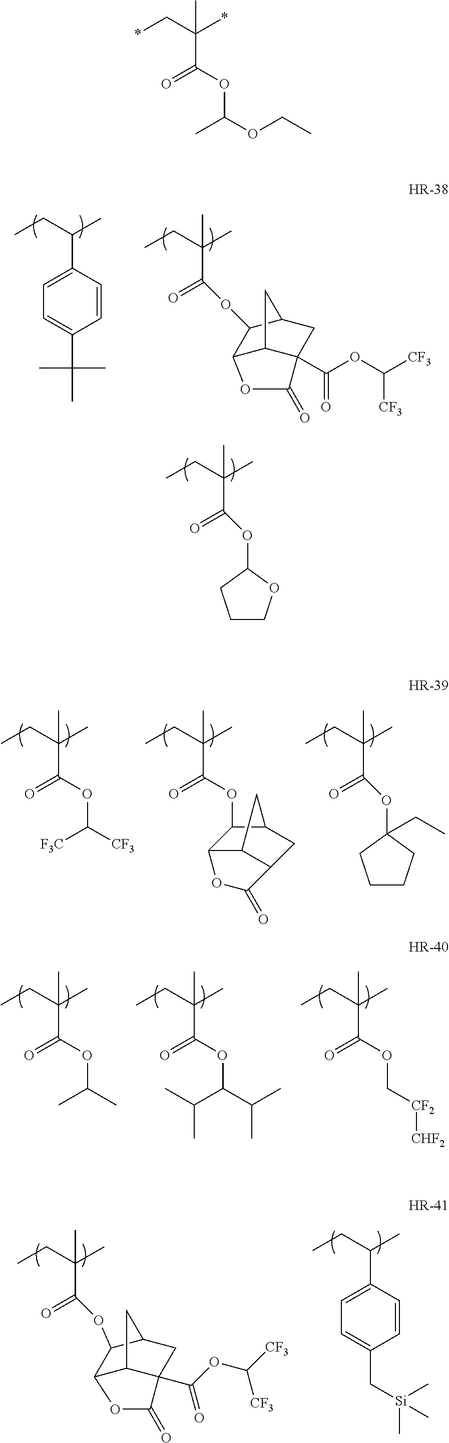

As hydrophobic resins (HR) other than the foregoing hydrophobic resins (HR), preferred use can be made of those described in JP-A's 2011-248019, 2010-175859 and 2012-032544.

It is especially preferred to employ hydrophobic resins (HR) containing acid-decomposable groups.

[2] Low-molecular compound (B) that when exposed to actinic rays or radiation, generates an acid

The actinic-ray- or radiation-sensitive resin composition of the present invention may further comprise a low-molecular compound (B) (hereinafter appropriately abbreviated as “acid generator (B)”) that when exposed to actinic rays or radiation, generates an acid.

Herein, the low-molecular compound (B) refers to a compound other than the compounds in which a moiety capable of generating an acid when exposed to actinic rays or radiation is introduced in the principal chain or a side chain of a resin, and typically refers to a compound resulting from the introduction of the above moiety in a monomolecular compound. The molecular weight of the low-molecular compound (B) is generally 4000 or less, preferably 2000 or less and more preferably 1000 or less. The molecular weight of the low-molecular compound (B) is generally 100 or greater, preferably 200 or greater.

As a preferred form of the acid generator (B), there can be mentioned an onium compound. As the acid generator (B), there can be mentioned, for example, a sulfonium salt, an iodonium salt, a phosphonium salt or the like.

Further, as another preferred form of the acid generator (B), there can be mentioned a compound that when exposed to actinic rays or radiation, generates a sulfonic acid, an imidic acid or a methide acid. As the acid generator (B) in this form, there can be mentioned, for example, a sulfonium salt, an iodonium salt, a phosphonium salt, an oxime sulfonate, an imide sulfonate or the like.

It is preferred for the acid generator (B) to be a compound that when exposed to electron beams, X-rays or soft X-rays, generates an acid.

It is optional for the actinic-ray- or radiation-sensitive resin composition of the present invention to contain the acid generator (B). When the acid generator (B) is contained, the content thereof based on the total solids of the composition is preferably in the range of 0.1 to 30 mass %, more preferably 0.5 to 20 mass % and further more preferably 1.0 to 10 mass %.

One of the acid generators (B) can be used alone, or two or more thereof can be used in combination.

Particular examples of the acid generators (B) that can be used in the present invention are shown below.

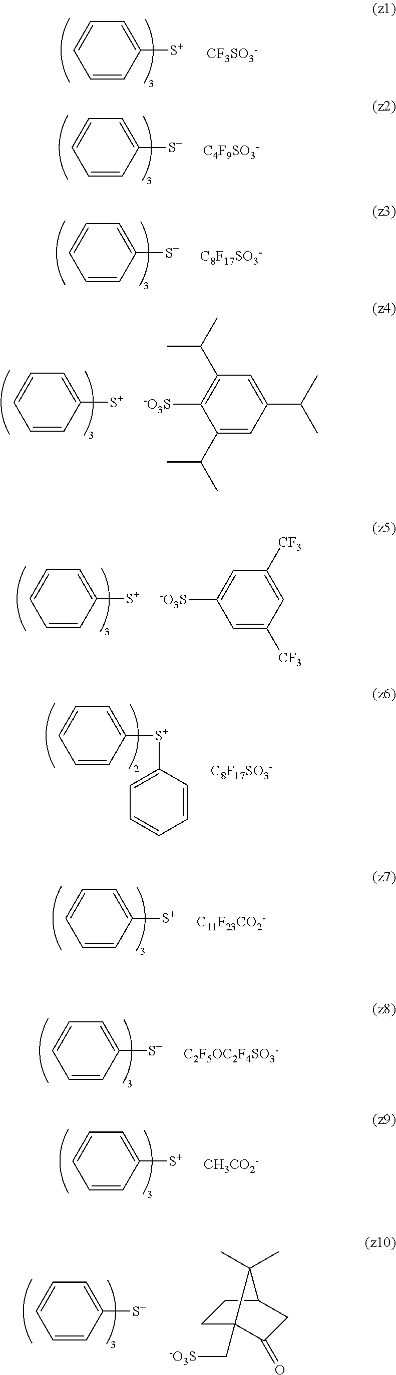

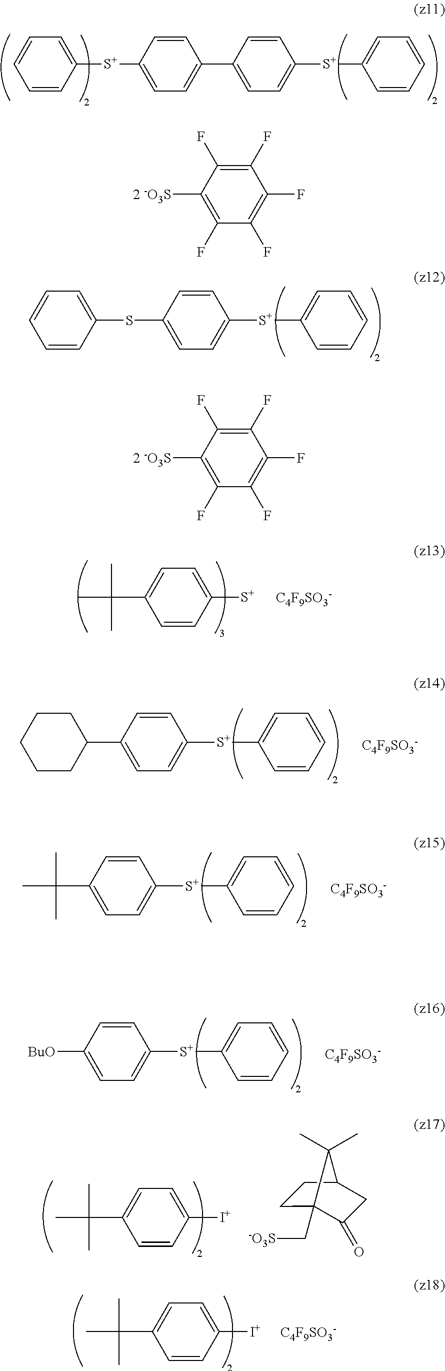

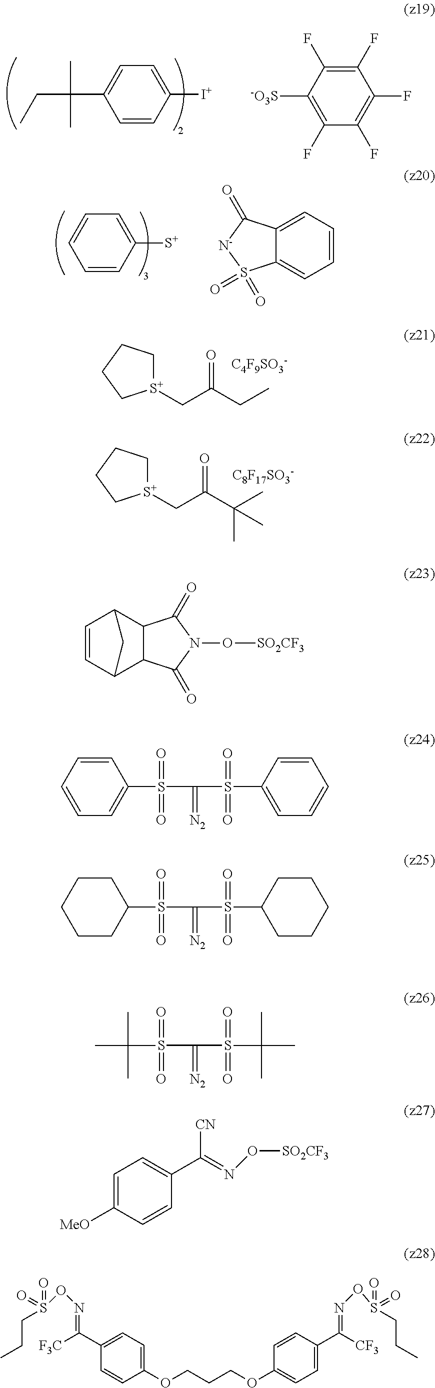

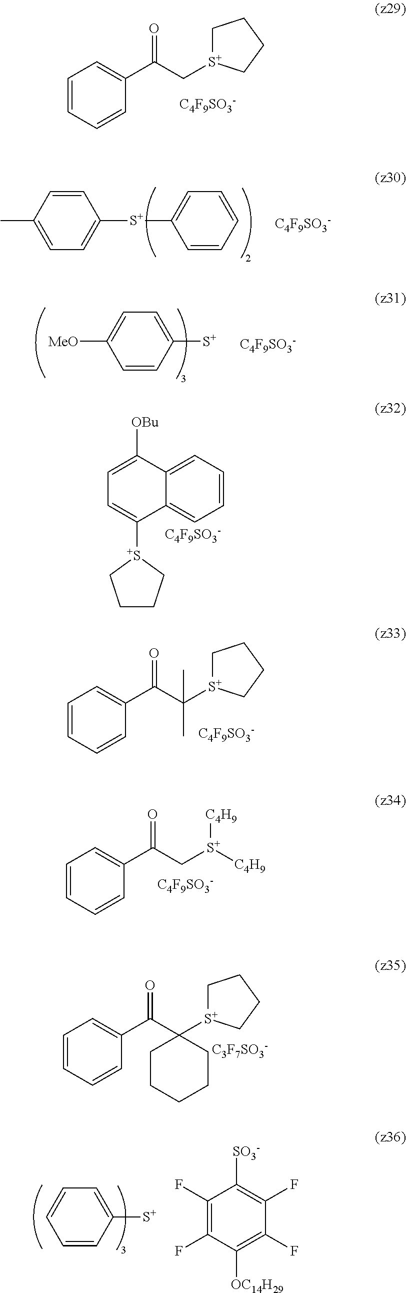

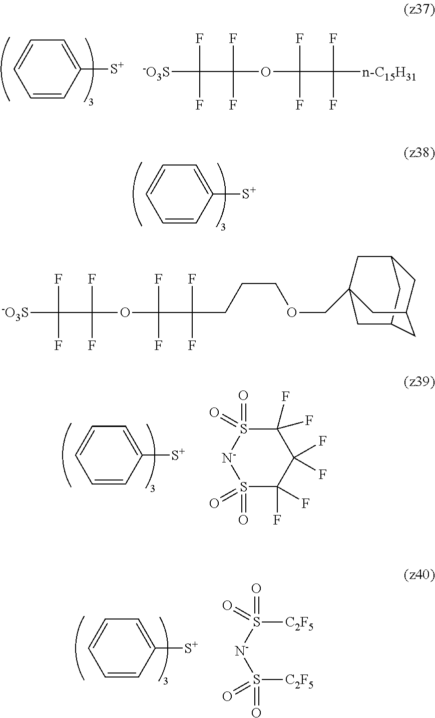

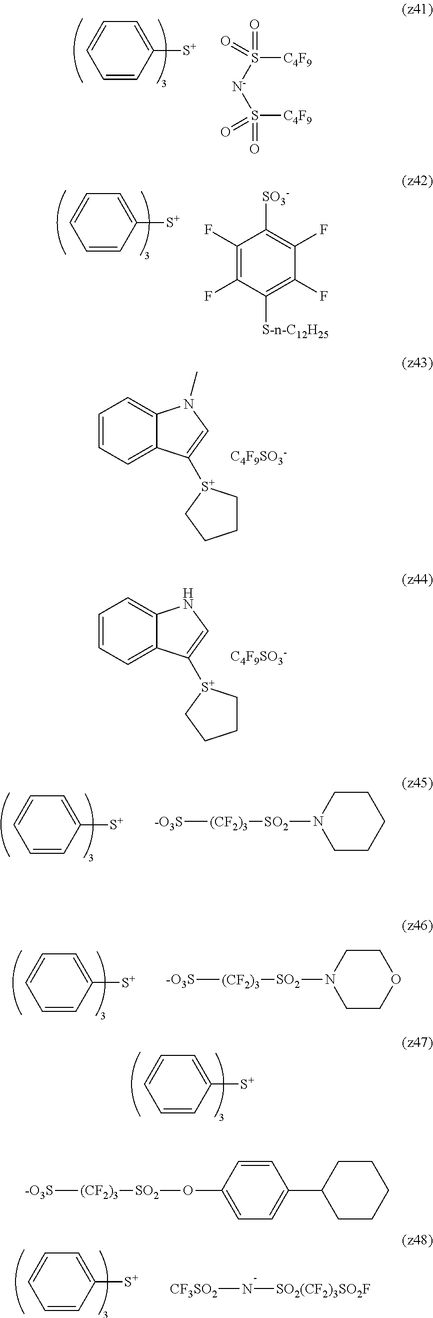

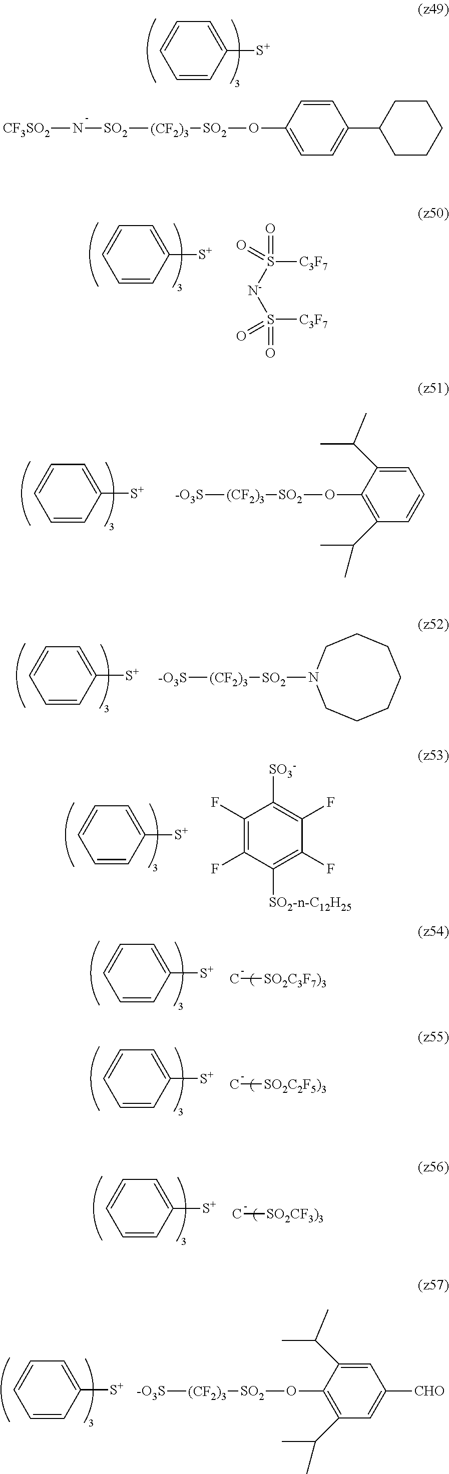

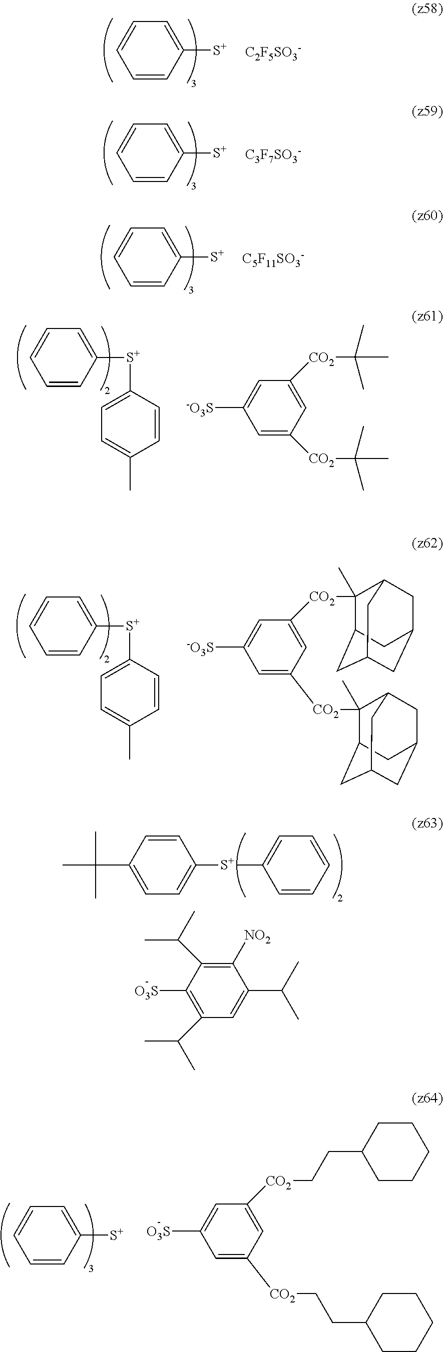

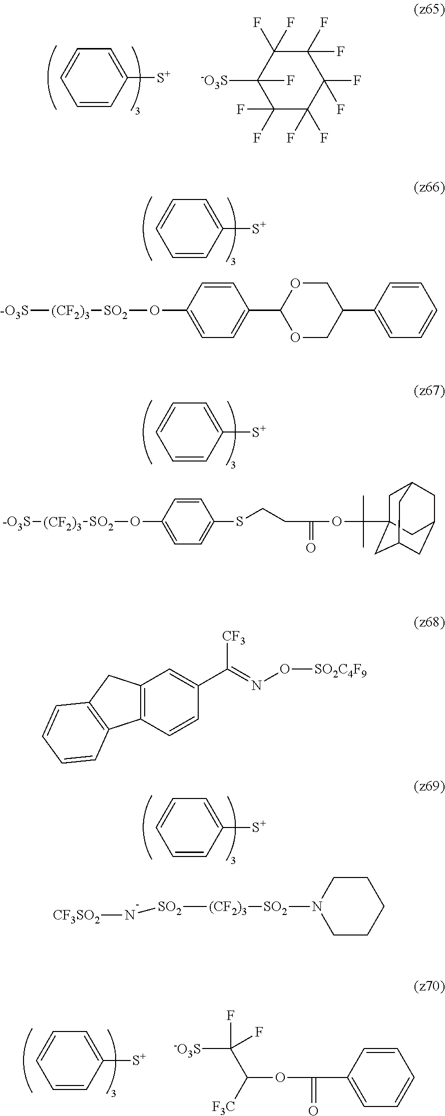

[3] Basic Compound

It is preferred for the actinic-ray- or radiation-sensitive resin composition of the present invention to comprise a basic compound as an acid trapping agent in addition to the foregoing components. The incorporation of a basic compound lessens any performance change over time from exposure to light to postbake. It is preferred for the basic compound to be an organic basic compound. In particular, as such, there can be mentioned aliphatic amines, aromatic amines, heterocyclic amines, a nitrogen-containing compound in which a carboxyl group is introduced, a nitrogen-containing compound in which a sulfonyl group is introduced, a nitrogen-containing compound in which a hydroxyl group is introduced, a nitrogen-containing compound in which a hydroxyphenyl group is introduced, an alcoholic nitrogen-containing compound, amide derivatives, imide derivatives and the like. Further, an amine oxide compound (described in JP-A-2008-102383) and an ammonium salt (preferably a hydroxide or a carboxylate, in particular, a tetraalkylammonium hydroxide, typically tetrabutylammonium hydroxide, is preferred from the viewpoint of LER) can be appropriately used.

Moreover, a compound whose basicity is increased by the action of an acid can be used as one type of basic compound.

Particular examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, tetrabutylammonium benzoate, compounds set forth as examples in column 3, line 60 et seq. of U.S. Pat. No. 6,040,112, 2-[2-{2-(2,2-dimethoxy-phenoxyethoxy)ethyl}-bis(2-methoxyethyl)]amine, compounds (C1-1) to (C3-3) set forth as examples in Section[0066] of U.S. Patent Application Publication No. 2007/0224539 A1, and the like. As compounds with a nitrogen-containing heterocyclic structure, there can be mentioned 2-phenylbenzimidazole, 2,4,5-triphenylimidazole, N-hydroxyethylpiperidine, bis(1,2,2,6,6-pentamethyl-4-piperidyl) sebacate, 4-dimethylaminopyridine, antipyrine, hydroxyantipyrine, 1,5-diazabicyclo[4.3.0]non-5-ene, 1,8-diazabicyclo[5.4.0]undec-7-ene, and the like. The ammonium salt is preferably tetrabutylammonium hydroxide.

Among these basic compounds, the ammonium salt is preferred from the viewpoint of resolution enhancement.

It is optional for the actinic-ray- or radiation-sensitive resin composition of the present invention to contain the basic compound. When the basic compound is contained, the content of basic compound for use in the present invention, based on the total solids of the composition, is preferably in the range of 0.01 to 10 mass %, more preferably 0.03 to 5 mass % and most preferably 0.05 to 3 mass %.

[4] Surfactant

The actinic-ray- or radiation-sensitive resin composition of the present invention may further comprise a surfactant in order to enhance its coatability. The surfactants are not particularly limited. As examples thereof, there can be mentioned nonionic surfactants, such as a polyoxyethylene alkyl ether, a polyoxyethylene alkylallyl ether, a polyoxyethylene-polyoxypropylene block copolymer, a sorbitan fatty acid ester and a polyoxyethylene sorbitan fatty acid ester; fluorinated surfactants, such as Megafac F176 (produced by DIC Corporation), Florad FC430 (produced by Sumitomo 3M Ltd.), Surfinol E1004 (produced by Asahi Glass Co., Ltd.) and PF656 and PF6320 (produced by OMNOVA SOLUTIONS, INC.); fluorinated and siliconized surfactants, such as Megafac R08 (produced by DIC Corporation); and organosiloxane polymers, such as polysiloxane polymer KP-341 (produced by Shin-Etsu Chemical Co., Ltd.).

It is optional for the actinic-ray- or radiation-sensitive resin composition of the present invention to contain the surfactant. When the surfactant is contained in the composition, the content thereof, based on the whole amount (excluding the solvent) of the composition, is preferably in the range of 0.0001 to 2 mass %, more preferably 0.0005 to 1 mass %.

[5] Compound that when Acted on by an Acid, is Decomposed to Thereby Generate an Acid

The actinic-ray- or radiation-sensitive resin composition of the present invention may further comprise one or two or more compounds that when acted on by an acid, are decomposed to thereby generate acids. It is preferred for the acid generated by the compound that when acted on by an acid, is decomposed to thereby generate an acid to be a sulfonic acid, a methide acid or an imidic acid.

Nonlimiting examples of the compounds decomposed when acted on by an acid to thereby generate acids that can be used in the present invention are shown below.

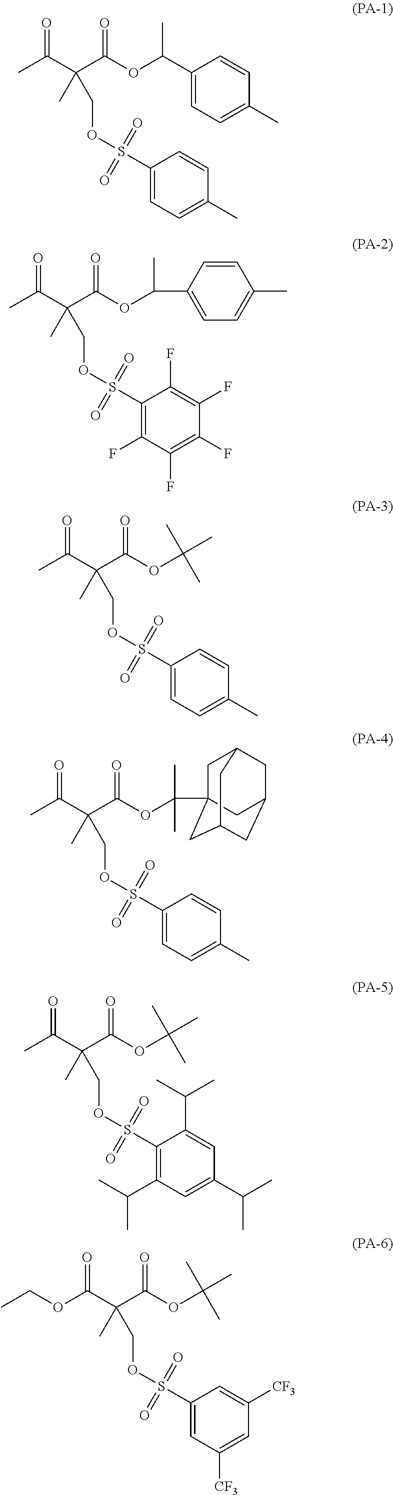

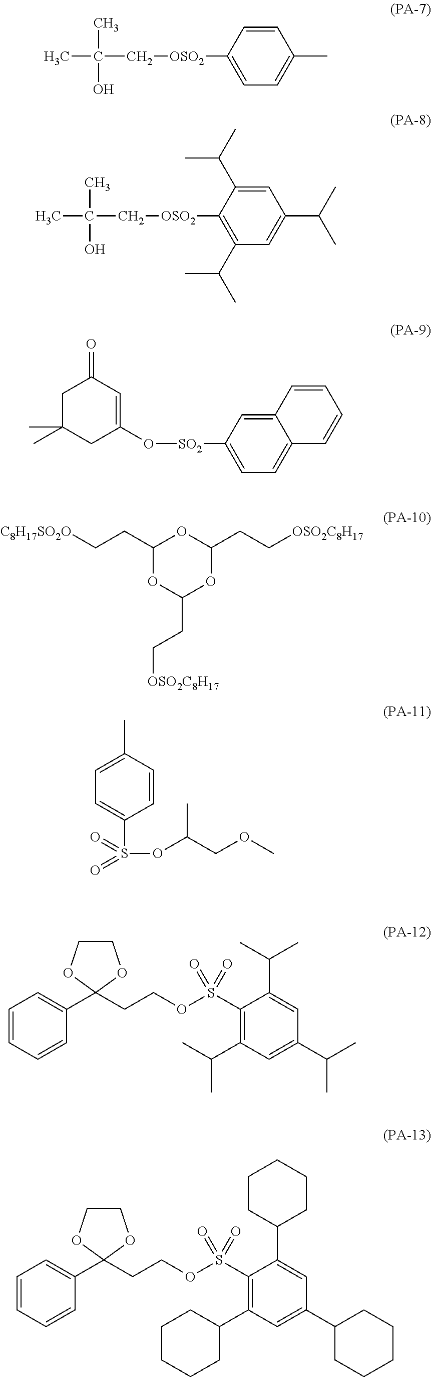

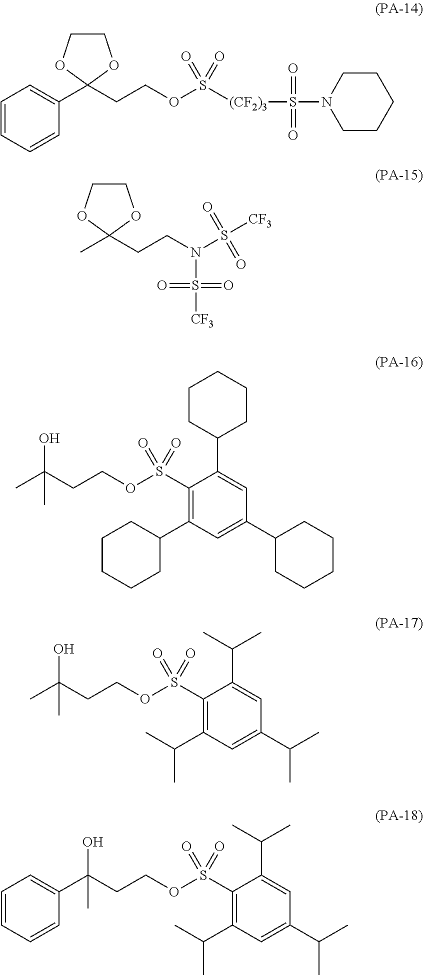

One of the compounds that when acted on by an acid, are decomposed to thereby generate acids may be used alone, or two or more thereof may be used in combination.

The content of compound that when acted on by an acid, is decomposed to thereby generate an acid, based on the total solids of the actinic-ray- or radiation-sensitive resin composition of the present invention, is preferably in the range of 0.1 to 40 mass %, more preferably 0.5 to 30 mass % and further more preferably 1.0 to 20 mass %.

According to necessity, the actinic-ray- or radiation-sensitive resin composition of the present invention can further be loaded with a dye, a plasticizer, a photodecomposable basic compound, a photobase generator, etc. As these additives, there can be mentioned the respective compounds described in JP-A-2002-6500.

Preferred examples of solvents for use in the actinic-ray- or radiation-sensitive resin composition of the present invention include ethylene glycol monoethyl ether acetate, cyclohexanone, 2-heptanone, propylene glycol monomethyl ether (PGME, also known as 1-methoxy-2-propanol), propylene glycol monomethyl ether acetate (PGMEA, also known as 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate, ethylene carbonate and the like. These solvents may be used individually or in combination.

Moreover, the composition of the present invention can be used in the process comprising, after the operations of coating, film formation and exposure, developing the exposed film with a developer containing an organic solvent as a main component to thereby obtain a negative pattern. As this process, use can be made of, for example, the process described in JP-A-2010-217884.

As such an organic developer, use can be made of not only a polar solvent, such as an ester solvent (butyl acetate, ethyl acetate, etc.), a ketone solvent (2-heptanone, cyclohexanone, etc.), an alcohol solvent, an amide solvent or an ether solvent, but also a hydrocarbon solvent. The water content of the organic developer as a whole is preferably below 10 mass %. More preferably, the organic developer contains substantially no trace of water.

Preferably, the solids of the actinic-ray- or radiation-sensitive resin composition are dissolved in the above solvent to thereby provide a solution of 1 to 40 mass % solid content. The solid content is more preferably in the range of 1 to 30 mass %, further more preferably 3 to 20 mass %.

The present invention also relates to an actinic-ray- or radiation-sensitive film (e.g., a resist film) formed from the actinic-ray- or radiation-sensitive resin composition of the present invention. For example, this actinic-ray- or radiation-sensitive film is formed by coating a support, such as a substrate, with the composition. The actinic-ray- or radiation-sensitive resin composition of the present invention is applied onto a substrate by an appropriate coating method, such as spin coating, roll coating, flow coating, dip coating, spray coating or doctor coating, and prebaked at 60 to 150° C. for 1 to 20 minutes, preferably 80 to 130° C. for 1 to 10 minutes, thereby obtaining a thin film. The thickness of this coating film is preferably in the range of 30 to 200 nm.

The substrate appropriately used in the present invention is a silicon substrate, or a substrate provided with a metal vapor-deposited film or a metal-containing film. The highly appropriate substrate is one provided at its surface with a vapor-deposited film of Cr, MoSi, TaSi or an oxide or nitride thereof.

Furthermore, the present invention relates to a resist-coated mask blank that is provided with the resist film obtained in the above manner. When a resist pattern is formed on a photomask blank for photomask fabrication in order to obtain the resist-coated mask blank, a transparent substrate of quartz, calcium fluoride or the like can be mentioned as a useful transparent substrate. Generally, the substrate is laminated with necessary films selected from among functional films, such as a light shielding film, an antireflection film and a phase shift film and, additionally, an etching stopper film and an etching mask film. As a material of each of the functional films, use is made of silicon or a transition metal, such as chromium, molybdenum, zirconium, tantalum, tungsten, titanium or niobium. A film containing such a material is used in the form of a laminate. As a material for use in the topmost surface layer, there can be mentioned, for example, one whose main constituent material is silicon or a material comprised of silicon and, contained therein, oxygen and/or nitrogen, a silicon compound material whose main constituent material is a material comprised of the same and, contained therein, a transition metal, or a transition metal compound material whose main constituent material is a transition metal, especially at least one member selected from among chromium, molybdenum, zirconium, tantalum, tungsten, titanium, niobium and the like, or a material comprised of the same and, contained therein, at least one element selected from among oxygen, nitrogen and carbon.

The light shielding film, although may be in the form of a monolayer, is preferably in the form of a multilayer structure comprised of a plurality of materials superimposed one upon another by coating. In the multilayer structure, the thickness of each of the layers is not particularly limited, which is however preferably in the range of 5 to 100 nm, more preferably 10 to 80 nm. The thickness of the whole of the light shielding film is not particularly limited, which is however preferably in the range of 5 to 200 nm, more preferably 10 to 150 nm.

When a pattern formation is performed using the actinic-ray- or radiation-sensitive resin composition on a photomask blank whose topmost surface layer contains a material comprised of chromium and, contained therein, oxygen or nitrogen among the above-mentioned materials, generally, it is likely to experience the occurrence of trailing near the substrate, known as a taper shape. This taper shape can be alleviated by the use of the actinic-ray- or radiation-sensitive resin composition of the present invention as compared with the prior art.

The resultant resist film is exposed to actinic rays or radiation (electron beams, etc.), preferably baked (usually 80 to 150° C., preferably 90 to 130° C.), and developed. Thus, a desirable pattern can be obtained. Using this pattern as a mask, appropriate etching treatment, ion injection, etc. are carried out, thereby obtaining a semiconductor nanocircuit, an imprint mold structure, a photomask, etc.

With respect to the process for manufacturing an imprint mold by use of the composition of the present invention, reference can be made to descriptions made in, for example, Japanese Patent No. 4109085, JP-A-2008-162101 and “Fundamentals of nanoimprint and its technology development/application deployment—technology of nanoimprint substrate and its latest technology deployment” edited by Yoshihiko Hirai, published by Frontier Publishing.

<Top Coat Composition>

In the pattern forming method of the present invention, a top coat layer may be formed on the above described actinic-ray- or radiation-sensitive film (resist film). The top coat composition used for the formation of the top coat layer will be described below.

The solvent for use in the top coat composition according to the present invention is preferably water or an organic solvent, more preferably water.

When the solvent is an organic solvent, it is preferably one not dissolving the resist film. The employable solvent is preferably an alcohol solvent, a fluorinated solvent or a hydrocarbon solvent, more preferably a non-fluorinated alcohol solvent. Among alcohol solvents, from the viewpoint of coatability, a primary alcohol is preferred. A primary alcohol having 4 to 8 carbon atoms is more preferred. As the primary alcohol having 4 to 8 carbon atoms, use can be made of a linear, branched or cyclic alcohol. A linear or branched alcohol is preferred. For example, there can be mentioned 1-butanol, 1-hexanol, 1-pentanol, 3-methyl-1-butanol or the like.

When the solvent for use in the top coat composition according to the present invention is water, the top coat composition preferably contains a water-soluble resin. It is presumed that selecting this combination can enhance the uniformity of developer wetting. As preferred water-soluble resins, there can be mentioned polyacrylic acid, polymethacrylic acid, polyhydroxystyrene, polyvinylpyrrolidone, polyvinyl alcohol, polyvinyl ether, polyvinyl acetal, polyacrylimide, polyethylene glycol, polyethylene oxide, polyethyleneimine, polyester polyol, polyether polyol, polysaccharide and the like. Polyacrylic acid, polymethacrylic acid, polyhydroxystyrene, polyvinylpyrrolidone and polyvinyl alcohol are especially preferred. The water-soluble resins are not limited to homopolymers, and copolymers may be used as the same. For example, use may be made of a copolymer comprising a monomer unit corresponding to the repeating unit of each of the above-mentioned homopolymers and another monomer unit. In particular, an acrylic acid-methacrylic acid copolymer, an acrylic acid-hydroxystyrene copolymer and the like can be use in the present invention.

As the resin for use in the top coat composition, preferred use can be made of any of the resins containing acid groups described in JP-A's 2009-134177 and 2009-91798.

The weight average molecular weight of the water-soluble resin is not particularly limited. The weight average molecular weight is preferably in the range of 2000 to 100 ten thousand, more preferably 5000 to 50 ten thousand, and most preferably 1 ten thousand to 10 ten thousand. Herein, the weight average molecular weight of the resin refers to a polystyrene-equivalent molecular weight determined by GPC (carrier: THF or N-methyl-2-pyrrolidone (NMP)).

The pH value of the top coat composition is not particularly limited. The pH value is preferably in the range of 1 to 10, more preferably 2 to 8, and most preferably 3 to 7.

When the solvent in the top coat composition is an organic solvent, it is preferred for the op coat composition to contain a hydrophobic resin. As the hydrophobic resin, preferred use is made of any of those described in JP-A-2008-209889.

The concentration of resin in the top coat composition is preferably in the range of 0.1 to 10 mass %, more preferably 0.2 to 5 mass %, and most preferably 0.3 to 3 mass %.

Non-resin components may be contained in top coat materials. The ratio of resin in the solid contents of the top coat composition is preferably in the range of 80 to 100 mass %, more preferably 90 to 100 mass %, and most preferably 95 to 100 mass %. As preferred non-resin components added to the top coat materials, there can be mentioned a photoacid generator and a basic compound. Particular examples of these compounds can be the same as set forth above in connection with the actinic-ray- or radiation-sensitive resin composition.

As non-resin components that can be added to the top coat materials, there can be mentioned a surfactant, a photoacid generator, a basic compound and the like. Particular examples of the photoacid generators and basic compounds can be the same as those of acid generators and basic compounds set forth above.

When a surfactant is used, the amount of surfactant used, based on the whole amount of the top coat composition, is preferably in the range of 0.0001 to 2 mass %, more preferably 0.001 to 1 mass %.

The addition of a surfactant to a treating agent comprising the top coat composition can enhance the coatability of the treating agent in the application thereof. As the surfactants, there can be mentioned nonionic, anionic, cationic and amphoteric surfactants.

As the nonionic surfactant, use can be made of any of Plufarac series produced by BASF; ELEBASE series, Finesurf series and Brownon series all produced by Aoki Oil Industrial Co., Ltd.; Adeka Pluronic P-103 produced by Asahi Denka Co., Ltd.; Emargen series, Amiet series, Aminon PK-02S, Emanon CH-25 and Reodol series all produced by Kao Corporation; Surfron S-141 produced by AGC Seimi Chemical Co., Ltd.; Neugen series produced by Daiichi Kogyo Seiyaku Co., Ltd.; Newcargen series produced by Takemoto Oil&Fat Co., Ltd.; DYNOL 604, EnviroGem AD01, Olfin EXP series and Surfinol series all produced by Nisshin Chemical Industry Co., Ltd.; Phthagent 300 produced by Ryoko Chemical Co., Ltd.; etc.

As the anionic surfactant, use can be made of any of Emal 20T and Poise 532A both produced by Kao Corporation; Phosphanol ML-200 produced by Toho Chemical Industry Co., Ltd.; EMULSOGEN series produced by Clariant Japan Co., Ltd.; Surfron S-111N and Surfron S-211 both produced by AGC Seimi Chemical Co., Ltd.; Plysurf series produced by Daiichi Kogyo Seiyaku Co., Ltd.; Pionin series produced by Takemoto Oil&Fat Co., Ltd.; Olfin PD-201 and Olfin PD-202 both produced by Nisshin Chemical Industry Co., Ltd.; AKYPO RLM45 and ECT-3 both produced by Nihon Surfactant Kogyo K.K.; Lipon produced by Lion Corporation; etc.

As the cationic surfactant, use can be made of any of Acetamin 24 and Acetamin 86 both produced by Kao Corporation, etc.

As the amphoteric surfactant, use can be made of any of Surfron S-131 (produced by AGC Seimi Chemical Co., Ltd.), Enagicol C-40H and Lipomin LA (both produced by Kao Corporation), etc.

These surfactants can be mixed together before use thereof.

<Method of Forming Pattern>

In the pattern forming method of the present invention, when, for example, a negative pattern is formed using an organic developer as the developer, a photoresist layer may be formed by applying the actinic-ray- or radiation-sensitive resin composition on a substrate, and a top coat layer may be formed on the photoresist layer with the use of the above top coat composition. The thickness of the top coat layer is preferably in the range of 10 to 200 nm, more preferably 20 to 100 nm and most preferably 40 to 80 nm.

The method of applying the actinic-ray- or radiation-sensitive resin composition on a substrate preferably comprises spin coating. The spin coating is preferably performed at a rotating speed of 1000 to 3000 rpm.

For example, the actinic-ray- or radiation-sensitive resin composition is applied on a substrate (e.g., silicon/silicon dioxide coating), such as one for use in the production of precision integrated circuit devices, by appropriate application means, such as a spinner or a coater. The thus applied composition is dried, thereby forming a resist film. The application of the composition on the substrate can be preceded by the application of a heretofore known antireflection film. Preferably, the resist film is dried prior to the formation of the top coat layer.

Thereafter, the top coat composition is applied and dried on the resultant resist film in the same manner as in the formation of the resist film, thereby forming a top coat layer.

The resist film with the top coat layer provided thereon is exposed, usually through a mask, to actinic rays or radiation, preferably baked (heated), and developed. Thus, a favorable pattern can be obtained.

One mode of using the actinic-ray- or radiation-sensitive resin composition of the present invention and a method of forming a resist pattern therewith are summarized below.

The present invention also relates to a method of forming a resist pattern, comprising exposing to light the above resist film or resist-coated mask blank and developing the exposed resist film or resist-coated mask blank. In the present invention, the exposure is preferably performed using electron beams, X-rays or soft X-rays.

With respect to the exposure to light (pattern forming operation) of the resist film in, for example, the manufacturing of a precision integrated circuit device, first, patternwise exposure of the resist film of the present invention is performed to electron beams, X-rays or soft X-rays. The exposure is performed in an amount (exposure amount) of, in the use of electron beams, about 0.1 to 60 μC/cm², preferably about 3 to 50 μC/cm², and, in the use of extreme ultraviolet, about 0.1 to 40 mJ/cm², preferably about 3 to 30 mJ/cm². Subsequently, post-exposure bake is performed on a hot plate at 60 to 150° C. for 1 to 20 minutes, preferably 80 to 120° C. for 1 to 10 minutes. Thereafter, development, rinse and drying are performed to thereby obtain a resist pattern. The development is performed with a developer for a period of 0.1 to 3 minutes, preferably 0.5 to 2 minutes by conventional methods, such as a dip method, a puddle method and a spray method. In the development, the portion in exposed areas is dissolved in the developer while the portion in unexposed areas is highly insoluble in the developer. Consequently, a desired pattern is formed on the substrate.

As the developer, use is made of an alkali developer or a developer comprising an organic solvent (hereinafter also referred to as an organic developer).

As the alkali developer, there can be mentioned, for example, an alkaline aqueous solution containing, for example, an inorganic alkali, such as sodium hydroxide, potassium hydroxide, sodium carbonate, sodium silicate, sodium metasilicate or aqueous ammonia; a primary amine, such as ethylamine or n-propylamine; a secondary amine, such as diethylamine or di-n-butylamine; a tertiary amine, such as triethylamine or methyldiethylamine; an alcoholamine, such as dimethylethanolamine or triethanolamine; a quaternary ammonium salt, such as tetramethylammonium hydroxide or tetraethylammonium hydroxide; or a cycloamine, such as pyrrole or piperidine.

Appropriate amounts of an alcohol and/or a surfactant may further be added to the above alkali developer before use.

The concentration of the alkali developer is generally in the range of 0.1 to 20 mass %. The pH value of the alkali developer is generally in the range of 10.0 to 15.0.

When the developer is an alkali developer, as a rinse liquid, pure water is used, to which an appropriate amount of surfactant can be added before use.

As the organic developer, use can be made of a polar solvent, such as a ketone solvent, an ester solvent, an alcohol solvent, an amide solvent or an ether solvent, and a hydrocarbon solvent. Preferred use is made of butyl acetate, 2-heptanone, anisole, 4-methyl-2-pentanol, 1-hexanol, decane and the like.

The organic developer may contain a basic compound. Particular examples and preferred examples of basic compounds that can be contained in the developer for use in the present invention are the same as set forth above in connection with components of the actinic-ray- or radiation-sensitive resin composition.

In the pattern forming method of the present invention, the development may be carried out through the operation of developing with a developer comprising an organic solvent (organic solvent developing operation), combined with the operation of developing with an alkaline aqueous solution (alkali developing operation). In this development, areas of low exposure intensity are removed by the organic solvent developing operation, while areas of high exposure intensity are removed by the alkali developing operation. This multi-development process in which development is performed two or more times can realize pattern formation without dissolving away only areas of intermediate exposure intensity, so that finer patterns than usually can be formed thereby (same mechanism as described in section [0077] of JP-A-2008-292975).

In the process combining the organic solvent developing operation with the alkali developing operation, the order of the alkali developing operation and organic solvent developing operation is not particularly limited. Preferably, however, the alkali development is performed prior to the organic solvent developing operation.

The organic developer as a whole preferably has a water content of less than 10 mass %, more preferably containing substantially no trace of water.

Namely, the amount of organic solvent used in the organic developer, based on the whole amount of the developer, is preferably in the range of 90 to 100 mass %, more preferably 95 to 100 mass %.

When the developer is an organic developer, as a rinse liquid, it is preferred to use a rinse liquid comprising at least one organic solvent selected from the group consisting of a ketone solvent, an ester solvent, an alcohol solvent and an amide solvent.

Further, the present invention relates to a photomask obtained by exposing the resist-coated mask blank to light and developing the exposed resist-coated mask blank. The above-described operations are applicable to the exposure and development. The obtained photomask can find appropriate application in the production of semiconductors.

The photomask of the present invention may be a light transmission mask for use in the exposure to an ArF excimer laser and the like, or a light reflection mask for use in reflection lithography using EUV light as a light source.

Still further, the present invention relates to a process for manufacturing a semiconductor device in which the above-described pattern forming method of the present invention is included, and relates to a semiconductor device manufactured by the process.

The semiconductor device of the present invention can be appropriately mounted in electrical and electronic equipments (household electronic appliance, OA/media-related equipment, optical apparatus, telecommunication equipment and the like).

### EXAMPLES

### Synthetic Example 1

### Synthesis of Monomer (M-001)

The following compounds (AA-1) and (AA-2) amounting to 50.0 g and 126.6 g, respectively, were dissolved in 500 g of methylene chloride, and 200 g of 1N aqueous NaOH solution and 7.1 g of tetrabutylammonium hydrogen sulfate were added to the solution. The mixture was agitated at room temperature for 2 hours. The thus obtained reaction liquid was transferred into a separatory funnel, and the separated organic phase was washed with 100 g of 1N aqueous NaOH solution twice and concentrated by means of an evaporator. The thus obtained transparent oil was dissolved in 500 g of acetonitrile, and 62.4 g of sodium iodide was added to the solution. The mixture was agitated at room temperature for 4 hours. Further, 142.9 g of triphenylsulfonium bromide was added to the reaction liquid, and agitated at room temperature for an hour. The resultant reaction liquid was concentrated by means of an evaporator and transferred into a separatory funnel loaded in advance with 300 ml of ethyl acetate. The separated organic phase was washed with 100 ml of distilled water five times and concentrated by means of an evaporator. Thus, 231.0 g of monomer (M-001) was obtained.

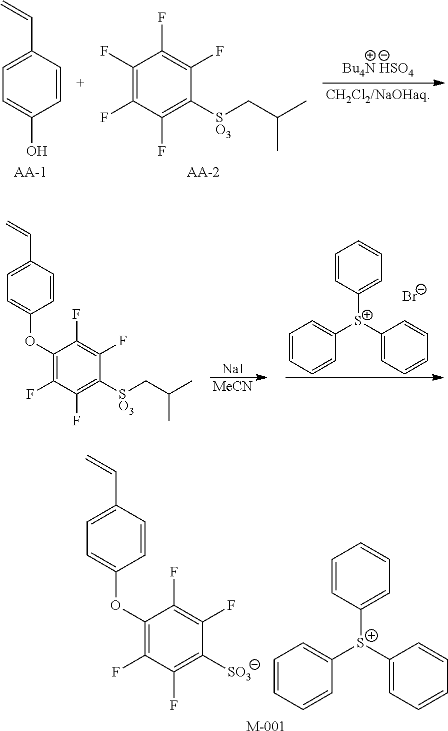

### Synthetic Example 2

### Synthesis of Resin (P-1)

In a nitrogen gas stream, 8.10 g of 1-methoxy-2-propanol was heated at 80° C. While agitating this liquid, a mixed solution comprised of 5.28 g of monomer (M-001), 6.12 g of monomer A of structural formula A below, 6.01 g of monomer B of structural formula B below, 32.5 g of 1-methoxy-2-propanol and 1.61 g of dimethyl 2,2′-azobisisobutyrate [V-601, produced by Wako Pure Chemical Industries, Ltd.] was dropped thereinto over a period of two hours. After the completion of the dropping, the mixture was further agitated at 80° C. for four hours. The obtained reaction liquid was allowed to stand still to cool, re-precipitated in a large volume of hexane, and dried in vacuum. Thus, 11.5 g of resin (P-1) according to the present invention was obtained.

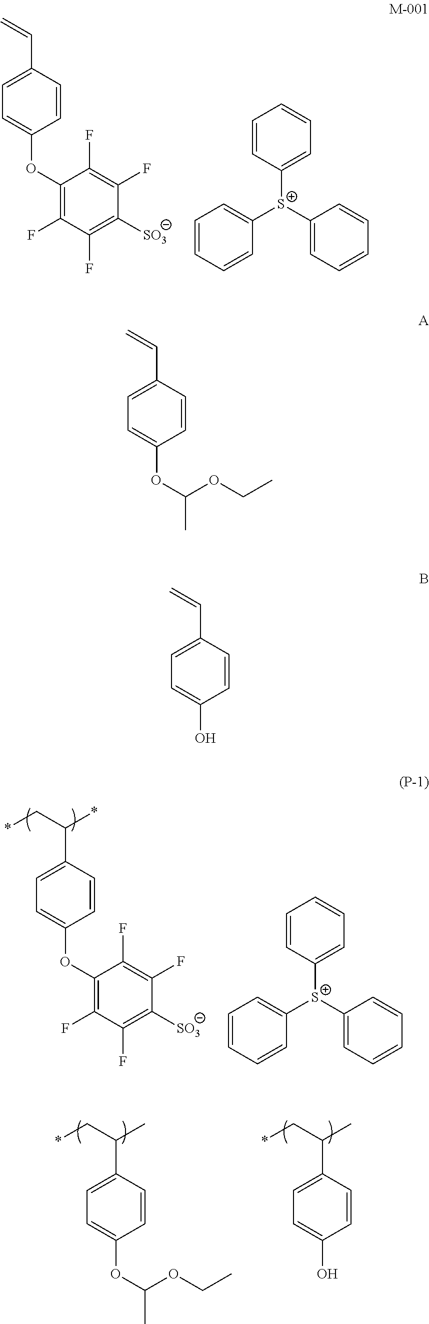

Resins (P-2) to (P-12) were synthesized in the same manner as described above.

With respect to each of the obtained resins, the component ratio (molar ratio) was calculated from ¹H-NMR measurements. Further, with respect to each of the obtained resins, the weight average molecular weight (Mw: polystyrene-equivalent), number average molecular weight (Mn: polystyrene-equivalent) and polydispersity index (Mw/Mn) were calculated from GPC (solvent: NMP) measurements. These results together with the chemical formulae are shown below.

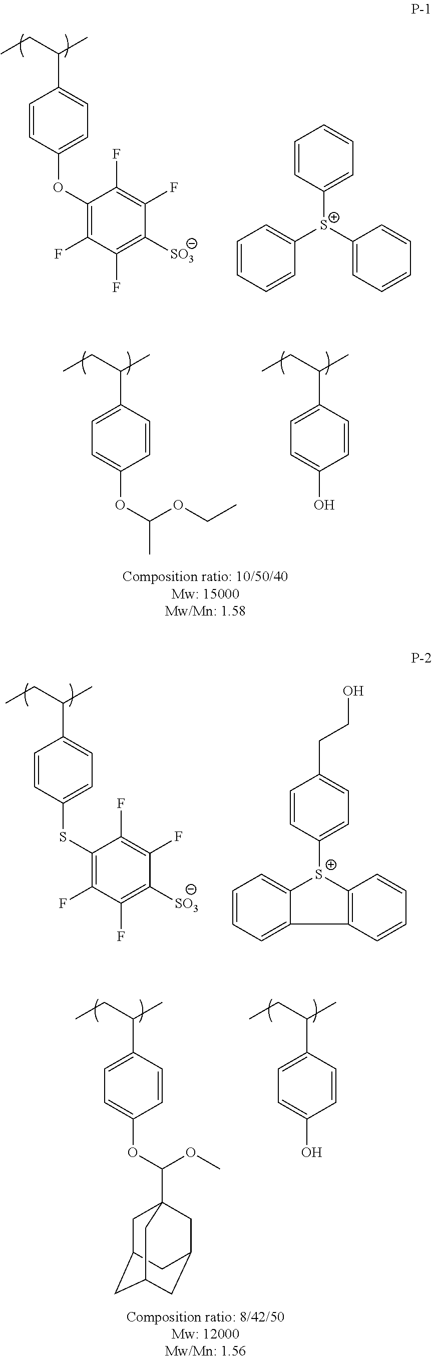

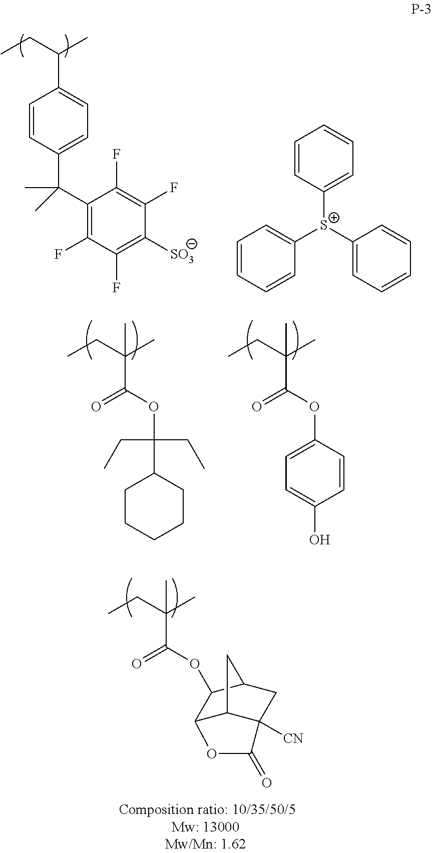

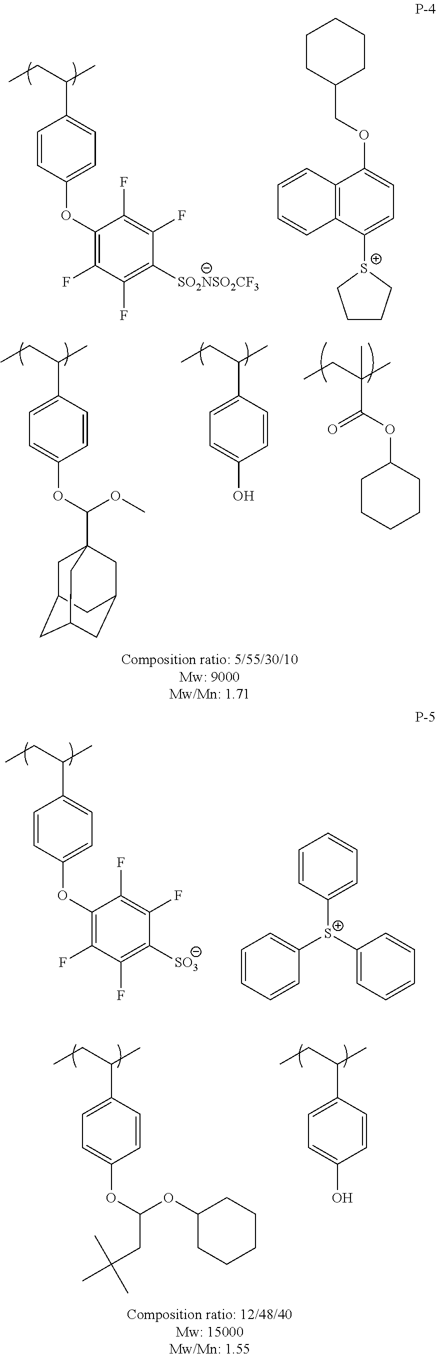

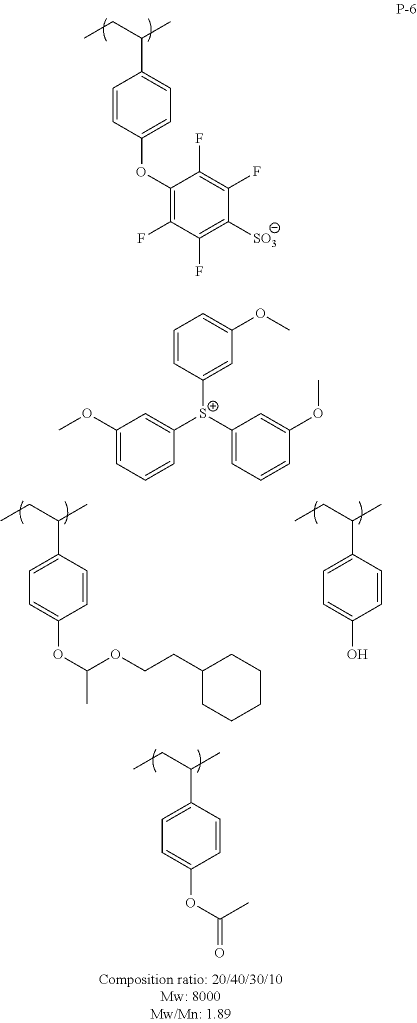

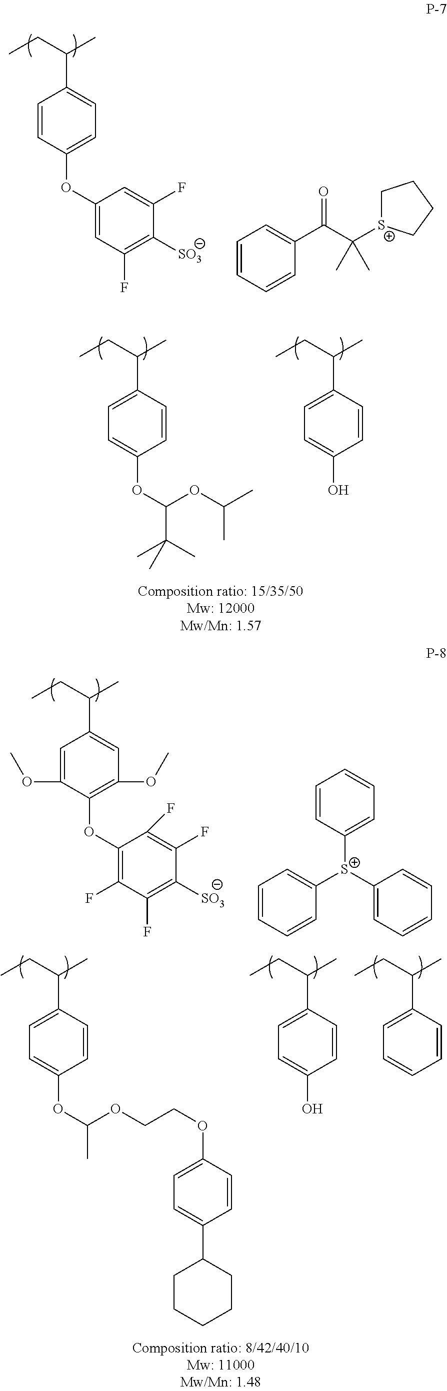

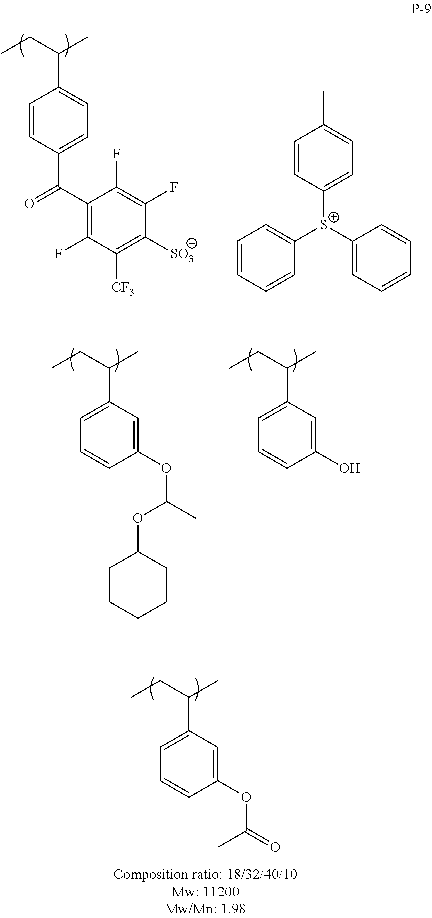

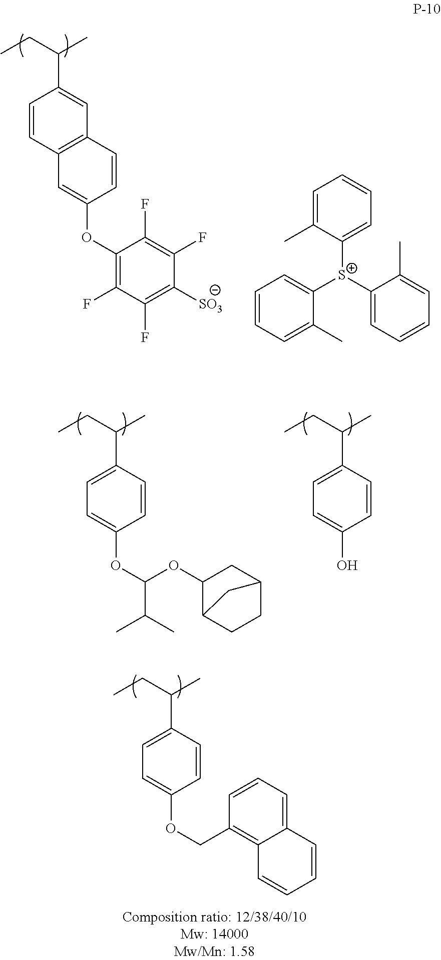

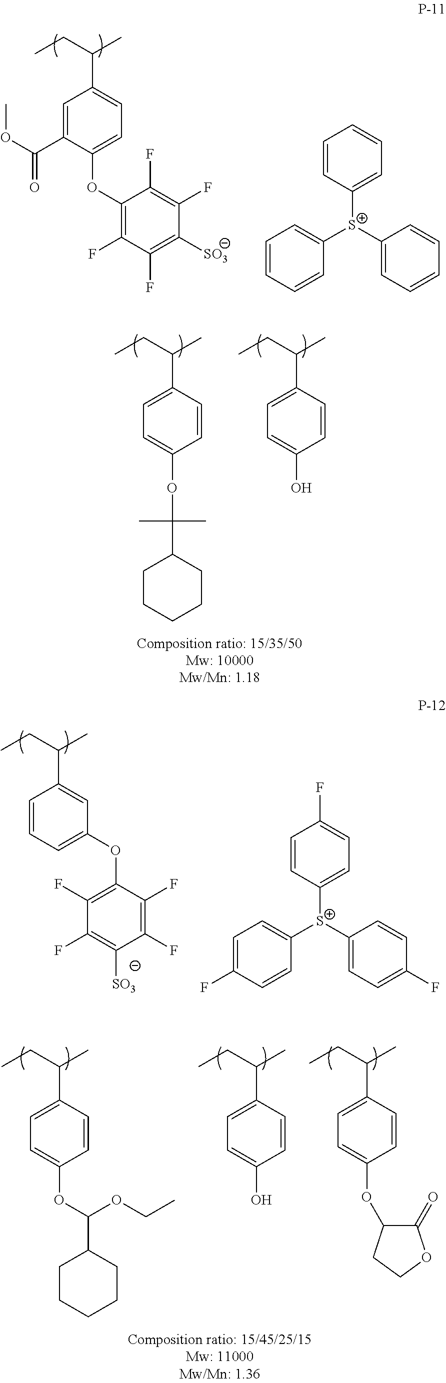

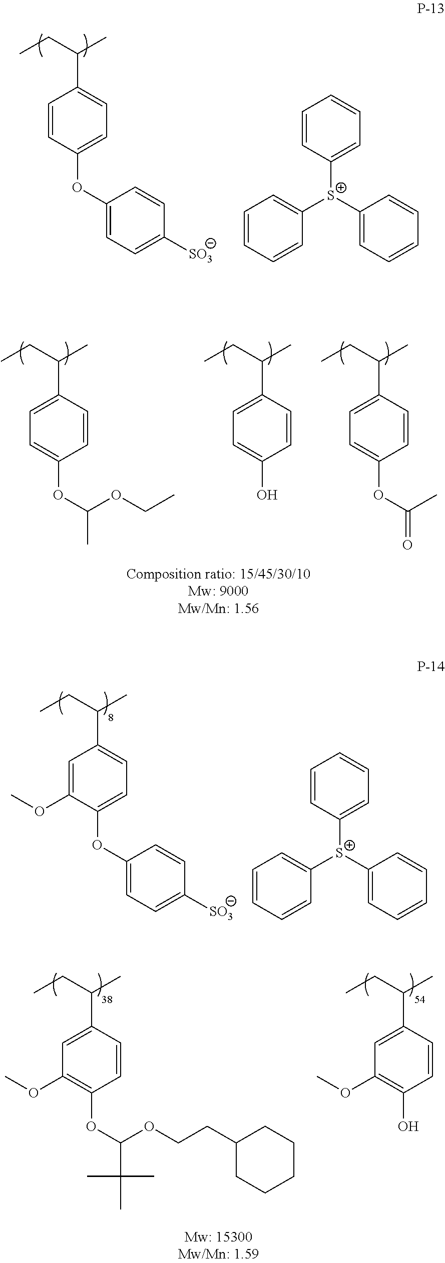

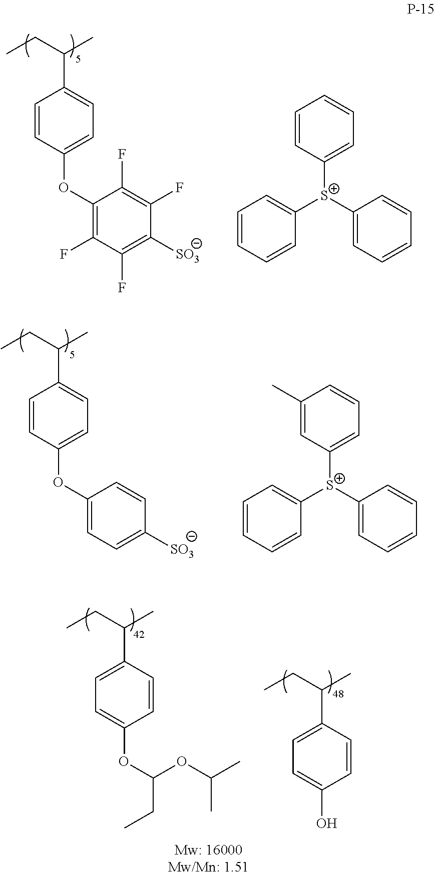

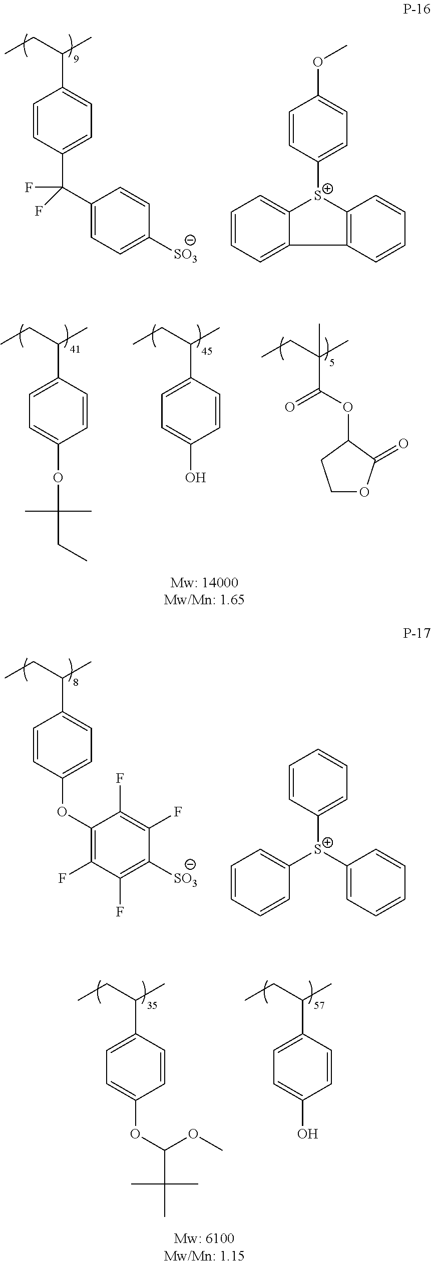

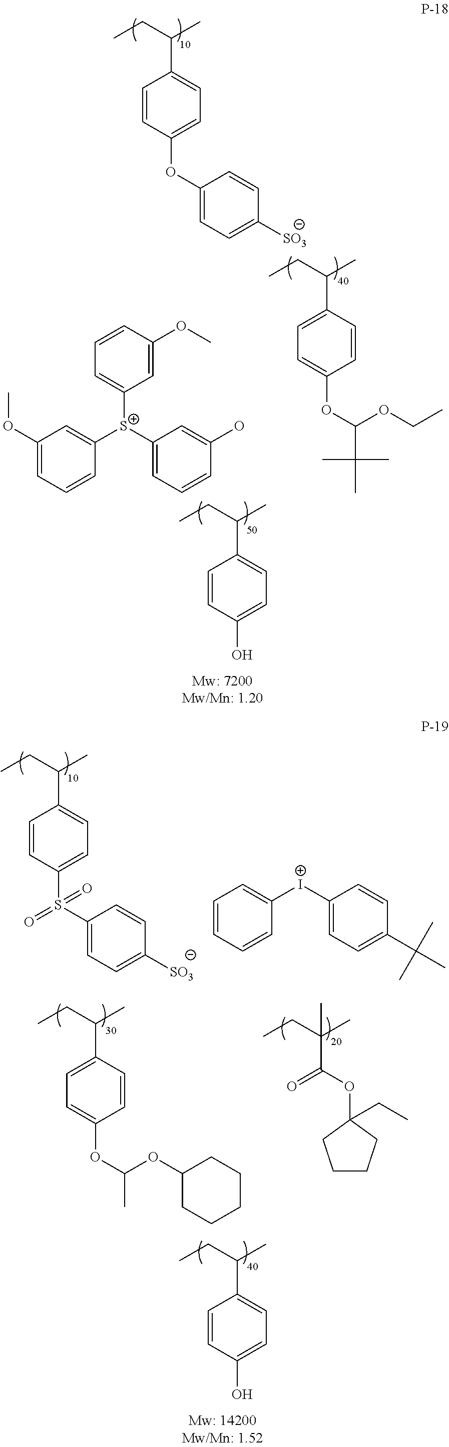

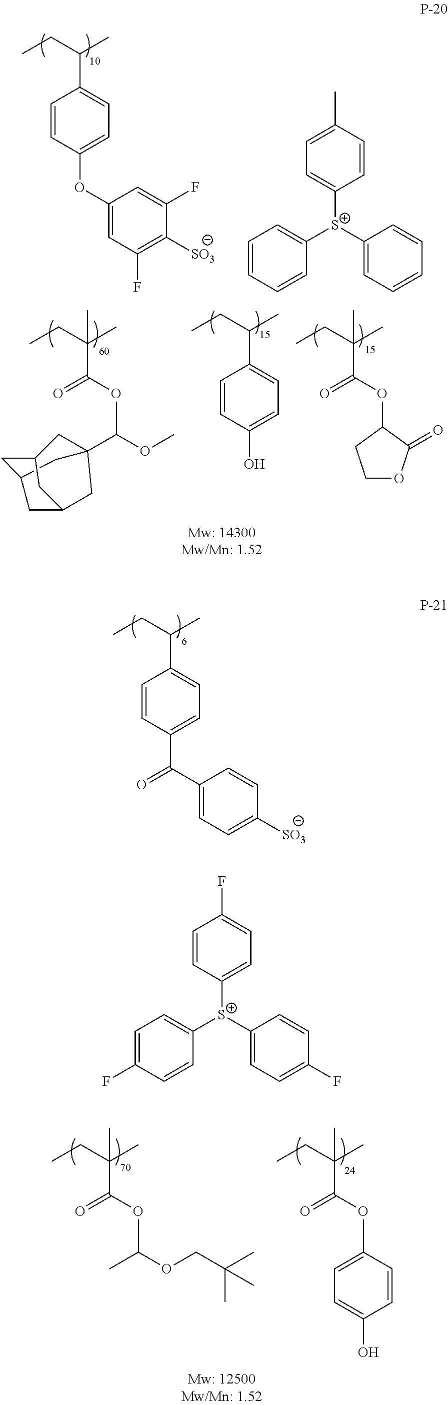

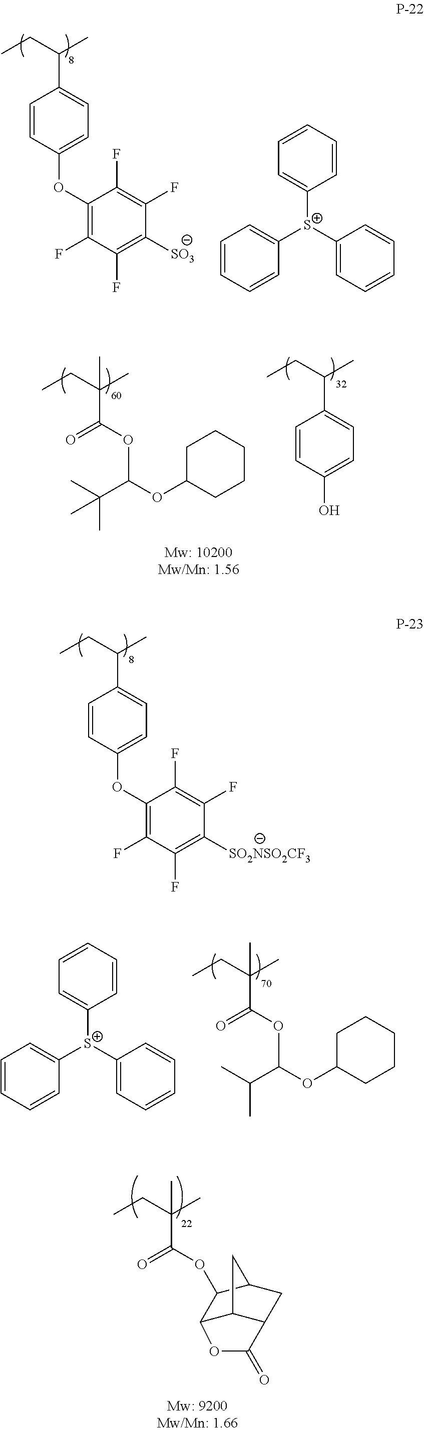

Moreover, resins R-1, R-2 and R-3 were synthesized as comparative or joint resins. With respect to each of these resins, the chemical formula, component ratio, weight average molecular weight (Mw) and polydispersity index (Mw/Mn) are shown below.

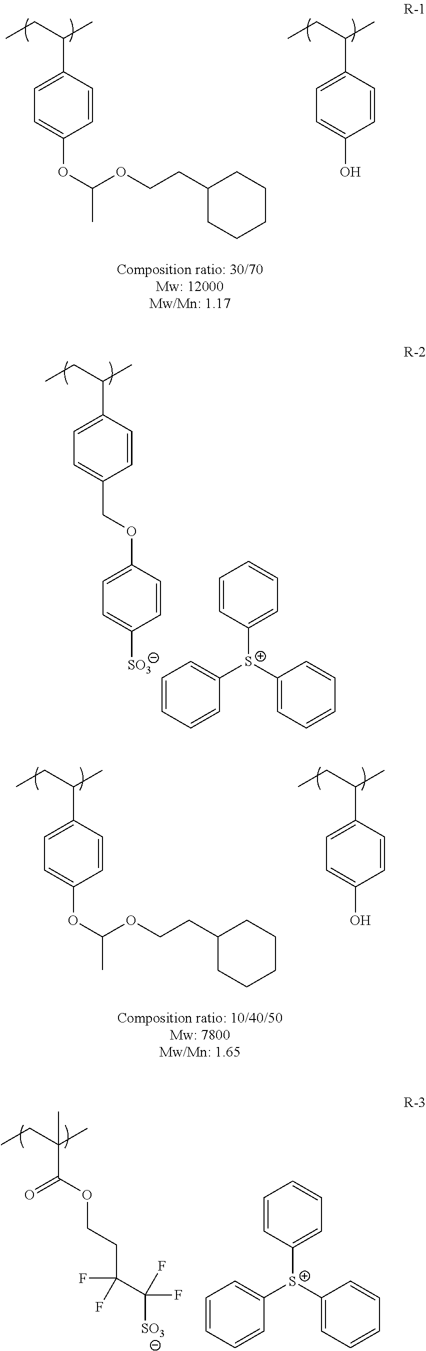

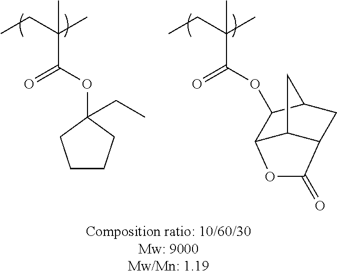

The photoacid generators, basic compounds, surfactants and solvents used in Examples and Comparative Examples are as follows.

[Photoacid Generator (Low-Molecular Compound]

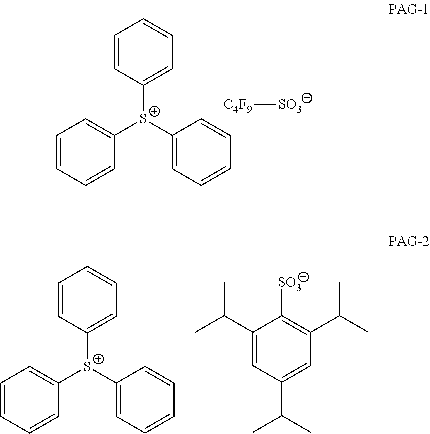

[Basic Compound]

TBAH: tetrabutylammonium hydroxide,

TOA: tri(n-octyl)amine,

TPI: 2,4,5-triphenylimidazole, and

TBAB: tetrabutylammonium benzoate.

[Surfactant]

W-1: Megafac F176 (produced by DIC Corporation, fluorinated),

W-2: Megafac R08 (produced by DIC Corporation, fluorinated and siliconized),

W-3: polysiloxane polymer KP-341 (produced by Shin-Etsu Chemical Co., Ltd., siliconized), and

W-4: PF6320 (produced by OMNOVA SOLUTIONS, INC., fluorinated).

[Solvent]

S1: propylene glycol monomethyl ether acetate (PGMEA, 1-methoxy-2-acetoxypropane),

S2: propylene glycol monomethyl ether (PGME, 1-methoxy-2-propanol),

S3: cyclohexanone, and

S4: γ-butyrolactone.

[Hydrophobic Resin (HR)]

The following compounds were used as hydrophobic resins. Each of the formulae is accompanied by the descriptions of the component ratio (molar ratio), weight average molecular weight (Mw) and polydispersity index (Mw/Mn).

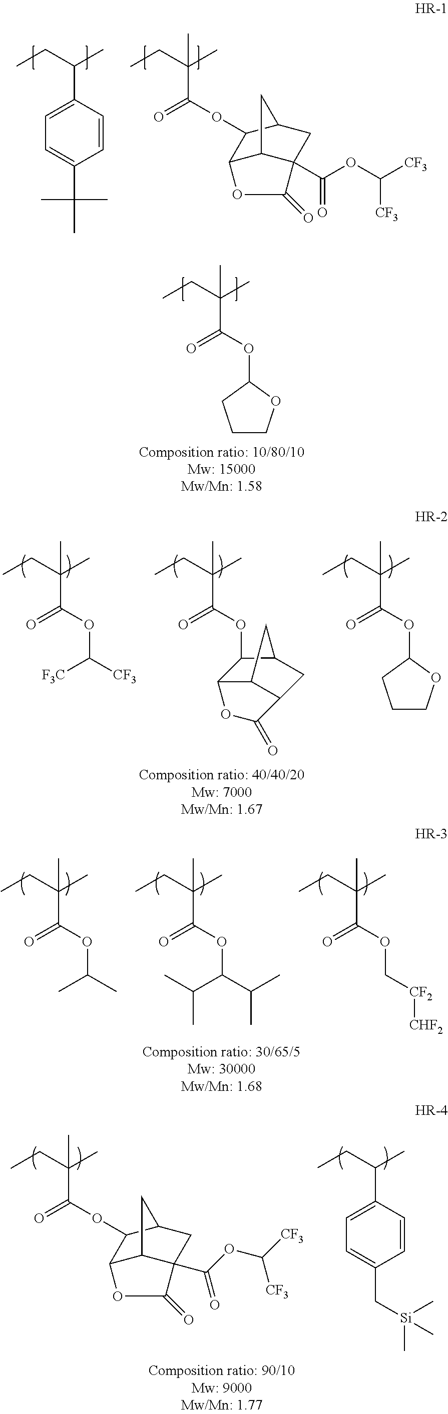

[Developer/Rinse Liquid]

The following compounds were used as developers and rinse liquids.

G-1: butyl acetate,

G-2: 2-heptanone,

G-3: anisole,

G-4: 4-methyl-2-pentanol,

G-5: 1-hexanol, and

G-6: decane.

<Evaluation of Resist>

Dissolution of individual components in solvents as indicated in Tables 2 and 3 below was carried out, thereby obtaining solutions each of 4 mass % solid content. The solutions were each passed through a polytetrafluoroethylene filter of 0.10 μm pore size, thereby obtaining actinic-ray- or radiation-sensitive resin compositions (resist compositions). The actinic-ray- or radiation-sensitive resin compositions were evaluated by the following methods, and the results are listed in Tables 2 and 3 below.

With respect to the individual components in the following Tables, when a plurality of different species thereof was used, the ratio refers to a mass ratio.

(Exposure Condition 1: Exposure to EB (Electron Beams)/Alkali Development), Examples 1 to 16 and 29 to 47 and Comparative Examples 1 to 3

Each of the above prepared actinic-ray- or radiation-sensitive resin compositions was uniformly applied onto a silicon substrate having undergone hexamethyldisilazane treatment by means of a spin coater, and dried by baking on a hot plate at 120° C. for 90 seconds. Thus, actinic-ray- or radiation-sensitive films (resist films) each having a thickness of 100 nm were formed. Each of the formed actinic-ray- or radiation-sensitive films was exposed to electron beams by means of an electron beam irradiating apparatus (HL750 manufactured by Hitachi, Ltd., acceleration voltage 50 KeV). The exposed film was immediately baked on a hot plate at 110° C. for 90 seconds. The baked film was developed with a 2.38 mass % aqueous tetramethylammonium hydroxide solution at 23° C. for 60 seconds, rinsed with pure water for 30 seconds and spin dried. Thus, resist patterns were obtained.

(Exposure Condition 2: Exposure to EUV (Extreme Ultraviolet/Alkali Development), Examples 17 to 28 and 48 to 60 and Comparative Examples 4 to 6

Each of the above prepared actinic-ray- or radiation-sensitive resin compositions was uniformly applied onto a silicon substrate having undergone hexamethyldisilazane treatment by means of a spin coater, and dried by baking on a hot plate at 120° C. for 90 seconds. Thus, actinic-ray- or radiation-sensitive films (resist films) each having a thickness of 100 nm were formed. Each of the formed actinic-ray- or radiation-sensitive films was exposed through a reflective mask of 100 nm line width 1:1 line and space pattern to EUV by means of an EUV exposure apparatus. The exposed film was immediately baked on a hot plate at 110° C. for 90 seconds. The baked film was developed with a 2.38 mass % aqueous tetramethylammonium hydroxide solution at 23° C. for 60 seconds, rinsed with pure water for 30 seconds and spin dried. Thus, resist patterns were obtained.

(Exposure Condition 3: Exposure to EB (Electron Beams)/Organic Solvent Development), Examples 61 to 76 and Comparative Examples 7 to 9

Each of the above prepared actinic-ray- or radiation-sensitive resin compositions was uniformly applied onto a silicon substrate having undergone hexamethyldisilazane treatment by means of a spin coater, and dried by baking on a hot plate at 120° C. for 90 seconds. Thus, actinic-ray- or radiation-sensitive films (resist films) each having a thickness of 100 nm were formed. Each of the formed actinic-ray- or radiation-sensitive films was exposed to electron beams by means of an electron beam irradiating apparatus (HL750 manufactured by Hitachi, Ltd., acceleration voltage 50 KeV). The exposed film was immediately baked on a hot plate at 110° C. for 90 seconds. The baked film was developed with the developer indicated in Table 4 below at 23° C. for 60 seconds, rinsed with the rinse liquid indicated in Table 4 below (when no rinse liquid was indicated, no rinse treatment was performed) for 30 seconds and spin dried. Thus, resist patterns were obtained.

(Exposure Condition 4: Exposure to EUV (Extreme Ultraviolet)/Organic Solvent Development), Examples 77 to 90 and Comparative Examples 10 to 12

Each of the above prepared actinic-ray- or radiation-sensitive resin compositions was uniformly applied onto a silicon substrate having undergone hexamethyldisilazane treatment by means of a spin coater, and dried by baking on a hot plate at 120° C. for 90 seconds. Thus, actinic-ray- or radiation-sensitive films (resist films) each having a thickness of 100 nm were formed. Each of the formed actinic-ray- or radiation-sensitive films was exposed through a reflective mask of 100 nm line width 1:1 line and space pattern to EUV by means of an EUV exposure apparatus (Micro Exposure Tool manufactured by Exitech Limited, NA0.3, Quadrupole, outer sigma 0.68, inner sigma 0.36). The exposed film was immediately baked on a hot plate at 110° C. for 90 seconds. The baked film was developed with the developer indicated in Table 5 below at 23° C. for 60 seconds, rinsed with the rinse liquid indicated in Table 5 below (when no rinse liquid was indicated, no rinse treatment was performed) for 30 seconds and spin dried. Thus, resist patterns were obtained.

(Evaluation of Sensitivity)

The shape of a cross section of each of the obtained patterns was observed by means of a scanning electron microscope (model S-9220, manufactured by Hitachi, Ltd.). The sensitivity was defined as the minimum exposure energy at which a 100 nm line width line and space pattern (line:space=1:1) could be resolved.

(Evaluation of Resolving Power)

The resolving power was defined as a limiting resolving power (minimum line width at which a line and a space could be separated and resolved from each other) under the amount of exposure exhibiting the above sensitivity.

(Evaluation of Pattern Shape)

The shape of a cross section of each 100 nm line width line and space pattern (line:space=1:1) formed in the amount of exposure exhibiting the above sensitivity was observed by means of a scanning electron microscope (model S-4300, manufactured by Hitachi, Ltd.) The pattern shape was graded into rectangle, rather taper, taper and inverse taper on a 4-point scale.

(Evaluation of Line Edge Roughness (LER))

With respect to each 100 nm line width line and space pattern (line:space=1:1) formed in the amount of exposure exhibiting the above sensitivity, the distance between actual edge and a reference line on which edges were to be present was measured on arbitrary 30 points within 50 μm in the longitudinal direction of the pattern by means of a scanning electron microscope (model S-9220, manufactured by Hitachi, Ltd.). The standard deviation of measured distances was determined, and 3σ was computed therefrom. The smaller the value thereof, the more favorable the line edge roughness performance.

(Evaluation of Exposure Latitude (EL, %))

The optimum exposure amount was defined as the exposure amount in which a (1:1) line-and-space mask pattern of 100 nm line width was reproduced. The exposure amount range in which when the exposure amount was varied, the pattern size allowed 50 nm±10% was measured. The exposure latitude is the quotient of the value of the exposure amount range divided by the optimum exposure amount, the quotient expressed by a percentage. The greater the value of the exposure latitude, the less the change of performance by exposure amount changes and the better the exposure latitude.

(Outgassing Performance: Ratio of Change in Film Thickness by Exposure)

Exposure to electron beams or extreme ultraviolet was carried out in the exposure amount equal to 2.0 times the exposure amount realizing the above sensitivity. The film thickness after the exposure but before postbake was measured, and the ratio of change from the film thickness before the exposure was calculated by the following formula.

Ratio of change in film thickness(%)=[(film thickness before exposure−film thickness after exposure)/(film thickness before exposure)]×100.

The smaller the value of this ratio, the more favorable the performance exhibited.

The obtained measurement results are listed in Tables 2 and 3 below.

TABLE 2
EB exposure/alkali development

| | | | | | Acid | | | | | | | | |
|---|---|---|---|---|---|---|---|---|---|---|---|---|---|
| | | | | | generator | | | | | | | | Conc. of |
| | | Conc. | Other | Conc. | (low- | Conc. | Basic | Conc. | Organic | Mass | Surfac- | Conc. | total |
| | Resin | * | resin | * | molecular) | * | comp. | * | solvent | ratio | tant | * | solids * |
| Ex. 1 | P-1 | 97.95 | Non | | Non | | TPI | 2 | S1/S2 | 40/60 | W-1 | 0.05 | 4.0 |
| Ex. 2 | P-1 | 97.95 | Non | | Non | | TBAH | 2 | S1/S2 | 40/60 | W-2 | 0.05 | 4.0 |
| Ex. 3 | P-2 | 97.95 | Non | | Non | | TPI | 2 | S1/S2 | 40/60 | W-1 | 0.05 | 4.0 |
| Ex. 4 | P-2 | 91.95 | Non | | PAG-1 | 5 | TPI | 3 | S1/S2 | 40/60 | W-1 | 0.05 | 4.0 |
| Ex. 5 | P-3 | 97.95 | Non | | Non | | TBAH | 2 | S1/S2 | 40/60 | W-2 | 0.05 | 4.0 |
| Ex. 6 | P-4 | 99 | Non | | Non | | TPI | 1 | S1/S2/S3 | 30/60/10 | Non | | 4.0 |
| Ex. 7 | P-5 | 97.95 | Non | | Non | | TPI | 2 | S1/S2 | 40/60 | W-1 | 0.05 | 4.0 |
| Ex. 8 | P-5 | 97.95 | Non | | Non | | TBAH | 2 | S1/S2 | 40/60 | W-1 | 0.05 | 4.0 |
| Ex. 9 | P-6 | 97.95 | Non | | Non | | TBAH | 2 | S1/S2 | 40/60 | W-1 | 0.05 | 4.0 |
| Ex. 10 | P-7 | 86.95 | P-13 | 10 | Non | | TOA | 3 | S1/S4 | 40/60 | W-4 | 0.05 | 4.0 |
| Ex. 11 | P-8 | 97.95 | Non | | Non | | TBAH | 2 | S1/S2 | 40/60 | W-2 | 0.05 | 4.0 |
| Ex. 12 | P-9 | 97.95 | Non | | Non | | TBAH | 2 | S1/S2 | 40/60 | W-1/W-2 | 0.05 | 4.0 |
| | | | | | | | | | | | (1/1) | | |
| Ex. 13 | P-10 | 95.95 | Non | | Non | | TBAH | 4 | S1/S2 | 40/60 | W-3 | 0.05 | 4.0 |
| Ex. 14 | P-11 | 95.95 | Non | | Non | | TPI | 4 | S1/S2 | 40/60 | W-1 | 0.05 | 4.0 |
| Ex. 15 | P-12 | 97.95 | Non | | Non | | TOA | 2 | S1/S2 | 40/60 | W-1 | 0.05 | 4.0 |
| Ex. 16 | P-13 | 97.95 | Non | | Non | | TBAH | 2 | S1/S2 | 40/60 | W-1 | 0.05 | 4.0 |
| Comp. | R-1 | 77.95 | Non | | PAG-2 | 20 | TBAH | 2 | S1/S2 | 40/60 | W-1 | 0.05 | 4.0 |
| Ex. 1 | | | | | | | | | | | | | |
| Comp. | R-2 | 97.95 | Non | | Non | | TBAH | 2 | S1/S2 | 40/60 | W-1 | 0.05 | 4.0 |
| Ex. 2 | | | | | | | | | | | | | |
| Comp. | R-3 | 97.95 | Non | | Non | | TBAH | 2 | S1/S2 | 40/60 | W-1 | 0.05 | 4.0 |
| Ex. 3 | | | | | | | | | | | | | |

| | | Resolving | | | | Outgassing |
|---|---|---|---|---|---|---|
| | Sensitivity | power | Pattern | LER | EL | performance |
| | (μC/cm²⁾ | (nm) | shape | (nm) | (%) | (%) |
| Ex. 1 | 28.5 | 55 | Rectangle | 5.5 | 15 | 1.5 |
| Ex. 2 | 28.3 | 60 | Rectangle | 5.6 | 15 | 1.5 |
| Ex. 3 | 28.6 | 70 | Rectangle | 5.1 | 12 | 3.8 |
| Ex. 4 | 29.5 | 75 | Rectangle | 5.3 | 13 | 3.2 |
| Ex. 5 | 31.2 | 70 | Rectangle | 6.0 | 12 | 4.3 |
| Ex. 6 | 34.5 | 70 | Rectangle | 5.9 | 12 | 4.0 |
| Ex. 7 | 28.1 | 65 | Rectangle | 5.5 | 15 | 1.6 |
| Ex. 8 | 27.6 | 50 | Rectangle | 5.3 | 12 | 1.2 |
| Ex. 9 | 27.4 | 55 | Rectangle | 5.2 | 13 | 1.9 |
| Ex. 10 | 28.3 | 50 | Rectangle | 5.1 | 13 | 3.4 |
| Ex. 11 | 27.0 | 55 | Rectangle | 5.9 | 13 | 2.8 |
| Ex. 12 | 33.3 | 70 | Rectangle | 6.0 | 11 | 1.8 |
| Ex. 13 | 28.9 | 65 | Rectangle | 5.3 | 12 | 1.4 |
| Ex. 14 | 33.0 | 65 | Rectangle | 5.2 | 12 | 1.6 |
| Ex. 15 | 31.2 | 70 | Rectangle | 5.4 | 12 | 1.7 |
| Ex. 16 | 34.5 | 75 | Rectangle | 6.2 | 12 | 2.2 |
| Comp. | 35.8 | 90 | Taper | 8.0 | 4 | 8.5 |
| Ex. 1 | | | | | | |
| Comp. | 35.5 | 85 | Taper | 7.0 | 6 | 4.5 |
| Ex. 2 | | | | | | |
| Comp. | 45.8 | 85 | Taper | 7.1 | 5 | 4.5 |
| Ex. 3 | | | | | | |

| | | | | | Acid | | | | | | | | |
|---|---|---|---|---|---|---|---|---|---|---|---|---|---|
| | | | Hydro- | | generator | | | | | | | | Conc. of |
| | | Conc. | phobic | Conc. | (low- | Conc. | Basic | Conc. | Organic | Mass | Surfac- | Conc. | total |
| | Resin | * | resin | * | molecular) | * | comp. | * | solvent | ratio | tant | * | solids * |
| Ex. 29 | P-1 | 97.95 | Non | | Non | | TBAB | 2 | S1/S2 | 40/60 | W-1 | 0.05 | 4.0 |
| Ex. 30 | P-1 | 92.95 | HR-4 | 5 | Non | | TBAH | 2 | S1/S2 | 40/60 | W-1 | 0.05 | 4.0 |
| Ex. 31 | P-2 | 97.95 | Non | | Non | | TBAB | 2 | S1/S2 | 40/60 | W-2 | 0.05 | 4.0 |
| Ex. 32 | P-3 | 93.95 | HR-1 | 4 | Non | | TOA | 2 | S1/S2/S4 | 30/60/10 | W-1 | 0.05 | 4.0 |
| Ex. 33 | P-5 | 92.95 | HR-1 | 4 | Non | | TBAB | 3 | S1/S2 | 40/60 | W-1 | 0.05 | 4.0 |
| Ex. 34 | P-6 | 86.95 | HR-3 | 10 | Non | | TPI | 3 | S1/S2 | 40/60 | W-1 | 0.05 | 4.0 |
| Ex. 35 | P-9 | 97.95 | Non | | Non | | TBAB | 2 | S1/S2 | 40/60 | W-2 | 0.05 | 4.0 |
| Ex. 36 | P-13 | 93.5 | HR-1 | 5 | Non | | TPI | 1.5 | S1/S2 | 40/60 | Non | | 4.0 |
| Ex. 37 | P-14 | 97.95 | Non | | Non | | TBAH | 2 | S1/S2 | 40/60 | W-1 | 0.05 | 4.0 |
| Ex. 38 | P-14 | 94.95 | HR-2 | 3 | Non | | TBAH | 2 | S1/S2 | 40/60 | W-1 | 0.05 | 4.0 |
| Ex. 39 | P-15 | 97.95 | Non | | Non | | TBAH | 2 | S1/S2/S3 | 30/60/10 | W-1 | 0.05 | 4.0 |
| Ex. 40 | P-16 | 92.95 | HR-4 | 5 | Non | | TPI | 2 | S1/S2 | 40/60 | W-1 | 0.05 | 4.0 |
| Ex. 41 | P-17 | 97.95 | Non | | Non | | TBAB | 2 | S1/S2 | 40/60 | W-2 | 0.05 | 4.0 |
| Ex. 42 | P-17 | 91.95 | HR-1 | 5 | Non | | TBAB | 3 | S1/S2 | 40/60 | W-4 | 0.05 | 4.0 |
| Ex. 43 | P-18 | 94.95 | HR-1 | 3 | Non | | TPI | 2 | S1/S2 | 40/60 | W-1 | 0.05 | 4.0 |
| Ex. 44 | P-18 | 97.95 | Non | | Non | | TBAB | 2 | S1/S2 | 40/60 | W-2 | 0.05 | 4.0 |
| Ex. 45 | P-19 | 80.95 | HR-2 | 10 | PAG-2 | 5 | TOA | 4 | S1/S2 | 40/60 | W-1 | 0.05 | 4.0 |
| Ex. 46 | P-20 | 97.95 | Non | | Non | | TBAB | 2 | S1/S2 | 40/60 | W-1 | 0.05 | 4.0 |
| Ex. 47 | P-22 | 90 | HR-4 | 7 | Non | | TBAH | 3 | S1/S2 | 40/60 | Non | | 4.0 |

| | | Resolving | | | | Outgassing |
|---|---|---|---|---|---|---|
| | Sensitivity | power | Pattern | LER | EL | performance |
| | (μC/cm²⁾ | (nm) | shape | (nm) | (%) | (%) |
| Ex. 29 | 28.3 | 55 | Rectangle | 5.1 | 15 | 1.6 |
| Ex. 30 | 29.3 | 60 | Rectangle | 5.2 | 14 | 1.5 |
| Ex. 31 | 29.2 | 70 | Rectangle | 5.3 | 11 | 4.0 |
| Ex. 32 | 30.0 | 70 | Rectangle | 5.8 | 12 | 4.2 |
| Ex. 33 | 30.2 | 65 | Rectangle | 5.4 | 15 | 1.4 |
| Ex. 34 | 28.4 | 55 | Rectangle | 6.0 | 13 | 2.2 |
| Ex. 35 | 28.5 | 70 | Rectangle | 5.0 | 11 | 1.9 |
| Ex. 36 | 32.5 | 75 | Rectangle | 5.2 | 12 | 2.3 |
| Ex. 37 | 28.5 | 65 | Rectangle | 5.3 | 11 | 2.5 |
| Ex. 38 | 28.1 | 70 | Rectangle | 5.1 | 12 | 2.4 |
| Ex. 39 | 27.6 | 60 | Rectangle | 5.0 | 13 | 3.1 |
| Ex. 40 | 28.5 | 70 | Rectangle | 5.3 | 12 | 1.2 |
| Ex. 41 | 28.5 | 55 | Rectangle | 5.5 | 15 | 1.5 |
| Ex. 42 | 27.9 | 60 | Rectangle | 5.4 | 14 | 1.5 |
| Ex. 43 | 28.5 | 65 | Rectangle | 5.8 | 13 | 2.1 |
| Ex. 44 | 27.0 | 65 | Rectangle | 5.9 | 12 | 2.3 |
| Ex. 45 | 28.5 | 75 | Rectangle | 5.7 | 10 | 4.2 |
| Ex. 46 | 27.0 | 70 | Rectangle | 6.1 | 12 | 3.5 |
| Ex. 47 | 30.5 | 70 | Rectangle | 6.2 | 14 | 3.4 |

* The conc. of each component is conc. (mass %) based on the amount of total solids.

TABLE 3
EUV exposure/alkali development

| | | | | | Acid | | | | | | | | |
|---|---|---|---|---|---|---|---|---|---|---|---|---|---|
| | | | | | generator | | | | | | | | Conc. of |
| | | Conc. | Other | Conc. | (low- | Conc. | Basic | Conc. | Organic | Mass | Surfac- | Conc. | total |
| | Resin | * | resin | * | molecular) | * | comp. | * | solvent | ratio | tant | * | solids * |
| Ex. 17 | P-1 | 97.95 | Non | | Non | | TPI | 2 | S1/S2 | 40/60 | W-1 | 0.05 | 4.0 |
| Ex. 18 | P-2 | 97.95 | Non | | Non | | TPI | 2 | S1/S2 | 40/60 | W-1 | 0.05 | 4.0 |
| Ex. 19 | P-3 | 97.95 | Non | | Non | | TBAH | 2 | S1/S2 | 40/60 | W-2 | 0.05 | 4.0 |
| Ex. 20 | P-5 | 97.95 | Non | | Non | | TPI | 2 | S1/S2 | 40/60 | W-1 | 0.05 | 4.0 |
| Ex. 21 | P-6 | 97.95 | Non | | Non | | TBAH | 2 | S1/S2 | 40/60 | W-2 | 0.05 | 4.0 |
| Ex. 22 | P-7 | 87.95 | R-1 | 10 | Non | | TOA | 2 | S1/S2 | 40/60 | W-1 | 0.05 | 4.0 |
| Ex. 23 | P-8 | 95.95 | Non | | Non | | TBAH | 4 | S1/S2 | 40/60 | W-1 | 0.05 | 4.0 |
| Ex. 24 | P-9 | 97.95 | Non | | Non | | TBAH | 2 | S1/S2 | 40/60 | W-1 | 0.05 | 4.0 |
| Ex. 25 | P-10 | 95.95 | Non | | Non | | TBAH | 4 | S1/S2 | 40/60 | W-1 | 0.05 | 4.0 |
| Ex. 26 | P-11 | 95.95 | Non | | Non | | TPI | 4 | S1/S2 | 40/60 | W-1 | 0.05 | 4.0 |
| Ex. 27 | P-12 | 95.95 | Non | | Non | | TBAH | 4 | S1/S2 | 40/60 | W-1 | 0.05 | 4.0 |
| Ex. 28 | P-13 | 97.95 | Non | | Non | | TBAH | 2 | S1/S2 | 40/60 | W-1 | 0.05 | 4.0 |
| Comp. | R-1 | 77.95 | Non | | PAG-2 | 20 | TBAH | 2 | S1/S2 | 40/60 | W-1 | 0.05 | 4.0 |
| Ex. 4 | | | | | | | | | | | | | |
| Comp. | R-2 | 97.95 | Non | | Non | | TBAH | 2 | S1/S2 | 40/60 | W-1 | 0.05 | 4.0 |
| Ex. 5 | | | | | | | | | | | | | |
| Comp. | R-3 | 97.95 | Non | | Non | | TBAH | 2 | S1/S2 | 40/60 | W-1 | 0.05 | 4.0 |
| Ex. 6 | | | | | | | | | | | | | |

| | Resolving | | | | | Outgassing |
|---|---|---|---|---|---|---|
| | power | Sensitivity | LER | Pattern | EL | performance |
| | (nm) | (mJ/cm²) | (nm) | shape | (%) | (%) |
| Ex. 17 | 55 | 25.3 | 5.0 | Rectangle | 15 | 2.0 |
| Ex. 18 | 55 | 28.8 | 5.5 | Rectangle | 13 | 4.5 |
| Ex. 19 | 65 | 27.5 | 6.5 | Rectangle | 13 | 5.0 |
| Ex. 20 | 50 | 23.9 | 5.0 | Rectangle | 15 | 1.2 |
| Ex. 21 | 55 | 24.7 | 4.5 | Rectangle | 12 | 2.2 |
| Ex. 22 | 65 | 26.3 | 7.0 | Rectangle | 13 | 2.0 |
| Ex. 23 | 65 | 27.3 | 6.5 | Rectangle | 11 | 2.2 |
| Ex. 24 | 65 | 26.0 | 6.5 | Rectangle | 12 | 3.5 |
| Ex. 25 | 55 | 25.0 | 5.5 | Rectangle | 10 | 3.5 |
| Ex. 26 | 55 | 25.5 | 7.0 | Rectangle | 11 | 4.0 |
| Ex. 27 | 55 | 26.3 | 6.0 | Rectangle | 12 | 3.2 |
| Ex. 28 | 55 | 29.5 | 7.0 | Rectangle | 12 | 3.3 |
| Comp. | 75 | 30.0 | 8.0 | Taper | 5 | 9.0 |
| Ex. 4 | | | | | | |
| Comp. | 70 | 30.0 | 7.5 | Taper | 8 | 5.5 |
| Ex. 5 | | | | | | |
| Comp. | 70 | 40.0 | 7.5 | Rather taper | 8 | 6.6 |
| Ex. 6 | | | | | | |

| | | | | | Acid | | | | | | | | |
|---|---|---|---|---|---|---|---|---|---|---|---|---|---|
| | | | Hydro- | | generator | | | | | | | | Conc. of |
| | | Conc. | phobic | Conc. | (low- | Conc. | Basic | Conc. | Organic | Mass | Surfac- | Conc. | total |
| | Resin | * | resin | * | molecular) | * | comp. | * | solvent | ratio | tant | * | solids * |
| Ex. 48 | P-1 | 97.95 | Non | | Non | | TBAB | 2 | S1/S2 | 40/60 | W-1 | 0.05 | 4.0 |
| Ex. 49 | P-1 | 92.95 | HR-4 | 5 | Non | | TBAH | 2 | S1/S2 | 40/60 | W-1 | 0.05 | 4.0 |
| Ex. 50 | P-5 | 97.95 | Non | | Non | | TBAB | 2 | S1/S2 | 40/60 | W-2 | 0.05 | 4.0 |
| Ex. 51 | P-6 | 93 | HR-1 | 5 | Non | | TBAB | 2 | S1/S2 | 40/60 | Non | | 4.0 |
| Ex. 52 | P-13 | 91.95 | HR-1 | 6 | Non | | TPI | 2 | S1/S2 | 40/60 | W-2 | 0.05 | 4.0 |
| Ex. 53 | P-15 | 94.95 | HR-4 | 3 | Non | | TBAB | 2 | S1/S2 | 40/60 | W-1 | 0.05 | 4.0 |
| Ex. 54 | P-17 | 97.95 | Non | | Non | | TBAB | 2 | S1/S2 | 40/60 | W-1 | 0.05 | 4.0 |
| Ex. 55 | P-17 | 92.95 | HR-1 | 5 | Non | | TBAH | 2 | S1/S2 | 40/60 | W-1 | 0.05 | 4.0 |
| Ex. 56 | P-18 | 96.95 | Non | | Non | | TBAB | 3 | S1/S2 | 40/60 | W-1 | 0.05 | 4.0 |
| Ex. 57 | P-18 | 93.95 | HR-2 | 4 | Non | | TBAH | 2 | S1/S2 | 40/60 | W-1 | 0.05 | 4.0 |
| Ex. 58 | P-19 | 97.95 | Non | | Non | | TPI | 2 | S1/S2 | 40/60 | W-1 | 0.05 | 4.0 |
| Ex. 59 | P-20 | 75.95 | HR-3 | 10 | PAG-2 | 10 | TPI | 4 | S1/S2 | 40/60 | W-1 | 0.05 | 4.0 |
| Ex. 60 | P-21 | 97 | Non | | Non | | TBAB | 3 | S1/S2 | 40/60 | Non | | 4.0 |

| | Resolving | | | | | Outgassing |
|---|---|---|---|---|---|---|
| | power | Sensitivity | LER | Pattern | EL | performance |
| | (nm) | (mJ/cm²) | (nm) | shape | (%) | (%) |
| Ex. 48 | 55 | 25.5 | 5.0 | Rectangle | 15 | 2.0 |
| Ex. 49 | 60 | 26.0 | 5.5 | Rectangle | 13 | 1.8 |
| Ex. 50 | 50 | 26.5 | 5.0 | Rectangle | 15 | 1.5 |
| Ex. 51 | 55 | 25.0 | 4.5 | Rectangle | 13 | 2.5 |
| Ex. 52 | 55 | 24.5 | 6.5 | Rectangle | 13 | 3.0 |
| Ex. 53 | 60 | 25.5 | 6.0 | Rectangle | 12 | 3.5 |
| Ex. 54 | 55 | 25.0 | 5.5 | Rectangle | 16 | 1.5 |
| Ex. 55 | 50 | 25.0 | 5.0 | Rectangle | 15 | 1.5 |
| Ex. 56 | 60 | 24.5 | 6.5 | Rectangle | 13 | 3.0 |
| Ex. 57 | 55 | 25.5 | 6.0 | Rectangle | 12 | 3.0 |
| Ex. 58 | 65 | 25.3 | 6.5 | Rectangle | 12 | 4.0 |
| Ex. 59 | 60 | 27.0 | 6.5 | Rectangle | 10 | 4.5 |
| Ex. 60 | 60 | 27.5 | 6.0 | Rectangle | 11 | 4.0 |

* The conc. of each component is conc. (mass %) based on the amount of total solids.

TABLE 4
EB exposure/organic solvent development

| | | | | | Acid | | | | | | | | | | |
|---|---|---|---|---|---|---|---|---|---|---|---|---|---|---|---|
| | | | Hydro- | | generator | | | | | | | | Conc. of | | |
| | | Conc. | phobic | Conc. | (low- | Conc. | Basic | Conc. | Organic | Mass | Surfac- | Conc. | total | | Rinse |
| | Resin | * | resin | * | molecular) | * | comp. | * | solvent | ratio | tant | * | solids * | Developer | liquid |
| Ex. 61 | P-1 | 97.95 | Non | | Non | | TBAH | 2 | S1/S2 | 40/60 | W-1 | 0.05 | 4.0 | G-1 | Non |
| Ex. 62 | P-2 | 82.95 | HR-4 | 3 | PAG-2 | 10 | TBAH | 4 | S1/S2 | 40/60 | W-1 | 0.05 | 4.0 | G-1 | G-5 |
| Ex. 63 | P-3 | 97.95 | Non | | Non | | TBAB | 2 | S1/S2 | 40/60 | W-2 | 0.05 | 4.0 | G-1 | G-5 |
| Ex. 64 | P-3 | 90 | HR-3 | 8 | Non | | TBAB | 2 | S1/S2 | 40/60 | Non | | 4.0 | G-1 | Non |
| Ex. 65 | P-5 | 91.95 | HR-1 | 5 | Non | | TPI | 3 | S1/S2 | 40/60 | W-1 | 0.05 | 4.0 | G-1 | G-6 |
| Ex. 66 | P-7 | 96.95 | Non | | Non | | TBAH | 3 | S1/S2 | 40/60 | W-2 | 0.05 | 4.0 | G-3 | Non |
| Ex. 67 | P-10 | 97.95 | Non | | Non | | TBAB | 2 | S1/S3 | 40/60 | W-1 | 0.05 | 4.0 | G-1 | Non |
| Ex. 68 | P-11 | 97.95 | Non | | Non | | TBAH | 2 | S1/S2 | 40/60 | W-1 | 0.05 | 4.0 | G-1 | G-5 |
| Ex. 69 | P-13 | 97.95 | Non | | Non | | TPI | 2 | S1/S2 | 40/60 | W-4 | 0.05 | 4.0 | G-1 | Non |
| Ex. 70 | P-15 | 87.95 | HR-2 | 10 | Non | | TBAB | 2 | S1/S2/S4 | 30/60/10 | W-2 | 0.05 | 4.0 | G-1 | Non |
| Ex. 71 | P-17 | 97.95 | Non | | Non | | TPI | 2 | S1/S2 | 40/60 | W-1 | 0.05 | 4.0 | G-1 | Non |
| Ex. 72 | P-18 | 97.95 | Non | | Non | | TBAB | 2 | S1/S2 | 40/60 | W-1 | 0.05 | 4.0 | G-2 | G-5 |
| Ex. 73 | P-20 | 97.95 | Non | | Non | | TBAH | 2 | S1/S2 | 40/60 | W-2 | 0.05 | 4.0 | G-1 | G-5 |
| Ex. 74 | P-21 | 90.95 | HR-4 | 5 | Non | | TPI | 4 | S1/S2 | 40/60 | W-3 | 0.05 | 4.0 | G-4 | G-5 |
| Ex. 75 | P-22 | 97.95 | Non | | Non | | TBAH | 2 | S1/S2 | 40/60 | W-2 | 0.05 | 4.0 | G-1 | Non |
| Ex. 76 | P-23 | 92 | Non | | PAG-1 | 5 | TBAB | 3 | S1/S2 | 40/60 | Non | | 4.0 | G-1 | Non |
| Comp. | R-1 | 77.95 | Non | | PAG-2 | 20 | TBAH | 2 | S1/S2 | 40/60 | W-1 | 0.05 | 4.0 | G-1 | G-6 |
| Ex. 7 | | | | | | | | | | | | | | | |
| Comp. | R-2 | 97.95 | Non | | Non | | TBAH | 2 | S1/S2 | 40/60 | W-2 | 0.05 | 4.0 | G-1 | Non |
| Ex. 8 | | | | | | | | | | | | | | | |
| Comp. | R-3 | 97.95 | Non | | Non | | TPI | 2 | S1/S2 | 40/60 | W-1 | 0.05 | 4.0 | G-1 | Non |
| Ex. 9 | | | | | | | | | | | | | | | |

| | | Resolving | | | | Outgassing |
|---|---|---|---|---|---|---|
| | Sensitivity | power | Pattern | LER | EL | performance |
| | (μC/cm²⁾ | (nm) | shape | (nm) | (%) | (%) |
| Ex. 61 | 38.0 | 65 | Rectangle | 6.1 | 14 | 3.5 |
| Ex. 62 | 40.0 | 80 | Rectangle | 6.3 | 8 | 3.4 |
| Ex. 63 | 37.0 | 65 | Rectangle | 6.8 | 10 | 3.9 |
| Ex. 64 | 38.5 | 65 | Rectangle | 6.4 | 12 | 4.3 |
| Ex. 65 | 39.0 | 60 | Rectangle | 6.8 | 15 | 4.5 |
| Ex. 66 | 40.0 | 70 | Rectangle | 7.0 | 9 | 3.8 |
| Ex. 67 | 41.0 | 75 | Rectangle | 6.3 | 12 | 3.5 |
| Ex. 68 | 38.0 | 75 | Rectangle | 6.5 | 10 | 2.2 |
| Ex. 69 | 37.0 | 65 | Rectangle | 7.0 | 12 | 3.0 |
| Ex. 70 | 28.5 | 65 | Rectangle | 7.5 | 10 | 4.5 |
| Ex. 71 | 31.5 | 65 | Rectangle | 6.8 | 14 | 4.2 |
| Ex. 72 | 33.0 | 70 | Rectangle | 6.8 | 14 | 4.2 |
| Ex. 73 | 35.0 | 70 | Rectangle | 6.4 | 14 | 3.1 |
| Ex. 74 | 36.5 | 70 | Rectangle | 6.9 | 13 | 2.5 |
| Ex. 75 | 35.0 | 65 | Rectangle | 6.4 | 15 | 3.1 |
| Ex. 76 | 33.5 | 65 | Rectangle | 6.2 | 13 | 3.1 |

| | |
|---|---|
| Comp. | Not resolved |
| Ex. 7 | |

| | | | | | | |
|---|---|---|---|---|---|---|
| Comp. | 45.0 | 90 | Inverse | 8.5 | 5 | 5.5 |
| Ex. 8 | | | taper | | | |
| Comp. | 46.5 | 95 | Inverse | 8.0 | 5 | 6.5 |
| Ex. 9 | | | taper | | | |

* The conc. of each component is conc. (mass %) based on the amount of total solids.

TABLE 5
EUV exposure/organic solvent development

| | | | | | Acid | | | | | | | | | | |
|---|---|---|---|---|---|---|---|---|---|---|---|---|---|---|---|
| | | | Hydro- | | generator | | | | | | | | Conc. of | | |
| | | Conc. | phobic | Conc. | (low- | Conc. | Basic | Conc. | Organic | Mass | Surfac- | Conc. | total | Devel- | Rinse |
| | Resin | * | resin | * | molecular) | * | comp. | * | solvent | ratio | tant | * | solids * | oper | liquid |
| Ex. 77 | P-1 | 97.95 | Non | | Non | | TBAH | 2 | S1/S2 | 40/60 | W-1 | 0.05 | 4.0 | G-1 | Non |
| Ex. 78 | P-1 | 88 | HR-4 | 3 | PAG-2 | 5 | TBAH | 4 | S1/S2/S4 | 30/60/10 | Non | | 4.0 | G-1 | Non |
| Ex. 79 | P-2 | 97.95 | Non | | Non | | TBAB | 2 | S1/S2 | 40/60 | W-2 | 0.05 | 4.0 | G-1 | G-6 |
| Ex. 80 | P-3 | 97.95 | Non | | Non | | TBAB | 2 | S1/S2 | 40/60 | W-1 | 0.05 | 4.0 | G-1 | Non |
| Ex. 81 | P-5 | 91.95 | HR-1 | 5 | Non | | TPI | 3 | S1/S2 | 40/60 | W-1 | 0.05 | 4.0 | G-4 | Non |
| Ex. 82 | P-11 | 96.95 | Non | | Non | | TBAH | 3 | S1/S2 | 40/60 | W-2 | 0.05 | 4.0 | G-1 | Non |
| Ex. 83 | P-13 | 97.95 | Non | | Non | | TBAB | 2 | S1/S3 | 40/60 | W-1 | 0.05 | 4.0 | G-1 | Non |
| Ex. 84 | P-14 | 97.95 | Non | | Non | | TBAH | 2 | S1/S2 | 40/60 | W-1 | 0.05 | 4.0 | G-1 | G-5 |
| Ex. 85 | P-16 | 97.95 | Non | | Non | | TBAH | 2 | S1/S2 | 40/60 | W-4 | 0.05 | 4.0 | G-3 | Non |
| Ex. 86 | P-17 | 87.95 | HR-2 | 10 | Non | | TBAB | 2 | S1/S2 | 40/60 | W-2 | 0.05 | 4.0 | G-1 | Non |
| Ex. 87 | P-20 | 97.95 | Non | | Non | | TBAB | 2 | S1/S2 | 40/60 | W-1 | 0.05 | 4.0 | G-1 | Non |
| Ex. 88 | P-21 | 97.95 | Non | | Non | | TBAH | 2 | S1/S2 | 40/60 | W-2 | 0.05 | 4.0 | G-1 | G-5 |
| Ex. 89 | P-22 | 92.95 | HR-4 | 5 | Non | | TPI | 2 | S1/S2 | 40/60 | W-3 | 0.05 | 4.0 | G-2 | Non |
| Ex. 90 | P-23 | 95 | HR-3 | 3 | Non | | TBAB | 2 | S1/S2 | 40/60 | Non | | 4.0 | G-4 | G-5 |
| Comp. | R-1 | 77.95 | Non | | PAG-2 | 20 | TBAH | 2 | S1/S2 | 40/60 | W-1 | 0.05 | 4.0 | G-1 | Non |
| Ex. 10 | | | | | | | | | | | | | | | |
| Comp. | R-2 | 97.95 | Non | | Non | | TBAH | 2 | S1/S2 | 40/60 | W-2 | 0.05 | 4.0 | G-1 | G-5 |
| Ex. 11 | | | | | | | | | | | | | | | |
| Comp. | R-3 | 97.95 | Non | | Non | | TPI | 2 | S1/S2 | 40/60 | W-1 | 0.05 | 4.0 | G-2 | Non |
| Ex. 12 | | | | | | | | | | | | | | | |

| | | Resolving | | | | Outgassing |
|---|---|---|---|---|---|---|
| | Sensitivity | power | Pattern | LER | EL | performance |
| | (mJ/cm²) | (nm) | shape | (nm) | (%) | (%) |
| Ex. 77 | 28.0 | 65 | Rectangle | 6.2 | A | 3.1 |
| Ex. 78 | 28.3 | 70 | Rectangle | 6.4 | A | 2.5 |
| Ex. 79 | 32.5 | 75 | Rectangle | 6.9 | A | 3.5 |
| Ex. 80 | 30.5 | 70 | Rectangle | 6.0 | A | 4.2 |
| Ex. 81 | 28.5 | 60 | Rectangle | 6.8 | A | 2.2 |
| Ex. 82 | 29.0 | 70 | Rectangle | 5.9 | A | 4.6 |
| Ex. 83 | 29.3 | 70 | Rectangle | 6.2 | A | 4.2 |
| Ex. 84 | 28.5 | 70 | Rectangle | 5.5 | A | 3.8 |
| Ex. 85 | 30.1 | 75 | Rectangle | 5.8 | A | 4.8 |
| Ex. 86 | 28.1 | 60 | Rectangle | 6.0 | A | 2.8 |
| Ex. 87 | 27.5 | 65 | Rectangle | 5.8 | A | 2.9 |
| Ex. 88 | 27.8 | 65 | Rectangle | 5.9 | A | 3.5 |
| Ex. 89 | 28.0 | 60 | Rectangle | 6.5 | A | 2.1 |
| Ex. 90 | 28.5 | 70 | Rectangle | 7.0 | A | 2.5 |
| Comp. | Not resolved | | | | | |
| Ex. 10 | | | | | | |
| Comp. | 35.0 | 85 | Inverse | 8.5 | B | 6.5 |
| Ex. 11 | | | taper | | | |
| Comp. | 40.0 | 80 | Inverse | 8.8 | B | 7.0 |
| Ex. 12 | | | taper | | | |

* The conc. of each component is conc. (mass %) based on the amount of total solids.

It is apparent from the results listed in the above Tables that the actinic-ray- or radiation-sensitive resin compositions of the present invention can simultaneously satisfy high sensitivity, high resolution, favorable pattern shape, favorable line edge roughness, favorable exposure latitude and favorable outgassing performance upon exposure to EB/alkali development as compared with those of Comparative Example 1, Comparative Example 2 and Comparative Example 3 all not containing the repeating unit (A).

It is also apparent that the actinic-ray- or radiation-sensitive resin compositions of the present invention can simultaneously satisfy high sensitivity, high resolution, favorable pattern shape, favorable line edge roughness, favorable exposure latitude and favorable outgassing performance upon exposure to EUV/alkali development as compared with those of Comparative Example 4, Comparative Example 5 and Comparative Example 6 all not containing the repeating unit (A).

Further, it is apparent that the actinic-ray- or radiation-sensitive resin compositions of the present invention can simultaneously satisfy high sensitivity, high resolution, favorable pattern shape, favorable line edge roughness, favorable exposure latitude and favorable outgassing performance upon exposure to EB/organic solvent development as compared with those of Comparative Example 7, Comparative Example 8 and Comparative Example 9 all not containing the repeating unit (A).

Still further, it is apparent that the actinic-ray- or radiation-sensitive resin compositions of the present invention can simultaneously satisfy high sensitivity, high resolution, favorable pattern shape, favorable line edge roughness, favorable exposure latitude and favorable outgassing performance upon exposure to EUV/organic solvent development as compared with those of Comparative Example 10, Comparative Example 11 and Comparative Example 12 all not containing the repeating unit (A).

What is claimed is:

1. An actinic-ray- or radiation-sensitive resin composition comprising a resin (P) comprising any of repeating units (A) of general formula (I) below, each of which contains an ionic structural moiety that when exposed to actinic rays or radiation, is decomposed to thereby generate an acid in a side chain of the resin, 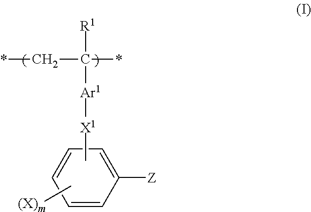
in which
R¹ represents a hydrogen atom, an alkyl group, a monovalent aliphatic hydrocarbon ring group, a halogen atom, a cyano group or an alkoxycarbonyl group;
Ar¹ represents a bivalent aromatic ring group;
X¹ represents a single bond, —O—, —S—, —C(═O)—, —S(═O)—, —S(═O)₂— or an optionally substituted methylene group;
X represents a substituent;
m is an integer of 0 to 4; and
Z represents a moiety that when exposed to actinic rays or radiation, is decomposed to thereby become a sulfonic acid group, an imidic acid group or a methide acid group.

2. The actinic-ray- or radiation-sensitive resin composition according to claim 1, wherein in general formula (I), m is an integer of 1 to 4, and at least one substituent represented by X is an F atom or a fluoroalkyl group.

3. The actinic-ray- or radiation-sensitive resin composition according to claim 1, wherein in general formula (I), X¹ is —O—.

4. The actinic-ray- or radiation-sensitive resin composition according to claim 1, wherein the resin (P) further comprises a repeating unit (B) containing a group that when acted on by an acid, is decomposed to thereby produce a polar group.

5. The actinic-ray- or radiation-sensitive resin composition according to claim 4, wherein the resin (P) comprises at least any of repeating units of general formula (II) below as the repeating unit (B), 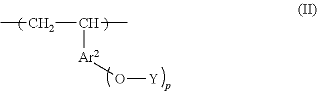
in which
Ar² represents a (p+1)-valent aromatic ring group;
Y represents a hydrogen atom or a group leaving when acted on by an acid, provided that when there are a plurality of Y's, the plurality of Y's may be identical to or different from each other, and that at least one Y is a group leaving when acted on by an acid; and
p is an integer of 1 or greater.

6. The actinic-ray- or radiation-sensitive resin composition according to claim 5, wherein in general formula (II), at least one group leaving when acted on by an acid, represented by Y is any of groups of general formula (V) below, 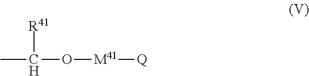
in which
R⁴¹ represents a hydrogen atom, an alkyl group, a cycloalkyl group, an aryl group or an aralkyl group;
M⁴¹ represents a single bond or a bivalent connecting group; and
Q represents an alkyl group, an alicyclic group optionally containing a heteroatom, or an aromatic ring group optionally containing a heteroatom,
provided that at least two of R⁴¹, M⁴¹ and Q may be bonded to each other to thereby form a ring.

7. The actinic-ray- or radiation-sensitive resin composition according to claim 4, wherein the resin (P) comprises at least any of repeating units of general formula (VI) below as the repeating unit (B), 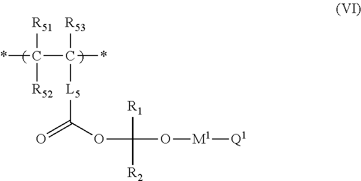
in which
each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group,
L₅ represents a single bond or a bivalent connecting group, provided that when a ring is formed in cooperation with R₅₂, L₅ represents a trivalent connecting group,
R₁ represents a hydrogen atom or an alkyl group,
R₂ represents a hydrogen atom, an alkyl group, a cycloalkyl group, an aryl group, an aralkyl group, an alkoxy group, an acyl group or a heterocyclic group,
M¹ represents a single bond or a bivalent connecting group, and
Q¹ represents an alkyl group, a cycloalkyl group, an aryl group or a heterocyclic group,
provided that at least two of Q¹, M¹ and R₂ may be bonded to each other through a single bond or a connecting group to thereby form a ring.

8. The actinic-ray- or radiation-sensitive resin composition according to claim 1 to be exposed to electron beams, X-rays or soft X-rays.

9. An actinic-ray- or radiation-sensitive film formed from the actinic-ray- or radiation-sensitive resin composition according to claim 1.

10. A method of forming a pattern, comprising exposing the actinic-ray- or radiation-sensitive film according to claim 9 to actinic rays or radiation and developing the exposed film.

11. The method according to claim 10, wherein the development is performed with a developer comprising an organic solvent to thereby form a negative pattern.

12. The method according to claim 10, wherein the exposure is performed by use of electron beams, X-rays or soft X-rays.

13. A process for manufacturing a semiconductor device, comprising the method according to claim 10.

14. A semiconductor device manufactured by the process according to claim 13.
